(19) United States
(12) Patent Application Publication
(10) Pub. No.: US 2022/0302392 A1
(43) Pub. Date: Sep. 22, 2022

(54) ORGANIC LIGHT EMITTING DEVICE

(71) Applicant: LG CHEM, LTD., Seoul (KR)

(72) Inventors: Jaegoo Lee, Daejeon (KR); Yongbum Cha, Daejeon (KR); Dong Uk Heo, Daejeon (KR); Woochul Lee, Daejeon (KR); Dongkeun Song, Daejeon (KR); Jiyoung Noh, Daejeon (KR)

(21) Appl. No.: 17/630,095

(22) PCT Filed: Oct. 29, 2020
(86) PCT No.: PCT/KR2020/014920

§ 371 Date: Jan. 25, 2022

(30) Foreign Application Priority Data
Nov. 5, 2019 (KR) 10-2019-0140357
Oct. 28, 2020 (KR) 10-2020-0140797

(51) Int. Cl. H01L 51/00

(52) U.S. Cl. CPC H01L 51/0072; H01L 51/006; H01L 51/0061; H01L 51/0058; H01L 51/0073; H01L 51/0067; H01L 51/5012

(57) ABSTRACT

The present disclosure relates to an organic light emitting device having improved driving voltage, efficiency and lifetime.

### CROSS-REFERENCE TO RELATED APPLICATION(S)

This application is a National Stage Application of International Application No. PCT/KR2020/014920, filed on Oct. 29, 2020, which claims priority to Korean Patent Application No. 10-2019-0140357 filed on Nov. 5, 2019 and Korean Patent Application No. 10-2020-0140797 filed on Oct. 28, 2020, the disclosures of which are incorporated herein by reference in their entirety.

### FIELD OF DISCLOSURE

The present disclosure relates to an organic light emitting device having improved driving voltage, efficiency and lifetime.

### BACKGROUND

In general, an organic light emitting phenomenon refers to a phenomenon where electric energy is converted into light energy by using an organic material. The organic light emitting device using the organic light emitting phenomenon has characteristics such as a wide viewing angle, an excellent contrast, a fast response time, an excellent luminance, driving voltage and response speed, and thus many studies have proceeded.

The organic light emitting device generally has a structure which comprises an anode, a cathode, and an organic material layer interposed between the anode and the cathode. The organic material layer frequently has a multilayered structure that comprises different materials in order to enhance efficiency and stability of the organic light emitting device, and for example, the organic material layer may be formed of a hole injection layer, a hole transport layer, a light emitting layer, an electron transport layer, an electron injection layer and the like. In the structure of the organic light emitting device, if a voltage is applied between two electrodes, the holes are injected from an anode into the organic material layer and the electrons are injected from the cathode into the organic material layer, and when the injected holes and electrons meet each other, an exciton is formed, and light is emitted when the exciton falls to a ground state again.

In the organic light emitting devices as described above, there is a continuing need for the development of an organic light emitting device having improved driving voltage, efficiency and lifetime.

### RELATED ARTS

(Patent Literature 1) Korean Unexamined Patent Publication No. 10-2000-0051826

### SUMMARY

The present disclosure relates to an organic light emitting device having improved driving voltage, efficiency and lifetime.

The present disclosure provides the following organic light emitting device:

An organic light emitting device comprising:

an anode,

a hole transport layer,

an electronic blocking layer,

a light emitting layer,

an electron transport layer, and

a cathode,

wherein the electron blocking layer comprises a compound represented by the following Chemical Formula 1,

wherein the light emitting layer comprises a compound represented by the following Chemical Formula 2, and

wherein the electron transport layer comprises a compound represented by the following Chemical Formula 3:

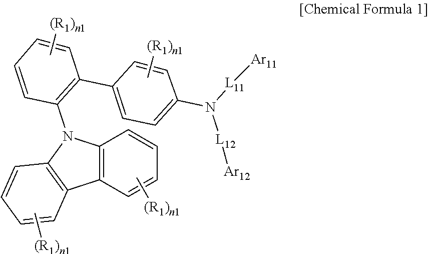

in Chemical Formula 1,

L₁₁ and L₁₂ are each independently a single bond; or a substituted or unsubstituted C₆₋₆₀ arylene,

Ar₁₁ and Ar₁₂ are each independently a substituted or unsubstituted C₆₋₆₀ aryl,

each R₁ is independently hydrogen or deuterium; or two adjacent radicals thereof are linked to form a C₆₋₆₀ aromatic ring,

each n1 is independently an integer of 1 to 4,

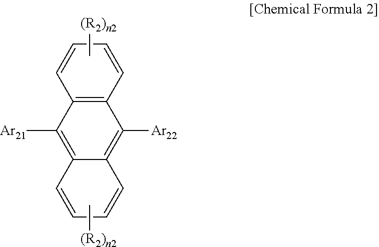

in Chemical Formula 2,

Ar₂₁ and Ar₂₂ are each independently a substituted or unsubstituted C₆₋₆₀ aryl; or a substituted or unsubstituted C₂₋₆₀ heteroaryl containing any one or more selected from the group consisting of N, O and S,

each R₂ is independently hydrogen; deuterium; or a substituted or unsubstituted C₆₋₆₀ aryl,

each n2 is independently an integer of 1 to 4,

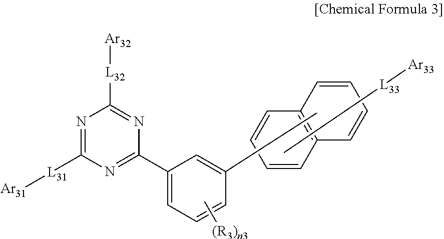

in Chemical Formula 3,

Ar₃₁ and Ar₃₂ are each independently a substituted or unsubstituted C₆₋₆₀ aryl; or a substituted or unsubstituted C₂₋₆₀ heteroaryl containing any one or more selected from the group consisting of N, O and S,

L₃₁ and L₃₂ are each independently a single bond; or a substituted or unsubstituted C₆₋₆₀ arylene,

Ar₃₃ is a substituted or unsubstituted C₆₋₆₀ aryl; or a substituted or unsubstituted C₂₋₆₀ heteroaryl containing any one or more selected from the group consisting of N, O and S,

L₃₃ is a single bond; or a substituted or unsubstituted C₆₋₆₀ arylene,

each R₃ is independently hydrogen, deuterium, or phenyl, and

n3 is an integer of 1 to 4.

### Advantageous Effects

The above-mentioned organic light emitting device has excellent driving voltage, efficiency and lifetime.

### BRIEF DESCRIPTION OF THE DRAWINGS

FIG. 1 shows an example of an organic light emitting device comprising a substrate 1, an anode 2, a hole transport layer 3, an electron blocking layer 4, a light emitting layer 5, an electron transport layer 6, and a cathode 7; and

FIG. 2 shows an example of an organic light emitting device comprising a substrate 1, an anode 2, a hole injection layer 8, a hole transport layer 3, an electron blocking layer 4, a light emitting layer 5, a hole blocking layer 9, an electron transport layer 6, and a cathode 7.

### DETAILED DESCRIPTION OF THE EMBODIMENTS

Hereinafter, embodiments of the present disclosure will be described in more detail to assist in the understanding of the invention.

As used herein, the notation

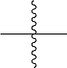

means a bond linked to another substituent group.

As used herein, the term “substituted or unsubstituted” means being unsubstituted or substituted with one or more substituents selected from the group consisting of deuterium; a halogen group; a nitrile group; a nitro group; a hydroxy group; a carbonyl group; an ester group; an imide group; an amino group; a phosphine oxide group; an alkoxy group; an aryloxy group; an alkylthioxy group; an arylthioxy group; an alkylsulfoxy group; an arylsulfoxy group; a silyl group; a boron group; an alkyl group; a cycloalkyl group; an alkenyl group; an aryl group; an aralkyl group; an aralkenyl group; an alkylaryl group; an alkylamine group; an aralkylamine group; a heteroarylamine group; an arylamine group; an arylphosphine group; or a heterocyclic group containing at least one of N, O and S atoms, or being unsubstituted or substituted with a substituent to which two or more substituents of the above-exemplified substituents are connected. For example, “a substituent in which two or more substituents are connected” may be a biphenyl group. Namely, a biphenyl group may be an aryl group, or it may also be interpreted as a substituent in which two phenyl groups are connected.

In the present disclosure, the carbon number of a carbonyl group is not particularly limited, but is preferably 1 to 40. Specifically, the carbonyl group may be a compound having the following structural formulas, but is not limited thereto.

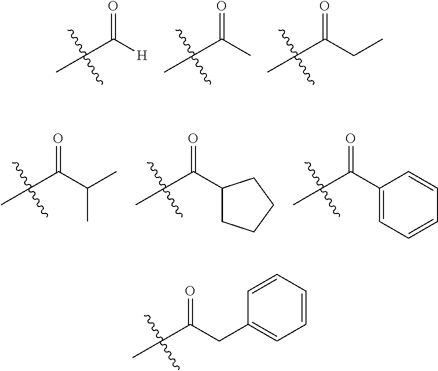

In the present disclosure, an ester group may have a structure in which oxygen of the ester group may be substituted by a straight-chain, branched, or cyclic alkyl group having 1 to 25 carbon atoms, or an aryl group having 6 to 25 carbon atoms. Specifically, the ester group may be a compound having the following structural formulas, but is not limited thereto.

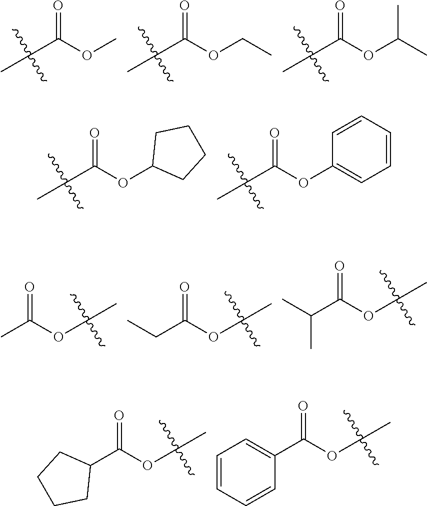

In the present disclosure, the carbon number of an imide group is not particularly limited, but is preferably 1 to 25. Specifically, the imide group may be a compound having the following structural formulas, but is not limited thereto.

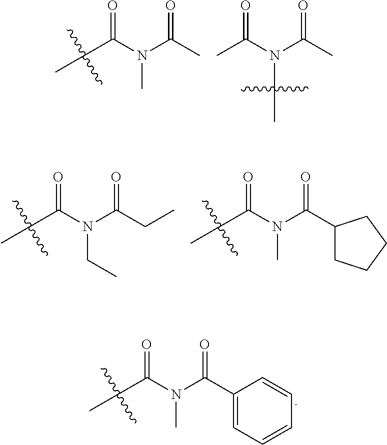

In the present disclosure, a silyl group specifically includes a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group and the like, but is not limited thereto.

In the present disclosure, a boron group specifically includes a trimethylboron group, a triethylboron group, a t-butyldimethylboron group, a triphenylboron group, and a phenylboron group, but is not limited thereto.

In the present disclosure, examples of a halogen group include fluorine, chlorine, bromine, or iodine.

In the present disclosure, the alkyl group may be straight-chain or branched-chain, and the carbon number thereof is not particularly limited, but is preferably 1 to 40. According to one embodiment, the carbon number of the alkyl group is 1 to 20. According to another embodiment, the carbon number of the alkyl group is 1 to 10. According to another embodiment, the carbon number of the alkyl group is 1 to 6. Specific examples of the alkyl group include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohectylmethyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, 5-methylhexyl, and the like, but are not limited thereto.

In the present disclosure, the alkenyl group may be straight-chain or branched-chain, and the carbon number thereof is not particularly limited, but is preferably 2 to 40. According to one embodiment, the carbon number of the alkenyl group is 2 to 20. According to another embodiment, the carbon number of the alkenyl group is 2 to 10. According to still another embodiment, the carbon number of the alkenyl group is 2 to 6. Specific examples thereof include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a stilbenyl group, a styrenyl group, and the like, but are not limited thereto.

In the present disclosure, a cycloalkyl group is not particularly limited, but the carbon number thereof is preferably 3 to 60. According to one embodiment, the carbon number of the cycloalkyl group is 3 to 30. According to another embodiment, the carbon number of the cycloalkyl group is 3 to 20. According to still another embodiment, the carbon number of the cycloalkyl group is 3 to 6. Specific examples thereof include cyclopropyl, cyclobutyl, cyclopentyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, cyclooctyl, and the like, but are not limited thereto.

In the present disclosure, an aryl group is not particularly limited, but the carbon number thereof is preferably 6 to 60, and it may be a monocyclic aryl group or a polycyclic aryl group. According to one embodiment, the carbon number of the aryl group is 6 to 30. According to one embodiment, the carbon number of the aryl group is 6 to 20. The aryl group may be a phenyl group, a biphenyl group, a terphenyl group or the like as the monocyclic aryl group, but is not limited thereto. The polycyclic aryl group includes a naphthyl group, an anthracenyl group, a phenanthryl group, a pyrenyl group, a perylenyl group, a chrysenyl group, a fluorenyl group, and the like, but is not limited thereto.

In the present disclosure, the fluorenyl group may be substituted, and two substituents may be linked with each other to form a spiro structure, in the case where the fluorenyl group is substituted,

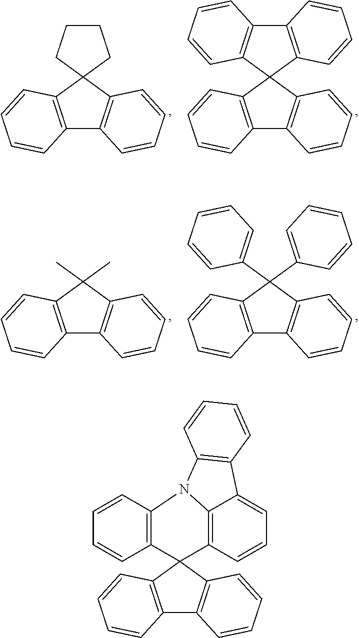

and the like can be formed. However, the structure is not limited thereto.

In the present disclosure, a heterocyclic group is a heterocyclic group containing one or more of O, N, Si and S as a heteroatom, and the carbon number thereof is not particularly limited, but is preferably 2 to 60. Examples of the heterocyclic group include a thiophene group, a furan group, a pyrrole group, an imidazole group, a thiazole group, an oxazol group, an oxadiazol group, a triazol group, a pyridyl group, a bipyridyl group, a pyrimidyl group, a triazine group, an acridyl group, a pyridazine group, a pyrazinyl group, a quinolinyl group, a quinazoline group, a quinoxalinyl group, a phthalazinyl group, a pyridopyrimidinyl group, a pyridopyrazinyl group, a pyrazinopyrazinyl group, an isoquinoline group, an indole group, a carbazole group, a benzoxazole group, a benzoimidazole group, a benzothiazol group, a benzocarbazole group, a benzothiophene group, a dibenzothiophene group, a benzofuranyl group, a phenanthroline group, an isoxazolyl group, a thiadiazolyl group, a phenothiazinyl group, a dibenzofuranyl group, and the like, but are not limited thereto.

In the present disclosure, the aryl group in the aralkyl group, the aralkenyl group, the alkylaryl group and the arylamine group is the same as the aforementioned examples of the aryl group. In the present disclosure, the alkyl group in the aralkyl group, the alkylaryl group and the alkylamine group is the same as the aforementioned examples of the alkyl group. In the present disclosure, the heteroaryl in the heteroarylamine can be applied to the aforementioned description of the heterocyclic group. In the present disclosure, the alkenyl group in the aralkenyl group is the same as the aforementioned examples of the alkenyl group. In the present disclosure, the aforementioned description of the aryl group may be applied except that the arylene is a divalent group. In the present disclosure, the aforementioned description of the heteroaryl group can be applied except that the heteroarylene is a divalent group. In the present disclosure, the aforementioned description of the aryl group or cycloalkyl group can be applied except that the hydrocarbon ring is not a monovalent group but formed by combining two substituent groups. In the present disclosure, the aforementioned description of the heterocyclic group can be applied, except that the heterocyclic group is not a monovalent group but formed by combining two substituent groups.

Hereinafter, the present disclosure will be described in detail for each configuration.

Anode and Cathode

The anode and cathode used in the present disclosure mean electrodes used in an organic light emitting device.

As the anode material, generally, a material having a large work function is preferably used so that holes can be smoothly injected into the organic material layer. Specific examples of the anode material include metals such as vanadium, chrome, copper, zinc, and gold, or an alloy thereof; metal oxides such as zinc oxides, indium oxides, indium tin oxides (ITO), and indium zinc oxides (IZO); a combination of metals and oxides, such as ZnO:Al or SNO₂:Sb, conductive polymers such as poly(3-methylthiophene), poly[3,4-(ethylene-1,2-dioxy)thiophene](PEDOT), polypyrrole, and polyaniline, and the like, but are not limited thereto.

As the cathode material, generally, a material having a small work function is preferably used so that electrons can be easily injected into the organic material layer. Specific examples of the cathode material include metals such as magnesium, calcium, sodium, potassium, titanium, indium, yttrium, lithium, gadolinium, aluminum, silver, tin, and lead, or an alloy thereof; a multilayered structure material such as LiF/Al or LiO₂/Al, and the like, but are not limited thereto.

Hole Injection Layer

The organic light emitting device according to the present disclosure may further include a hole injection layer between the anode and the hole transport layer, if necessary.

The hole injection layer is a layer injecting holes from an electrode, and the hole injection material is preferably a compound which has a capability of transporting the holes, has a hole injection effect in the anode and an excellent hole injection effect to the light emitting layer or the light emitting material, prevents movement of an exciton generated in the light emitting layer to the electron injection layer or the electron injection material, and is excellent in the ability to form a thin film. Further, it is preferable that a HOMO (highest occupied molecular orbital) of the hole injection material is between the work function of the anode material and a HOMO of a peripheral organic material layer.

Specific examples of the hole injection material include metal porphyrine, oligothiophene, an arylamine-based organic material, a hexanitrilehexaazatriphenylene-based organic material, a quinacridone-based organic material, a perylene-based organic material, anthraquinone, polyaniline and polythiophene-based conductive polymer, and the like, but are not limited thereto.

Hole Transport Layer

The organic light emitting device according to the present disclosure may further include a hole transport layer between the electron blocking layer and the anode.

The hole transport layer is a layer that receives holes from a hole injection layer and transports the holes to the light emitting layer. The hole transport material is suitably a material having large mobility to the holes, which may receive holes from the anode or the hole injection layer and transfer the holes to the light emitting layer.

Specific examples of the hole transport material include an arylamine-based organic material, a conductive polymer, a block copolymer in which a conjugate portion and a non-conjugate portion are present together, and the like, but are not limited thereto.

Electron Blocking Layer

The organic light emitting device according to the present disclosure includes an electron blocking layer between the hole transport layer and the light emitting layer. Preferably, the electron blocking layer comes into contact with the light emitting layer.

The electron blocking layer serves to suppress the electrons injected from the cathode from being transmitted toward the anode without being recombined in the light emitting layer, thereby improving the efficiency of the organic light emitting device. In the present disclosure, the compound represented by Chemical Formula 1 is used as a material constituting the electron blocking layer.

Preferably, the Chemical Formula 1 is represented by the following Chemical Formulas 1-1, 1-2, or 1-3:

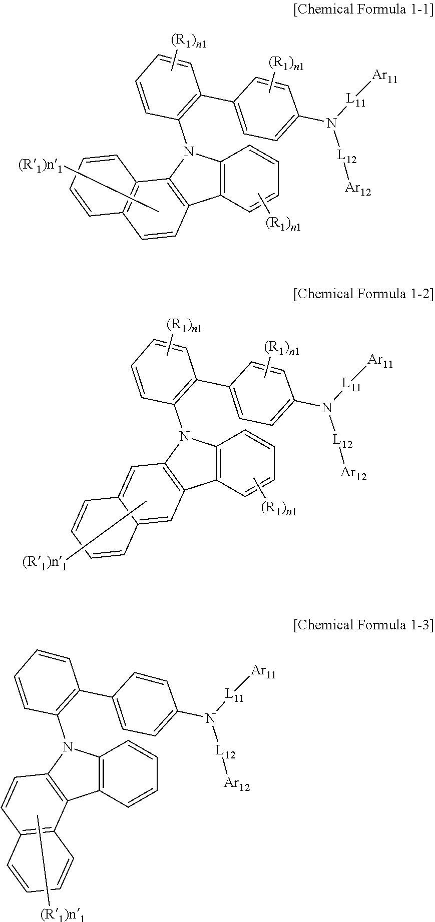

in Chemical Formulas 1-1, 1-2, or 1-3, the remaining substituents except for R′₁ and n′₁ are the same as defined in Chemical Formula 1 above, R′₁ is hydrogen or deuterium, and n′₁ is an integer of 1 to 6.

Preferably, L₁₁ and L₁₂ are each independently a single bond, phenylene, or dimethylfluorenylene.

Preferably, Ar₁₁ and Ar₁₂ are each independently phenyl, biphenylyl, terphenylyl, dimethylfluorenyl, diphenylfluorenyl, spirobifluorenyl, naphthyl, phenylnaphthyl, naphthylphenyl, anthracenyl, or triphenylenyl, with the Ar₁₁ and Ar₁₂ being each independently unsubstituted or substituted with a substituent selected from the group consisting of deuterium, halogen, cyano, and Si(C₁₋₄ alkyl)₃. In this case, being substituted with deuterium means that at least one of the substitutable hydrogens present in each substituent is substituted with deuterium.

Preferably, at least one of Ar₁₁ and Ar₁₂ is phenyl, biphenylyl, phenylnaphthyl or naphthylphenyl.

Representative examples of the compound represented by Chemical Formula 1 are as follows:

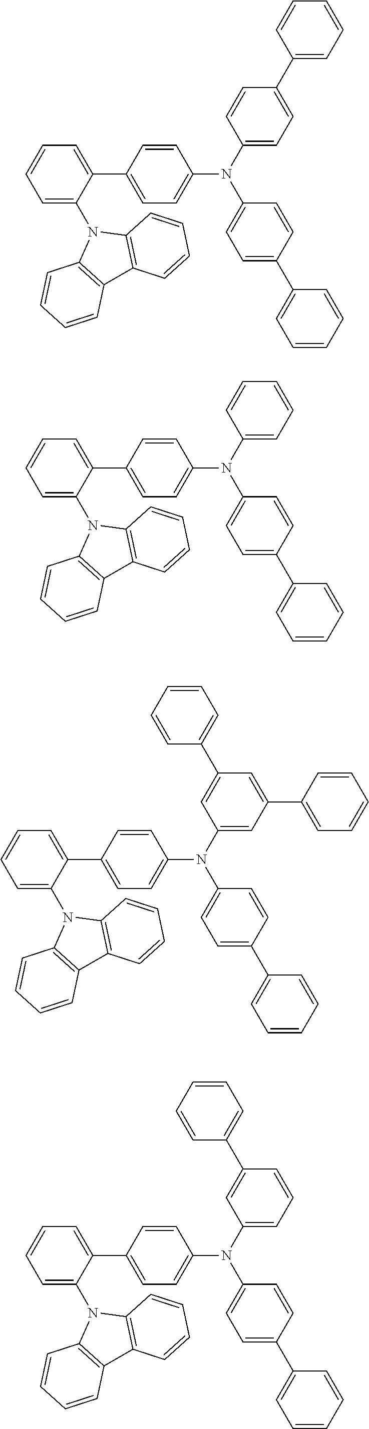

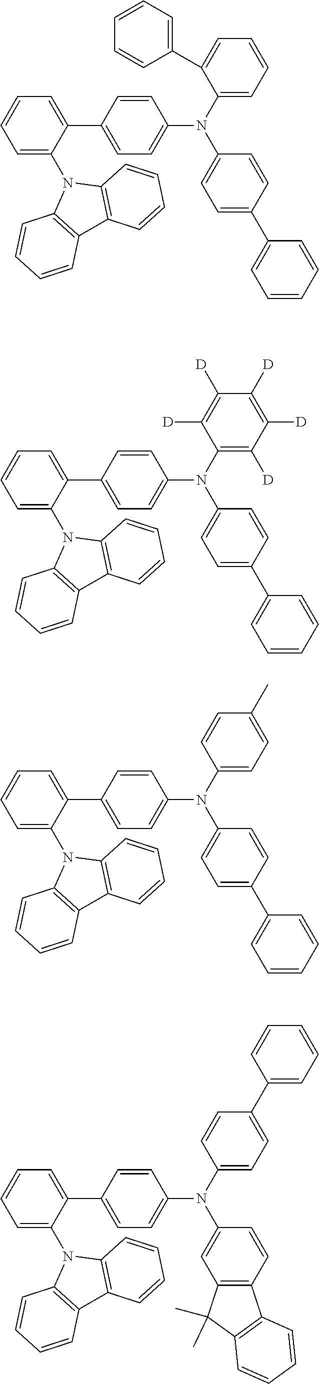

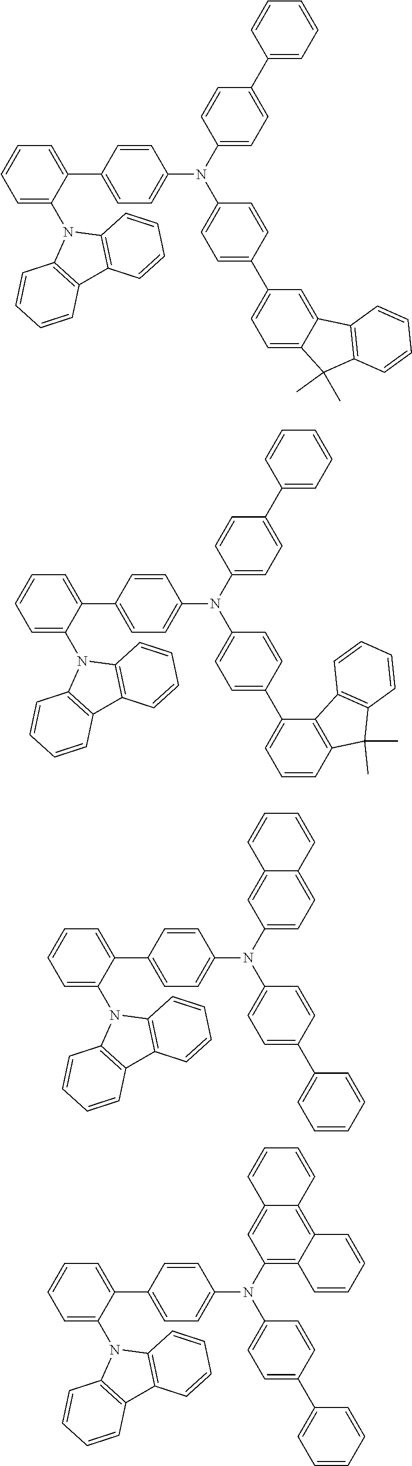

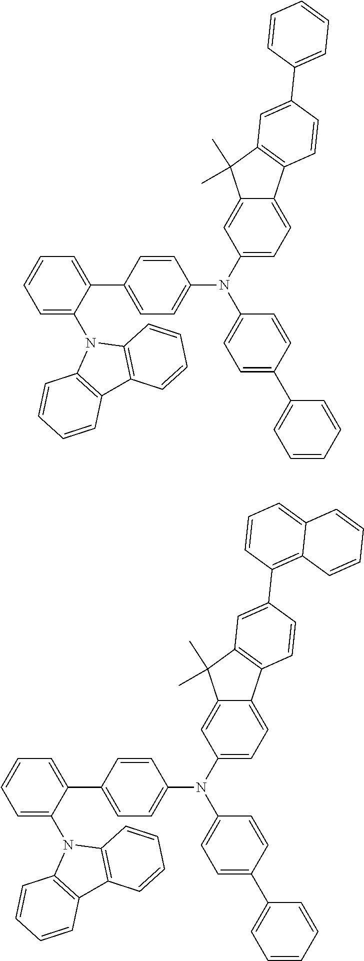

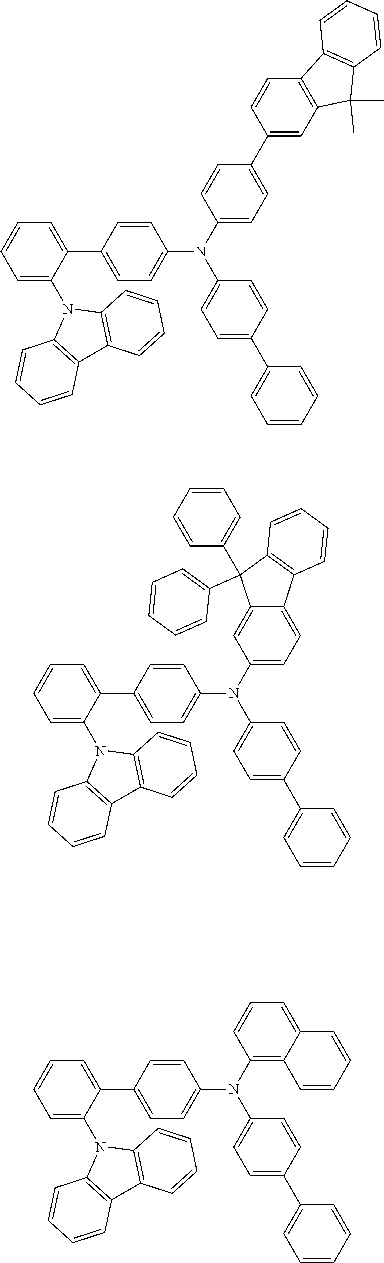 [SMILES: CC1(C)c2ccccc2-c2ccc(-c3ccc(N(c4ccc(-c5ccccc5)cc4)c4ccc(-c5ccccc5-n5c6ccccc6c6ccccc65)cc4)cc3)cc21 ; c1ccc(-c2ccc(N(c3ccc(-c4ccccc4-n4c5ccccc5c5ccccc54)cc3)c3ccc4c(c3)C(c3ccccc3)(c3ccccc3)c3ccccc3-4)cc2)cc1 ; c1ccc(-c2ccc(N(c3ccc(-c4ccccc4-n4c5ccccc5c5ccccc54)cc3)c3cccc4ccccc34)cc2)cc1]

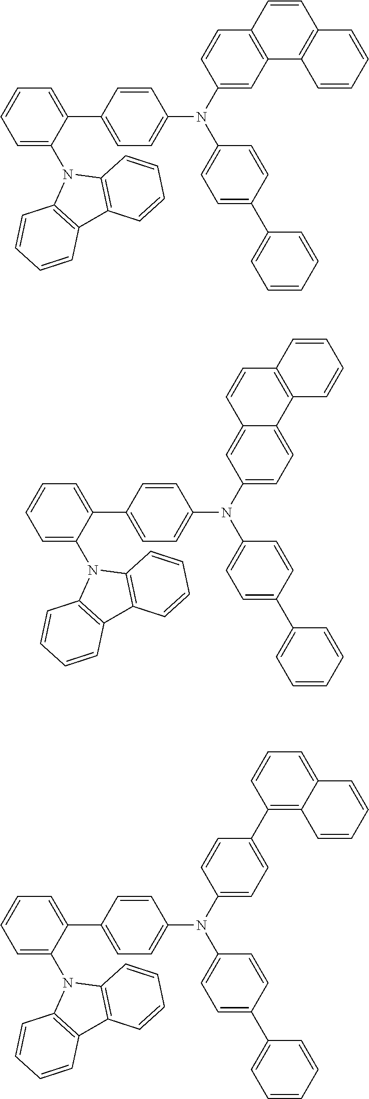 [SMILES: c1ccc(-c2ccc(N(c3ccc(-c4ccccc4-n4c5ccccc5c5ccccc54)cc3)c3ccc4ccc5ccccc5c4c3)cc2)cc1 ; c1ccc(-c2ccc(N(c3ccc(-c4ccccc4-n4c5ccccc5c5ccccc54)cc3)c3ccc4c(ccc5ccccc54)c3)cc2)cc1 ; c1ccc(-c2ccc(N(c3ccc(-c4ccccc4-n4c5ccccc5c5ccccc54)cc3)c3ccc(-c4cccc5ccccc45)cc3)cc2)cc1]

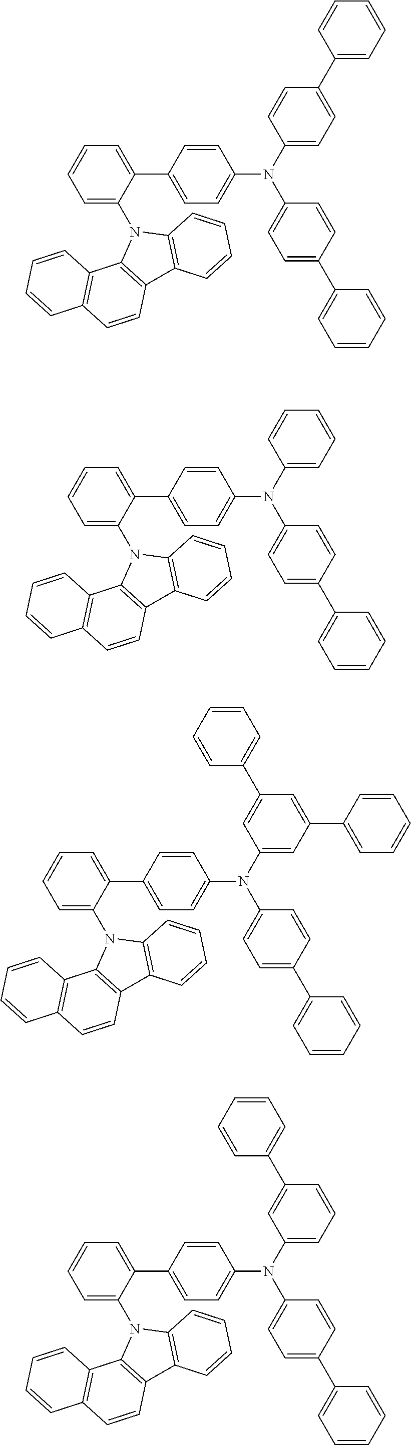 [SMILES: c1ccc(-c2ccc(N(c3ccc(-c4ccccc4)cc3)c3ccc(-c4ccccc4-n4c5ccccc5c5ccc6ccccc6c54)cc3)cc2)cc1 ; c1ccc(-c2ccc(N(c3ccccc3)c3ccc(-c4ccccc4-n4c5ccccc5c5ccc6ccccc6c54)cc3)cc2)cc1 ; c1ccc(-c2ccc(N(c3ccc(-c4ccccc4-n4c5ccccc5c5ccc6ccccc6c54)cc3)c3cc(-c4ccccc4)cc(-c4ccccc4)c3)cc2)cc1 ; c1ccc(-c2ccc(N(c3ccc(-c4ccccc4-n4c5ccccc5c5ccc6ccccc6c54)cc3)c3cccc(-c4ccccc4)c3)cc2)cc1]

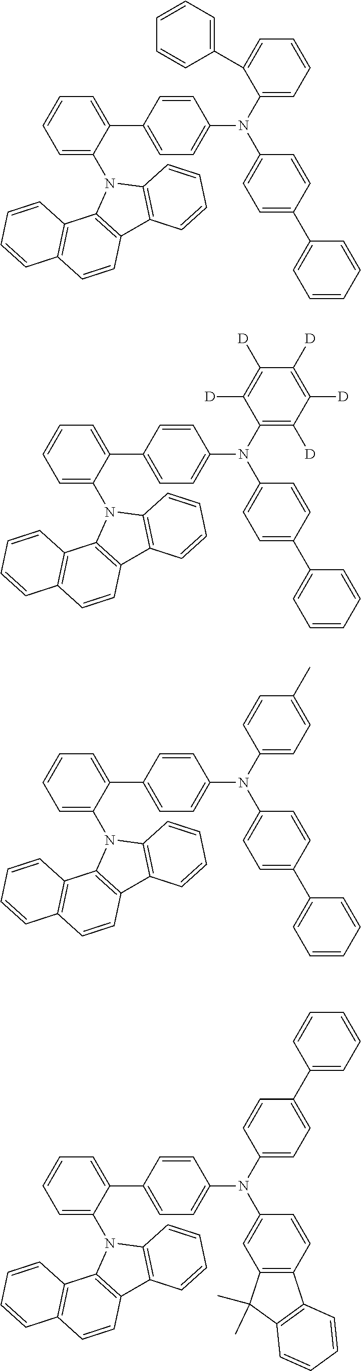

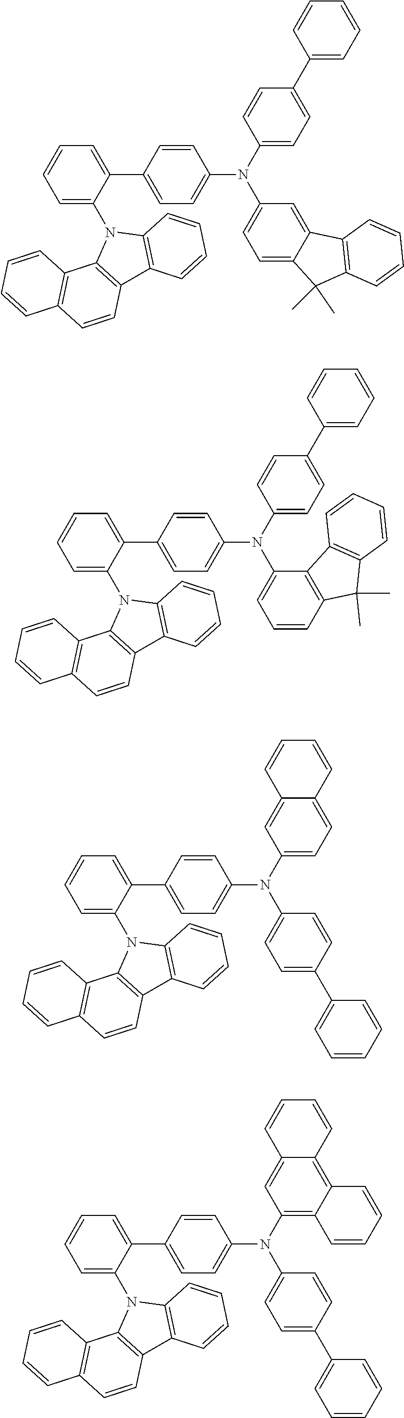

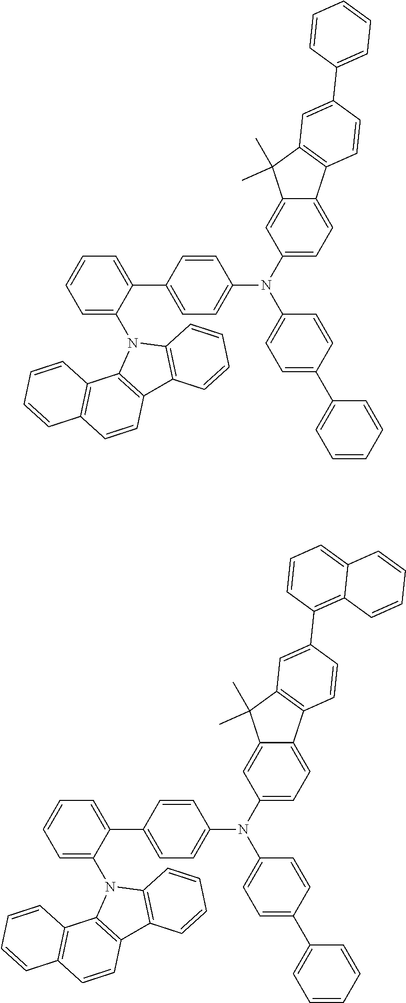 [SMILES: CC1(C)c2cc(-c3ccccc3)ccc2-c2ccc(N(c3ccc(-c4ccccc4)cc3)c3ccc(-c4ccccc4-n4c5ccccc5c5ccc6ccccc6c54)cc3)cc21 ; CC1(C)c2cc(-c3cccc4ccccc34)ccc2-c2ccc(N(c3ccc(-c4ccccc4)cc3)c3ccc(-c4ccccc4-n4c5ccccc5c5ccc6ccccc6c54)cc3)cc21]

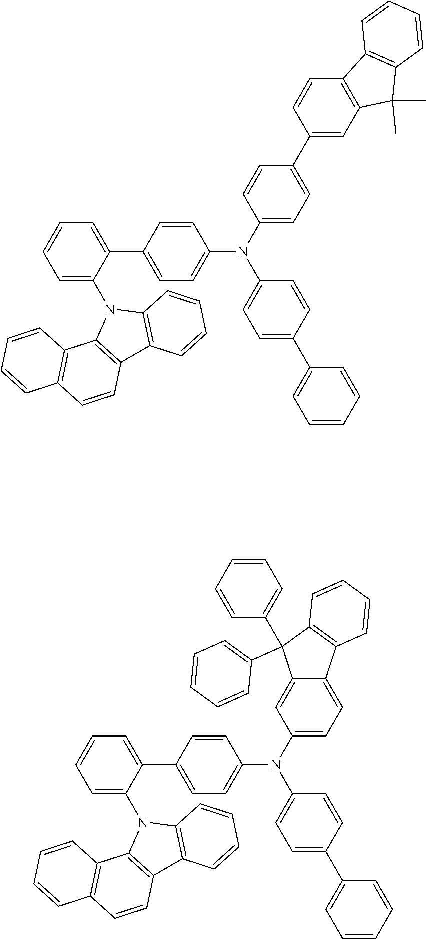 [SMILES: CC1(C)c2ccccc2-c2ccc(-c3ccc(N(c4ccc(-c5ccccc5)cc4)c4ccc(-c5ccccc5-n5c6ccccc6c6ccc7ccccc7c65)cc4)cc3)cc21 ; c1ccc(-c2ccc(N(c3ccc(-c4ccccc4-n4c5ccccc5c5ccc6ccccc6c54)cc3)c3ccc4c(c3)C(c3ccccc3)(c3ccccc3)c3ccccc3-4)cc2)cc1]

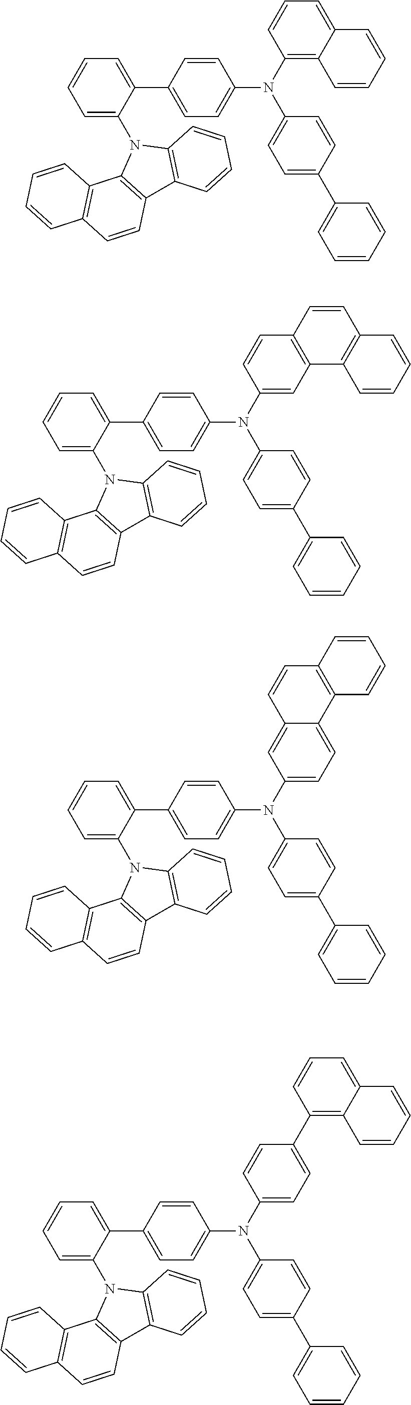

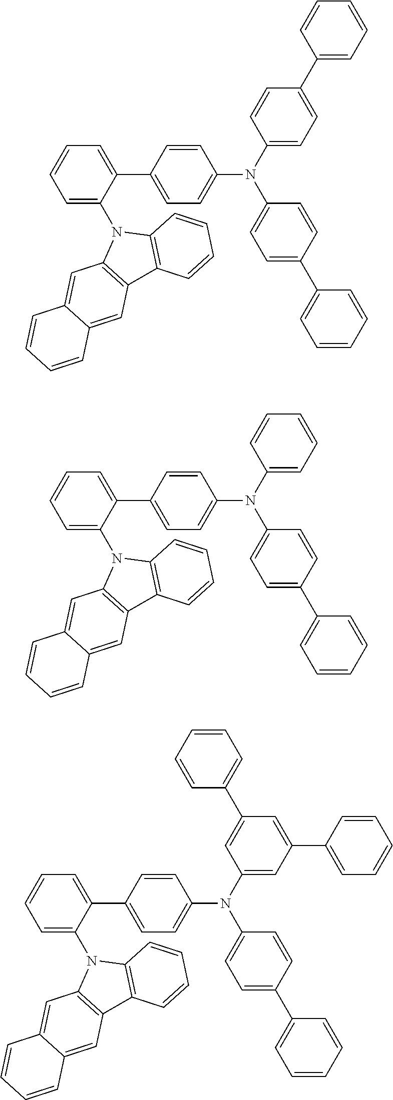 [SMILES: c1ccc(-c2ccc(N(c3ccc(-c4ccccc4)cc3)c3ccc(-c4ccccc4-n4c5ccccc5c5cc6ccccc6cc54)cc3)cc2)cc1 ; c1ccc(-c2ccc(N(c3ccccc3)c3ccc(-c4ccccc4-n4c5ccccc5c5cc6ccccc6cc54)cc3)cc2)cc1 ; c1ccc(-c2ccc(N(c3ccc(-c4ccccc4-n4c5ccccc5c5cc6ccccc6cc54)cc3)c3cc(-c4ccccc4)cc(-c4ccccc4)c3)cc2)cc1]

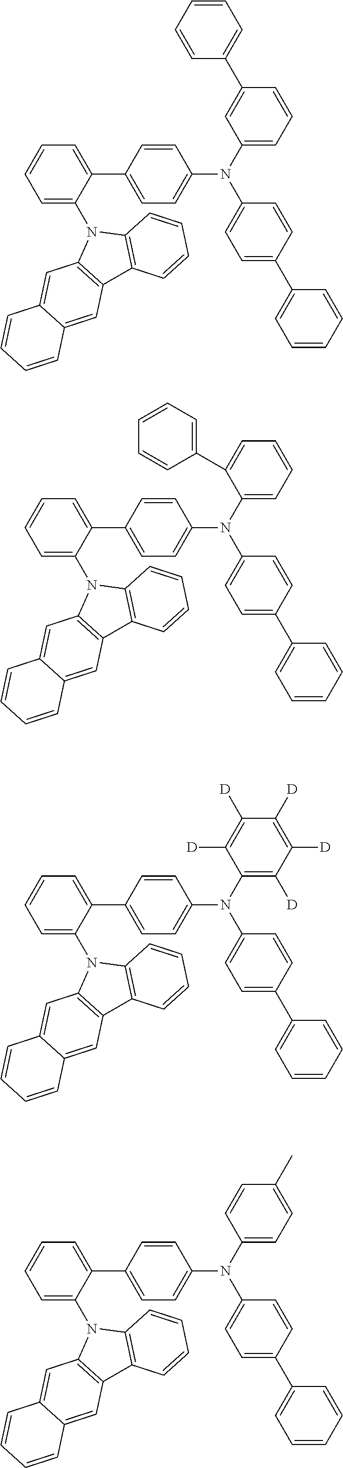 [SMILES: c1ccc(-c2ccc(N(c3ccc(-c4ccccc4-n4c5ccccc5c5cc6ccccc6cc54)cc3)c3cccc(-c4ccccc4)c3)cc2)cc1 ; c1ccc(-c2ccc(N(c3ccc(-c4ccccc4-n4c5ccccc5c5cc6ccccc6cc54)cc3)c3ccccc3-c3ccccc3)cc2)cc1 ; [2H]c1c([2H])c([2H])c(N(c2ccc(-c3ccccc3)cc2)c2ccc(-c3ccccc3-n3c4ccccc4c4cc5ccccc5cc43)cc2)c([2H])c1[2H] ; Cc1ccc(N(c2ccc(-c3ccccc3)cc2)c2ccc(-c3ccccc3-n3c4ccccc4c4cc5ccccc5cc43)cc2)cc1]

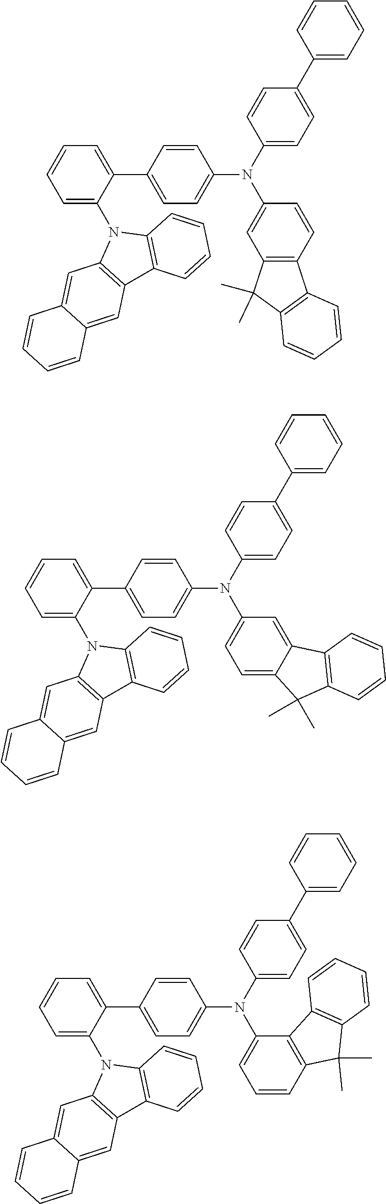 [SMILES: CC1(C)c2ccccc2-c2ccc(N(c3ccc(-c4ccccc4)cc3)c3ccc(-c4ccccc4-n4c5ccccc5c5cc6ccccc6cc54)cc3)cc21 ; CC1(C)c2ccccc2-c2cc(N(c3ccc(-c4ccccc4)cc3)c3ccc(-c4ccccc4-n4c5ccccc5c5cc6ccccc6cc54)cc3)ccc21 ; CC1(C)c2ccccc2-c2c(N(c3ccc(-c4ccccc4)cc3)c3ccc(-c4ccccc4-n4c5ccccc5c5cc6ccccc6cc54)cc3)cccc21]

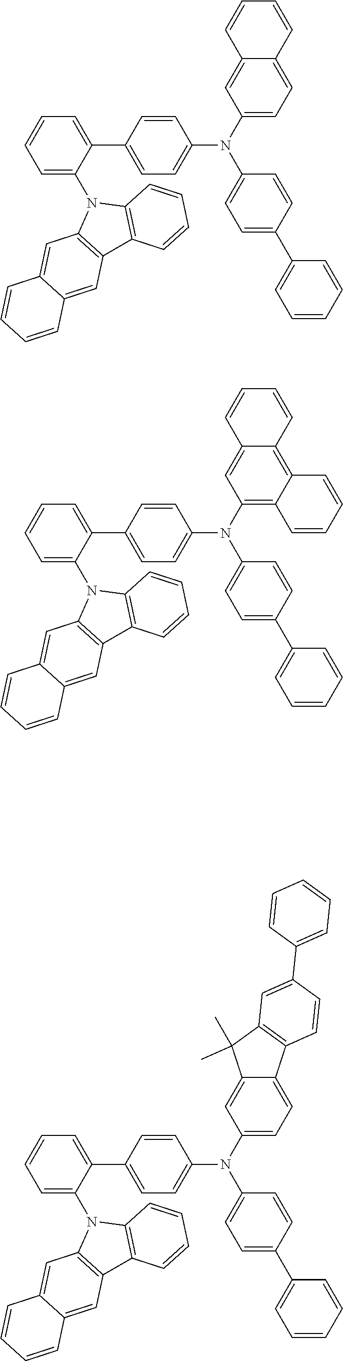 [SMILES: c1ccc(-c2ccc(N(c3ccc(-c4ccccc4-n4c5ccccc5c5cc6ccccc6cc54)cc3)c3ccc4ccccc4c3)cc2)cc1 ; c1ccc(-c2ccc(N(c3ccc(-c4ccccc4-n4c5ccccc5c5cc6ccccc6cc54)cc3)c3cc4ccccc4c4ccccc34)cc2)cc1 ; CC1(C)c2cc(-c3ccccc3)ccc2-c2ccc(N(c3ccc(-c4ccccc4)cc3)c3ccc(-c4ccccc4-n4c5ccccc5c5cc6ccccc6cc54)cc3)cc21]

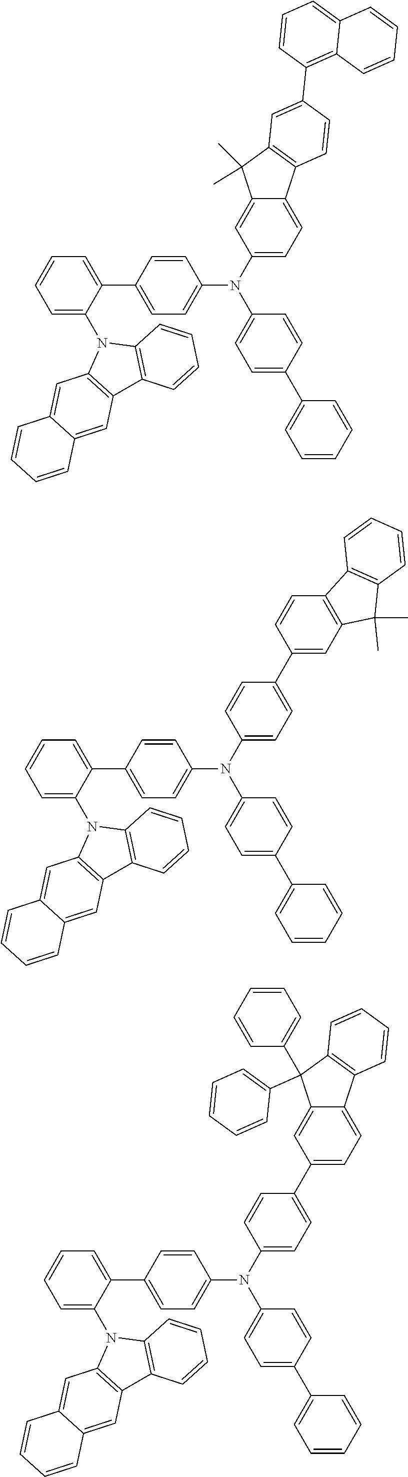 [SMILES: CC1(C)c2cc(-c3cccc4ccccc34)ccc2-c2ccc(N(c3ccc(-c4ccccc4)cc3)c3ccc(-c4ccccc4-n4c5ccccc5c5cc6ccccc6cc54)cc3)cc21 ; CC1(C)c2ccccc2-c2ccc(-c3ccc(N(c4ccc(-c5ccccc5)cc4)c4ccc(-c5ccccc5-n5c6ccccc6c6cc7ccccc7cc65)cc4)cc3)cc21 ; c1ccc(-c2ccc(N(c3ccc(-c4ccc5c(c4)C(c4ccccc4)(c4ccccc4)c4ccccc4-5)cc3)c3ccc(-c4ccccc4-n4c5ccccc5c5cc6ccccc6cc54)cc3)cc2)cc1]

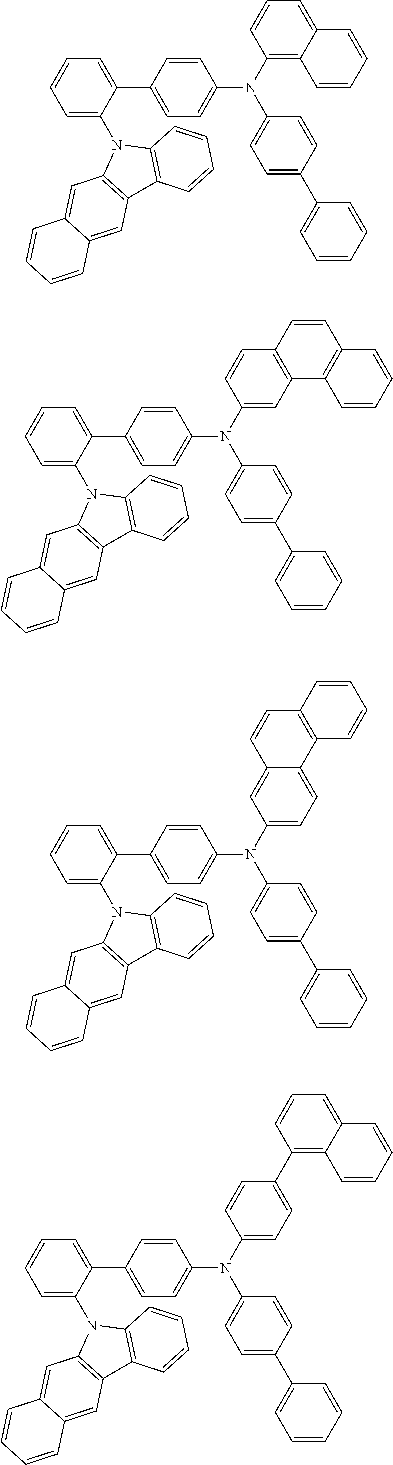 [SMILES: c1ccc(-c2ccc(N(c3ccc(-c4ccccc4-n4c5ccccc5c5cc6ccccc6cc54)cc3)c3cccc4ccccc34)cc2)cc1 ; c1ccc(-c2ccc(N(c3ccc(-c4ccccc4-n4c5ccccc5c5cc6ccccc6cc54)cc3)c3ccc4ccc5ccccc5c4c3)cc2)cc1 ; c1ccc(-c2ccc(N(c3ccc(-c4ccccc4-n4c5ccccc5c5cc6ccccc6cc54)cc3)c3ccc4c(ccc5ccccc54)c3)cc2)cc1 ; c1ccc(-c2ccc(N(c3ccc(-c4ccccc4-n4c5ccccc5c5cc6ccccc6cc54)cc3)c3ccc(-c4cccc5ccccc45)cc3)cc2)cc1]

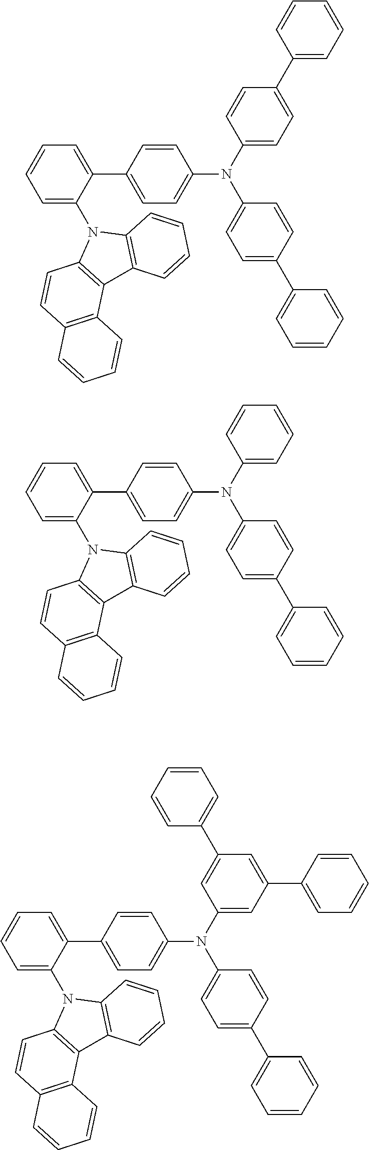 [SMILES: c1ccc(-c2ccc(N(c3ccc(-c4ccccc4)cc3)c3ccc(-c4ccccc4-n4c5ccccc5c5c6ccccc6ccc54)cc3)cc2)cc1 ; c1ccc(-c2ccc(N(c3ccccc3)c3ccc(-c4ccccc4-n4c5ccccc5c5c6ccccc6ccc54)cc3)cc2)cc1 ; c1ccc(-c2ccc(N(c3ccc(-c4ccccc4-n4c5ccccc5c5c6ccccc6ccc54)cc3)c3cc(-c4ccccc4)cc(-c4ccccc4)c3)cc2)cc1]

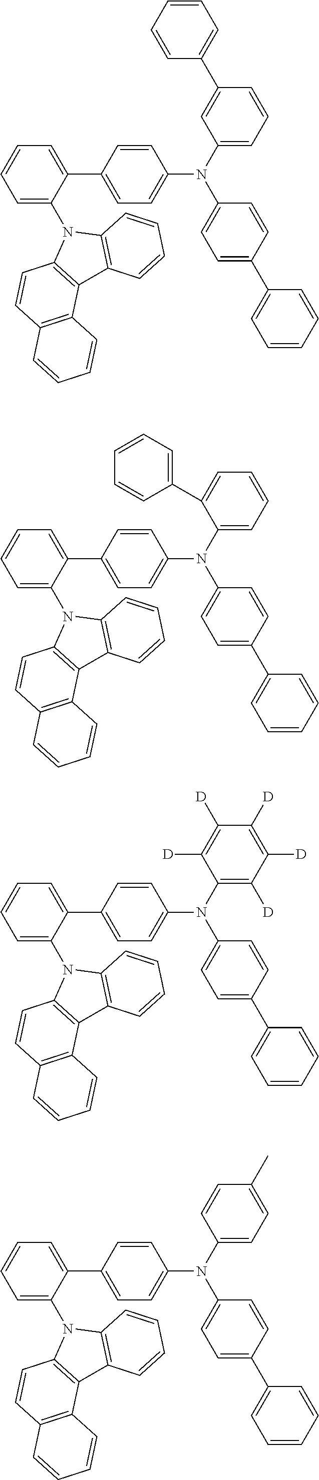 [SMILES: c1ccc(-c2ccc(N(c3ccc(-c4ccccc4-n4c5ccccc5c5c6ccccc6ccc54)cc3)c3cccc(-c4ccccc4)c3)cc2)cc1 ; c1ccc(-c2ccc(N(c3ccc(-c4ccccc4-n4c5ccccc5c5c6ccccc6ccc54)cc3)c3ccccc3-c3ccccc3)cc2)cc1 ; [2H]c1c([2H])c([2H])c(N(c2ccc(-c3ccccc3)cc2)c2ccc(-c3ccccc3-n3c4ccccc4c4c5ccccc5ccc43)cc2)c([2H])c1[2H] ; Cc1ccc(N(c2ccc(-c3ccccc3)cc2)c2ccc(-c3ccccc3-n3c4ccccc4c4c5ccccc5ccc43)cc2)cc1]

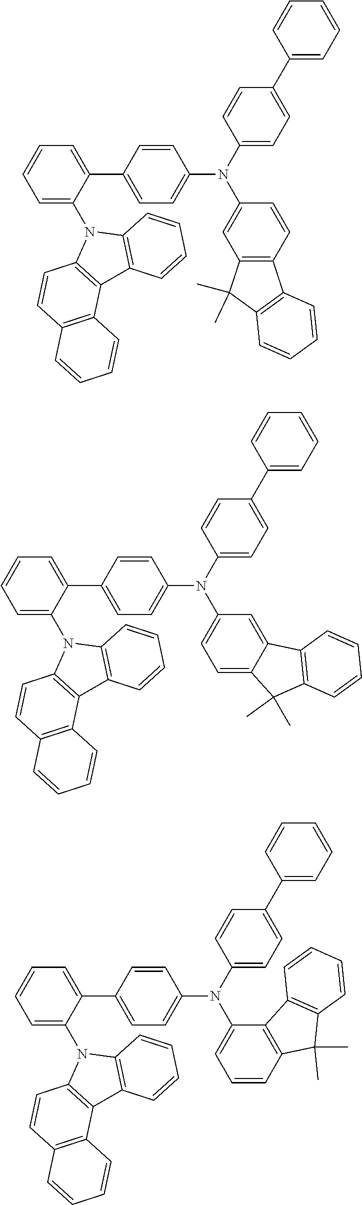 [SMILES: CC1(C)c2ccccc2-c2ccc(N(c3ccc(-c4ccccc4)cc3)c3ccc(-c4ccccc4-n4c5ccccc5c5c6ccccc6ccc54)cc3)cc21 ; CC1(C)c2ccccc2-c2cc(N(c3ccc(-c4ccccc4)cc3)c3ccc(-c4ccccc4-n4c5ccccc5c5c6ccccc6ccc54)cc3)ccc21 ; CC1(C)c2ccccc2-c2c(N(c3ccc(-c4ccccc4)cc3)c3ccc(-c4ccccc4-n4c5ccccc5c5c6ccccc6ccc54)cc3)cccc21]

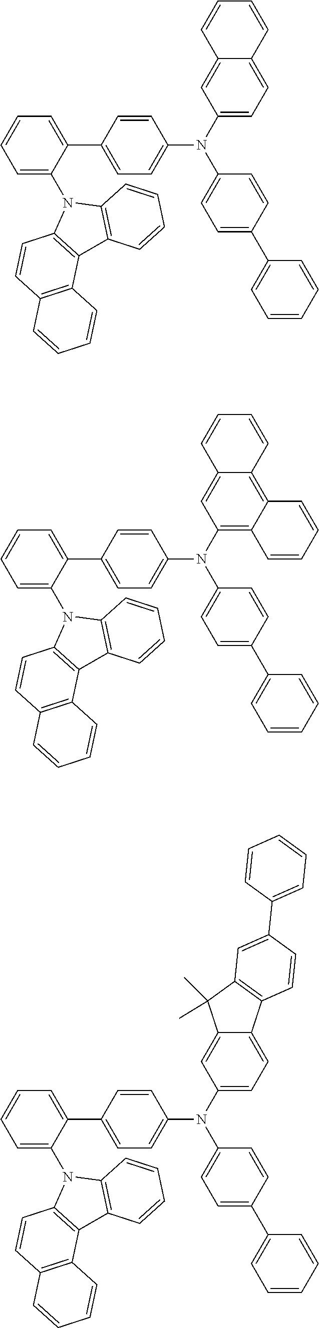 [SMILES: c1ccc(-c2ccc(N(c3ccc(-c4ccccc4-n4c5ccccc5c5c6ccccc6ccc54)cc3)c3ccc4ccccc4c3)cc2)cc1 ; c1ccc(-c2ccc(N(c3ccc(-c4ccccc4-n4c5ccccc5c5c6ccccc6ccc54)cc3)c3cc4ccccc4c4ccccc34)cc2)cc1 ; CC1(C)c2cc(-c3ccccc3)ccc2-c2ccc(N(c3ccc(-c4ccccc4)cc3)c3ccc(-c4ccccc4-n4c5ccccc5c5c6ccccc6ccc54)cc3)cc21]

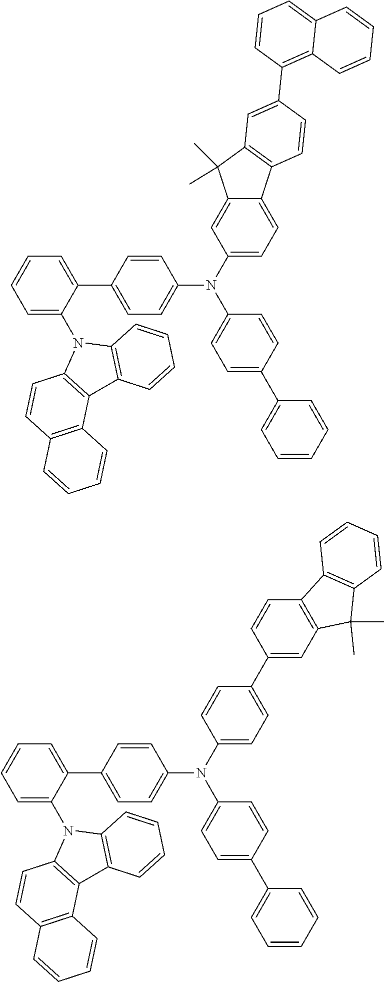 [SMILES: CC1(C)c2cc(-c3cccc4ccccc34)ccc2-c2ccc(N(c3ccc(-c4ccccc4)cc3)c3ccc(-c4ccccc4-n4c5ccccc5c5c6ccccc6ccc54)cc3)cc21 ; CC1(C)c2ccccc2-c2ccc(-c3ccc(N(c4ccc(-c5ccccc5)cc4)c4ccc(-c5ccccc5-n5c6ccccc6c6c7ccccc7ccc65)cc4)cc3)cc21]

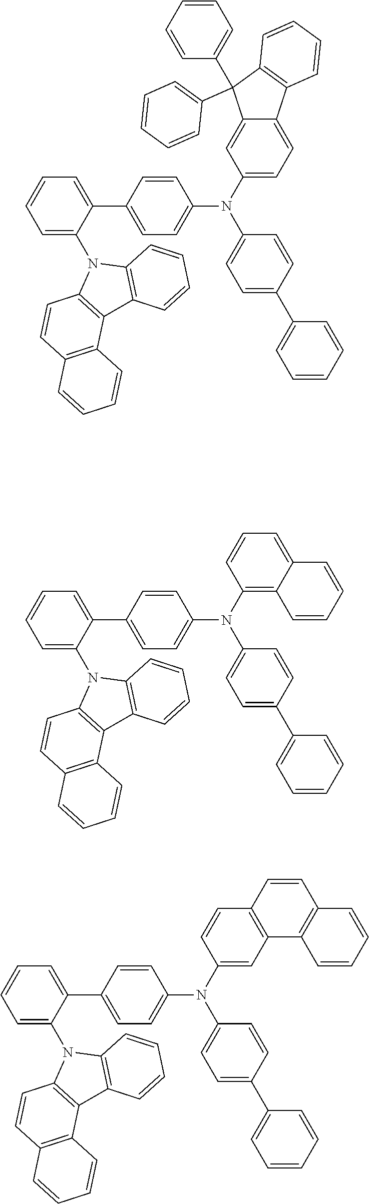 [SMILES: c1ccc(-c2ccc(N(c3ccc(-c4ccccc4-n4c5ccccc5c5c6ccccc6ccc54)cc3)c3ccc4c(c3)C(c3ccccc3)(c3ccccc3)c3ccccc3-4)cc2)cc1 ; c1ccc(-c2ccc(N(c3ccc(-c4ccccc4-n4c5ccccc5c5c6ccccc6ccc54)cc3)c3cccc4ccccc34)cc2)cc1 ; c1ccc(-c2ccc(N(c3ccc(-c4ccccc4-n4c5ccccc5c5c6ccccc6ccc54)cc3)c3ccc4ccc5ccccc5c4c3)cc2)cc1]

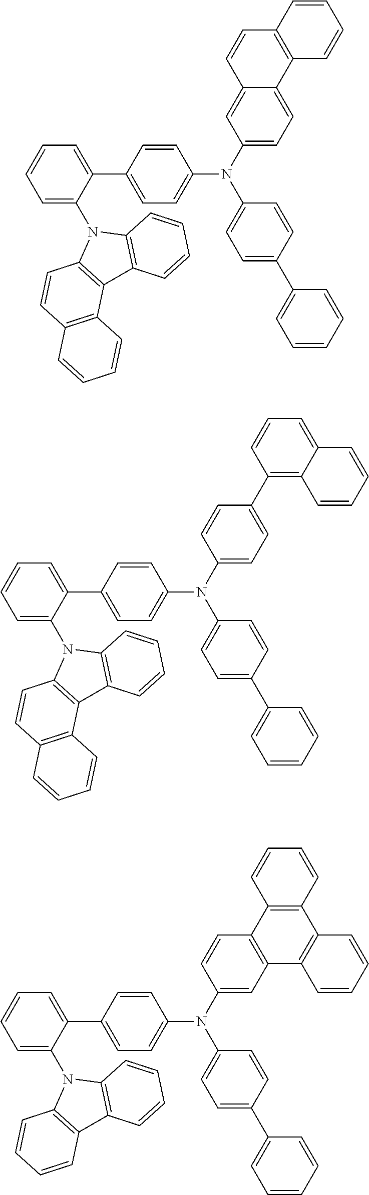 [SMILES: c1ccc(-c2ccc(N(c3ccc(-c4ccccc4-n4c5ccccc5c5c6ccccc6ccc54)cc3)c3ccc4c(ccc5ccccc54)c3)cc2)cc1 ; c1ccc(-c2ccc(N(c3ccc(-c4ccccc4-n4c5ccccc5c5c6ccccc6ccc54)cc3)c3ccc(-c4cccc5ccccc45)cc3)cc2)cc1 ; c1ccc(-c2ccc(N(c3ccc(-c4ccccc4-n4c5ccccc5c5ccccc54)cc3)c3ccc4c5ccccc5c5ccccc5c4c3)cc2)cc1]

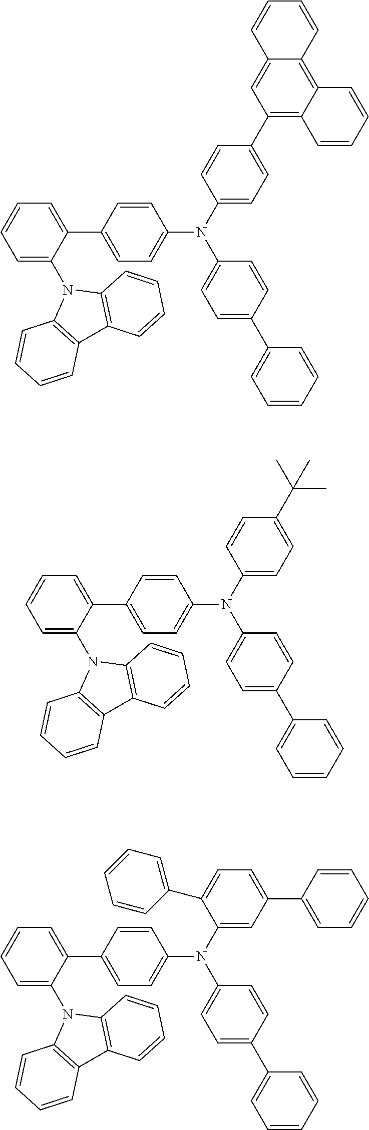 [SMILES: c1ccc(-c2ccc(N(c3ccc(-c4ccccc4-n4c5ccccc5c5ccccc54)cc3)c3ccc(-c4cc5ccccc5c5ccccc45)cc3)cc2)cc1 ; CC(C)(C)c1ccc(N(c2ccc(-c3ccccc3)cc2)c2ccc(-c3ccccc3-n3c4ccccc4c4ccccc43)cc2)cc1 ; c1ccc(-c2ccc(N(c3ccc(-c4ccccc4-n4c5ccccc5c5ccccc54)cc3)c3cc(-c4ccccc4)ccc3-c3ccccc3)cc2)cc1]

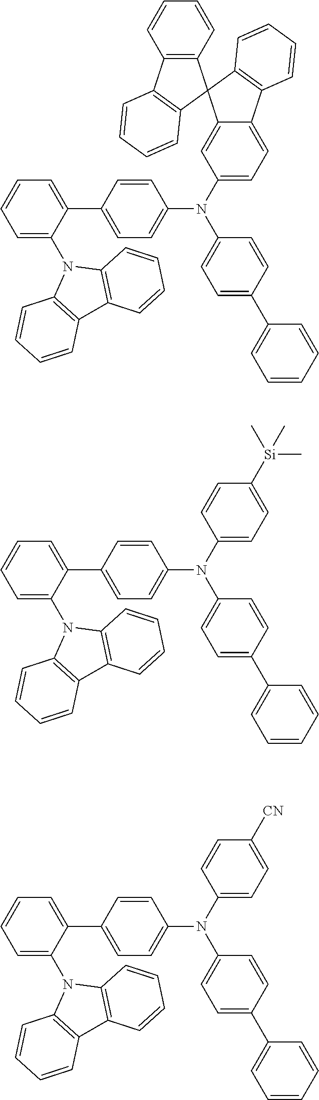

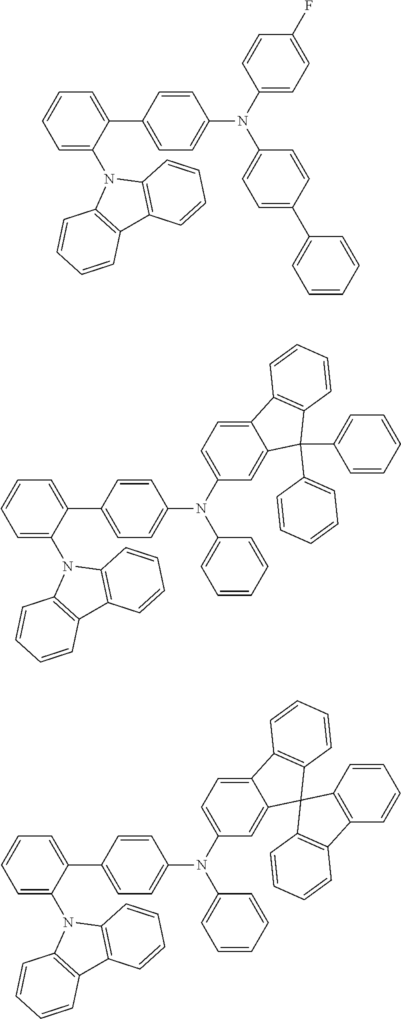 [SMILES: Fc1ccc(N(c2ccc(-c3ccccc3)cc2)c2ccc(-c3ccccc3-n3c4ccccc4c4ccccc43)cc2)cc1 ; c1ccc(N(c2ccc(-c3ccccc3-n3c4ccccc4c4ccccc43)cc2)c2ccc3c(c2)C(c2ccccc2)(c2ccccc2)c2ccccc2-3)cc1 ; c1ccc(N(c2ccc(-c3ccccc3-n3c4ccccc4c4ccccc43)cc2)c2ccc3c(c2)C2(c4ccccc4-c4ccccc42)c2ccccc2-3)cc1]

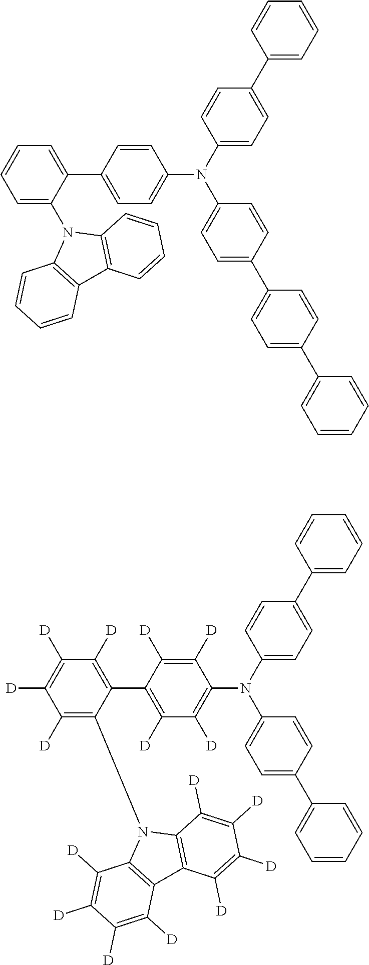 [SMILES: c1ccc(-c2ccc(-c3ccc(N(c4ccc(-c5ccccc5)cc4)c4ccc(-c5ccccc5-n5c6ccccc6c6ccccc65)cc4)cc3)cc2)cc1 ; [2H]c1c([2H])c([2H])c(-n2c3c([2H])c([2H])c([2H])c([2H])c3c3c([2H])c([2H])c([2H])c([2H])c32)c(-c2c([2H])c([2H])c(N(c3ccc(-c4ccccc4)cc3)c3ccc(-c4ccccc4)cc3)c([2H])c2[2H])c1[2H]]

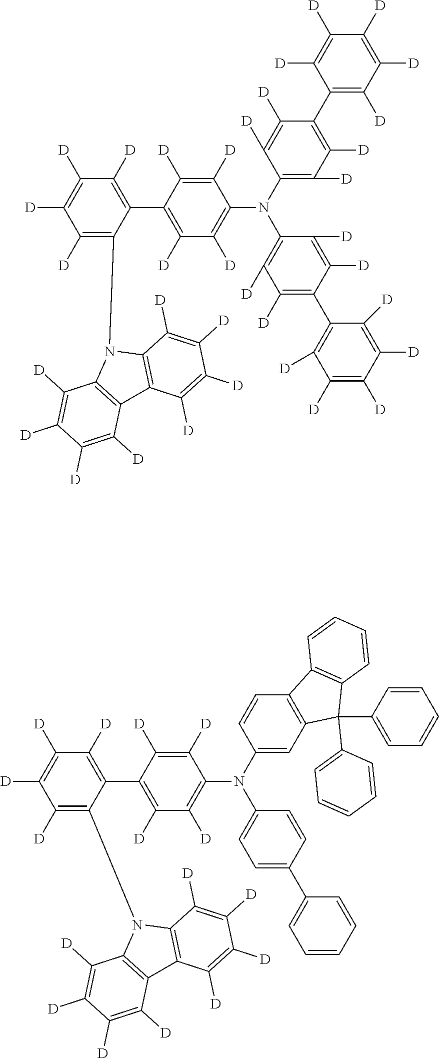 [SMILES: [2H]c1c([2H])c([2H])c(-c2c([2H])c([2H])c(N(c3c([2H])c([2H])c(-c4c([2H])c([2H])c([2H])c([2H])c4[2H])c([2H])c3[2H])c3c([2H])c([2H])c(-c4c([2H])c([2H])c([2H])c([2H])c4-n4c5c([2H])c([2H])c([2H])c([2H])c5c5c([2H])c([2H])c([2H])c([2H])c54)c([2H])c3[2H])c([2H])c2[2H])c([2H])c1[2H] ; [2H]c1c([2H])c([2H])c(-n2c3c([2H])c([2H])c([2H])c([2H])c3c3c([2H])c([2H])c([2H])c([2H])c32)c(-c2c([2H])c([2H])c(N(c3ccc(-c4ccccc4)cc3)c3ccc4c(c3)C(c3ccccc3)(c3ccccc3)c3ccccc3-4)c([2H])c2[2H])c1[2H]]

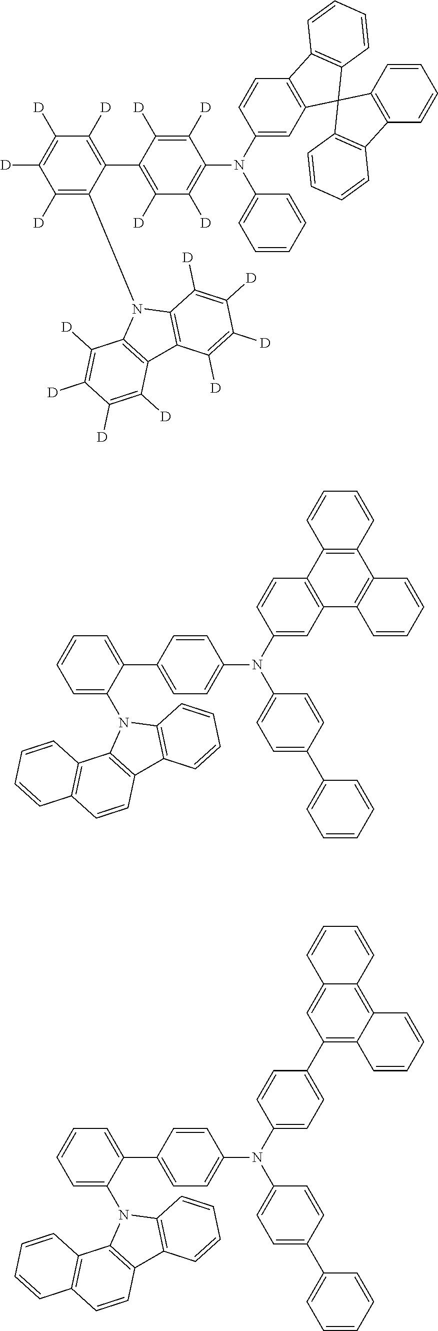 [SMILES: [2H]c1c([2H])c([2H])c(-n2c3c([2H])c([2H])c([2H])c([2H])c3c3c([2H])c([2H])c([2H])c([2H])c32)c(-c2c([2H])c([2H])c(N(c3ccccc3)c3ccc4c(c3)C3(c5ccccc5-c5ccccc53)c3ccccc3-4)c([2H])c2[2H])c1[2H] ; c1ccc(-c2ccc(N(c3ccc(-c4ccccc4-n4c5ccccc5c5ccc6ccccc6c54)cc3)c3ccc4c5ccccc5c5ccccc5c4c3)cc2)cc1 ; c1ccc(-c2ccc(N(c3ccc(-c4ccccc4-n4c5ccccc5c5ccc6ccccc6c54)cc3)c3ccc(-c4cc5ccccc5c5ccccc45)cc3)cc2)cc1]

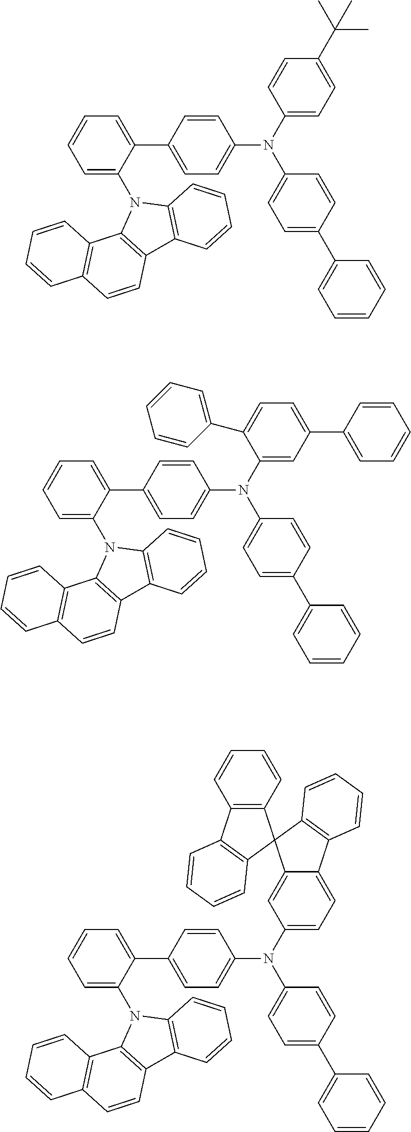 [SMILES: CC(C)(C)c1ccc(N(c2ccc(-c3ccccc3)cc2)c2ccc(-c3ccccc3-n3c4ccccc4c4ccc5ccccc5c43)cc2)cc1 ; c1ccc(-c2ccc(N(c3ccc(-c4ccccc4-n4c5ccccc5c5ccc6ccccc6c54)cc3)c3cc(-c4ccccc4)ccc3-c3ccccc3)cc2)cc1 ; c1ccc(-c2ccc(N(c3ccc(-c4ccccc4-n4c5ccccc5c5ccc6ccccc6c54)cc3)c3ccc4c(c3)C3(c5ccccc5-c5ccccc53)c3ccccc3-4)cc2)cc1]

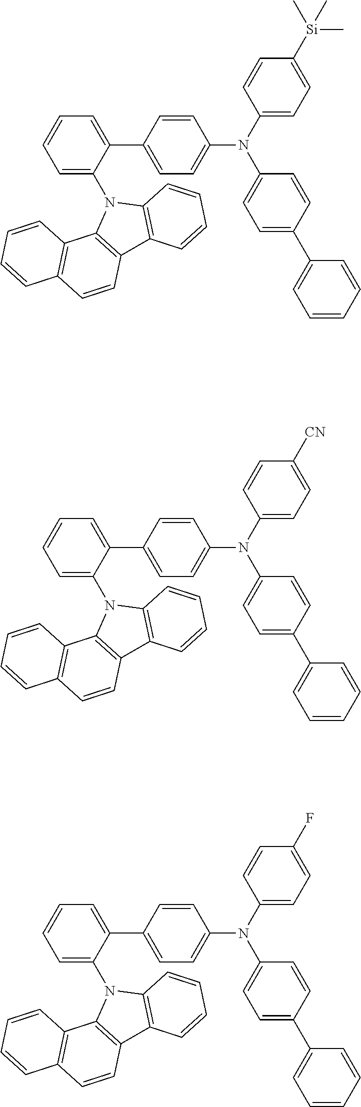 [SMILES: C[Si](C)(C)c1ccc(N(c2ccc(-c3ccccc3)cc2)c2ccc(-c3ccccc3-n3c4ccccc4c4ccc5ccccc5c43)cc2)cc1 ; N#Cc1ccc(N(c2ccc(-c3ccccc3)cc2)c2ccc(-c3ccccc3-n3c4ccccc4c4ccc5ccccc5c43)cc2)cc1 ; Fc1ccc(N(c2ccc(-c3ccccc3)cc2)c2ccc(-c3ccccc3-n3c4ccccc4c4ccc5ccccc5c43)cc2)cc1]

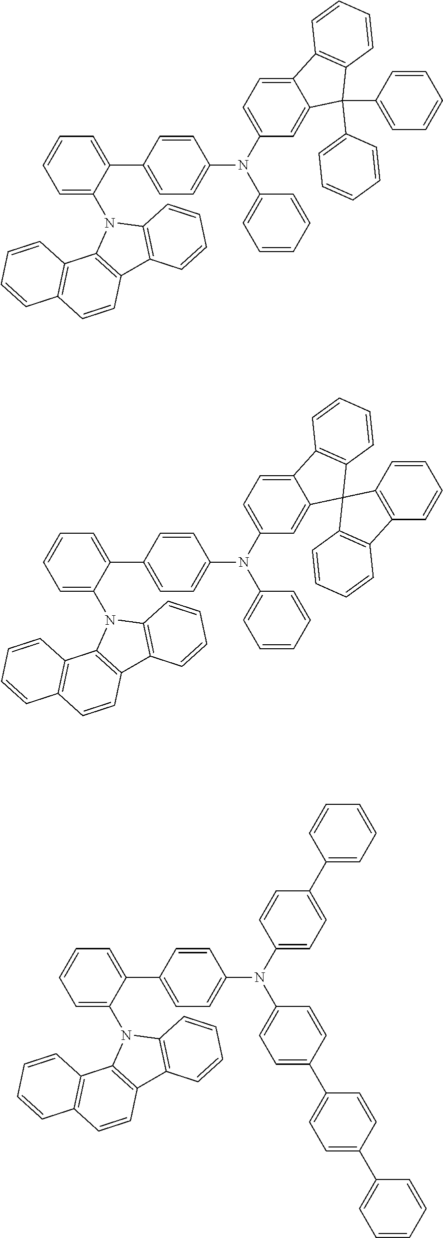 [SMILES: c1ccc(N(c2ccc(-c3ccccc3-n3c4ccccc4c4ccc5ccccc5c43)cc2)c2ccc3c(c2)C(c2ccccc2)(c2ccccc2)c2ccccc2-3)cc1 ; c1ccc(N(c2ccc(-c3ccccc3-n3c4ccccc4c4ccc5ccccc5c43)cc2)c2ccc3c(c2)C2(c4ccccc4-c4ccccc42)c2ccccc2-3)cc1 ; c1ccc(-c2ccc(-c3ccc(N(c4ccc(-c5ccccc5)cc4)c4ccc(-c5ccccc5-n5c6ccccc6c6ccc7ccccc7c65)cc4)cc3)cc2)cc1]

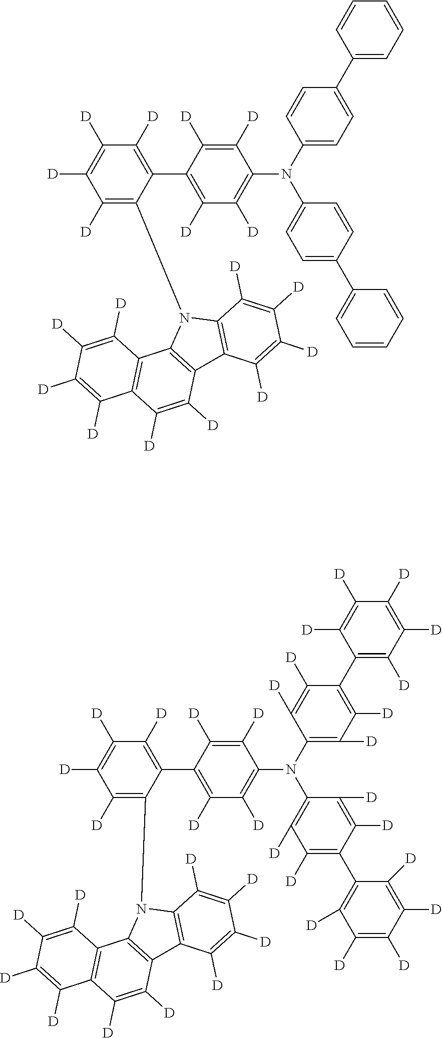 [SMILES: [2H]c1c([2H])c([2H])c(-n2c3c([2H])c([2H])c([2H])c([2H])c3c3c([2H])c([2H])c4c([2H])c([2H])c([2H])c([2H])c4c32)c(-c2c([2H])c([2H])c(N(c3ccc(-c4ccccc4)cc3)c3ccc(-c4ccccc4)cc3)c([2H])c2[2H])c1[2H] ; [2H]c1c([2H])c([2H])c(-c2c([2H])c([2H])c(N(c3c([2H])c([2H])c(-c4c([2H])c([2H])c([2H])c([2H])c4[2H])c([2H])c3[2H])c3c([2H])c([2H])c(-c4c([2H])c([2H])c([2H])c([2H])c4-n4c5c([2H])c([2H])c([2H])c([2H])c5c5c([2H])c([2H])c6c([2H])c([2H])c([2H])c([2H])c6c54)c([2H])c3[2H])c([2H])c2[2H])c([2H])c1[2H]]

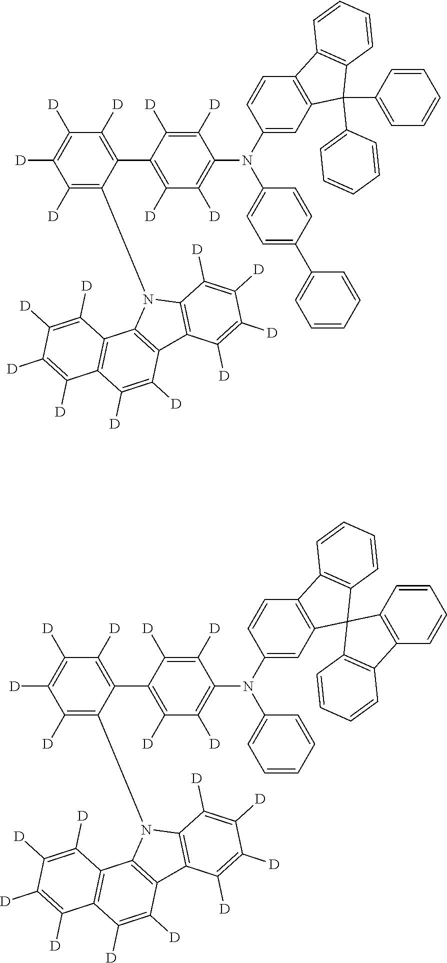 [SMILES: [2H]c1c([2H])c([2H])c(-n2c3c([2H])c([2H])c([2H])c([2H])c3c3c([2H])c([2H])c4c([2H])c([2H])c([2H])c([2H])c4c32)c(-c2c([2H])c([2H])c(N(c3ccc(-c4ccccc4)cc3)c3ccc4c(c3)C(c3ccccc3)(c3ccccc3)c3ccccc3-4)c([2H])c2[2H])c1[2H] ; [2H]c1c([2H])c([2H])c(-n2c3c([2H])c([2H])c([2H])c([2H])c3c3c([2H])c([2H])c4c([2H])c([2H])c([2H])c([2H])c4c32)c(-c2c([2H])c([2H])c(N(c3ccccc3)c3ccc4c(c3)C3(c5ccccc5-c5ccccc53)c3ccccc3-4)c([2H])c2[2H])c1[2H]]

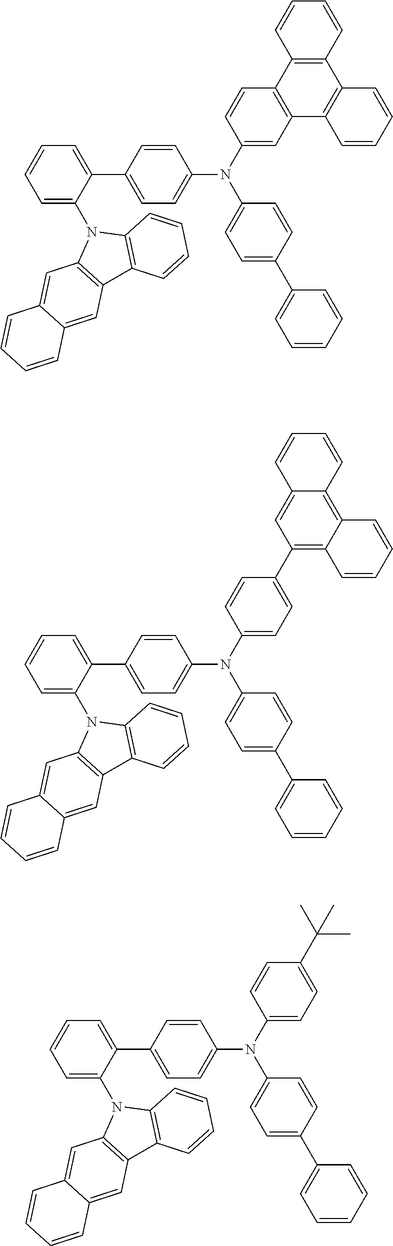 [SMILES: c1ccc(-c2ccc(N(c3ccc(-c4ccccc4-n4c5ccccc5c5cc6ccccc6cc54)cc3)c3ccc4c5ccccc5c5ccccc5c4c3)cc2)cc1 ; c1ccc(-c2ccc(N(c3ccc(-c4ccccc4-n4c5ccccc5c5cc6ccccc6cc54)cc3)c3ccc(-c4cc5ccccc5c5ccccc45)cc3)cc2)cc1 ; CC(C)(C)c1ccc(N(c2ccc(-c3ccccc3)cc2)c2ccc(-c3ccccc3-n3c4ccccc4c4cc5ccccc5cc43)cc2)cc1]

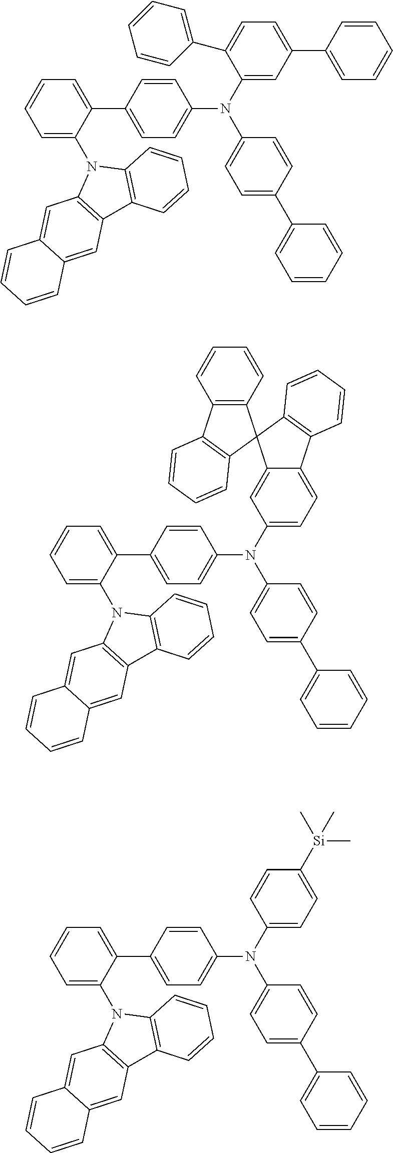 [SMILES: c1ccc(-c2ccc(N(c3ccc(-c4ccccc4-n4c5ccccc5c5cc6ccccc6cc54)cc3)c3cc(-c4ccccc4)ccc3-c3ccccc3)cc2)cc1 ; c1ccc(-c2ccc(N(c3ccc(-c4ccccc4-n4c5ccccc5c5cc6ccccc6cc54)cc3)c3ccc4c(c3)C3(c5ccccc5-c5ccccc53)c3ccccc3-4)cc2)cc1 ; C[Si](C)(C)c1ccc(N(c2ccc(-c3ccccc3)cc2)c2ccc(-c3ccccc3-n3c4ccccc4c4cc5ccccc5cc43)cc2)cc1]

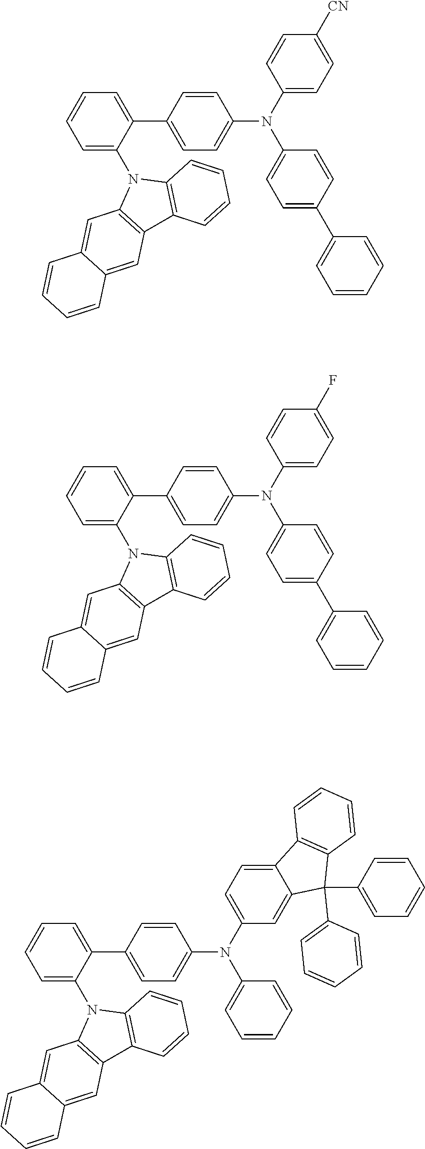 [SMILES: N#Cc1ccc(N(c2ccc(-c3ccccc3)cc2)c2ccc(-c3ccccc3-n3c4ccccc4c4cc5ccccc5cc43)cc2)cc1 ; Fc1ccc(N(c2ccc(-c3ccccc3)cc2)c2ccc(-c3ccccc3-n3c4ccccc4c4cc5ccccc5cc43)cc2)cc1 ; c1ccc(N(c2ccc(-c3ccccc3-n3c4ccccc4c4cc5ccccc5cc43)cc2)c2ccc3c(c2)C(c2ccccc2)(c2ccccc2)c2ccccc2-3)cc1]

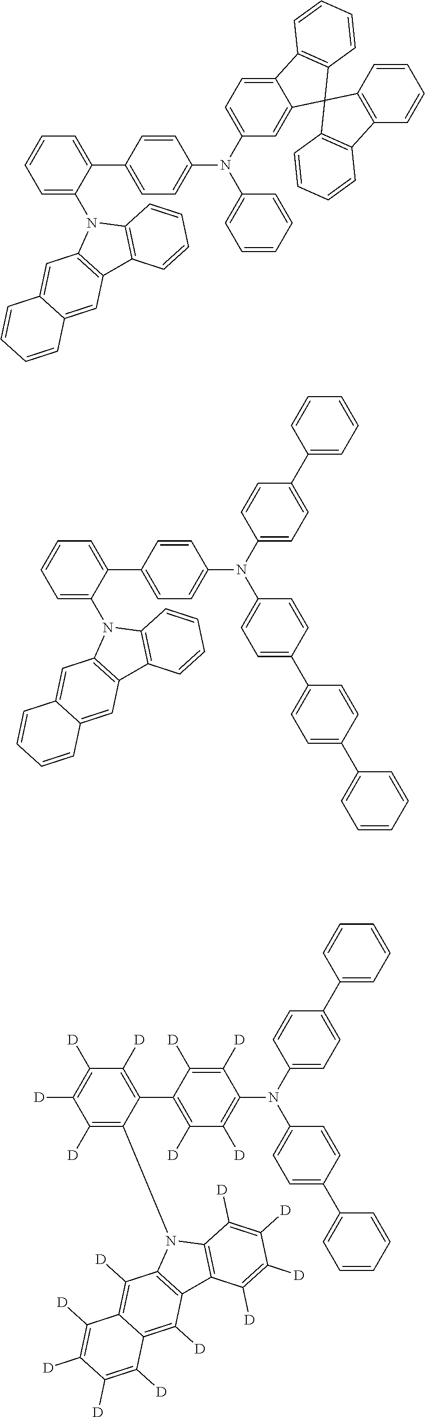 [SMILES: c1ccc(N(c2ccc(-c3ccccc3-n3c4ccccc4c4cc5ccccc5cc43)cc2)c2ccc3c(c2)C2(c4ccccc4-c4ccccc42)c2ccccc2-3)cc1 ; c1ccc(-c2ccc(-c3ccc(N(c4ccc(-c5ccccc5)cc4)c4ccc(-c5ccccc5-n5c6ccccc6c6cc7ccccc7cc65)cc4)cc3)cc2)cc1 ; [2H]c1c([2H])c([2H])c(-n2c3c([2H])c([2H])c([2H])c([2H])c3c3c([2H])c4c([2H])c([2H])c([2H])c([2H])c4c([2H])c32)c(-c2c([2H])c([2H])c(N(c3ccc(-c4ccccc4)cc3)c3ccc(-c4ccccc4)cc3)c([2H])c2[2H])c1[2H]]

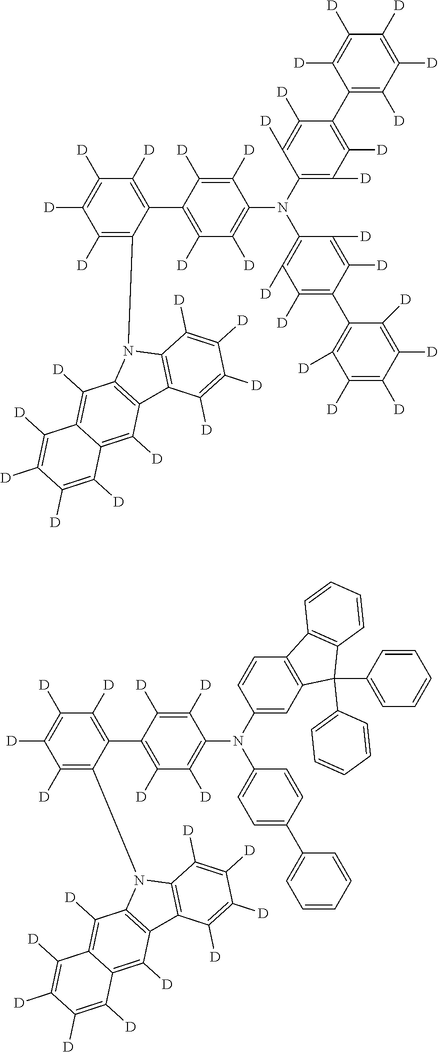

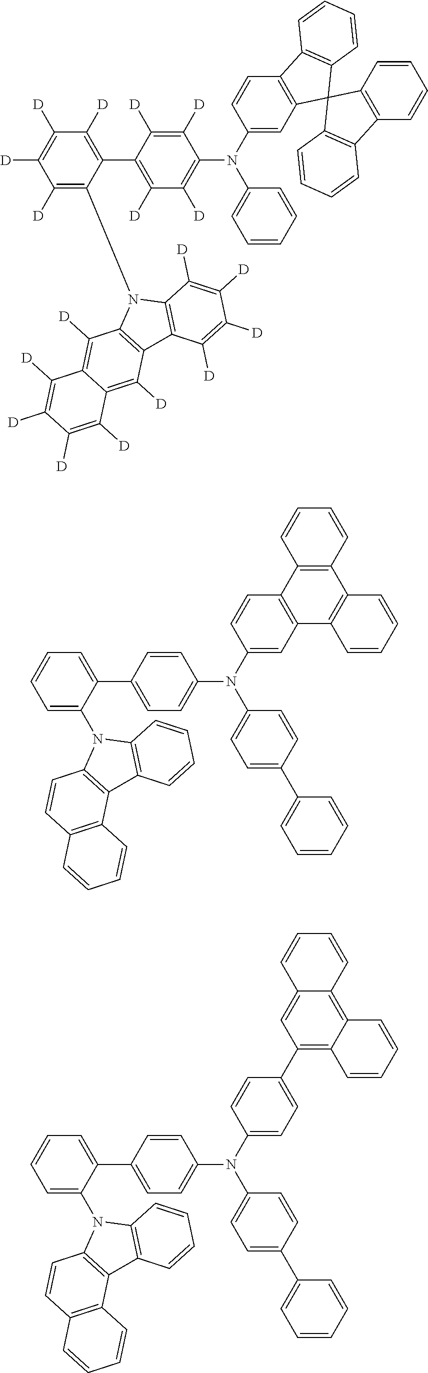 [SMILES: [2H]c1c([2H])c([2H])c(-n2c3c([2H])c([2H])c([2H])c([2H])c3c3c([2H])c4c([2H])c([2H])c([2H])c([2H])c4c([2H])c32)c(-c2c([2H])c([2H])c(N(c3ccccc3)c3ccc4c(c3)C3(c5ccccc5-c5ccccc53)c3ccccc3-4)c([2H])c2[2H])c1[2H] ; c1ccc(-c2ccc(N(c3ccc(-c4ccccc4-n4c5ccccc5c5c6ccccc6ccc54)cc3)c3ccc4c5ccccc5c5ccccc5c4c3)cc2)cc1 ; c1ccc(-c2ccc(N(c3ccc(-c4ccccc4-n4c5ccccc5c5c6ccccc6ccc54)cc3)c3ccc(-c4cc5ccccc5c5ccccc45)cc3)cc2)cc1]

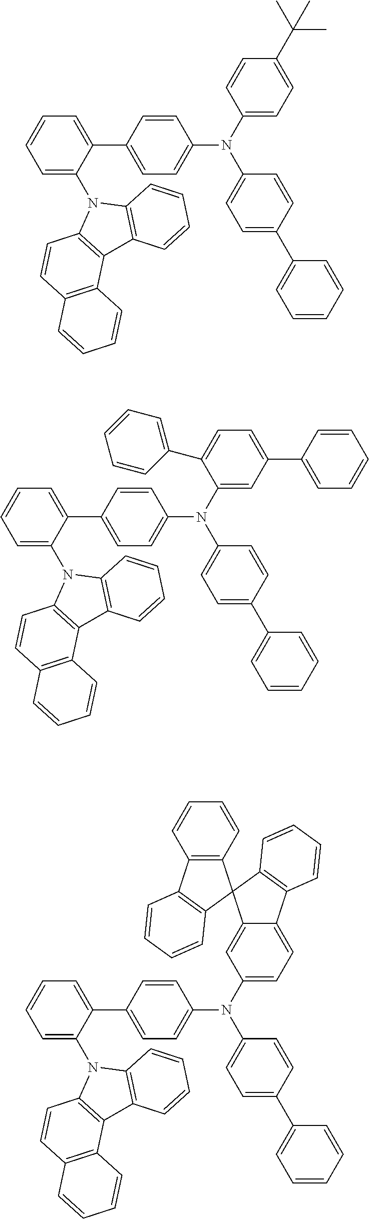 [SMILES: CC(C)(C)c1ccc(N(c2ccc(-c3ccccc3)cc2)c2ccc(-c3ccccc3-n3c4ccccc4c4c5ccccc5ccc43)cc2)cc1 ; c1ccc(-c2ccc(N(c3ccc(-c4ccccc4-n4c5ccccc5c5c6ccccc6ccc54)cc3)c3cc(-c4ccccc4)ccc3-c3ccccc3)cc2)cc1 ; c1ccc(-c2ccc(N(c3ccc(-c4ccccc4-n4c5ccccc5c5c6ccccc6ccc54)cc3)c3ccc4c(c3)C3(c5ccccc5-c5ccccc53)c3ccccc3-4)cc2)cc1]

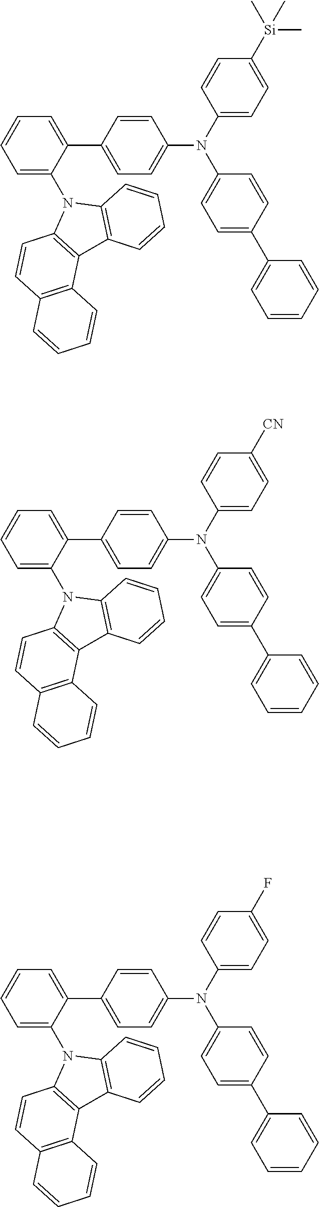 [SMILES: C[Si](C)(C)c1ccc(N(c2ccc(-c3ccccc3)cc2)c2ccc(-c3ccccc3-n3c4ccccc4c4c5ccccc5ccc43)cc2)cc1 ; N#Cc1ccc(N(c2ccc(-c3ccccc3)cc2)c2ccc(-c3ccccc3-n3c4ccccc4c4c5ccccc5ccc43)cc2)cc1 ; Fc1ccc(N(c2ccc(-c3ccccc3)cc2)c2ccc(-c3ccccc3-n3c4ccccc4c4c5ccccc5ccc43)cc2)cc1]

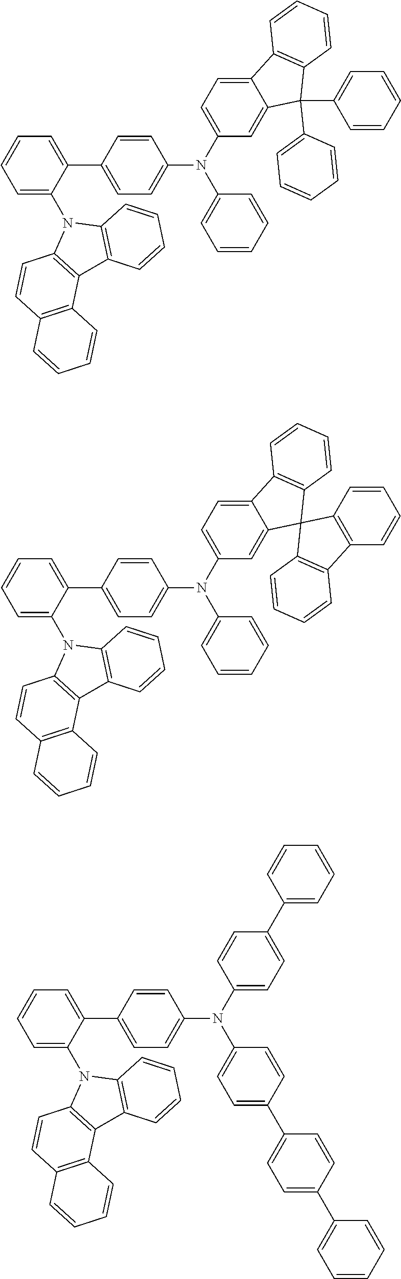 [SMILES: c1ccc(N(c2ccc(-c3ccccc3-n3c4ccccc4c4c5ccccc5ccc43)cc2)c2ccc3c(c2)C(c2ccccc2)(c2ccccc2)c2ccccc2-3)cc1 ; c1ccc(N(c2ccc(-c3ccccc3-n3c4ccccc4c4c5ccccc5ccc43)cc2)c2ccc3c(c2)C2(c4ccccc4-c4ccccc42)c2ccccc2-3)cc1 ; c1ccc(-c2ccc(-c3ccc(N(c4ccc(-c5ccccc5)cc4)c4ccc(-c5ccccc5-n5c6ccccc6c6c7ccccc7ccc65)cc4)cc3)cc2)cc1]

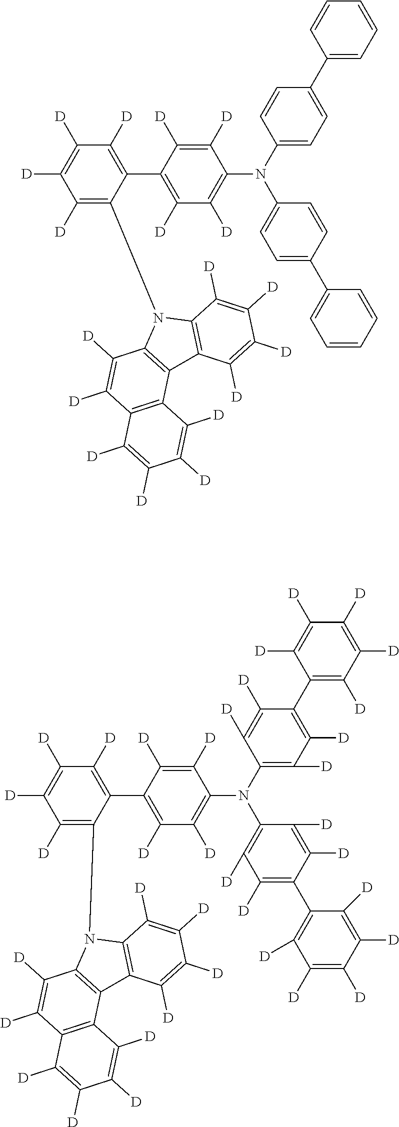 [SMILES: [2H]c1c([2H])c([2H])c(-n2c3c([2H])c([2H])c([2H])c([2H])c3c3c4c([2H])c([2H])c([2H])c([2H])c4c([2H])c([2H])c32)c(-c2c([2H])c([2H])c(N(c3ccc(-c4ccccc4)cc3)c3ccc(-c4ccccc4)cc3)c([2H])c2[2H])c1[2H] ; [2H]c1c([2H])c([2H])c(-c2c([2H])c([2H])c(N(c3c([2H])c([2H])c(-c4c([2H])c([2H])c([2H])c([2H])c4[2H])c([2H])c3[2H])c3c([2H])c([2H])c(-c4c([2H])c([2H])c([2H])c([2H])c4-n4c5c([2H])c([2H])c([2H])c([2H])c5c5c6c([2H])c([2H])c([2H])c([2H])c6c([2H])c([2H])c54)c([2H])c3[2H])c([2H])c2[2H])c([2H])c1[2H]]

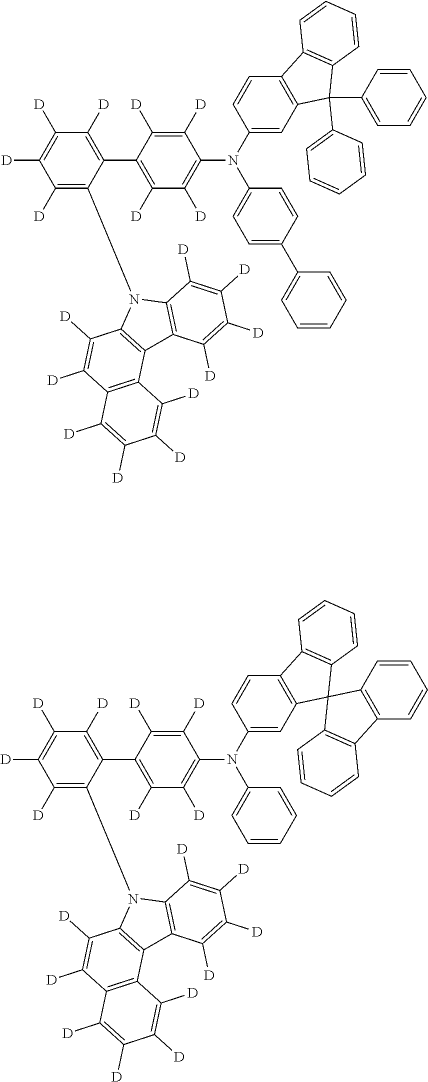 [SMILES: [2H]c1c([2H])c([2H])c(-n2c3c([2H])c([2H])c([2H])c([2H])c3c3c4c([2H])c([2H])c([2H])c([2H])c4c([2H])c([2H])c32)c(-c2c([2H])c([2H])c(N(c3ccc(-c4ccccc4)cc3)c3ccc4c(c3)C(c3ccccc3)(c3ccccc3)c3ccccc3-4)c([2H])c2[2H])c1[2H] ; [2H]c1c([2H])c([2H])c(-n2c3c([2H])c([2H])c([2H])c([2H])c3c3c4c([2H])c([2H])c([2H])c([2H])c4c([2H])c([2H])c32)c(-c2c([2H])c([2H])c(N(c3ccccc3)c3ccc4c(c3)C3(c5ccccc5-c5ccccc53)c3ccccc3-4)c([2H])c2[2H])c1[2H]]

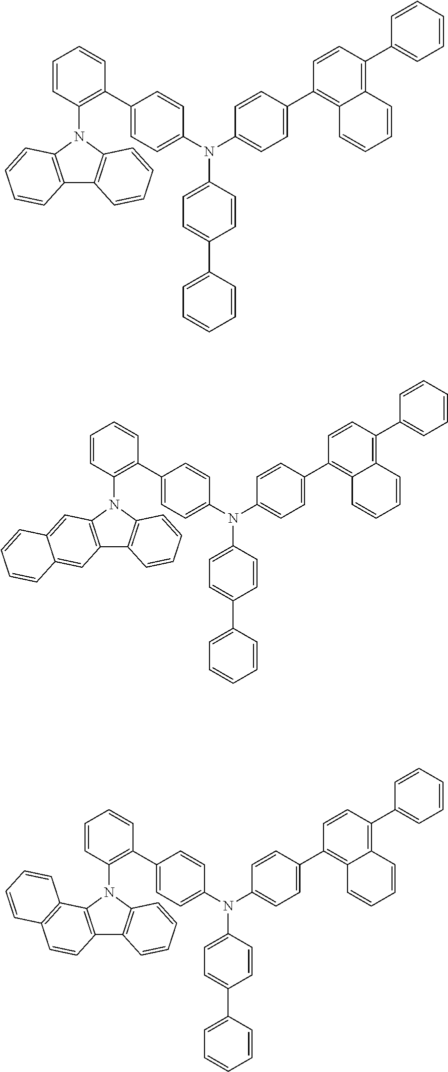 [SMILES: c1ccc(-c2ccc(N(c3ccc(-c4ccccc4-n4c5ccccc5c5ccccc54)cc3)c3ccc(-c4ccc(-c5ccccc5)c5ccccc45)cc3)cc2)cc1 ; c1ccc(-c2ccc(N(c3ccc(-c4ccccc4-n4c5ccccc5c5cc6ccccc6cc54)cc3)c3ccc(-c4ccc(-c5ccccc5)c5ccccc45)cc3)cc2)cc1 ; c1ccc(-c2ccc(N(c3ccc(-c4ccccc4-n4c5ccccc5c5ccc6ccccc6c54)cc3)c3ccc(-c4ccc(-c5ccccc5)c5ccccc45)cc3)cc2)cc1]

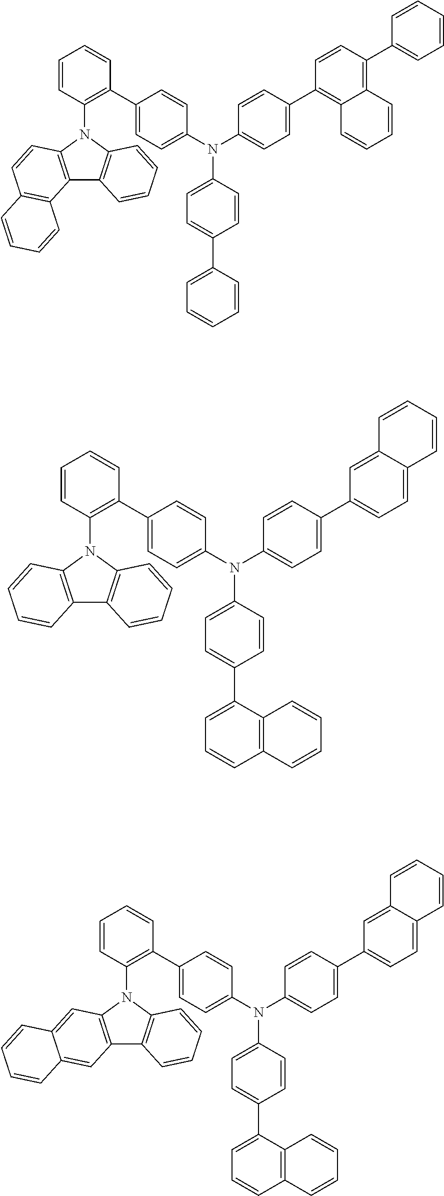 [SMILES: c1ccc(-c2ccc(N(c3ccc(-c4ccccc4-n4c5ccccc5c5c6ccccc6ccc54)cc3)c3ccc(-c4ccc(-c5ccccc5)c5ccccc45)cc3)cc2)cc1 ; c1ccc(-n2c3ccccc3c3ccccc32)c(-c2ccc(N(c3ccc(-c4ccc5ccccc5c4)cc3)c3ccc(-c4cccc5ccccc45)cc3)cc2)c1 ; c1ccc(-n2c3ccccc3c3cc4ccccc4cc32)c(-c2ccc(N(c3ccc(-c4ccc5ccccc5c4)cc3)c3ccc(-c4cccc5ccccc45)cc3)cc2)c1]

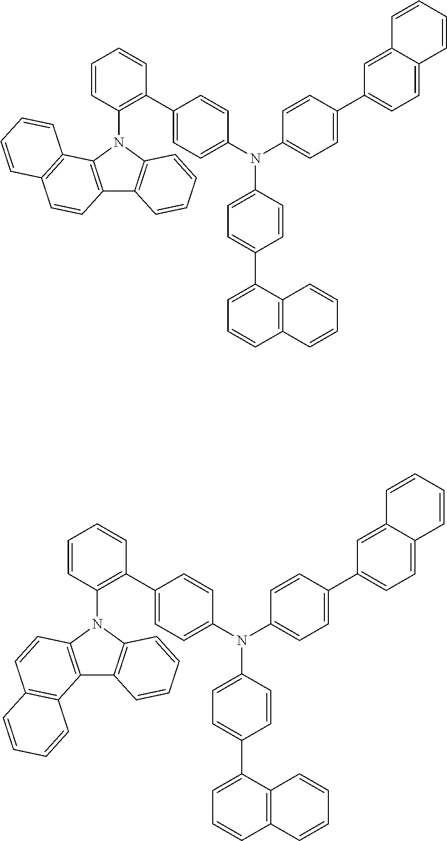 [SMILES: c1ccc(-n2c3ccccc3c3ccc4ccccc4c32)c(-c2ccc(N(c3ccc(-c4ccc5ccccc5c4)cc3)c3ccc(-c4cccc5ccccc45)cc3)cc2)c1 ; c1ccc(-n2c3ccccc3c3c4ccccc4ccc32)c(-c2ccc(N(c3ccc(-c4ccc5ccccc5c4)cc3)c3ccc(-c4cccc5ccccc45)cc3)cc2)c1]

Further, the present disclosure provides a method for preparing the compound represented by Chemical Formula 1 as shown in the following Reaction Scheme 1.

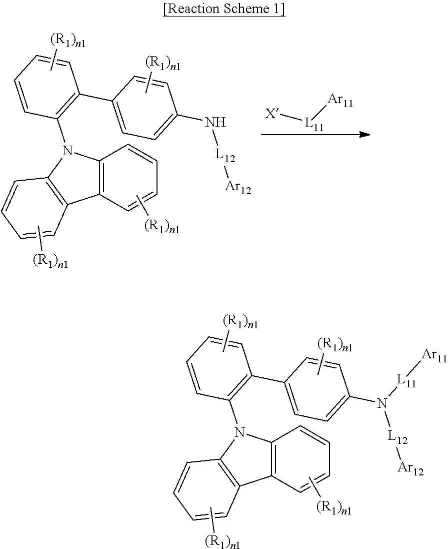

in Reaction Scheme 1, the definition of the remaining substituents except for X′ are the same as defined above, and X′ is halogen, preferably fluoro, chloro or bromo. The above reaction is an amine substitution reaction which is preferably carried out in the presence of a palladium catalyst and a base, and a reactive group for the amine substitution reaction can be modified as known in the art. The above preparation method can be further embodied in Preparation Examples described hereinafter.

Light Emitting Layer

The light emitting layer used in the present disclosure means a layer that can emit light in the visible light region by combining holes and electrons transported from the anode and the cathode. Generally, the light emitting layer includes a host material and a dopant material, and in the present disclosure, the compound represented by Chemical Formula 2 is included as a host.

Preferably, Ar₂₁ and Ar₂₂ are each independently phenyl, biphenylyl, naphthyl, phenylnaphthyl, naphthylphenyl, dibenzofuranyl, (phenyl)dibenzofuranyl, or benzonaphthofuranyl, with the Ar₂₁ and Ar₂₂ being unsubstituted or substituted with at least one deuterium. In this case, being substituted with deuterium means that at least one of the substitutable hydrogens present in each substituent is substituted with deuterium.

Preferably. R₂ is hydrogen, deuterium, phenyl, phenyl substituted with 1 to 5 deuteriums, naphthyl or naphthyl substituted with 1 to 7 deuteriums.

Preferably, one of R₂ is phenyl, phenyl substituted with 1 to 5 deuteriums, naphthyl or naphthyl substituted with 1 to 7 deuteriums, and the rest is hydrogen or deuterium.

Representative examples of the compound represented by Chemical Formula 2 are as follows:

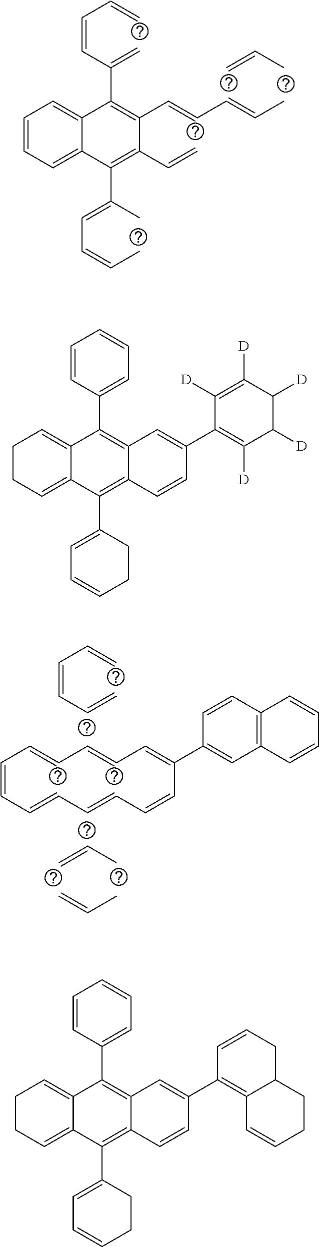

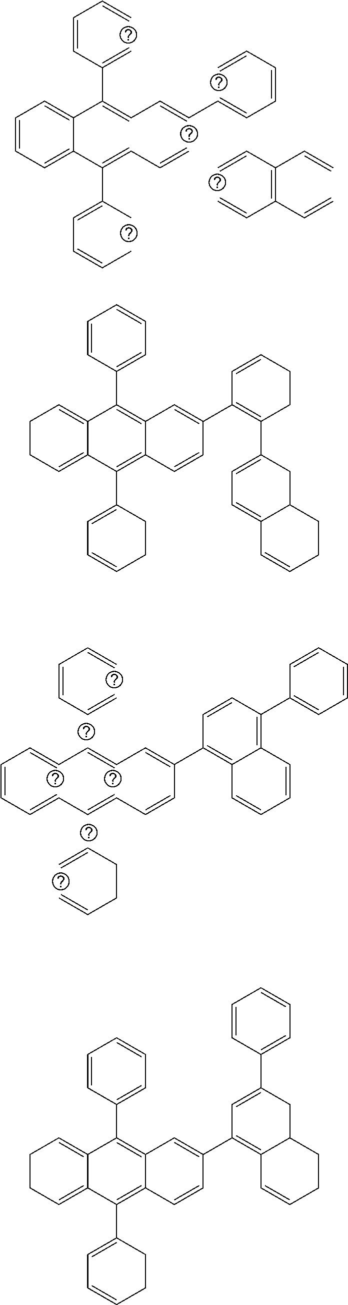

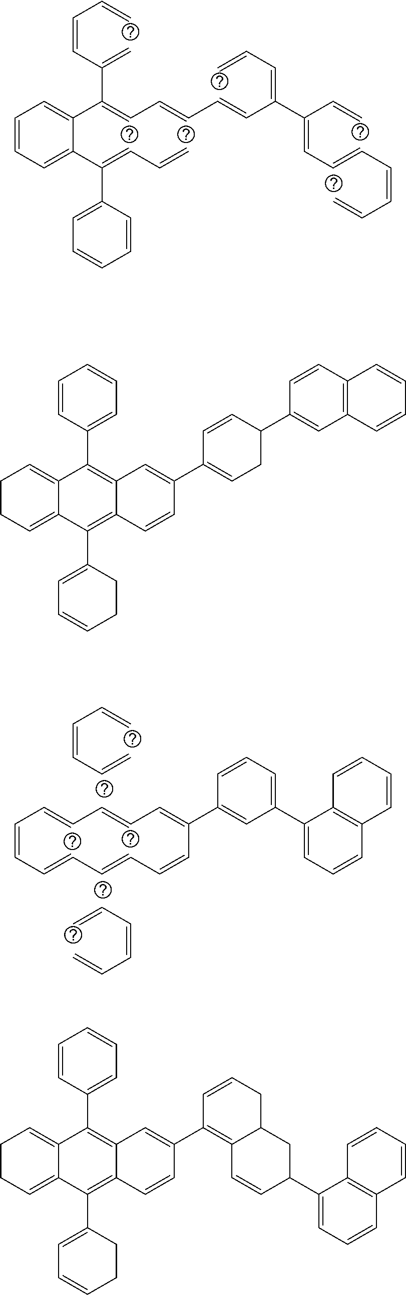

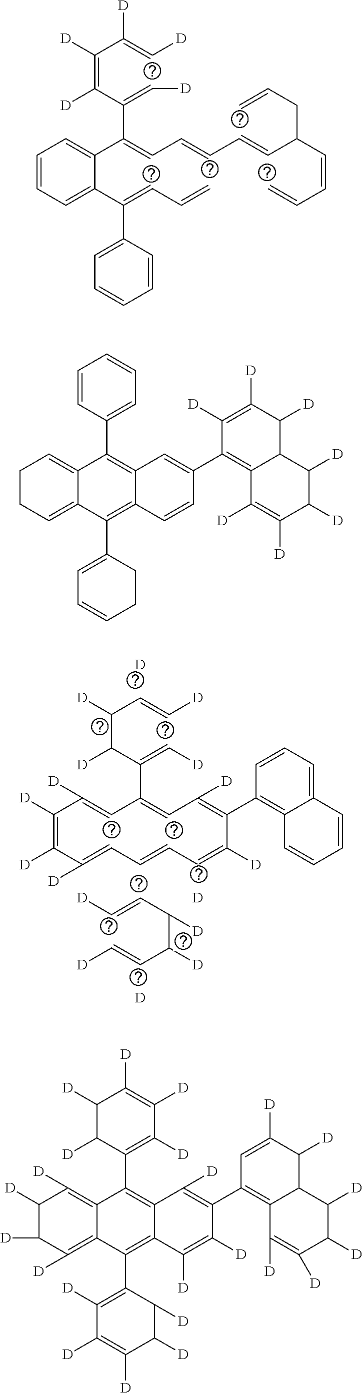

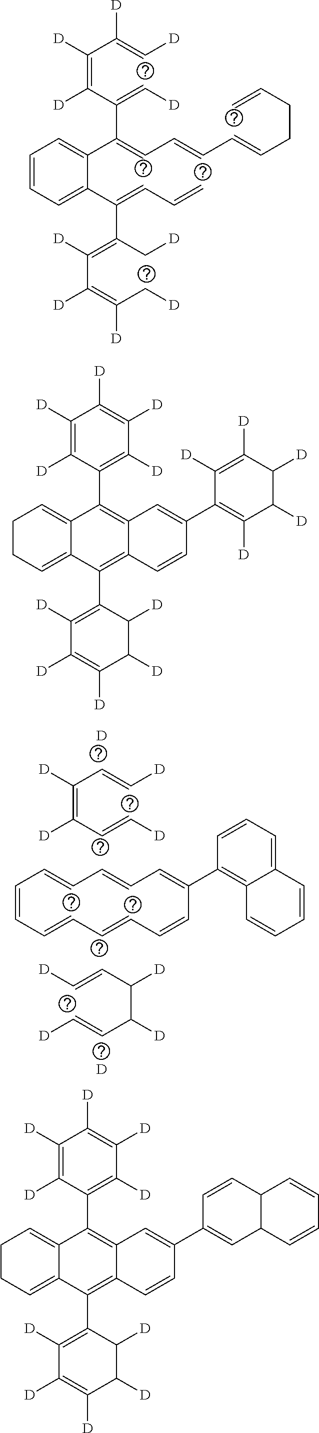

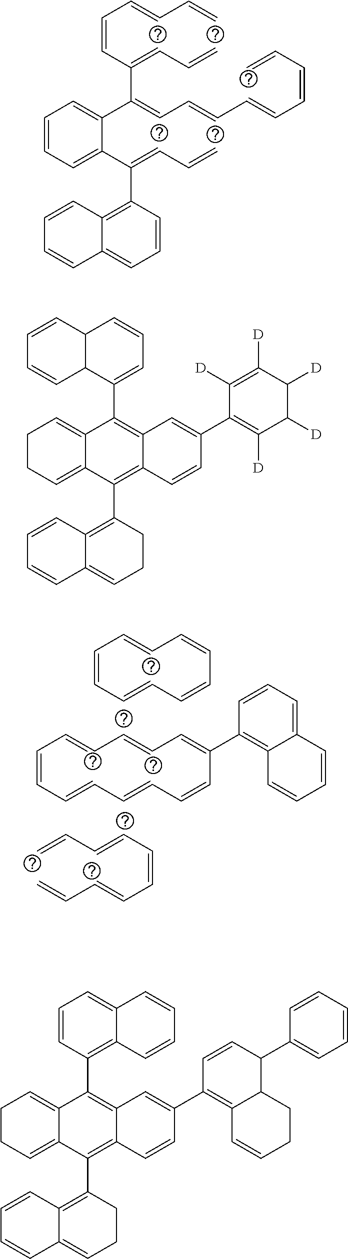

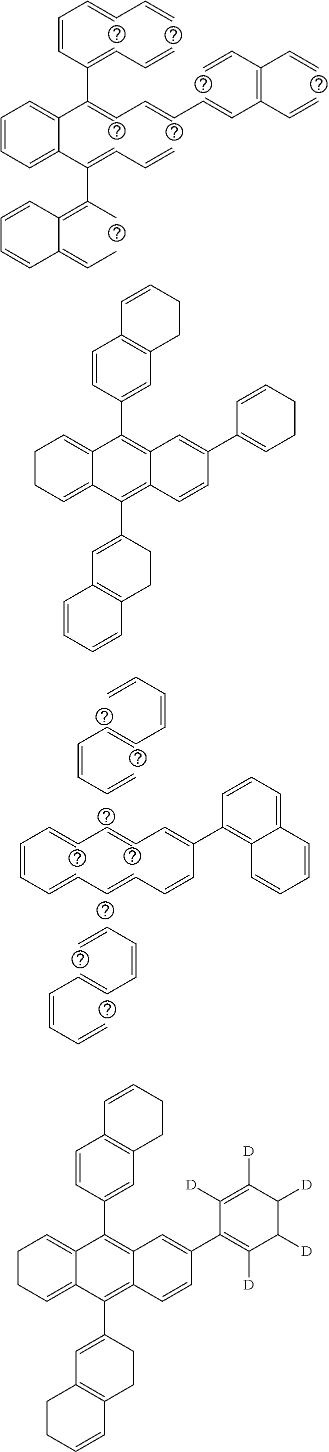

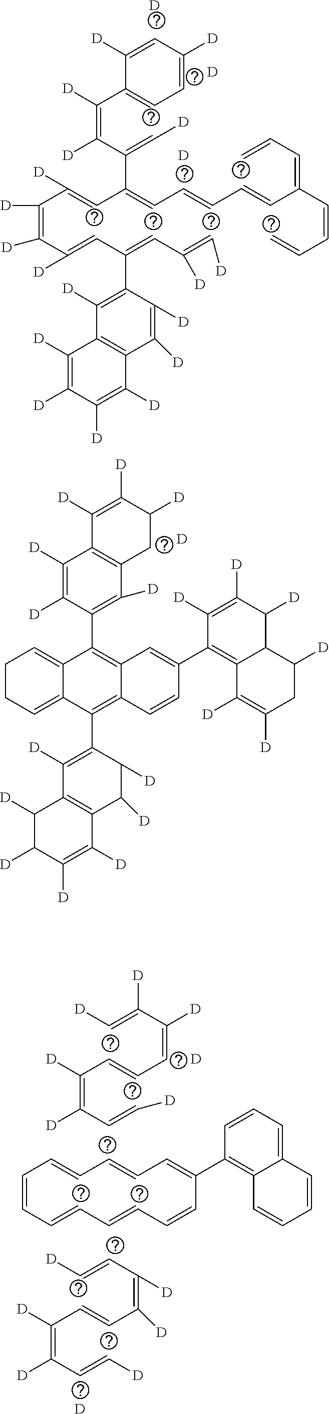

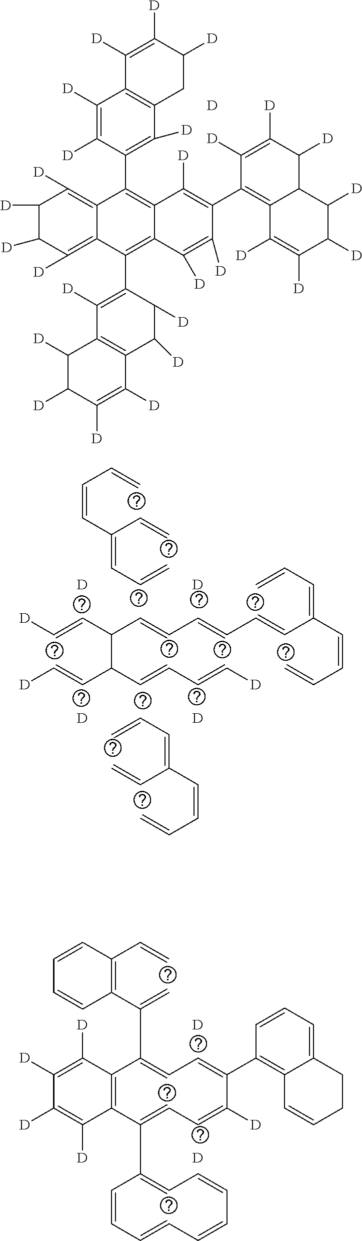

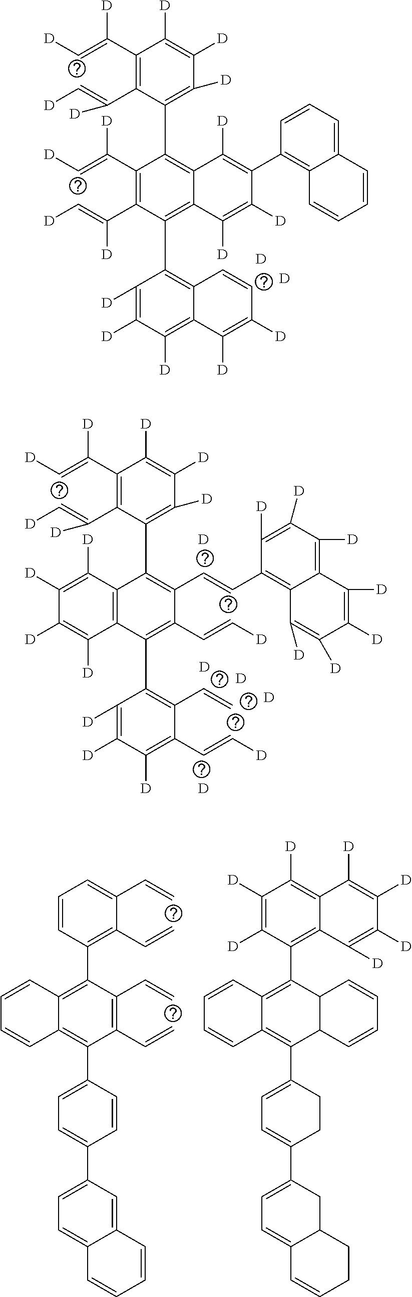

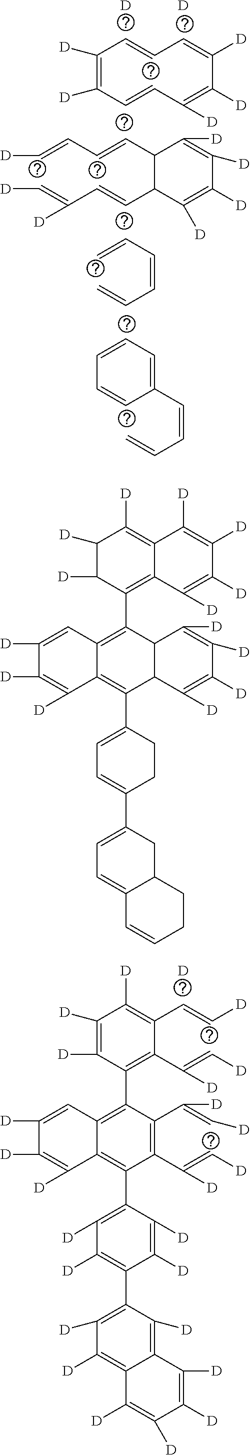

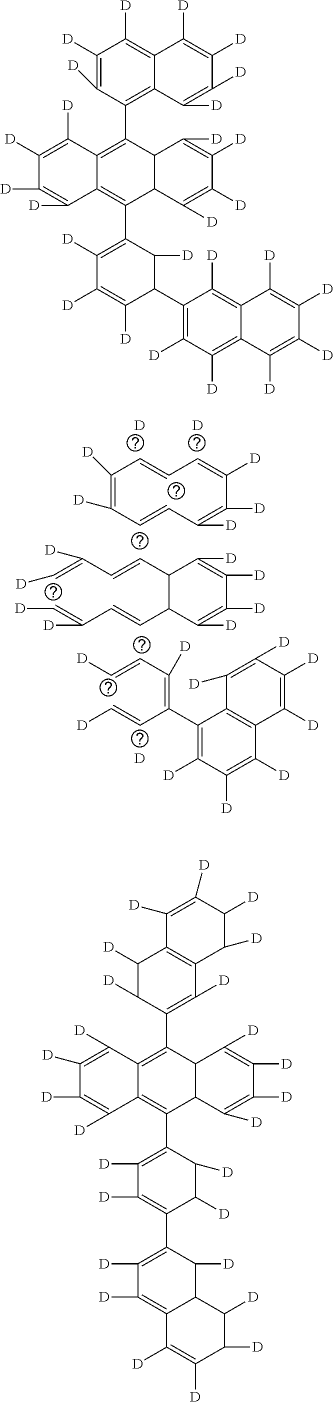

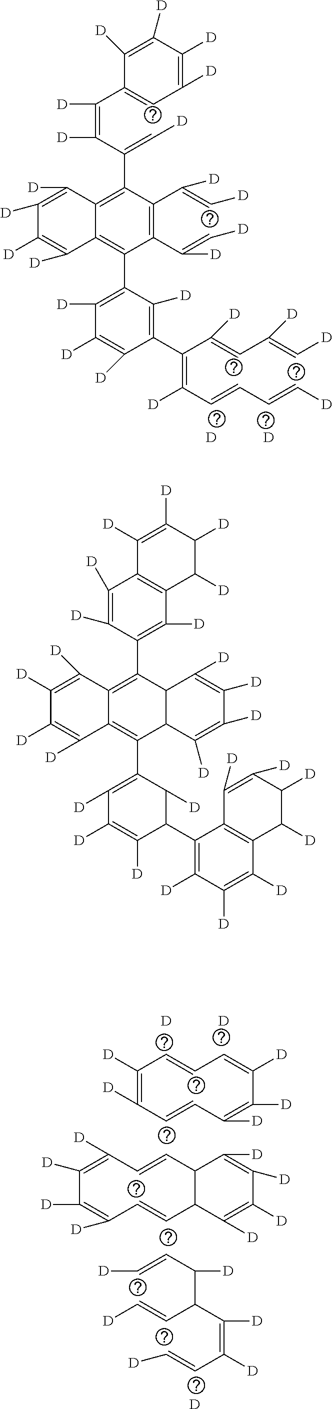

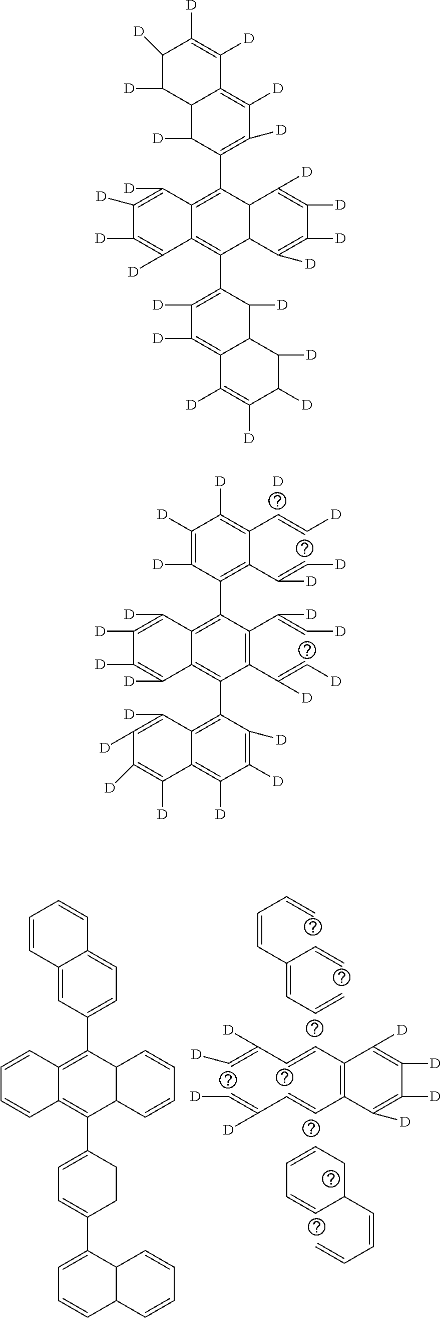

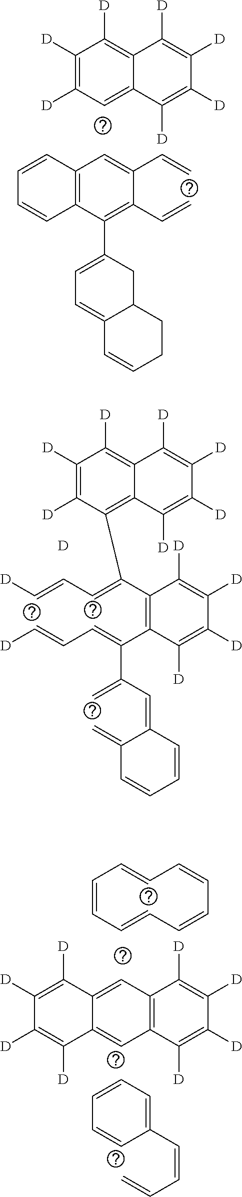

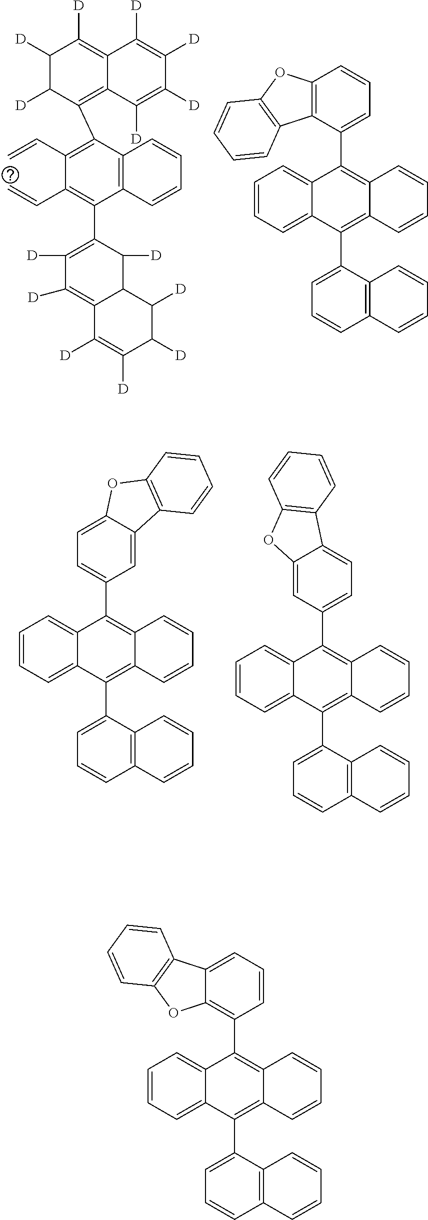

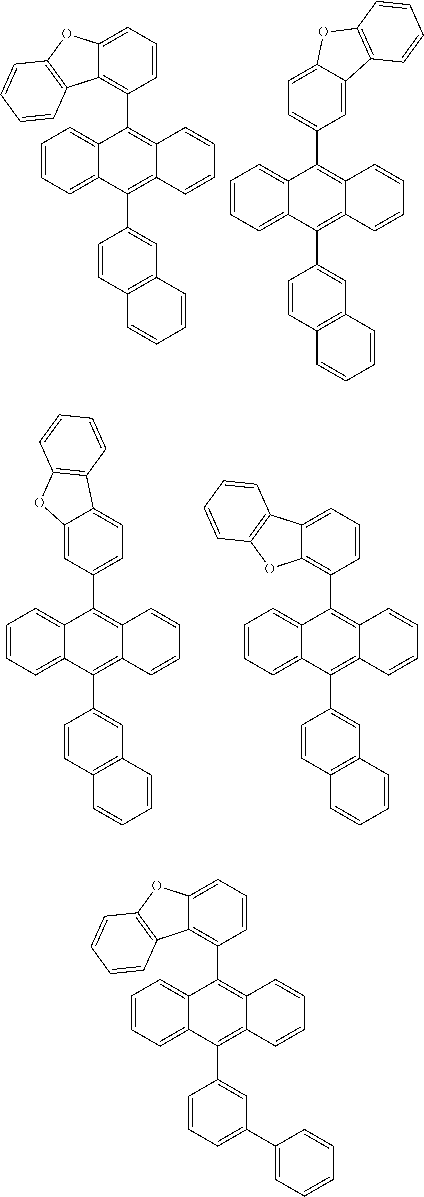

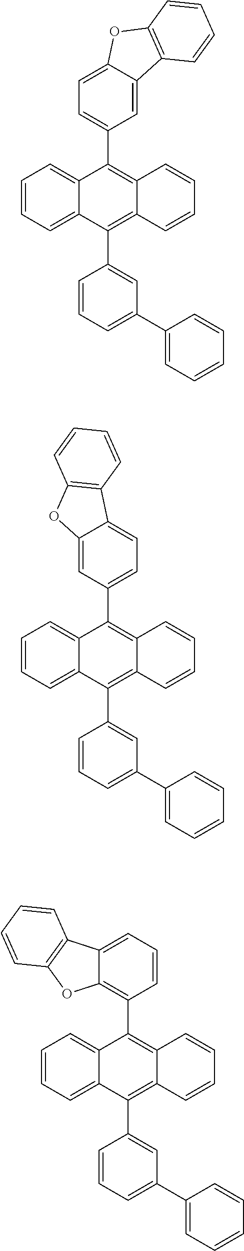 [SMILES: c1ccc(-c2cccc(-c3c4ccccc4c(-c4ccc5oc6ccccc6c5c4)c4ccccc34)c2)cc1 ; c1ccc(-c2cccc(-c3c4ccccc4c(-c4ccc5c(c4)oc4ccccc45)c4ccccc34)c2)cc1 ; c1ccc(-c2cccc(-c3c4ccccc4c(-c4cccc5c4oc4ccccc45)c4ccccc34)c2)cc1]

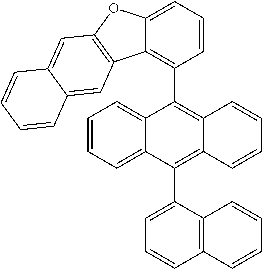 [SMILES: c1ccc2cc3c(cc2c1)oc1cccc(-c2c4ccccc4c(-c4cccc5ccccc45)c4ccccc24)c13]

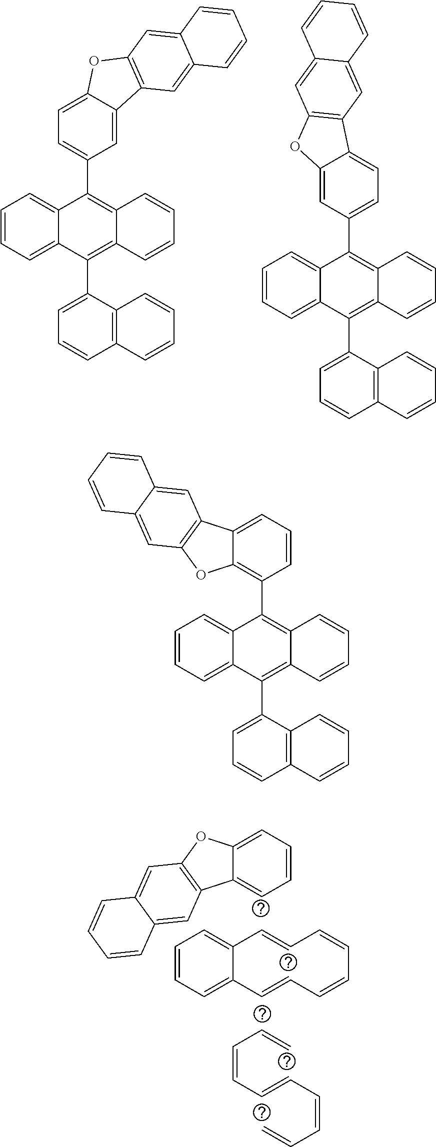

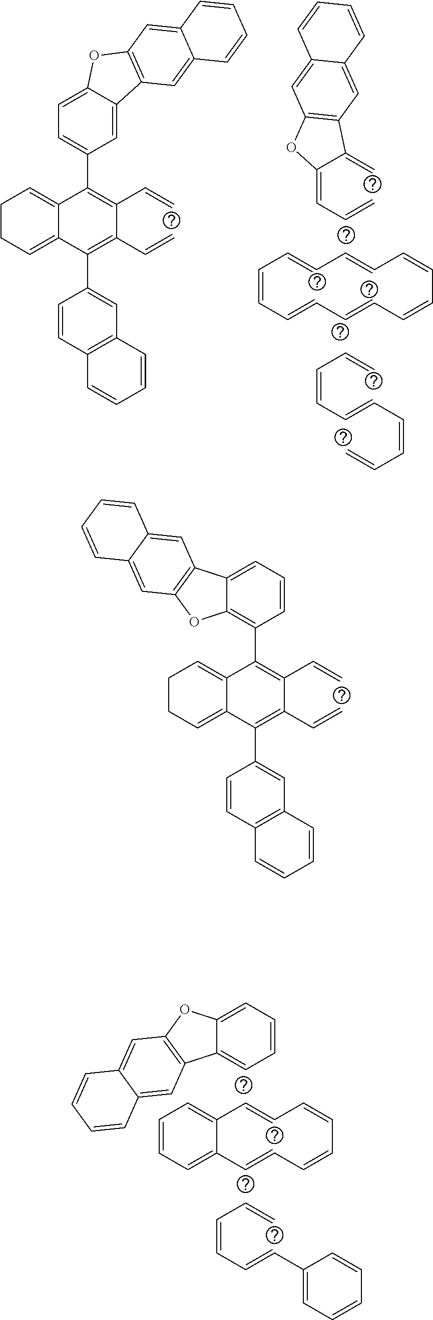

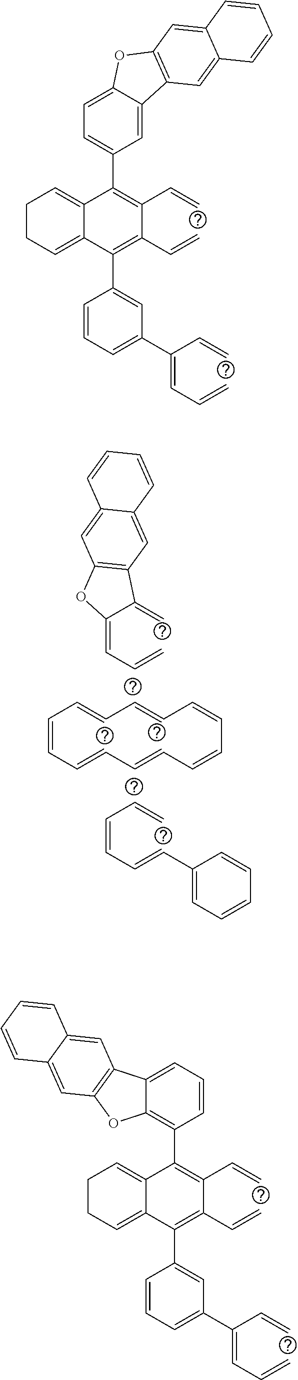

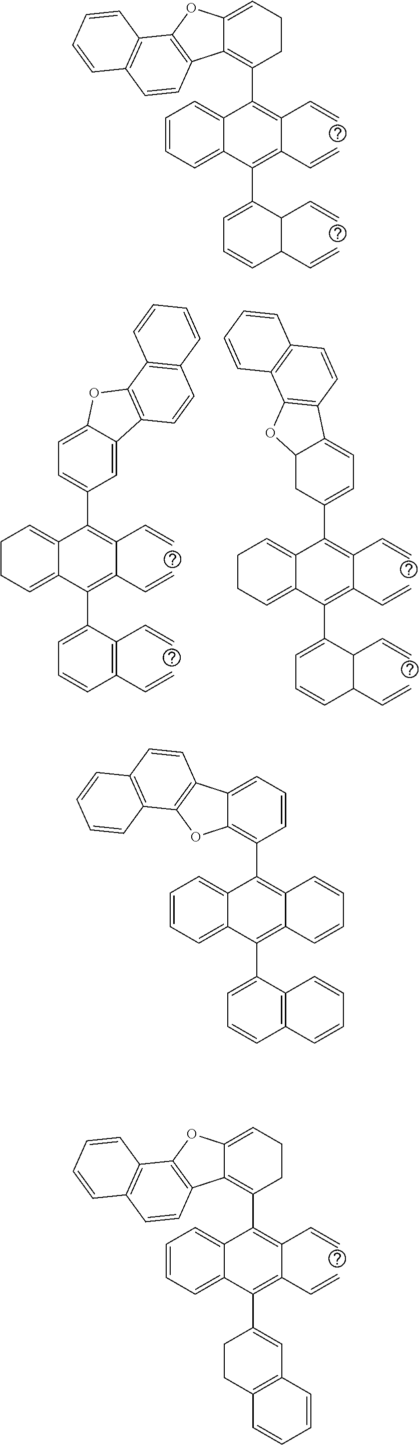

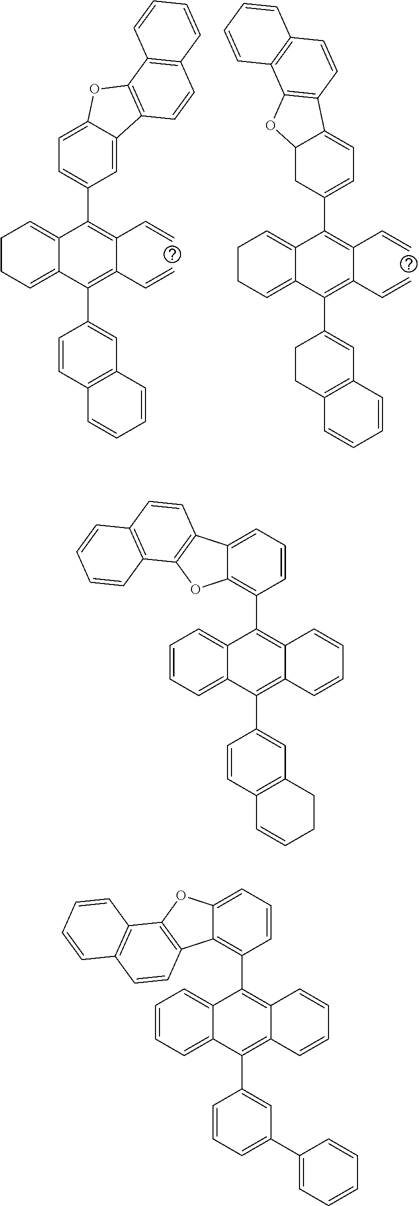

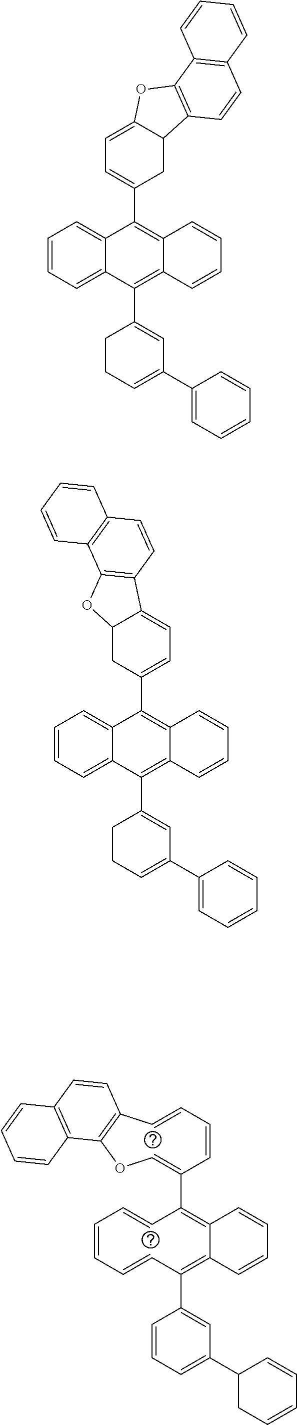 [SMILES: C1=C(c2ccccc2)C=C(c2c3ccccc3c(C3=CC=C4Oc5c(ccc6ccccc56)C4C3)c3ccccc23)CC1 ; C1=C(c2ccccc2)C=C(c2c3ccccc3c(C3=CC=C4c5ccc6ccccc6c5OC4C3)c3ccccc23)CC1 ; C1=CCC(c2cccc(-c3ccccccc(C4=C\Oc5c(ccc6ccccc56)/C=C/C=C\4)c4ccccc34)c2)C=C1]

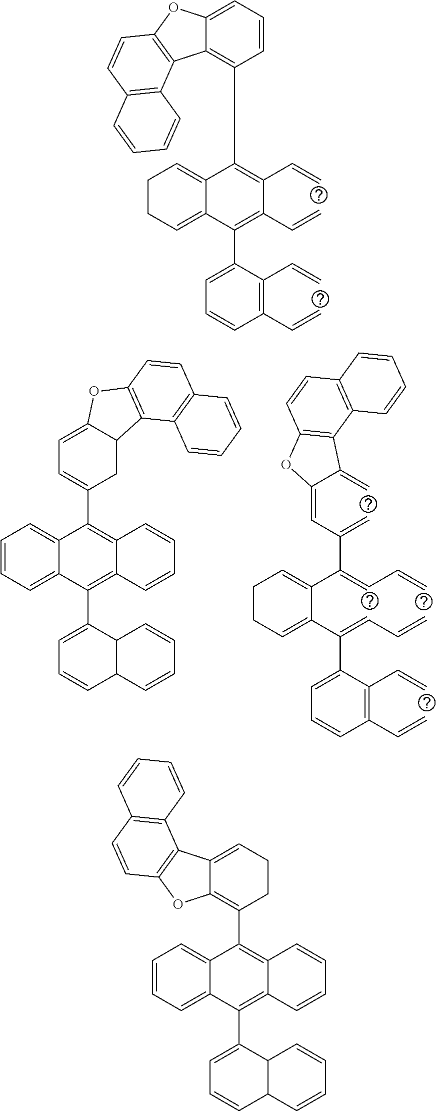 [SMILES: C=Cc1cccc(-c2c(C=C)c(C=C)c(-c3cccc4oc5ccc6ccccc6c5c34)c3c2=CCCC=3)c1C=C ; C1=CC2C=CC=C(c3c4ccccc4c(C4=CC=C5Oc6ccc7ccccc7c6C5C4)c4ccccc34)C2C=C1 ; C=C/C=C(/C1=CCCC=C1/C(=C/C=C)C(=C)/C=c1/oc2ccc3ccccc3c2c1=C)c1cccc(C=C)c1C=C ; C1=CC2C=CC=C(c3c4ccccc4c(C4=c5oc6ccc7ccccc7c6c5=CCC4)c4ccccc34)C2C=C1]

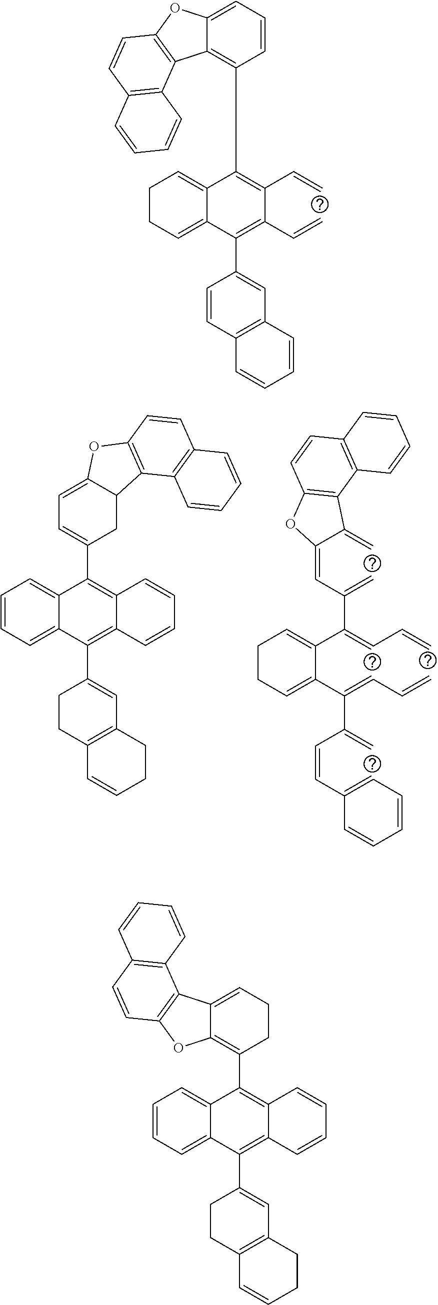 [SMILES: C=Cc1c(C=C)c(-c2cccc3oc4ccc5ccccc5c4c23)c2c(c1-c1ccc3ccccc3c1)=CCCC=2 ; C1=CC2=C(C=C(c3c4ccccc4c(C4=CC=C5Oc6ccc7ccccc7c6C5C4)c4ccccc34)CC2)CC1 ; C=C/C=C(\C(=C)/C=C\c1ccccc1)C1=CCCC=C1/C(=C/C=C)C(=C)/C=c1/oc2ccc3ccccc3c2c1=C ; C1=CC2=C(C=C(c3c4ccccc4c(C4=c5oc6ccc7ccccc7c6c5=CCC4)c4ccccc34)CC2)CC1]

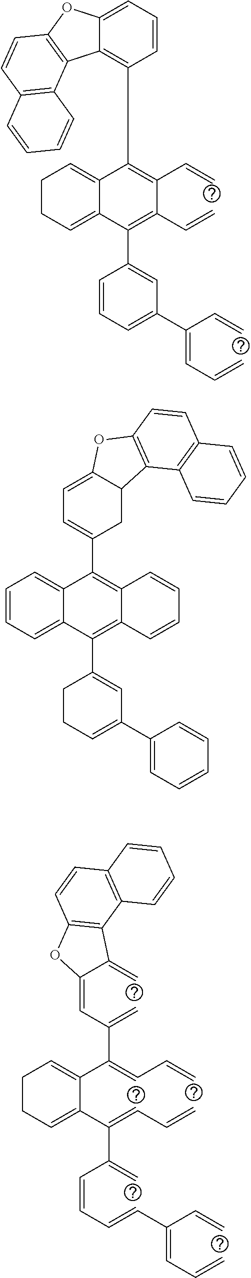

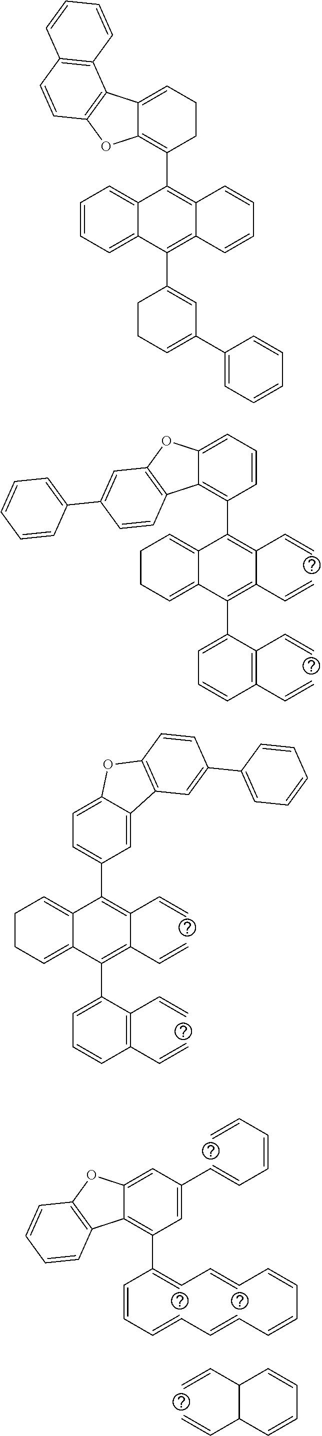

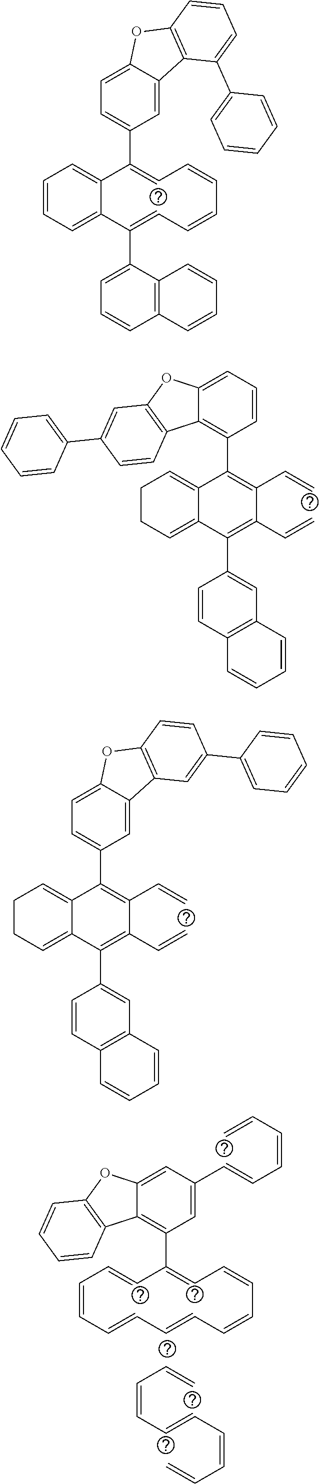

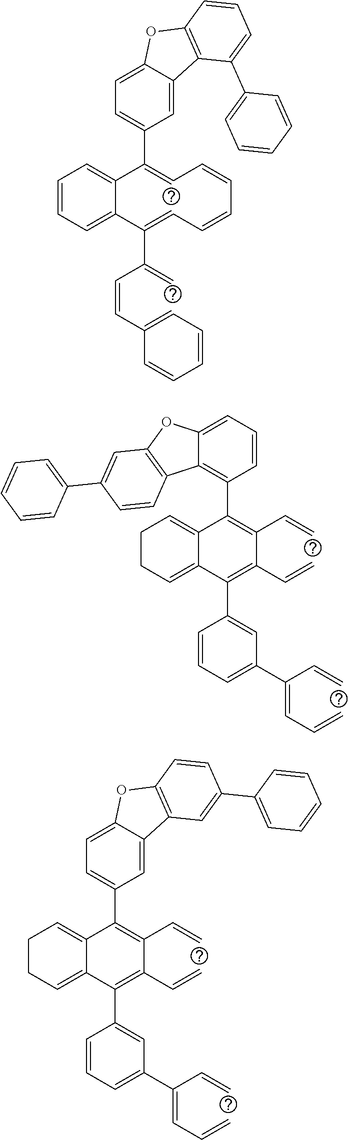

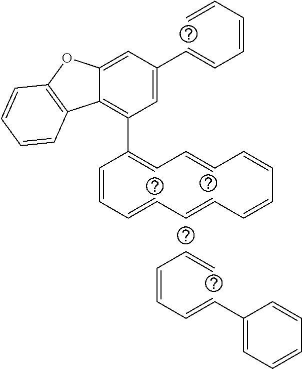

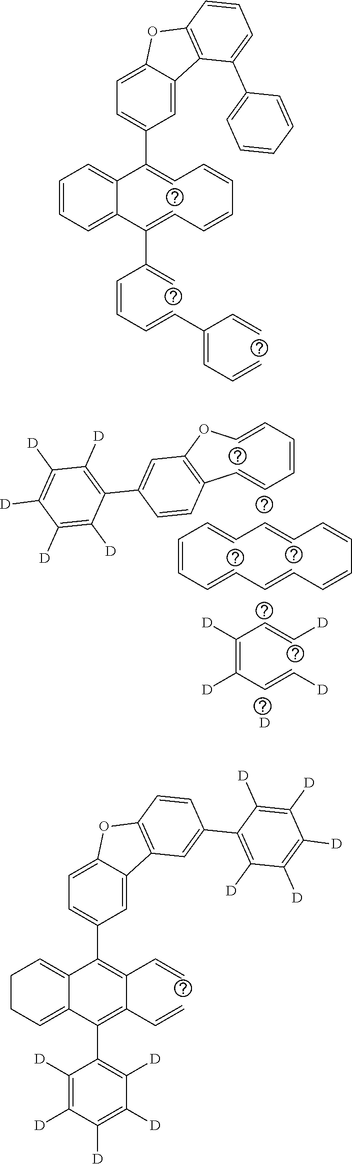

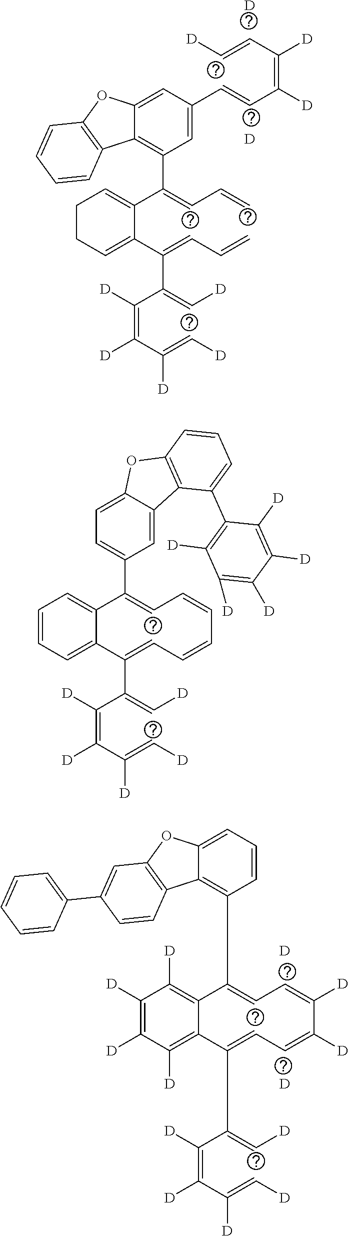

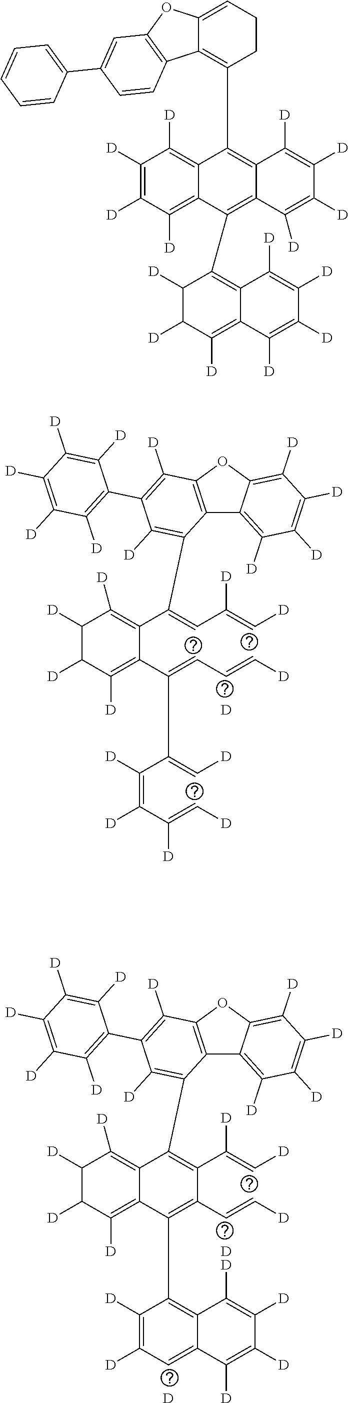

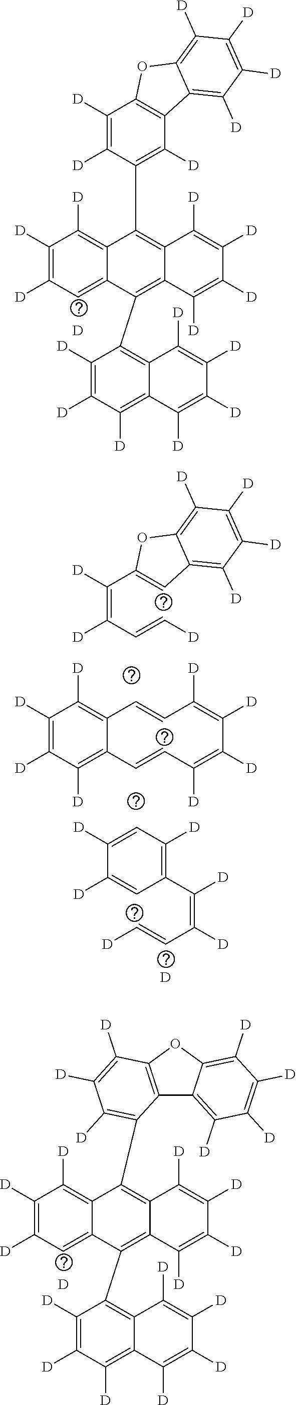

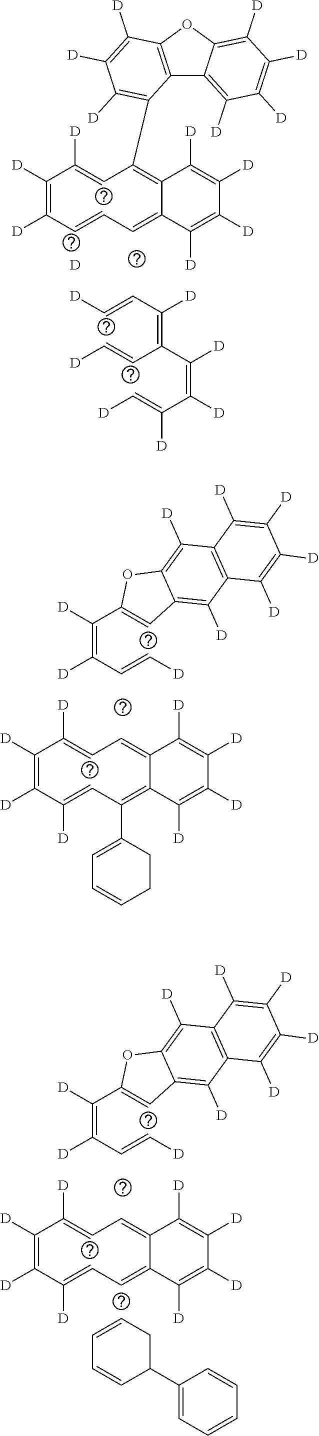

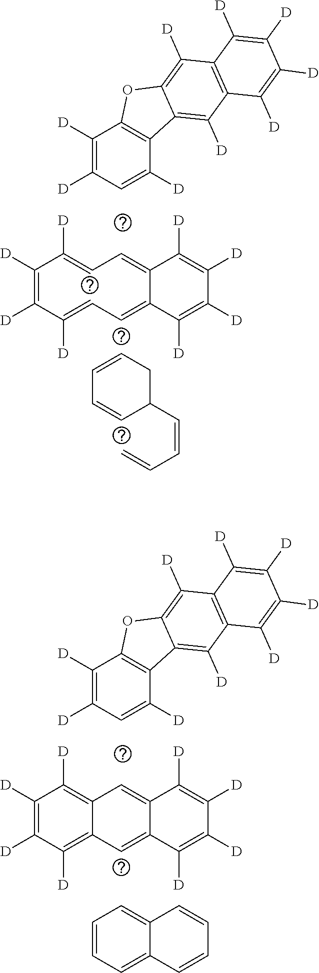

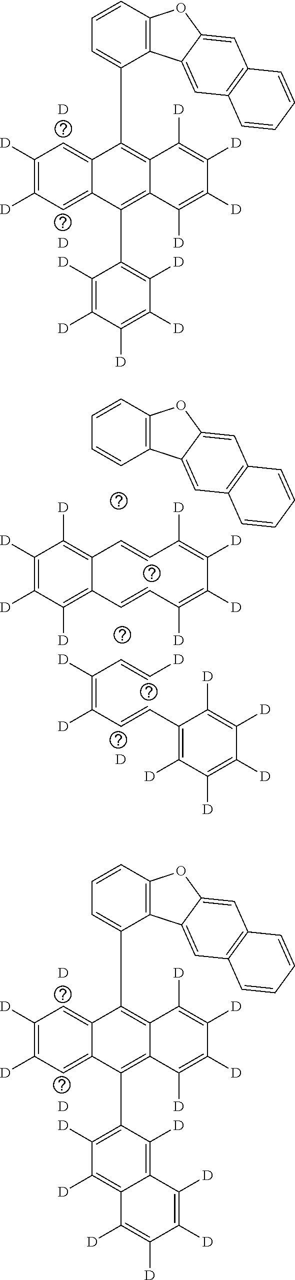

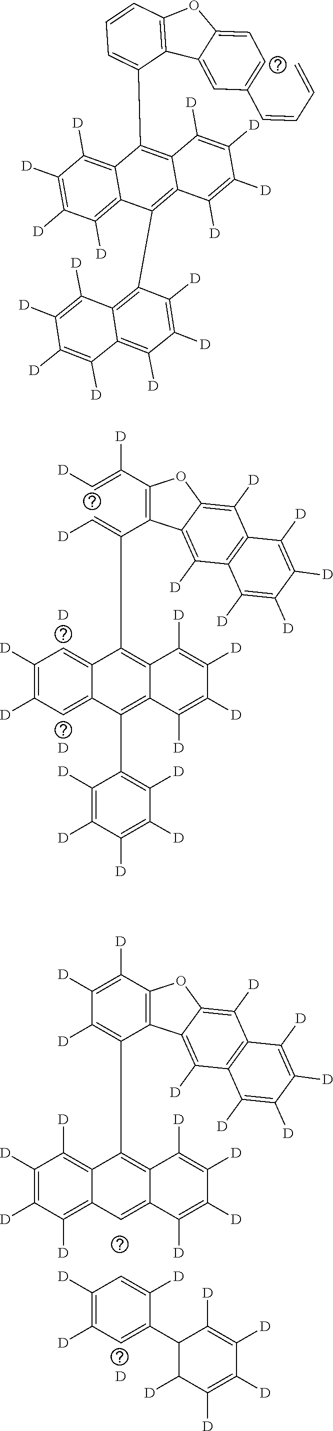

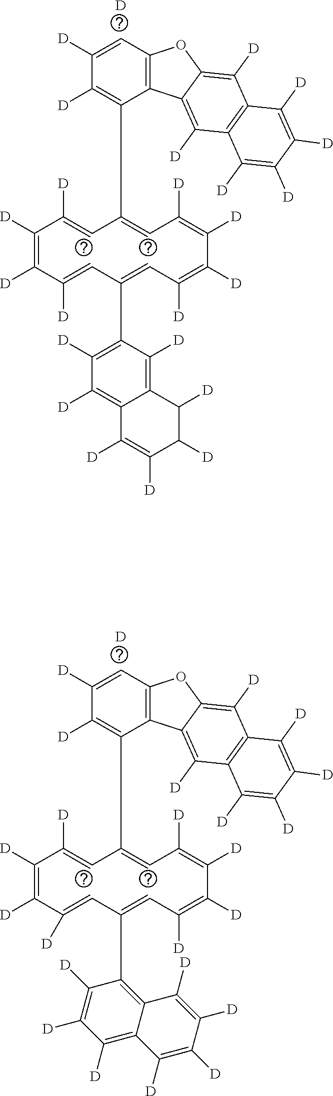

Further, the present disclosure provides a method for preparing the compound represented by Chemical Formula 2 as shown in the following Reaction Scheme 2.

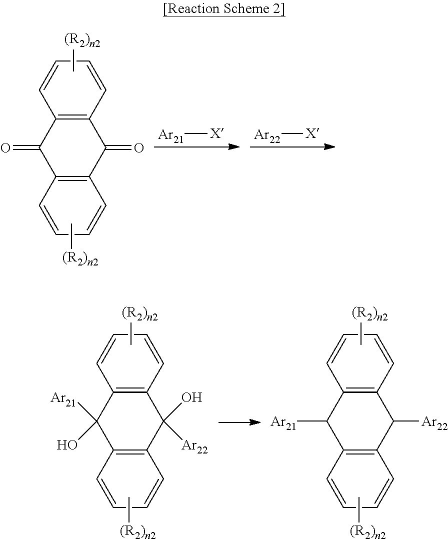

in Reaction Scheme 2, the definition of the remaining substituents except for X′ are the same as defined above, and X is halogen, more preferably bromo or chloro. The first step of the reaction is a step of sequentially reacting with each aryl halide compound using an anthraquinone-based compound as a starting material, and when Ar₂₁ and Ar₂₂ are identical to each other, the step can proceed with a single reaction. The second step of the reaction is a step of preparing an anthracene-based compound, which can be prepared by refluxing potassium iodide and sodium hypophosphite in acetic acid. The above preparation method can be further embodied in Preparation Examples described hereinafter.

The dopant material is not particularly limited as long as it is a material used for the organic light emitting device. As an example, an aromatic amine derivative, a styrylamine compound, a boron complex, a fluoranthene compound, a metal complex, and the like can be mentioned. Specific examples of the aromatic amine derivatives include substituted or unsubstituted fused aromatic ring derivatives having an arylamino group, examples thereof include pyrene, anthracene, chrysene, and periflanthene having the arylamino group, and the like. The styrylamine compound is a compound where at least one arylvinyl group is substituted in substituted or unsubstituted arylamine, wherein one or two or more substituent groups selected from the group consisting of an aryl group, a silyl group, an alkyl group, a cycloalkyl group and an arylamino group are substituted or unsubstituted. Specific examples thereof include styrylamine, styryldiamine, styryltriamine, styryltetramine, and the like, but are not limited thereto. Further, examples of the metal complex include an iridium complex, a platinum complex, and the like, but are not limited thereto

Hole Blocking Layer

The organic light emitting device according to the present disclosure includes a hole blocking layer between the light emitting layer and the electron transport layer, if necessary. Preferably, the hole blocking layer comes into contact with the light emitting layer.

The hole blocking layer serves to suppress the holes injected from the anode from being transmitted toward the cathode without being recombined in the light emitting layer. Specific examples of the material that can be used as the material for the hole blocking layer include an oxadiazole derivative, a triazole derivative, a phenanthroline derivative, BCP, an aluminum complex, and the like, but are not limited thereto.

Electron Transport Layer

The organic light emitting device according to the present disclosure may include an electron transport layer between the light emitting layer (or hole blocking layer) and the cathode.

The electron transport layer is a layer that receives electrons from a cathode and an electron injection layer formed on the cathode and transports the electrons to the light emitting layer, and that suppress the transfer of holes from the light emitting layer, and the electron transport material is a material which can receive electrons well from a cathode and transfer the electrons to a light emitting layer, and the compound represented by Chemical Formula 3 is used in the present disclosure.

Preferably, the Chemical Formula 3 is represented by the following Chemical Formulas 3-1, 3-2, 3-3, 3-4 or 3-5.

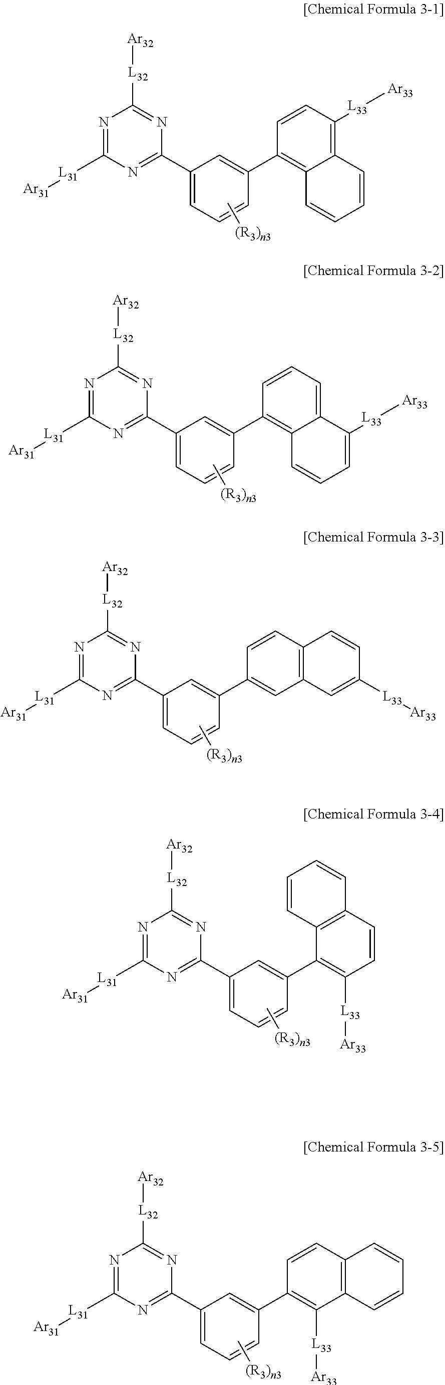

Preferably, Ar₃₁ and Ar₃₂ are each independently phenyl, biphenylyl, naphthylphenyl, phenylnaphthyl, or pyridinylphenyl, with the Ar₃₁ and Ar₃₂ being unsubstituted or substituted with at least one deuterium, cyano, or a C₁₋₁₀ alkyl.

Preferably, L₃₁ and L₃₂ are each independently a single bond or phenylene.

Preferably, Ar₃₃ is phenyl, biphenylyl, dimethyl fluorenyl, naphthyl, triphenylenyl, fluoranthenyl, diphenylfluorenyl, pyridinyl, pyrimidinyl, quinolinyl, isoquinolinyl, imidazolyl, (uranyl, pyridazinyl, dibenzofuranyl, carbazol-9-yl, with the Ar₃₃ being unsubstituted or substituted with at least one cyano, C₁₋₁₀ alkyl, or C₆₋₂₀ aryl.

Preferably, L₃₃ is a single bond, phenylene, furandiyl, or pyridinylene.

Preferably, R₃ is hydrogen, deuterium, or phenyl.

Representative examples of the compound represented by Chemical Formula 3 are as follows:

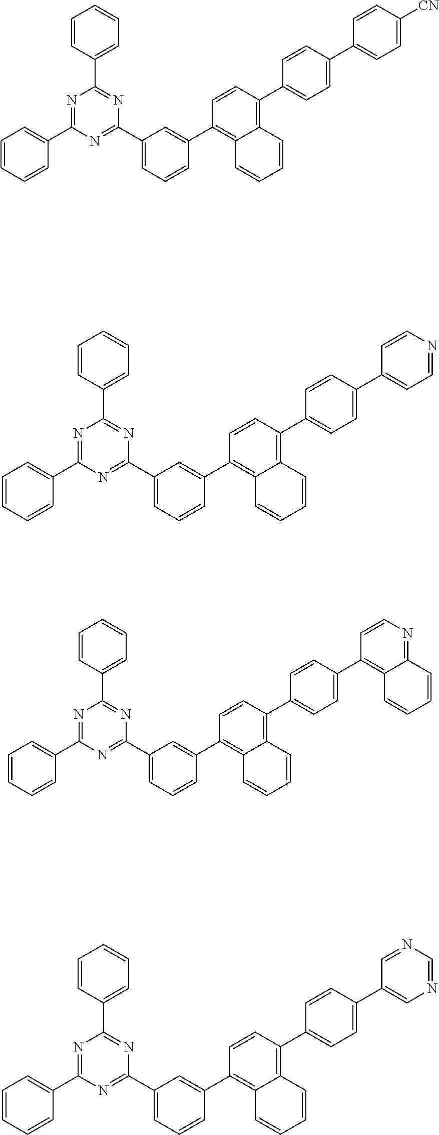 [SMILES: N#Cc1ccc(-c2ccc(-c3ccc(-c4cccc(-c5nc(-c6ccccc6)nc(-c6ccccc6)n5)c4)c4ccccc34)cc2)cc1 ; c1ccc(-c2nc(-c3ccccc3)nc(-c3cccc(-c4ccc(-c5ccc(-c6ccncc6)cc5)c5ccccc45)c3)n2)cc1 ; c1ccc(-c2nc(-c3ccccc3)nc(-c3cccc(-c4ccc(-c5ccc(-c6ccnc7ccccc67)cc5)c5ccccc45)c3)n2)cc1 ; c1ccc(-c2nc(-c3ccccc3)nc(-c3cccc(-c4ccc(-c5ccc(-c6cncnc6)cc5)c5ccccc45)c3)n2)cc1]

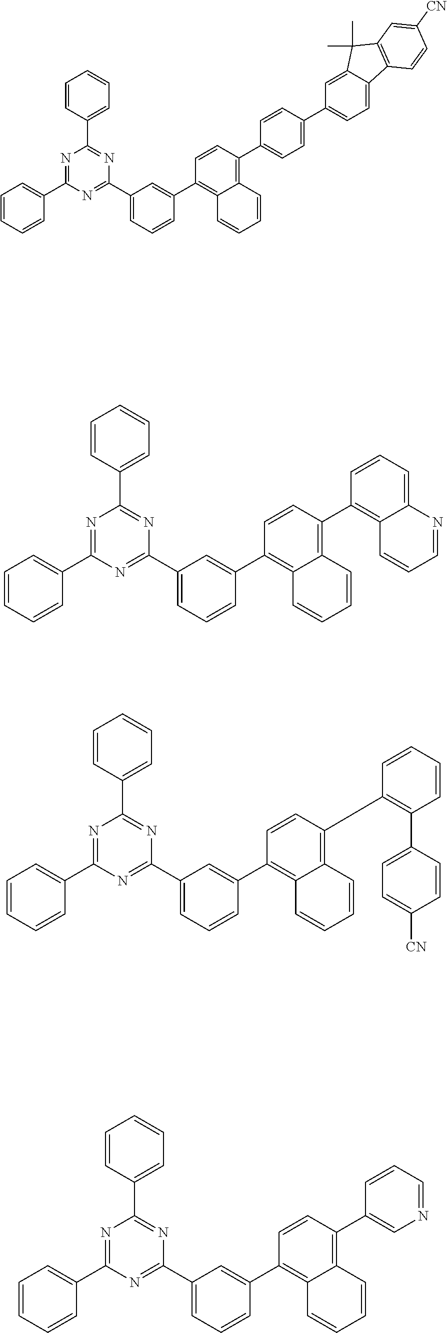 [SMILES: CC1(C)c2cc(C#N)ccc2-c2ccc(-c3ccc(-c4ccc(-c5cccc(-c6nc(-c7ccccc7)nc(-c7ccccc7)n6)c5)c5ccccc45)cc3)cc21 ; c1ccc(-c2nc(-c3ccccc3)nc(-c3cccc(-c4ccc(-c5cccc6ncccc56)c5ccccc45)c3)n2)cc1 ; N#Cc1ccc(-c2ccccc2-c2ccc(-c3cccc(-c4nc(-c5ccccc5)nc(-c5ccccc5)n4)c3)c3ccccc23)cc1 ; c1ccc(-c2nc(-c3ccccc3)nc(-c3cccc(-c4ccc(-c5cccnc5)c5ccccc45)c3)n2)cc1]

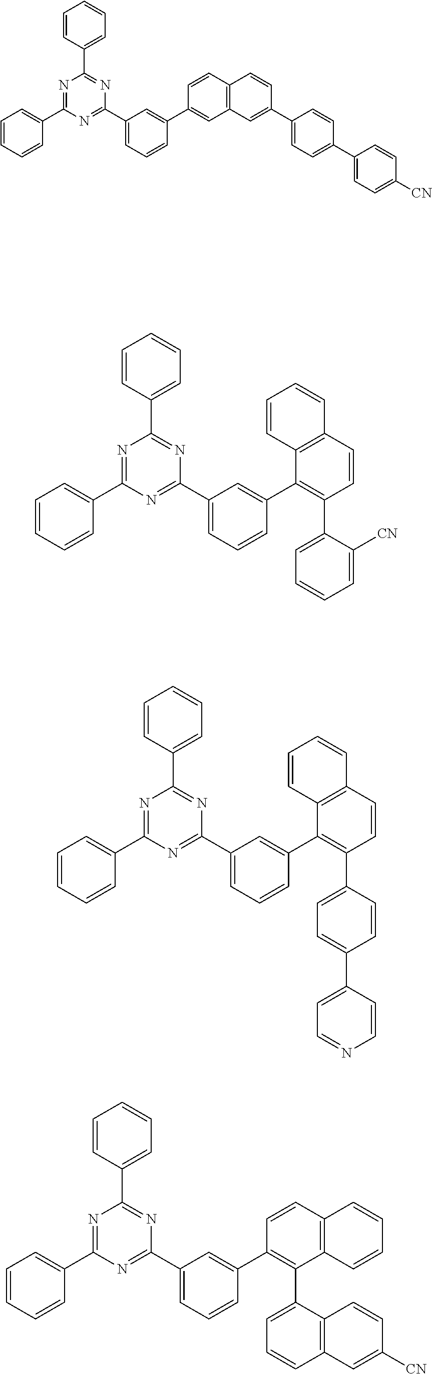 [SMILES: N#Cc1ccc(-c2ccc(-c3ccc4ccc(-c5cccc(-c6nc(-c7ccccc7)nc(-c7ccccc7)n6)c5)cc4c3)cc2)cc1 ; N#Cc1ccccc1-c1ccc2ccccc2c1-c1cccc(-c2nc(-c3ccccc3)nc(-c3ccccc3)n2)c1 ; c1ccc(-c2nc(-c3ccccc3)nc(-c3cccc(-c4c(-c5ccc(-c6ccncc6)cc5)ccc5ccccc45)c3)n2)cc1 ; N#Cc1ccc2c(-c3c(-c4cccc(-c5nc(-c6ccccc6)nc(-c6ccccc6)n5)c4)ccc4ccccc34)cccc2c1]

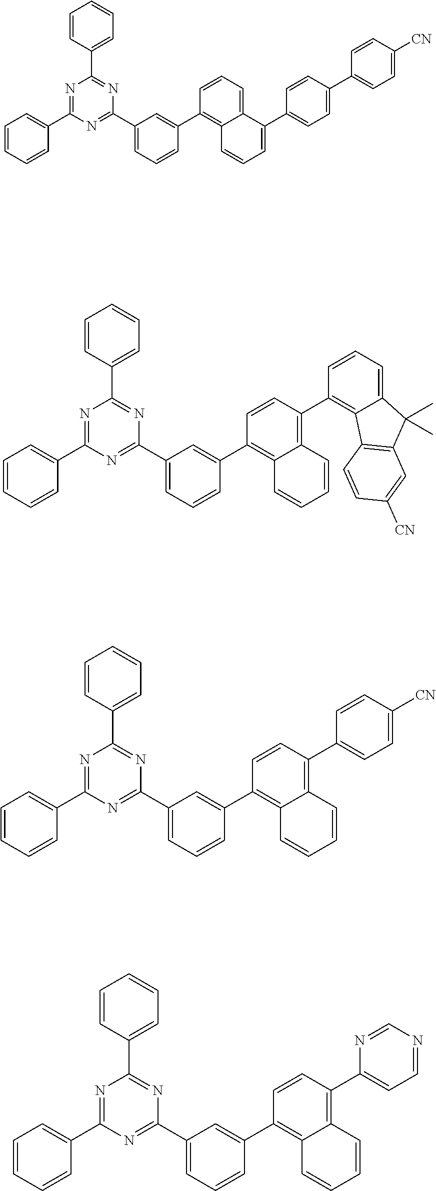 [SMILES: N#Cc1ccc(-c2ccc(-c3cccc4c(-c5cccc(-c6nc(-c7ccccc7)nc(-c7ccccc7)n6)c5)cccc34)cc2)cc1 ; CC1(C)c2cc(C#N)ccc2-c2c(-c3ccc(-c4cccc(-c5nc(-c6ccccc6)nc(-c6ccccc6)n5)c4)c4ccccc34)cccc21 ; N#Cc1ccc(-c2ccc(-c3cccc(-c4nc(-c5ccccc5)nc(-c5ccccc5)n4)c3)c3ccccc23)cc1 ; c1ccc(-c2nc(-c3ccccc3)nc(-c3cccc(-c4ccc(-c5ccncn5)c5ccccc45)c3)n2)cc1]

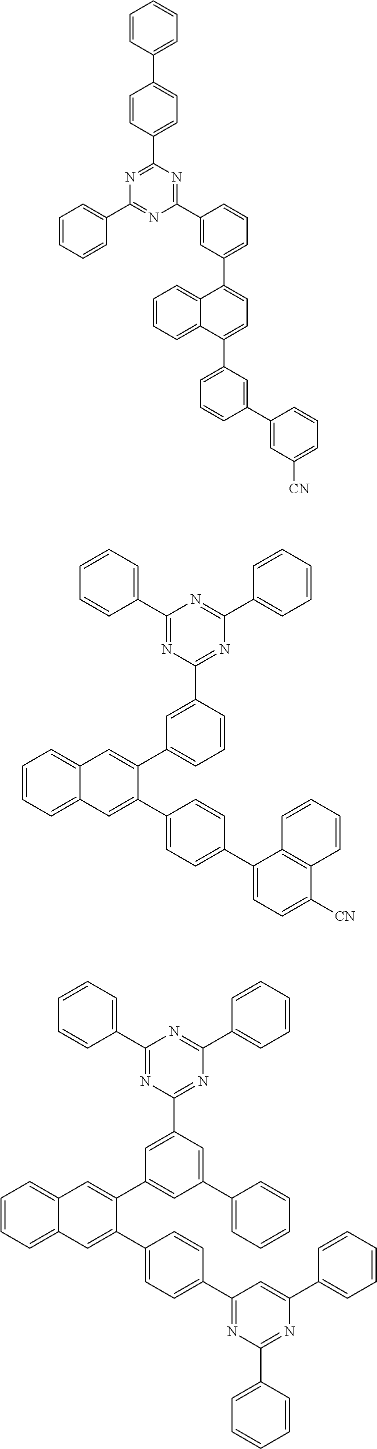 [SMILES: N#Cc1cccc(-c2cccc(-c3ccc(-c4cccc(-c5nc(-c6ccccc6)nc(-c6ccc(-c7ccccc7)cc6)n5)c4)c4ccccc34)c2)c1 ; N#Cc1ccc(-c2ccc(-c3cc4ccccc4cc3-c3cccc(-c4nc(-c5ccccc5)nc(-c5ccccc5)n4)c3)cc2)c2ccccc12 ; c1ccc(-c2cc(-c3nc(-c4ccccc4)nc(-c4ccccc4)n3)cc(-c3cc4ccccc4cc3-c3ccc(-c4cc(-c5ccccc5)nc(-c5ccccc5)n4)cc3)c2)cc1]

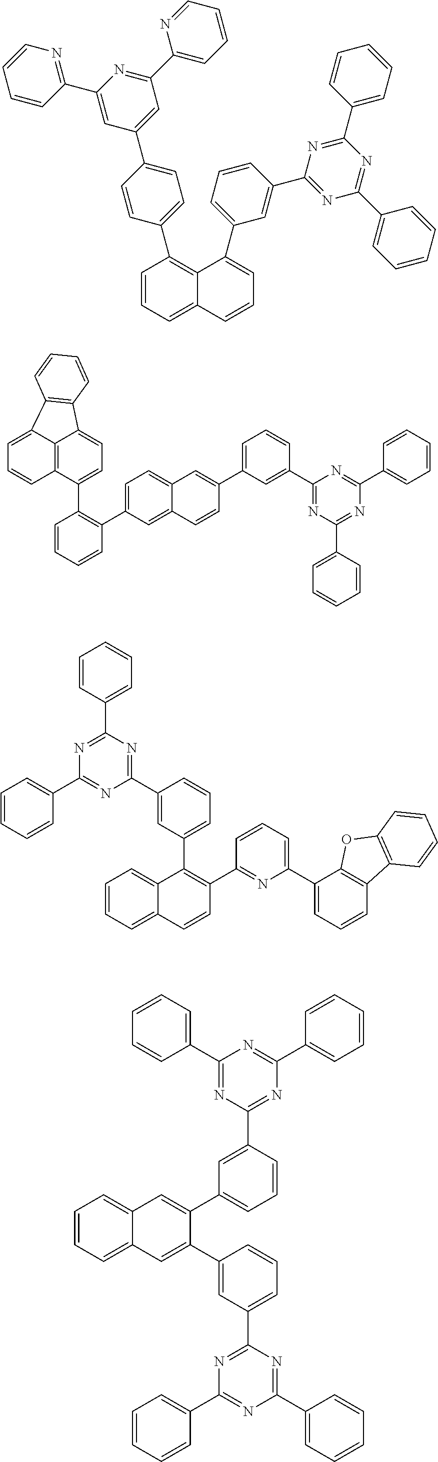 [SMILES: c1ccc(-c2nc(-c3ccccc3)nc(-c3cccc(-c4cccc5cccc(-c6ccc(-c7cc(-c8ccccn8)nc(-c8ccccn8)c7)cc6)c45)c3)n2)cc1 ; c1ccc(-c2nc(-c3ccccc3)nc(-c3cccc(-c4ccc5cc(-c6ccccc6-c6ccc7c8c(cccc68)-c6ccccc6-7)ccc5c4)c3)n2)cc1 ; c1ccc(-c2nc(-c3ccccc3)nc(-c3cccc(-c4c(-c5cccc(-c6cccc7c6oc6ccccc67)n5)ccc5ccccc45)c3)n2)cc1 ; c1ccc(-c2nc(-c3ccccc3)nc(-c3cccc(-c4cc5ccccc5cc4-c4cccc(-c5nc(-c6ccccc6)nc(-c6ccccc6)n5)c4)c3)n2)cc1]

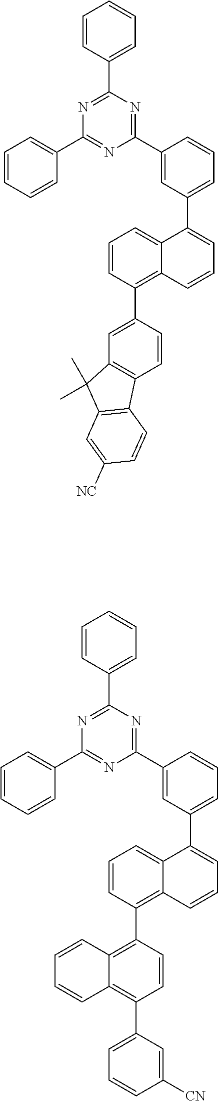 [SMILES: CC1(C)c2cc(C#N)ccc2-c2ccc(-c3cccc4c(-c5cccc(-c6nc(-c7ccccc7)nc(-c7ccccc7)n6)c5)cccc34)cc21 ; N#Cc1cccc(-c2ccc(-c3cccc4c(-c5cccc(-c6nc(-c7ccccc7)nc(-c7ccccc7)n6)c5)cccc34)c3ccccc23)c1]

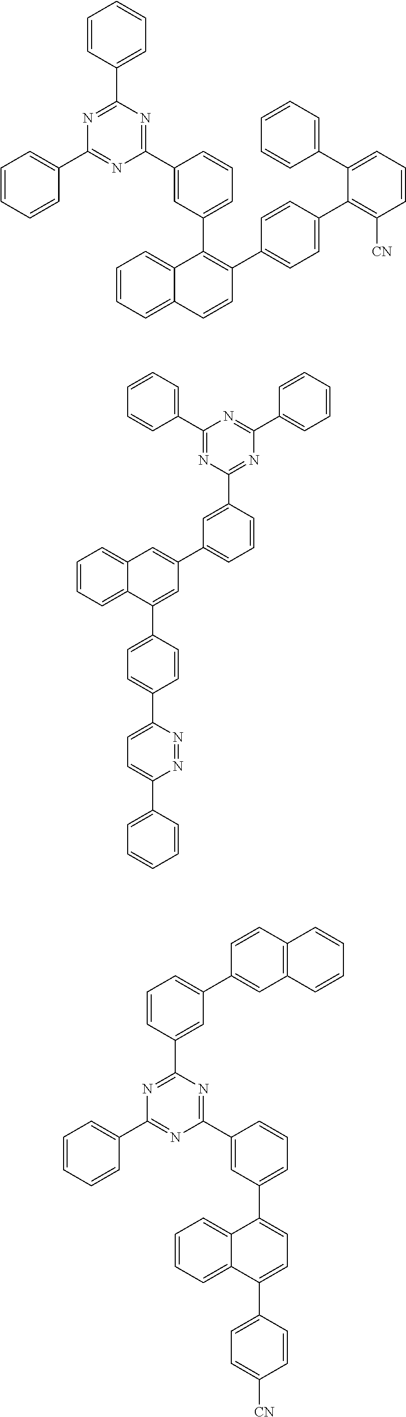 [SMILES: N#Cc1cccc(-c2ccccc2)c1-c1ccc(-c2ccc3ccccc3c2-c2cccc(-c3nc(-c4ccccc4)nc(-c4ccccc4)n3)c2)cc1 ; c1ccc(-c2ccc(-c3ccc(-c4cc(-c5cccc(-c6nc(-c7ccccc7)nc(-c7ccccc7)n6)c5)cc5ccccc45)cc3)nn2)cc1 ; N#Cc1ccc(-c2ccc(-c3cccc(-c4nc(-c5ccccc5)nc(-c5cccc(-c6ccc7ccccc7c6)c5)n4)c3)c3ccccc23)cc1]

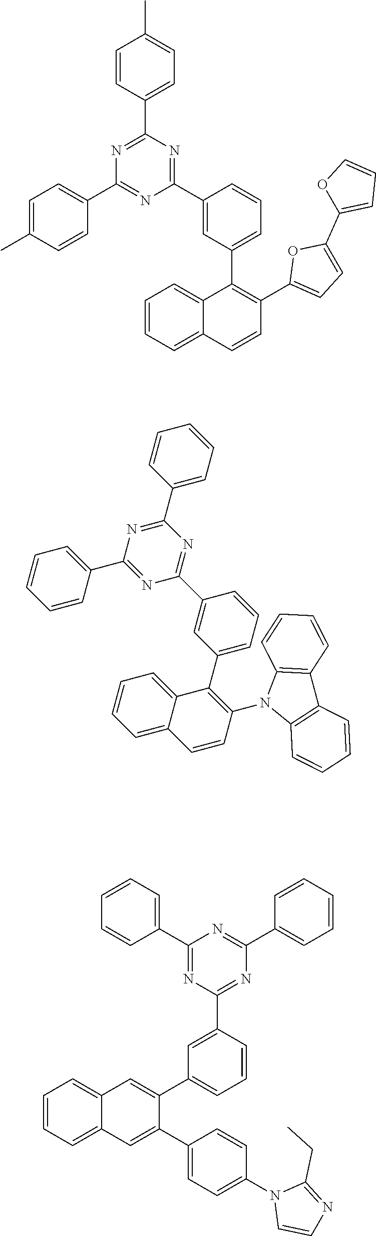 [SMILES: Cc1ccc(-c2nc(-c3ccc(C)cc3)nc(-c3cccc(-c4c(-c5ccc(-c6ccco6)o5)ccc5ccccc45)c3)n2)cc1 ; c1ccc(-c2nc(-c3ccccc3)nc(-c3cccc(-c4c(-n5c6ccccc6c6ccccc65)ccc5ccccc45)c3)n2)cc1 ; CCc1nccn1-c1ccc(-c2cc3ccccc3cc2-c2cccc(-c3nc(-c4ccccc4)nc(-c4ccccc4)n3)c2)cc1]

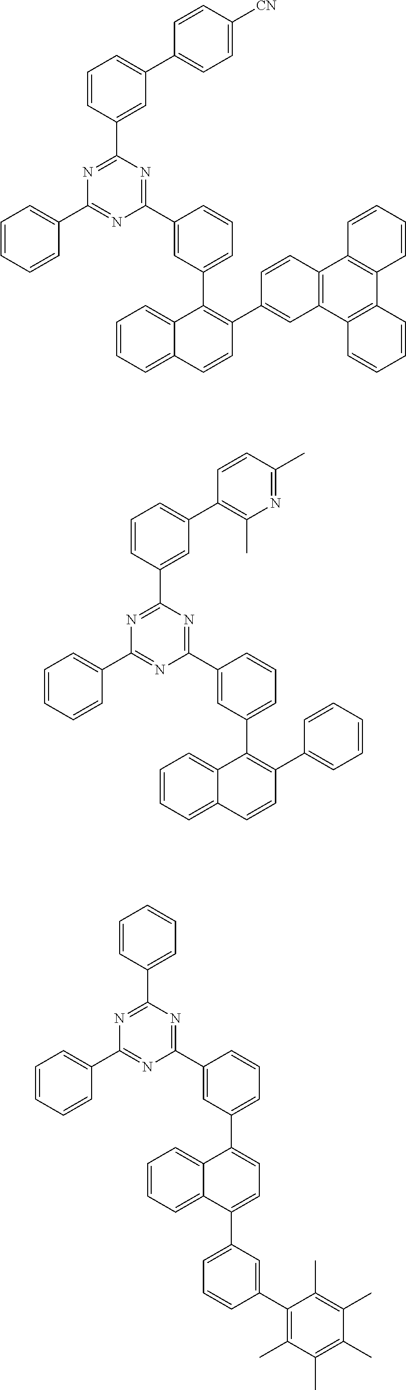 [SMILES: N#Cc1ccc(-c2cccc(-c3nc(-c4ccccc4)nc(-c4cccc(-c5c(-c6ccc7c8ccccc8c8ccccc8c7c6)ccc6ccccc56)c4)n3)c2)cc1 ; Cc1ccc(-c2cccc(-c3nc(-c4ccccc4)nc(-c4cccc(-c5c(-c6ccccc6)ccc6ccccc56)c4)n3)c2)c(C)n1 ; Cc1c(C)c(C)c(-c2cccc(-c3ccc(-c4cccc(-c5nc(-c6ccccc6)nc(-c6ccccc6)n5)c4)c4ccccc34)c2)c(C)c1C]

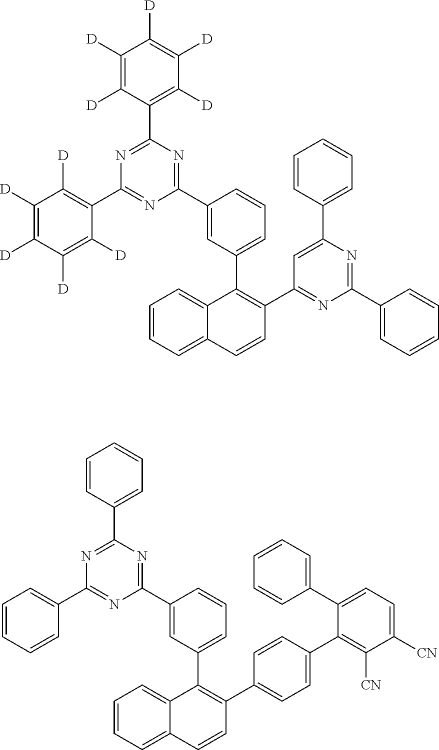 [SMILES: [2H]c1c([2H])c([2H])c(-c2nc(-c3cccc(-c4c(-c5cc(-c6ccccc6)nc(-c6ccccc6)n5)ccc5ccccc45)c3)nc(-c3c([2H])c([2H])c([2H])c([2H])c3[2H])n2)c([2H])c1[2H] ; N#Cc1ccc(-c2ccccc2)c(-c2ccc(-c3ccc4ccccc4c3-c3cccc(-c4nc(-c5ccccc5)nc(-c5ccccc5)n4)c3)cc2)c1C#N]

Further, the present disclosure provides a method for preparing the compound represented by Chemical Formula 3 as shown in the following Reaction Scheme 3.

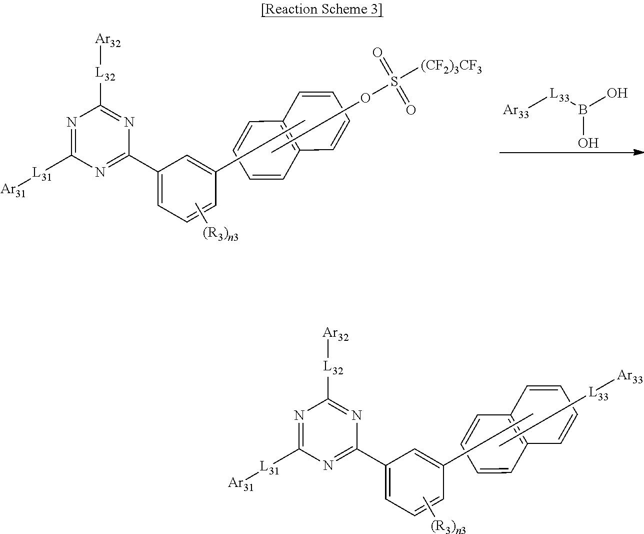

The above reaction is a Suzuki coupling reaction which is preferably carried out in the presence of a palladium catalyst and a base, and a reactive group for the Suzuki coupling reaction can be modified as known in the art. The above preparation method can be further embodied in Preparation Examples described hereinafter.

Further, the electron transport layer may further include a metal complex compound. Examples of the metal complex compound include 8-hydroxyquinolinato lithium, bis(8-hydroxyquinolinato)zinc, bis(8-hydroxyquinolinato)copper, bis(8-hydroxyquinolinato)manganese, tris(8-hydroxyquinolinato)aluminum, tris(2-methyl-8-hydroxyquinolinato)aluminum, tris(8-hydroxyquinolinato)gallium, bis(10-hydroxybenzo[h]quinolinato)beryllium, bis(10-hydroxybenzo[h]quinolinato)zinc, bis(2-methyl-8-quinolinato)chlorogallium, bis(2-methyl-8-quinolinato)(o-cresolato)gallium, bis(2-methyl-8-quinolinato)(1-naphtholato)aluminum, bis(2-methyl-8-quinolinato)(2-naphtholato)gallium, and the like, but are not limited thereto.

Electron Injection Layer

The organic light emitting device according to the present disclosure may further include an electron injection layer between the electron transport layer and the cathode, if necessary.

The electron injection layer is a layer which injects electrons from an electrode, and is preferably a compound which has a capability of transporting electrons, has an effect of injecting electrons from a cathode and an excellent effect of injecting electrons into a light emitting layer or a light emitting material, prevents excitons produced from the light emitting layer from moving to a hole injection layer, and is also excellent in the ability to form a thin film.

Specific examples of the materials that can be used as the electron injection layer include fluorenone, anthraquinodimethane, diphenoquinone, thiopyran dioxide, oxazole, oxadiazole, triazole, imidazole, perylenetetracarboxylic acid, fluorenylidene methane, anthrone, and the like, and derivatives thereof, a metal complex compound, a nitrogen-containing 5-membered ring derivative, and the like, but are not limited thereto.

Examples of the metal complex compound include 8-hydroxyquinolinato lithium, bis(8-hydroxyquinolinato)zinc, bis(8-hydroxyquinolinato)copper, bis(8-hydroxyquinolinato)manganese, tris(8-hydroxyquinolinato)aluminum, tris(2-methyl-8-hydroxyquinolinato)aluminum, tris(8-hydroxyquinolinato)gallium, bis(10-hydroxybenzo[h]quinolinato)beryllium, bis(10-hydroxybenzo[h]quinolinato)zinc, bis(2-methyl-8-quinolinato)chlorogallium, bis(2-methyl-8-quinolinato)(o-cresolato)gallium, bis(2-methyl-8-quinolinato)(1-naphtholato)aluminum, bis(2-methyl-8-quinolinato)(2-naphtholato)gallium, and the like, but are not limited thereto.

Organic Light Emitting Device

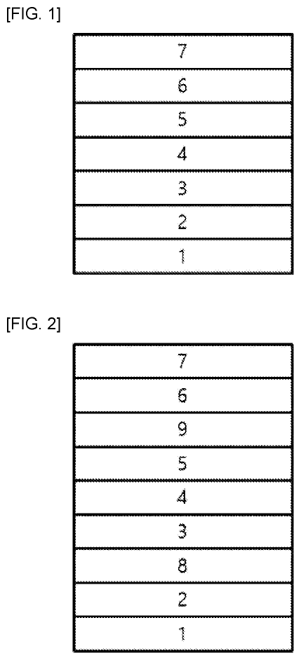

The structure of the organic light emitting device according to the present disclosure is illustrated in FIG. 1.

FIG. 1 shows an example of an organic light emitting device comprising a substrate 1, an anode 2, a hole transport layer 3, an electron blocking layer 4, a light emitting layer 5, an electron transport layer 6, and a cathode 7. In addition, FIG. 2 shows an example of an organic light emitting device comprising a substrate 1, an anode 2, a hole injection layer 8, a hole transport layer 3, an electron blocking layer 4, a light emitting layer 5, a hole blocking layer 9, an electron transport layer 6, and a cathode 7.

The organic light emitting device according to the present disclosure can be manufactured by sequentially stacking the above-described structures. In this case, the organic light emitting device may be manufactured by depositing a metal, metal oxides having conductivity, or an alloy thereof on the substrate by using a PVD (physical vapor deposition) method such as a sputtering method or an e-beam evaporation method to form the anode, forming the respective layers described above thereon, and then depositing a material that can be used as the cathode thereon. In addition to such a method, the organic light emitting device can be manufactured by sequentially depositing from the cathode material to the anode material on a substrate in the reverse order of the above-mentioned configuration (WO 2003/012890). Further, the light emitting layer may be formed by subjecting a host and a dopant to a vacuum deposition method and a solution coating method. Herein, the solution coating method means a spin coating, a dip coating, a doctor blading, an inkjet printing, a screen printing, a spray method, a roll coating, or the like, but is not limited thereto.

On the other hand, the organic light emitting device according to the present disclosure may be a front side emission type, a back side emission type, or a double-sided emission type according to the used material.

Hereinafter, preferred examples are presented to assist in the understanding of the present disclosure. However, the following examples are only provided for a better understanding of the present disclosure, and is not intended to limit the content of the present disclosure.

### PREPARATION EXAMPLE

### Preparation Example 1-1: Preparation of Compound EBL-1

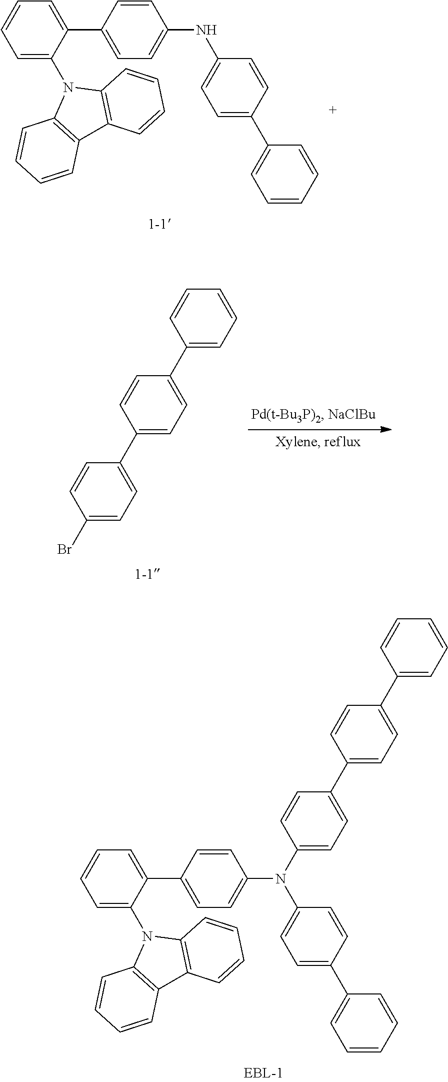 [SMILES: c1ccc(-c2ccc(Nc3ccc(-c4ccccc4-n4c5ccccc5c5ccccc54)cc3)cc2)cc1 ; Brc1ccc(-c2ccc(-c3ccccc3)cc2)cc1 ; c1ccc(-c2ccc(-c3ccc(N(c4ccc(-c5ccccc5)cc4)c4ccc(-c5ccccc5-n5c6ccccc6c6ccccc65)cc4)cc3)cc2)cc1]

Compound 1-1′ (14.34 g, 29.51 mmol) and Compound 1-1″ (8.29 g, 26.83 mmol) were completely dissolved in tetrahydrofuran (240 mL) in a 500 mL round bottom flask under a nitrogen atmosphere, to which 2M potassium carbonate aqueous solution (120 mL) was added and Pd(t-Bu₃P)₂ (0.25 g, 0.49 mmol) was added, and then the resulting mixture was heated and stirred for 5 hours. The temperature was lowered to normal temperature, the aqueous layer was removed, and the resulting product was dried over anhydrous magnesium sulfate, then concentrated under reduced pressure, and recrystallized with ethylacetate (370 mL) to give Compound EBL-1 (11.69 g, yield: 61%).

MS[M+H]⁺=715

### Preparation Example 1-2: Preparation of Compound EBL-2

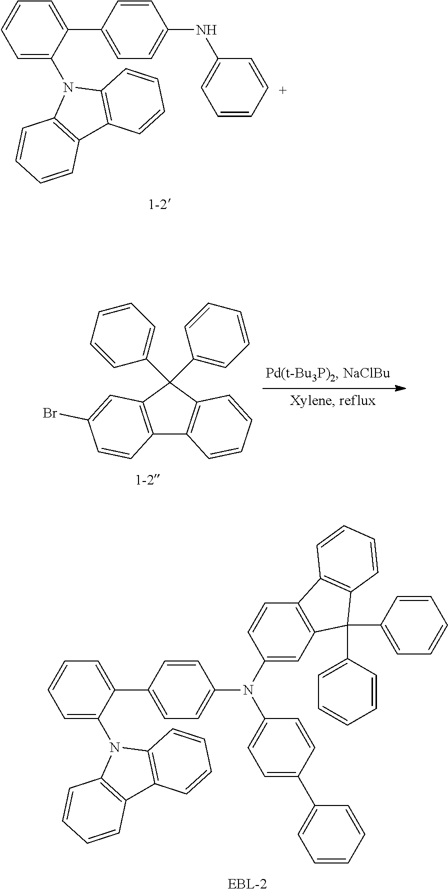 [SMILES: [C+]1=CC(Nc2ccc(-c3ccccc3-n3c4ccccc4c4ccccc43)cc2)=CC=C1 ; Brc1ccc2c(c1)C(c1ccccc1)(c1ccccc1)c1ccccc1-2 ; c1ccc(-c2ccc(N(c3ccc(-c4ccccc4-n4c5ccccc5c5ccccc54)cc3)c3ccc4c(c3)C(c3ccccc3)(c3ccccc3)c3ccccc3-4)cc2)cc1]

Compound 1-2′ (8.61 g, 20.95 mmol) and Compound 1-2″ (7.56 g, 19.04 mmol) were completely dissolved in tetrahydrofuran (240 mL) in a 500 mL round bottom flask under a nitrogen atmosphere, to which 2M potassium carbonate aqueous solution (120 mL) was added and Pd(t-Bu₃P)₂ (0.19 g, 0.38 mmol) was added, and then the resulting mixture was heated and stirred for 5 hours. The temperature was lowered to normal temperature, the aqueous layer was removed, and the resulting product was dried over anhydrous magnesium sulfate, then concentrated under reduced pressure, and recrystallized from ethylacetate (350 mL) to give Compound EBL-2 (10.88 g, yield: 71%).

MS[M+H]⁺=803

### Preparation Example 1-3: Preparation of Compound EBL-3

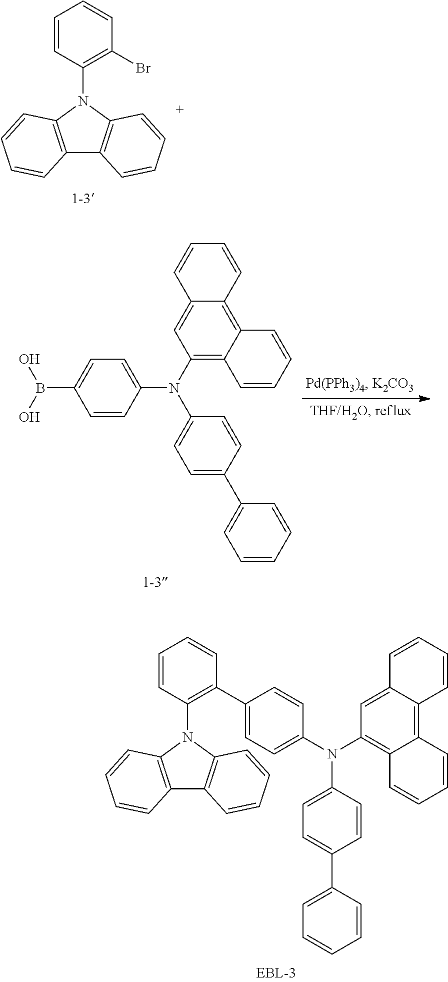 [SMILES: Brc1ccccc1-n1c2ccccc2c2ccccc21 ; OB(O)c1ccc(N(c2ccc(-c3ccccc3)cc2)c2cc3ccccc3c3ccccc23)cc1 ; c1ccc(-c2ccc(N(c3ccc(-c4ccccc4-n4c5ccccc5c5ccccc54)cc3)c3cc4ccccc4c4ccccc34)cc2)cc1]

Compound 1-3′ (5.78 g, 17.95 mmol) and Compound 1-3″ (9.60 g, 20.64 mmol) were completely dissolved in tetrahydrofuran (240 mL) in a 500 mL round bottom flask under a nitrogen atmosphere, to which 2M potassium carbonate aqueous solution (120 mL) was added and tetrakis-(triphenylphosphine)palladium (0.62 g, 0.54 mmol) was added, and then the resulting mixture was heated and stirred for 5 hours. The temperature was lowered to normal temperature, the aqueous layer was removed, and the resulting product was dried over anhydrous magnesium sulfate, then concentrated under reduced pressure, and recrystallized with ethylacetate (350 mL) to give Compound EBL-3 (7.78 g, yield: 65%).

MS[M+H]⁺=663

### Preparation Example 14: Preparation of Compound EBL-4

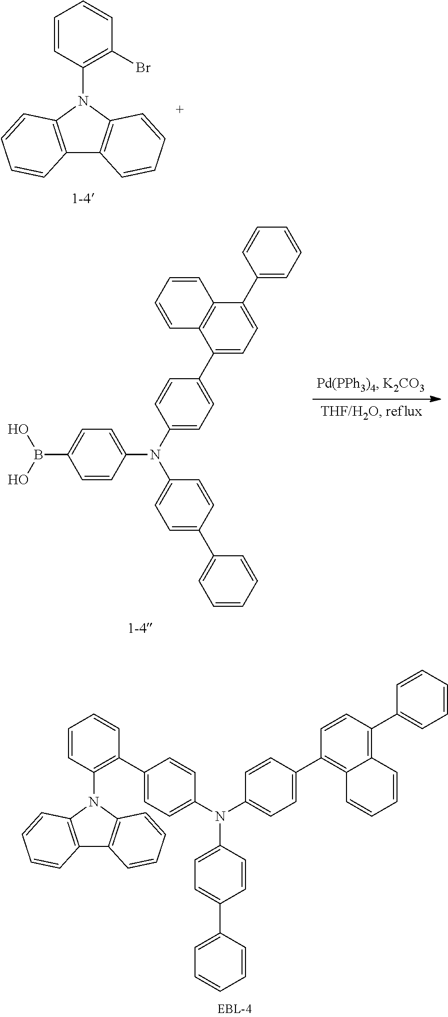 [SMILES: Brc1ccccc1-n1c2ccccc2c2ccccc21 ; OB(O)c1ccc(N(c2ccc(-c3ccccc3)cc2)c2ccc(-c3ccc(-c4ccccc4)c4ccccc34)cc2)cc1 ; c1ccc(-c2ccc(N(c3ccc(-c4ccccc4-n4c5ccccc5c5ccccc54)cc3)c3ccc(-c4ccc(-c5ccccc5)c5ccccc45)cc3)cc2)cc1]

Compound 1-4′ (6.11 g, 18.98 mmol) and Compound 1-4″ (12.37 g, 21.82 mmol) were completely dissolved in tetrahydrofuran (240 mL) in a 500 mL round bottom flask under a nitrogen atmosphere, to which 2M potassium carbonate aqueous solution (120 mL) was added and tetrakis-(triphenylphosphine)palladium (0.66 g, 0.57 mmol) was added, and then the resulting mixture was heated and stirred for 4 hours. The temperature was lowered to normal temperature, the aqueous layer was removed, and the resulting product was dried over anhydrous magnesium sulfate, then concentrated under reduced pressure, and recrystallized from ethylacetate (350 mL) to give Compound EBL-4 (8.95 g, yield: 62%).

MS[M+H]⁺=765

### Preparation Example 1-5: Preparation of Compound EBL-5

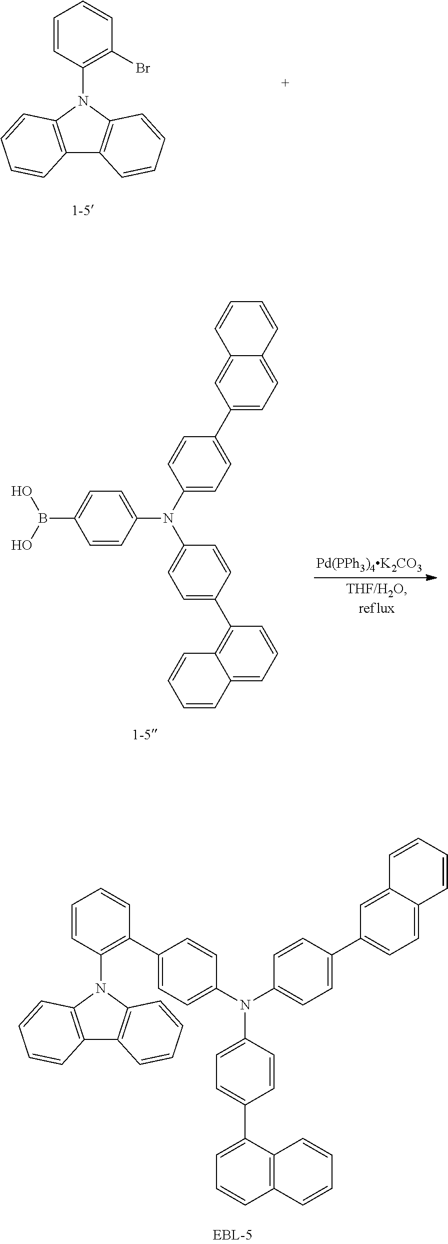 [SMILES: Brc1ccccc1-n1c2ccccc2c2ccccc21 ; OB(O)c1ccc(N(c2ccc(-c3ccc4ccccc4c3)cc2)c2ccc(-c3cccc4ccccc34)cc2)cc1 ; c1ccc(-n2c3ccccc3c3ccccc32)c(-c2ccc(N(c3ccc(-c4ccc5ccccc5c4)cc3)c3ccc(-c4cccc5ccccc45)cc3)cc2)c1]

Compound 1-5′ (6.53 g, 20.28 mmol) and Compound 1-5″ (12.66 g, 23.32 mmol) were completely dissolved in tetrahydrofuran (240 mL) in a 500 mL round bottom flask under a nitrogen atmosphere, to which 2M potassium carbonate aqueous solution (120 mL) was added and tetrakis-(triphenylphosphine)palladium (0.70 g, 0.61 mmol) was added, and then the resulting mixture was heated and stirred for 3 hours. The temperature was lowered to normal temperature, the aqueous layer was removed, and the resulting product was dried over anhydrous magnesium sulfate, then concentrated under reduced pressure, and recrystallized from ethylacetate (280 mL) to give Compound EBL-5 (9.98 g, yield: 67%).

MS[M+H]⁺=739

### Preparation Example 2-1: Preparation of Compound HOST-1

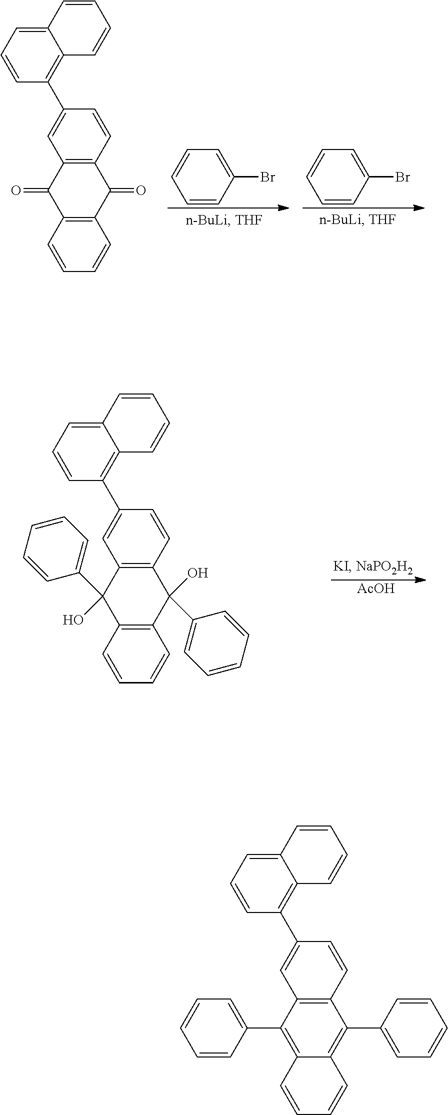

Phenyl bromide (1 eq) was dissolved in tetrahydrofuran under a nitrogen atmosphere, and then n-BuLi (1.1 eq) was slowly added dropwise at −78° C. After 30 minutes, 2-naphthylanthraquinone (1 eq) was added thereto. When the temperature was raised to room temperature and then the reaction was completed, the mixture was extracted with ethyl acetate and washed with water. The above method was carried out once more using phenyl bromide. After completion of the reaction, the reaction mixture was extracted with ethyl acetate and washed with water. All ethyl acetate was evaporated, and precipitated with hexane to give 2-naphthalene-9,10-phenyl-9,10-dihydroanthracene-9,10-diol as a solid in a yield of 50%.

2-Naphthalene-9,10-phenyl-9,10-dihydroanthracene-9,10-diol (1 eq), KI (3 eq), and NaPO₂H₂ (5 eq) were added to acetic add, and the temperature was raised to 120° C. and the mixture was refluxed. After completion of the reaction, an excessive amount of water was poured and the resulting solid was filtered. The filtrate was dissolved in ethyl acetate, extracted, washed with water, and recrystallized from toluene to give Compound HOST-1 in a yield of 70%.

MS[M+H]⁺=456.5

### Preparation Example 2-2: Preparation of Compound HOST-2

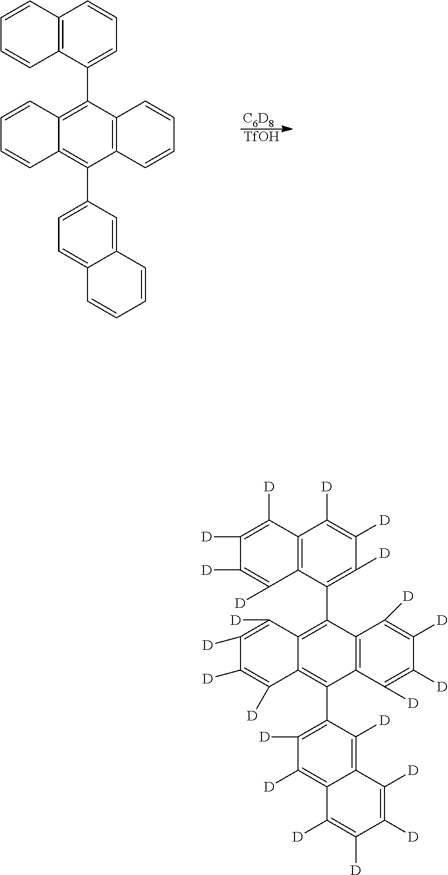

9-(Naphthalen-1-yl)-10-(naphthalen-2-yl)anthracene (20 g), and trifluoromethanesulfonic acid (2 g) were added to C₆D₆ (500 mL), and the mixture was stirred at 70° C. for 2 hours. After completion of the reaction, D₂O (60 mL) was added thereto, the mixture was stirred for 30 minutes, and then trimethylamine (6 mL) was added dropwise. The reaction solution was transferred to a reparatory funnel, and extracted with water and toluene. The extract was dried over MgSO₄ and recrystallized from ethyl acetate to give Compound HOST-2 in a yield of 64%.

MS[M+H]⁺=448˜452

Preparation 2-3: Preparation of Compound HOST-3

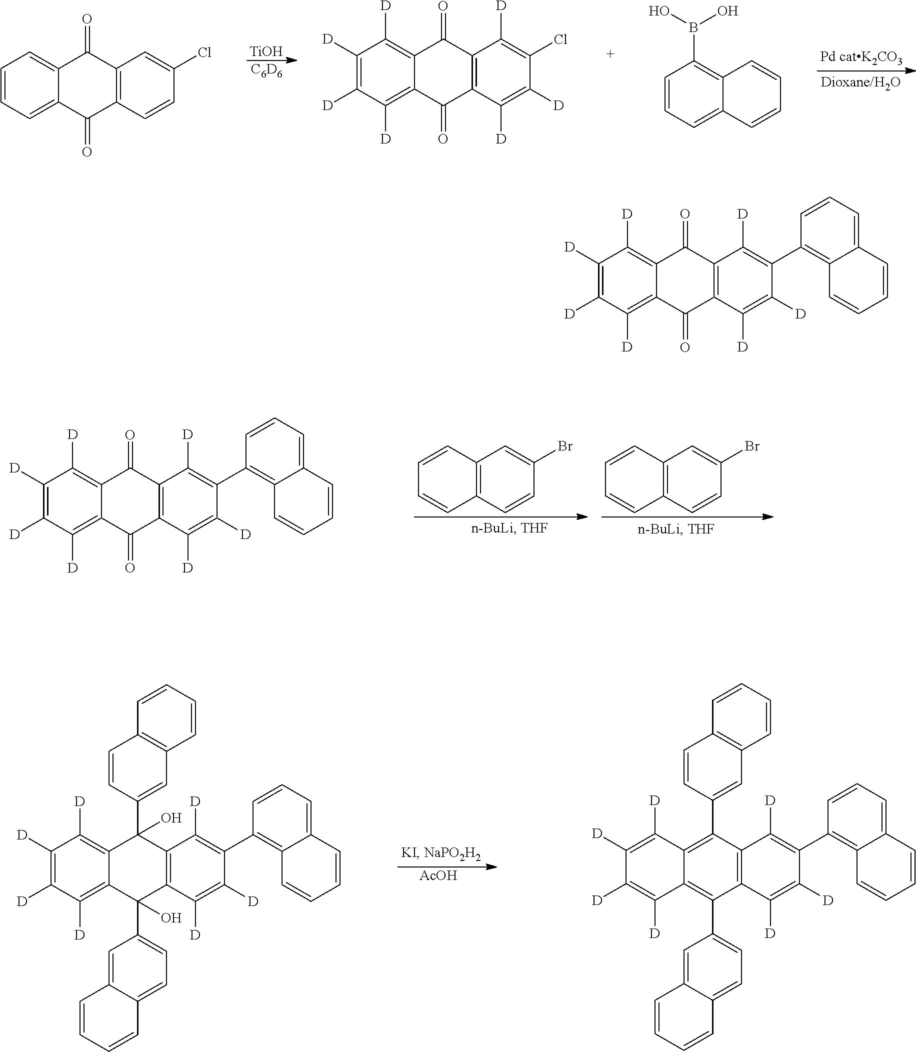

2-Chloroanthraquinone (20 g) and trifluoromethanesulfonic acid (2 g) were added to C₆D₆ (500 mL), and the mixture was stirred at 70° C. for 2 hours. After completion of the reaction, D₂O (60 mL) was added, the mixture was stirred for 30 minutes, and then trimethylamine (6 mL) was added dropwise. The reaction solution was transferred to a reparatory funnel, and extracted with water and toluene. The extract was dried over MgSO₄ and recrystallized from ethyl acetate to give 2-chloroanthraquinone-d7 (yield: 44%).

MS[M+H]⁺=250.7

2-Chloroanthraquinone-d7 (10 g) and 1-naphthaleneboronic acid (7.6 g) were placed in a round bottom flask and dissolved in dioxane (500 mL). K₂CO₃ (20 g) was dissolved in distilled water (30 mL), added thereto, and bis(tri-tert-butylphosphine)palladium(0) (40 mg) was added. The mixture was refluxed for 2 hours, cooled and then filtered. The filtered solid was recrystallized from toluene to give 2-(naphthalen-1-yl)anthracene-9,10-dione-d7 (yield: 78%),

MS[M+H]⁺=342.4

2-Naphthyl bromide (1 eq) was dissolved in tetrahydrofuran under a nitrogen atmosphere, and then n-BuLi (1.1 eq) was slowly added dropwise at −73° C. After 30 minutes, 2-(naphthalen-1-yl)anthracene-9,10-dione-d7 (1 eq) was added thereto. When the temperature was raised to room temperature and then the reaction was completed, the mixture was extracted with ethyl acetate and washed with water. The above method was carried out once more using 2-naphthyl bromide. After completion of the reaction, the reaction mixture was extracted with ethyl acetate and washed with water. All ethyl acetate was evaporated, and precipitated with hexane to obtain a solid, and the next reaction proceeded immediately without purification.

The previously obtained Compound (1 eq), KI (3 eq), and NaPO₂H₂ (5 eq) were added to acetic acid, the temperature was raised to 120° C., and the mixture was refluxed. After completion of the reaction, an excessive amount of water was poured and the resulting solid was filtered. The filtrate was dissolved in ethyl acetate, extracted, washed with water, and recrystallized from toluene to give Compound HOST-3 (Yield: 70%).

MS[M+H]⁺=564.7

### Preparation Example 2-4: Preparation of Compound HOST-4

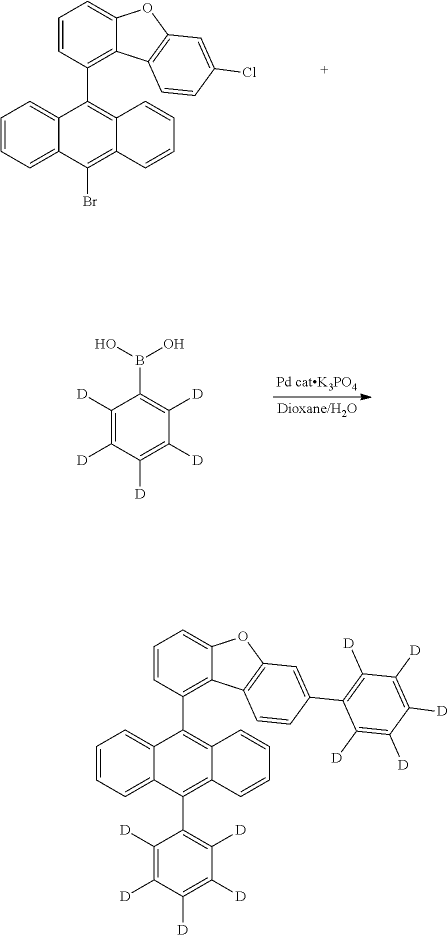 [SMILES: Clc1ccc2c(c1)oc1cccc(-c3c4ccccc4c(Br)c4ccccc34)c12 ; [2H]c1c([2H])c([2H])c(B(O)O)c([2H])c1[2H] ; [2H]c1c([2H])c([2H])c(-c2ccc3c(c2)oc2cccc(-c4c5ccccc5c(-c5c([2H])c([2H])c([2H])c([2H])c5[2H])c5ccccc45)c23)c([2H])c1[2H]]

1-(10-Bromoanthracen-9-yl)-7-chlorodibenzofuran (20 g, 43.7 mmol) and phenylboronic acid-d5 (11.0 g, 87.4 mmol) were added to dioxane (400 mL) under a nitrogen atmosphere, and the mixture was stirred and refluxed. Then, potassium phosphate tribasic (27.8 g, 131.1 mmol) was dissolved in water (28 mL), stirred sufficiently, and then dibenzylideneacetonepalladium (0.8 g, 1.3 mmol) and tricyclohexylphosphine (0.7 g, 2.6 mmol) were added. After the reaction for 5 hours, the reaction mixture was cooled to room temperature and then the resulting solid was filtered. The solid was added to and dissolved in chloroform (664 mL), washed twice with water, the organic layer was separated, anhydrous magnesium sulfate was added thereto, stirred, filtered, and then the filtrate was distilled under reduced pressure. The concentrated compound was recrystallized from chloroform and ethyl acetate to give a solid compound Host-4 (10 g, Yield: 45%) as a greenish powder.

MS: [M+H]⁺=507.7

### Preparation Example 2-5: Preparation of Compound HOST-5

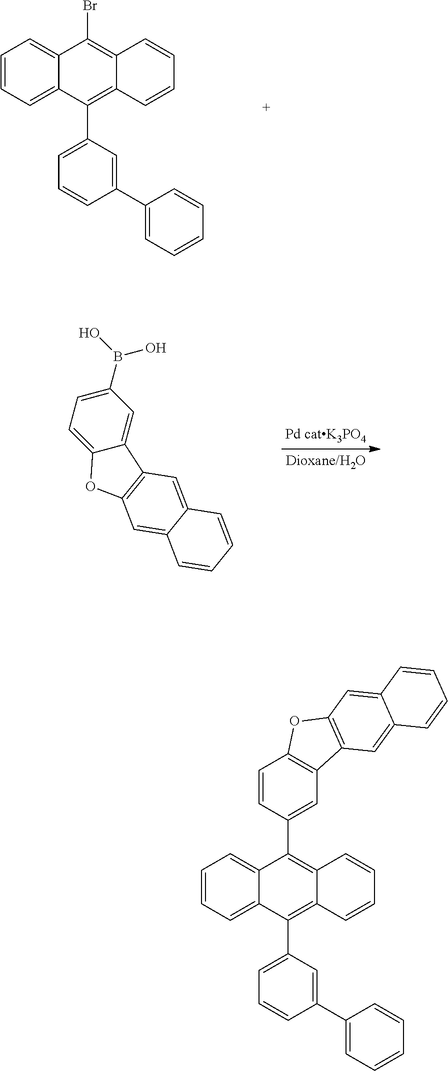 [SMILES: Brc1c2ccccc2c(-c2cccc(-c3ccccc3)c2)c2ccccc12 ; OB(O)c1ccc2oc3cc4ccccc4cc3c2c1 ; c1ccc(-c2cccc(-c3c4ccccc4c(-c4ccc5oc6cc7ccccc7cc6c5c4)c4ccccc34)c2)cc1]

9-([1,1′-biphenyl]-3-yl)-10-bromoanthracene (20 g, 48.9 mmol) and naphtho[b]benzofuran-2-ylboronic acid (12.8 g, 48.9 mmol) were added to dioxane (400 mL) under a nitrogen atmosphere, and the mixture was stirred and refluxed. Then, potassium phosphate tribasic (31.1 g, 146.6 mmol) was dissolved in water (31 mL), added thereto, stirred sufficiently, and then dibenzylideneacetonepalladium (0.8 g, 1.5 mmol) and tricyclohexylphosphine (0.8 g, 2.9 mmol) were added. After the reaction for 9 hours, the reaction mixture was cooled to room temperature and then the resulting solid was filtered. The solid was added to and dissolved in chloroform (801 mL), washed twice with water, the organic layer was separated, anhydrous magnesium sulfate was added thereto, stirred, filtered, and then the filtrate was distilled under reduced pressure. The concentrated compound was recrystallized from chloroform and ethyl acetate to give a solid compound Host-5 (19.8 g, Yield: 74%) as a greenish powder.

MS: [M+H]⁺=547.7

### Preparation Example 2-6: Preparation of Compound HOST-6

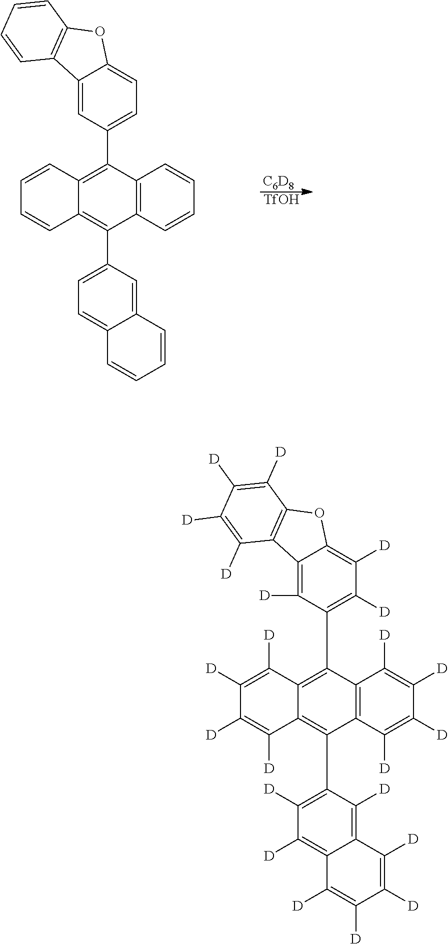

2-(10-(Naphthalen-2-yl)anthracen-9-yl)dibenzo[b,d]furan (20 g) and trifluoromethanesulfonic acid (2 g) were added to C₆D₆ (500 mL), and the mixture was stirred at 70° C. for 2 hours. After completion of the reaction, D₂O (60 mL) was added, the mixture was stirred for 30 minutes, and then trimethylamine (6 mL) was added dropwise. The reaction solution was transferred to a separatory funnel, and extracted with water and toluene. The extract was dried over MgSO₄ and recrystallized from ethyl acetate to give HOST-6 in a yield of 52%.

cal. m/s: 492.71; exp. m/s (M⁺) 458˜492

### Preparation 3-1: Preparation of Compound ETL-1

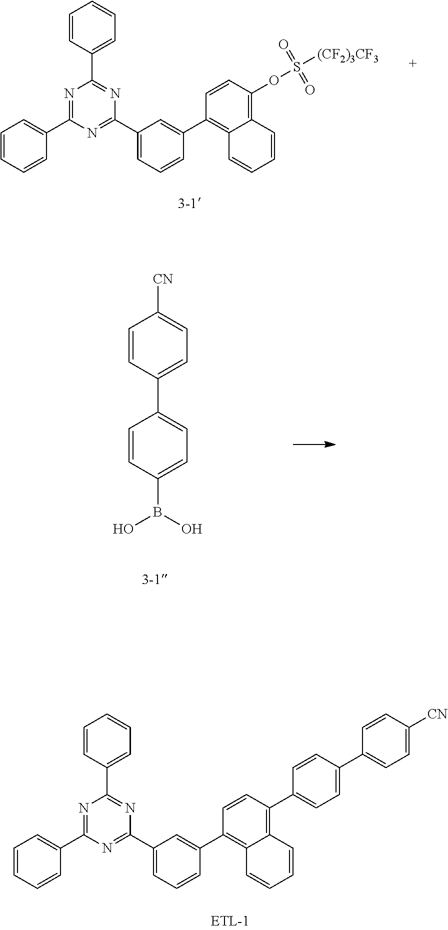

Compound 3-1′ (20 g, 27.3 mmol) and Compound 3-1″(6.1 g, 27.3 mmol) were completely dissolved in THF (200 mL), and potassium carbonate (11.3 g, 81.8 mmol) was dissolved in water (50 mL) and added thereto. Tetrakistriphenyl-phosphinopalladium (0.95 g, 0.818 mmol) was added and then the mixture was heated and stirred for 8 hours. After the temperature was lowered to room temperature and the reaction was completed, a potassium carbonate solution was removed and the white solid was filtered. The filtered white solid was washed twice with THF and ethyl acetate. respectively, to give Compound ETL-1 (11.9 g, Yield: 71%).

MS[M+H]⁺=613

### Preparation 3-2: Preparation of Compound ETL-2

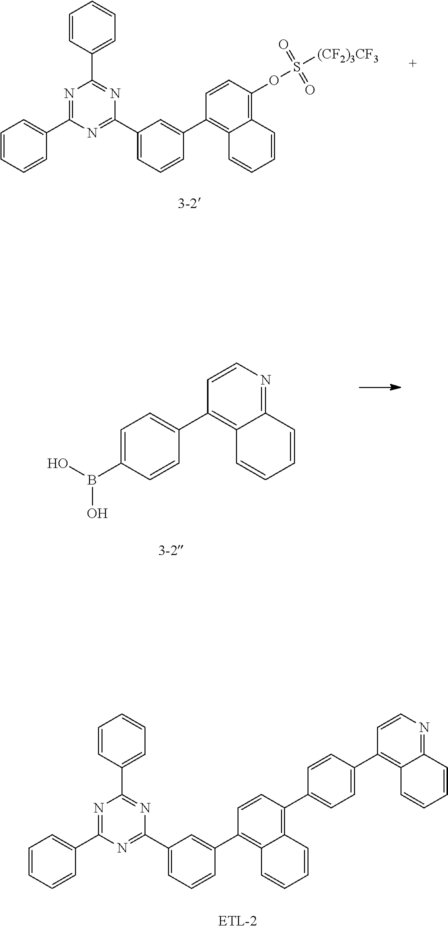

Compound ETL-2 was prepared in the same manner as in the preparation method of Compound ETL-1 of Preparation Example 3-1, except that each starting material was used as in the above Reaction Scheme.

MS[M+H]⁺=639

### Preparation Example 3-3: Preparation of Compound ETL-3

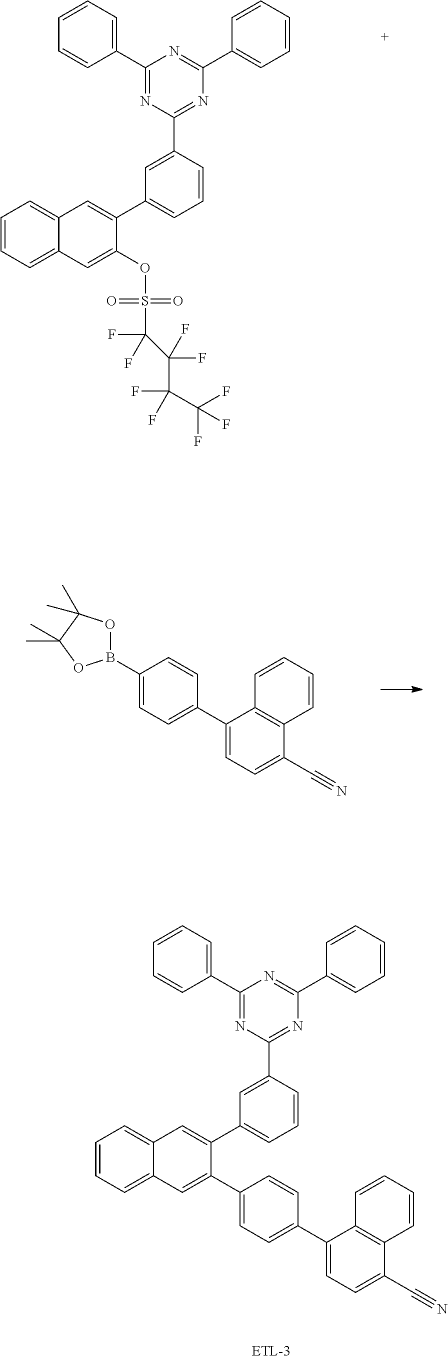 [SMILES: O=S(=O)(Oc1cc2ccccc2cc1-c1cccc(-c2nc(-c3ccccc3)nc(-c3ccccc3)n2)c1)C(F)(F)C(F)(F)C(F)(F)C(F)(F)F ; CC1(C)OB(c2ccc(-c3ccc(C#N)c4ccccc34)cc2)OC1(C)C ; N#Cc1ccc(-c2ccc(-c3cc4ccccc4cc3-c3cccc(-c4nc(-c5ccccc5)nc(-c5ccccc5)n4)c3)cc2)c2ccccc12]

Compound ETL-3 was prepared in the same manner as in the preparation method of Compound ETL-1 of Preparation Example 3-1, except that each starting material was used as in the above Reaction Scheme.

MS[M+H]⁺=663

### Preparation Example 34: Preparation of Compound ETL-4

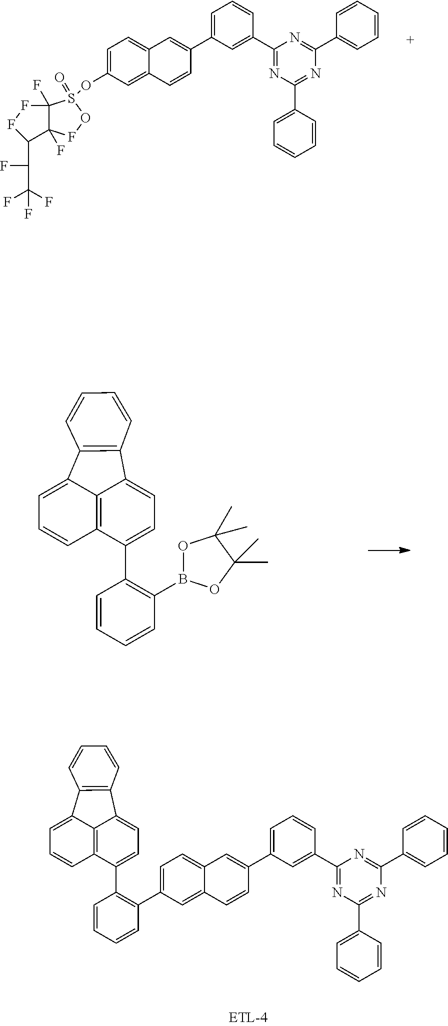

Compound ETL-4 was prepared in the same manner as in the preparation method of Compound ETL-1 of Preparation Example 3-1, except that each starting material was used as in the above Reaction Scheme.

MS[M+H]⁺=712

### Preparation Example 3-5: Preparation of Compound ETL-5

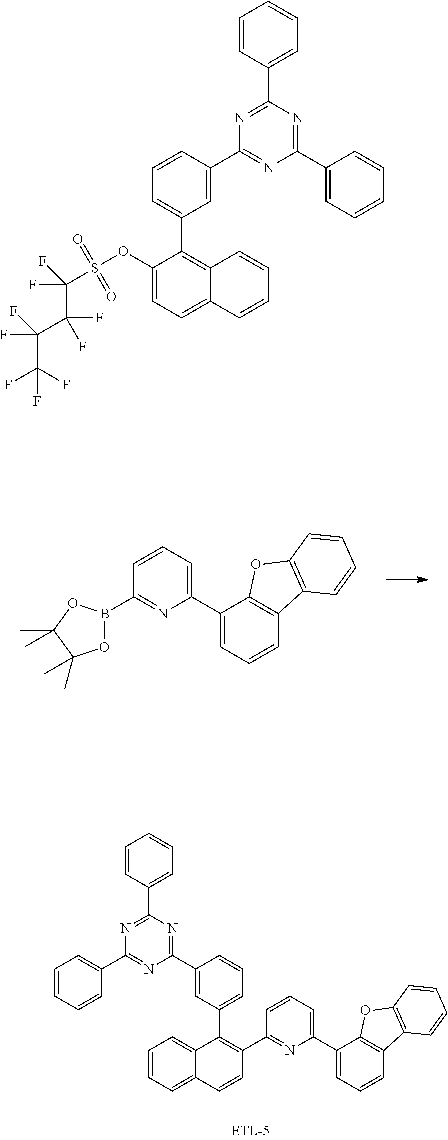 [SMILES: O=S(=O)(Oc1ccc2ccccc2c1-c1cccc(-c2nc(-c3ccccc3)nc(-c3ccccc3)n2)c1)C(F)(F)C(F)(F)C(F)(F)C(F)(F)F ; CC1(C)OB(c2cccc(-c3cccc4c3oc3ccccc34)n2)OC1(C)C ; c1ccc(-c2nc(-c3ccccc3)nc(-c3cccc(-c4c(-c5cccc(-c6cccc7c6oc6ccccc67)n5)ccc5ccccc45)c3)n2)cc1]

Compound ETL-5 was prepared in the same manner as in the preparation method of Compound ETL-1 of Preparation Example 3-1, except that each starting material was used as in the above Reaction Scheme.

MS[M+H]⁺=679

### Preparation Example 3-6: Preparation of Compound ETL-6

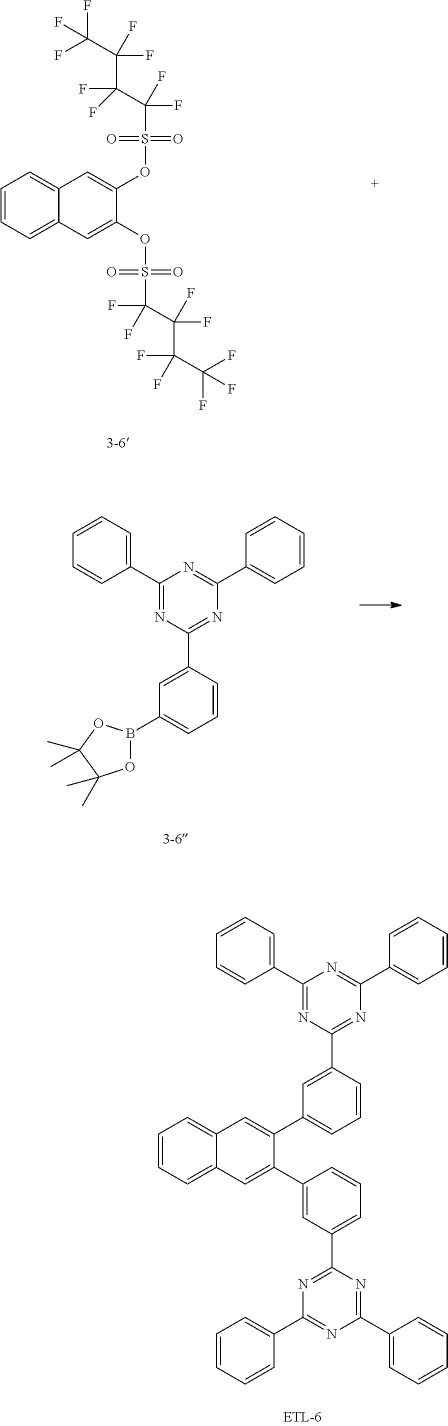 [SMILES: O=S(=O)(Oc1cc2ccccc2cc1OS(=O)(=O)C(F)(F)C(F)(F)C(F)(F)C(F)(F)F)C(F)(F)C(F)(F)C(F)(F)C(F)(F)F ; CC1(C)OB(c2cccc(-c3nc(-c4ccccc4)nc(-c4ccccc4)n3)c2)OC1(C)C ; c1ccc(-c2nc(-c3ccccc3)nc(-c3cccc(-c4cc5ccccc5cc4-c4cccc(-c5nc(-c6ccccc6)nc(-c6ccccc6)n5)c4)c3)n2)cc1]

Compound 3-6′ (20 g, 27.6 mmol) and Compound 3-6″ (24 g, 55.2 mmol) were added to tetrahydrofuran (400 mL) under a nitrogen atmosphere, and the mixture was stirred and refluxed. Then, potassium carbonate (11.4 g, 82.8 mmol) was dissolved in water (11 mL), added thereto, stirred sufficiently, and then tetrakistriphenyl-phosphinopalladium (1 g, 0.8 mmol) was added. After the reaction for 1 hour, the reaction mixture was cooled to room temperature, the organic layer and the aqueous layer were separated, and then the organic layer was distilled. This was added to and dissolved in chloroform (410 mL), washed twice with water, and the organic layer was separated. Anhydrous magnesium sulfate was added, and the mixture was stirred, filtered, and the filtrate was distilled under reduced pressure. The concentrated compound was recrystallized from chloroform and ethyl acetate to give a white solid compound ETL-6 (11.9 g, Yield: 58%).

MS[M+H]⁺=743

### Preparation Example 3-7: Preparation of Compound ETL-7

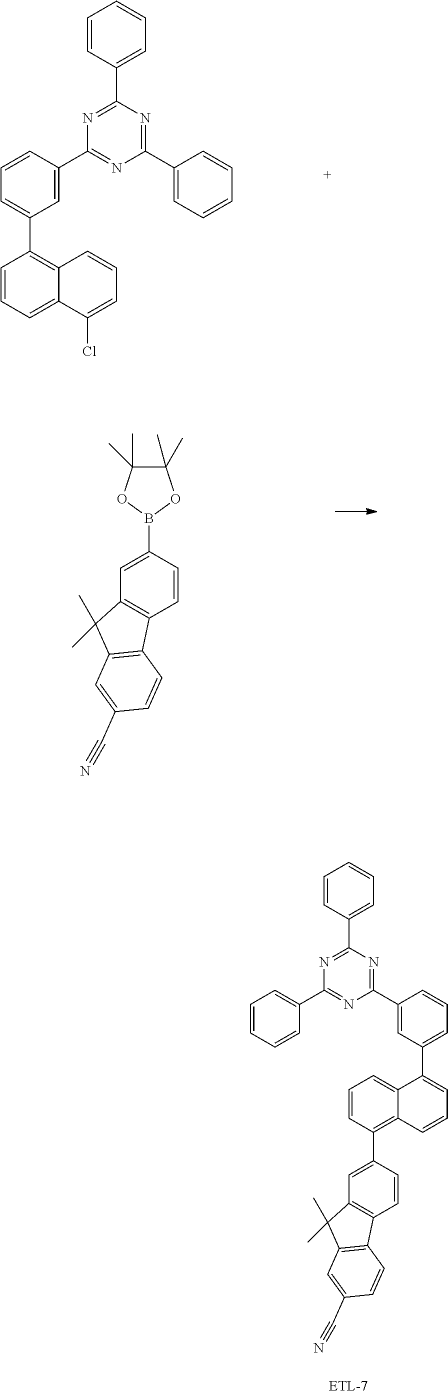

Compound ETL-7 was prepared in the same manner as in the preparation method of Compound ETL-1 of Preparation Example 3-1, except that each starting material was used as in the above Reaction Scheme.

MS[M+H]⁺=653

### Preparation Example 3-8: Preparation of Compound ETL-8

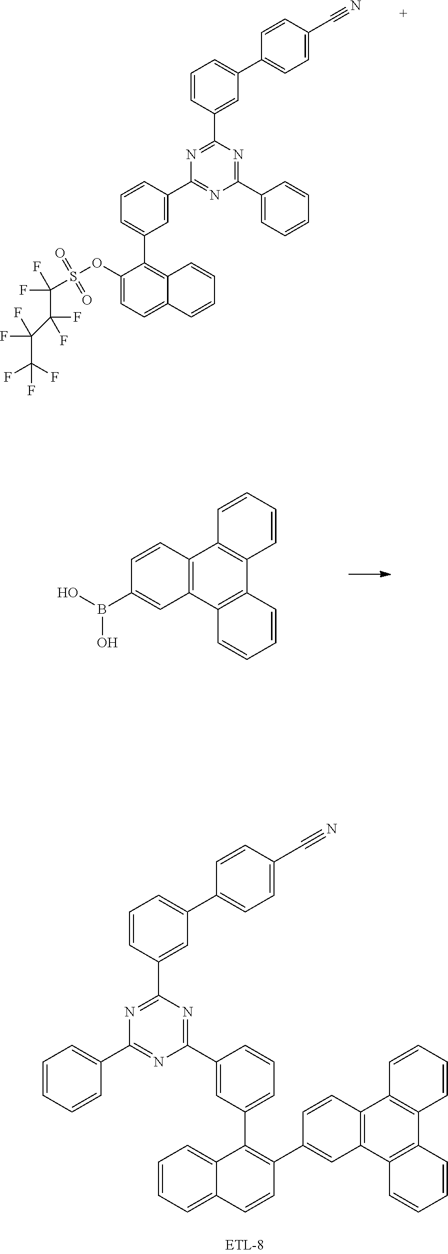 [SMILES: N#Cc1ccc(-c2cccc(-c3nc(-c4ccccc4)nc(-c4cccc(-c5c(OS(=O)(=O)C(F)(F)C(F)(F)C(F)(F)C(F)(F)F)ccc6ccccc56)c4)n3)c2)cc1 ; OB(O)c1ccc2c3ccccc3c3ccccc3c2c1 ; N#Cc1ccc(-c2cccc(-c3nc(-c4ccccc4)nc(-c4cccc(-c5c(-c6ccc7c8ccccc8c8ccccc8c7c6)ccc6ccccc56)c4)n3)c2)cc1]

Compound ETL-8 was prepared in the same manner as in the preparation method of Compound ETL-1 of Preparation Example 3-1, except that each starting material was used as in the above Reaction Scheme.

MS[M+H]⁺=763

### EXAMPLE

### Example 1

A glass substrate on which a thin film of ITO (indium tin oxide) was coated in a thickness of 1,000 Å was put into distilled water containing the detergent dissolved therein and washed by the ultrasonic wave. In this case, the used detergent was a product commercially available from Fisher Co. and the distilled water was one which had been twice filtered by using a filter commercially available from Millipore Co. The ITO was washed for 30 minutes, and ultrasonic washing was then repeated twice for 10 minutes by using distilled water. After the washing with distilled water was completed, the substrate was ultrasonically washed with isopropyl alcohol, acetone, and methanol solvent, and dried, after which it was transported to a plasma cleaner. Then, the substrate was cleaned with oxygen plasma for 5 minutes, and then transferred to a vacuum evaporator.

On the ITO transparent electrode prepared as above, the following compound HT1 and the following compound HI1 were vacuum-deposited at a ratio of 100:6 in a thickness of 100 Å to form a hole injection layer. The following compound HT1 was vacuum-deposited in a thickness of 1150 Å on the hole injection layer to form a hole transport layer. The previously prepared compound EBL-1 was vacuum-deposited in a thickness of 50 Å on the hole transport layer to form an electron blocking layer. The previously prepared compound HOST-1 and the following compound BD were vacuum-deposited at a ratio of 96:4 in a thickness of 200 Å on the electron blocking layer to form a light emitting layer. The following compound HBL was vacuum-deposited in a thickness of 50 Å on the light emitting layer to form a hole blocking layer. The previously prepared compound ETL-1 and the following compound LiQ were vacuum-deposited at a ratio of 1:1 in a thickness of 310 Å on the hole blocking layer to form an electron transport layer. On the electron transport layer, magnesium and silver were deposited at a weight ratio of 9:1 in a thickness of 120 Å and then aluminum was deposited in a thickness of 1,000 Å to form a cathode.

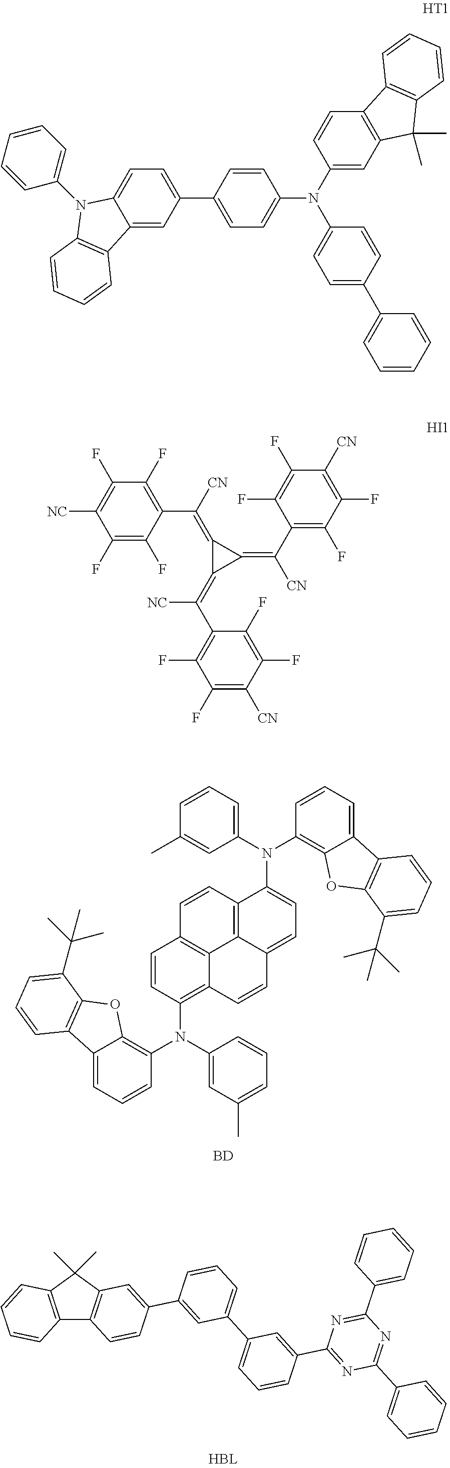

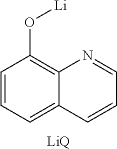

In the above-mentioned process, the vapor deposition rate of the organic material was maintained at 0.4 to 2 Å/sec. The deposition rates of magnesium, silver (Ag) and aluminum were maintained at 1 Å/sec, 0.1 Å/sec and 2 Å/sec, respectively. The degree of vacuum during the deposition was maintained at 2×10⁻⁷ to 5×10⁻⁶ torr, thereby manufacturing an organic light emitting device.

### Examples 2 to 17

The organic light emitting devices were manufactured in the same manner as in Example 1, except that the compounds described in Table 1 below were used instead of the compound EBL-1, the compound HOST-1 and/or the compound ETL-1.

### Comparative Examples 1 and 2

The organic light emitting devices were manufactured in the same manner as in Example 1, except that the compounds described in Table 1 below were used instead of the compound EBL-1, the compound HOST-1 and/or the compound ETL-1. The compound EBL′, the compound HOST and the compound ETL′ described in Table 1 are as follows.

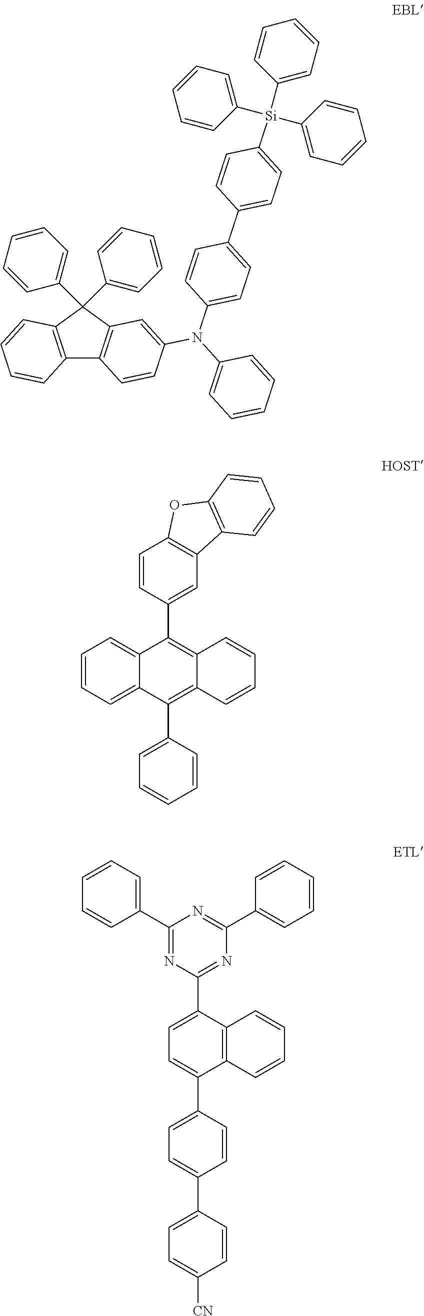 [SMILES: c1ccc(N(c2ccc(-c3ccc([Si](c4ccccc4)(c4ccccc4)c4ccccc4)cc3)cc2)c2ccc3c(c2)C(c2ccccc2)(c2ccccc2)c2ccccc2-3)cc1 ; c1ccc(-c2c3ccccc3c(-c3ccc4oc5ccccc5c4c3)c3ccccc23)cc1 ; N#Cc1ccc(-c2ccc(-c3ccc(-c4nc(-c5ccccc5)nc(-c5ccccc5)n4)c4ccccc34)cc2)cc1]

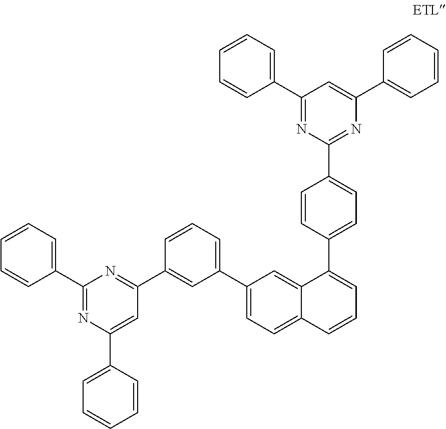 [SMILES: c1ccc(-c2cc(-c3ccccc3)nc(-c3ccc(-c4cccc5ccc(-c6cccc(-c7cc(-c8ccccc8)nc(-c8ccccc8)n7)c6)cc45)cc3)n2)cc1]

The driving voltage, luminous efficiency and lifetime were measured by applying a current density of 10 mA/cm² to the organic light emitting devices manufactured in Examples and Comparative Examples, and the results are shown in Table 1 below. The lifetime (T95) means the time required for the luminance to be reduced to 95% of the initial luminance.

TABLE 1

| | | Light | | | | |
|---|---|---|---|---|---|---|
| | Electron | emitting | Electron | Driving | Luminous | Lifetime |
| | blocking | layer | transport | voltage | efficiency | (T95) |
| | layer | (host) | layer | (V) | (Im/W) | (hr) |
| Ex. 1 | EBL-1 | HOST-1 | ETL-1 | 4.18 | 5.75 | 431 |
| Ex. 2 | EBL-2 | HOST-1 | ETL-1 | 4.15 | 5.94 | 453 |
| Ex. 3 | EBL-1 | HOST-2 | ETL-1 | 3.97 | 5.93 | 510 |
| Ex. 4 | EBL-1 | HOST-1 | ETL-2 | 3.95 | 6.33 | 360 |
| Ex. 5 | EBL-3 | HOST-1 | ETL-1 | 3.72 | 6.21 | 452 |
| Ex. 6 | EBL-4 | HOST-1 | ETL-1 | 3.83 | 6.14 | 508 |
| Ex. 7 | EBL-5 | HOST-1 | ETL-1 | 3.78 | 6.03 | 488 |
| Ex. 8 | EBL-1 | HOST-1 | ETL-3 | 3.71 | 6.38 | 401 |
| Ex. 9 | EBL-1 | HOST-1 | ETL-4 | 4.07 | 5.85 | 440 |
| Ex. 10 | EBL-1 | HOST-1 | ETL-5 | 4.22 | 5.70 | 508 |
| Ex. 11 | EBL-1 | HOST-1 | ETL-6 | 3.65 | 6.41 | 389 |
| Ex. 12 | EBL-1 | HOST-1 | ETL-7 | 3.75 | 6.27 | 415 |
| Ex. 13 | EBL-1 | HOST-1 | ETL-8 | 3.89 | 6.16 | 422 |
| Ex. 14 | EBL-1 | HOST-3 | ETL-1 | 3.85 | 5.88 | 458 |
| Ex. 15 | EBL-1 | HOST-4 | ETL-1 | 3.48 | 6.24 | 430 |
| Ex. 16 | EBL-1 | HOST-5 | ELT-1 | 3.61 | 6.18 | 422 |
| Ex. 17 | EBL-1 | HOST-6 | ETL-1 | 3.52 | 6.17 | 502 |
| Comparative | EBL′ | HOST′ | ETL′ | 3.69 | 5.95 | 306 |
| Ex. 1 | | | | | | |
| Comparative | EBL′ | HOST′ | ETL″ | 3.87 | 6.13 | 290 |
| Ex. 2 | | | | | | |

Description of Reference Numerals

| | |
|---|---|
| 1: | substrate |
| 2: | anode |
| 3: | hole transport layer |
| 4: | electron blocking layer |
| 5: | light emitting layer |
| 6: | electron transport layer |
| 7: | cathode |
| 8: | hole injection layer |
| 9: | hole blocking layer |

1. An organic light emitting device comprising:
an anode,
a hole transport layer,
an electronic blocking layer,
a light emitting layer,
an electron transport layer, and
a cathode,
wherein the electron blocking layer comprises a compound represented by the following Chemical Formula 1,
wherein the light emitting layer comprises a compound represented by the following Chemical Formula 2, and
wherein the electron transport layer comprises a compound represented by the following Chemical Formula 3: 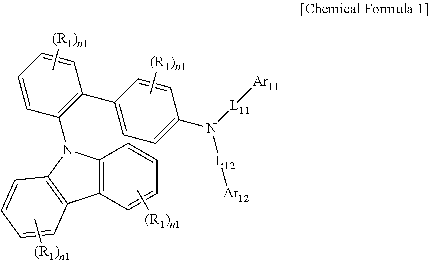
in Chemical Formula 1,
L₁₁ and L₁₂ are each independently a single bond; or a substituted or unsubstituted C₆₋₆₀ arylene,
Ar₁₁ and Ar₁₂ are each independently a substituted or unsubstituted C₆₋₆₀ aryl,
each R₁ is independently hydrogen or deuterium; or two adjacent radicals thereof are linked to form a C₆₋₆₀ aromatic ring,
each n1 is independently an integer of 1 to 4, 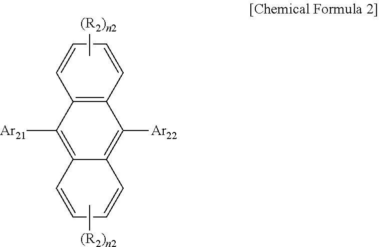
in Chemical Formula 2,
Ar₂₁ and Ar₂₂ are each independently a substituted or unsubstituted C₆₋₆₀ aryl; or a substituted or unsubstituted C₂₋₆₀ heteroaryl containing any one or more selected from the group consisting of N, O and S,
each R₂ is independently hydrogen; deuterium; or a substituted or unsubstituted C₆₋₆₀ aryl,
each n2 is independently an integer of 1 to 4, 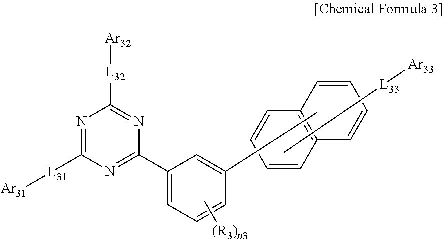
in Chemical Formula 3,
Ar₃₁ and Ar₃₂ are each independently a substituted or unsubstituted C₆₋₆₀ aryl; or a substituted or unsubstituted C₂₋₆₀ heteroaryl containing any one or more selected from the group consisting of N, O and S,
L₃₁ and L₃₂ are each independently a single bond; or a substituted or unsubstituted C₆₋₆₀ arylene,
Ar₃₃ is a substituted or unsubstituted C₆₋₆₀ aryl; or a substituted or unsubstituted C₂₋₆₀ heteroaryl containing any one or more selected from the group consisting of N, O and S,
L₃₃ is a single bond; or a substituted or unsubstituted C₆₋₆₀ arylene,
each R₃ is independently hydrogen, deuterium, or phenyl, and
n3 is an integer of 1 to 4.

2. The organic light emitting device according to claim 1, wherein
L₁₁ and L₁₂ are each independently a single bond, phenylene, or dimethylfluorenylene.

3. The organic light emitting device according to claim 1, wherein
Ar₁₁ and Ar₁₂ are each independently phenyl, biphenylyl, terphenylyl, dimethylfluorenyl, diphenylfluorenyl, spirobifluorenyl, naphthyl, phenylnaphthyl, naphthylphenyl, anthracenyl, or triphenylenyl, and
Ar₁₁ and Ar₁₂ are each independently unsubstituted or substituted with a substituent selected from the group consisting of deuterium, halogen, cyano, and Si(C₁₋₄ alkyl)₃.

4. The organic light emitting device according to claim 1, wherein
at least one of Ar₁₁ and Ar₁₂ is phenyl, biphenylyl, phenylnaphthyl or naphthylphenyl.

5. The organic light emitting device according to claim 1, wherein
the compound represented by Chemical Formula 1 is any one selected from the group consisting of the following:

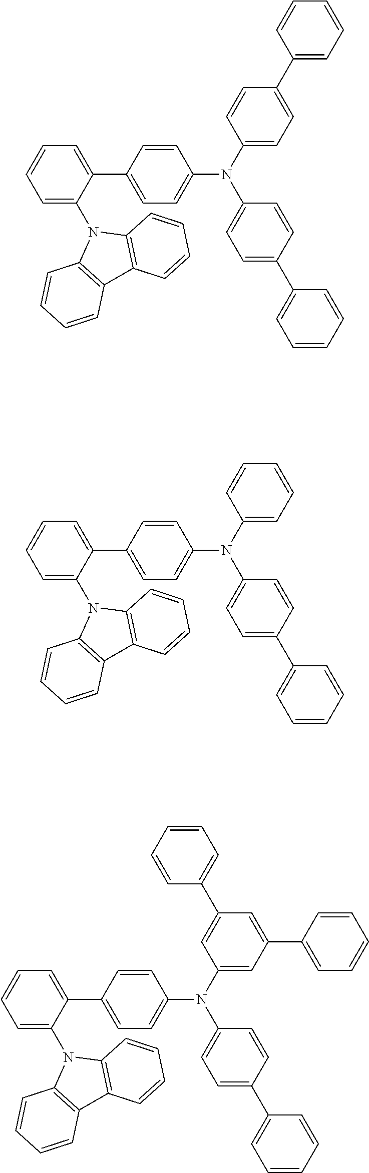 [SMILES: c1ccc(-c2ccc(N(c3ccc(-c4ccccc4)cc3)c3ccc(-c4ccccc4-n4c5ccccc5c5ccccc54)cc3)cc2)cc1 ; c1ccc(-c2ccc(N(c3ccccc3)c3ccc(-c4ccccc4-n4c5ccccc5c5ccccc54)cc3)cc2)cc1 ; c1ccc(-c2ccc(N(c3ccc(-c4ccccc4-n4c5ccccc5c5ccccc54)cc3)c3cc(-c4ccccc4)cc(-c4ccccc4)c3)cc2)cc1]

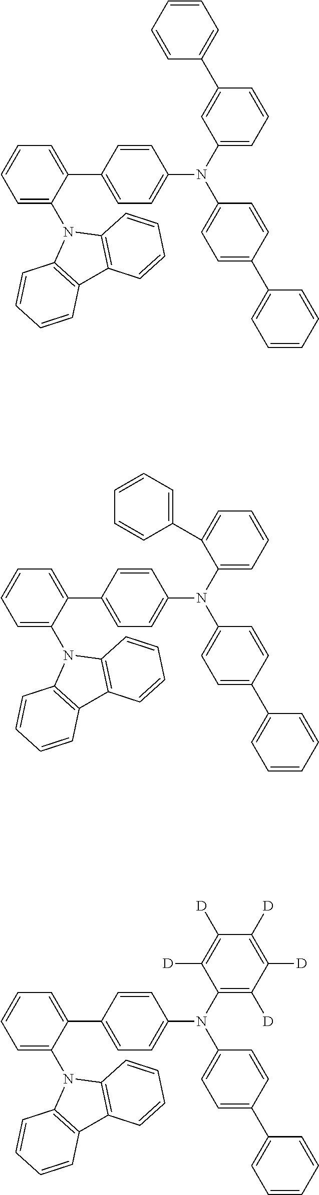 [SMILES: c1ccc(-c2ccc(N(c3ccc(-c4ccccc4-n4c5ccccc5c5ccccc54)cc3)c3cccc(-c4ccccc4)c3)cc2)cc1 ; c1ccc(-c2ccc(N(c3ccc(-c4ccccc4-n4c5ccccc5c5ccccc54)cc3)c3ccccc3-c3ccccc3)cc2)cc1 ; [2H]c1c([2H])c([2H])c(N(c2ccc(-c3ccccc3)cc2)c2ccc(-c3ccccc3-n3c4ccccc4c4ccccc43)cc2)c([2H])c1[2H]]

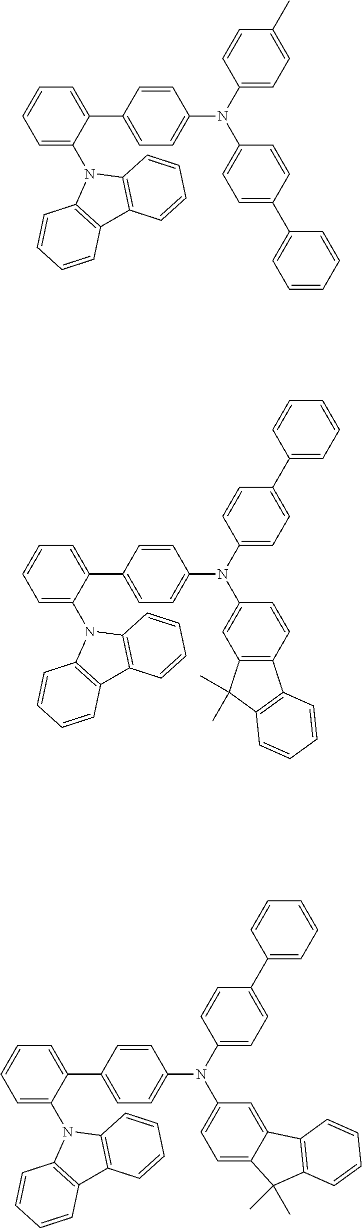 [SMILES: Cc1ccc(N(c2ccc(-c3ccccc3)cc2)c2ccc(-c3ccccc3-n3c4ccccc4c4ccccc43)cc2)cc1 ; CC1(C)c2ccccc2-c2ccc(N(c3ccc(-c4ccccc4)cc3)c3ccc(-c4ccccc4-n4c5ccccc5c5ccccc54)cc3)cc21 ; CC1(C)c2ccccc2-c2cc(N(c3ccc(-c4ccccc4)cc3)c3ccc(-c4ccccc4-n4c5ccccc5c5ccccc54)cc3)ccc21]

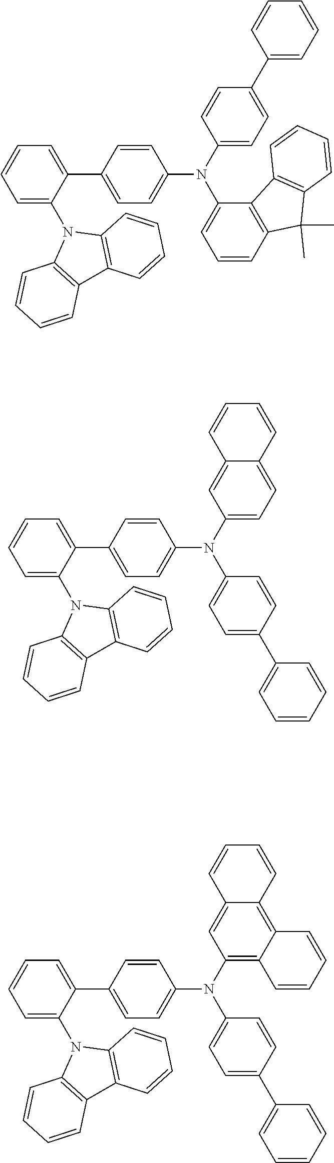 [SMILES: CC1(C)c2ccccc2-c2c(N(c3ccc(-c4ccccc4)cc3)c3ccc(-c4ccccc4-n4c5ccccc5c5ccccc54)cc3)cccc21 ; c1ccc(-c2ccc(N(c3ccc(-c4ccccc4-n4c5ccccc5c5ccccc54)cc3)c3ccc4ccccc4c3)cc2)cc1 ; c1ccc(-c2ccc(N(c3ccc(-c4ccccc4-n4c5ccccc5c5ccccc54)cc3)c3cc4ccccc4c4ccccc34)cc2)cc1]

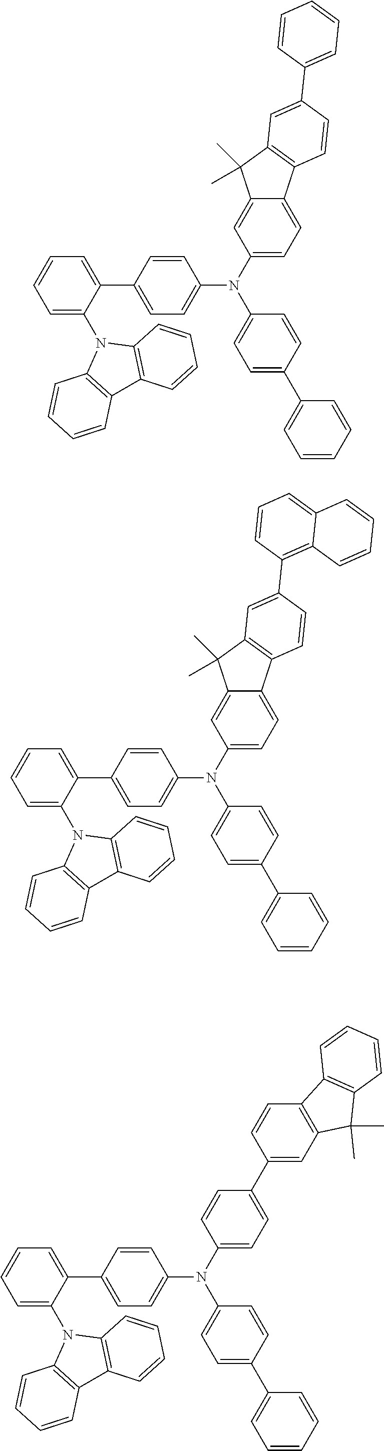

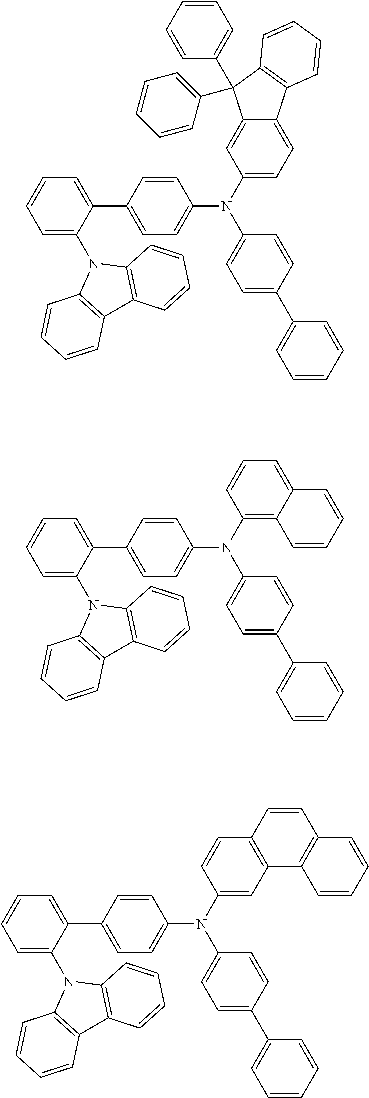 [SMILES: c1ccc(-c2ccc(N(c3ccc(-c4ccccc4-n4c5ccccc5c5ccccc54)cc3)c3ccc4c(c3)C(c3ccccc3)(c3ccccc3)c3ccccc3-4)cc2)cc1 ; c1ccc(-c2ccc(N(c3ccc(-c4ccccc4-n4c5ccccc5c5ccccc54)cc3)c3cccc4ccccc34)cc2)cc1 ; c1ccc(-c2ccc(N(c3ccc(-c4ccccc4-n4c5ccccc5c5ccccc54)cc3)c3ccc4ccc5ccccc5c4c3)cc2)cc1]

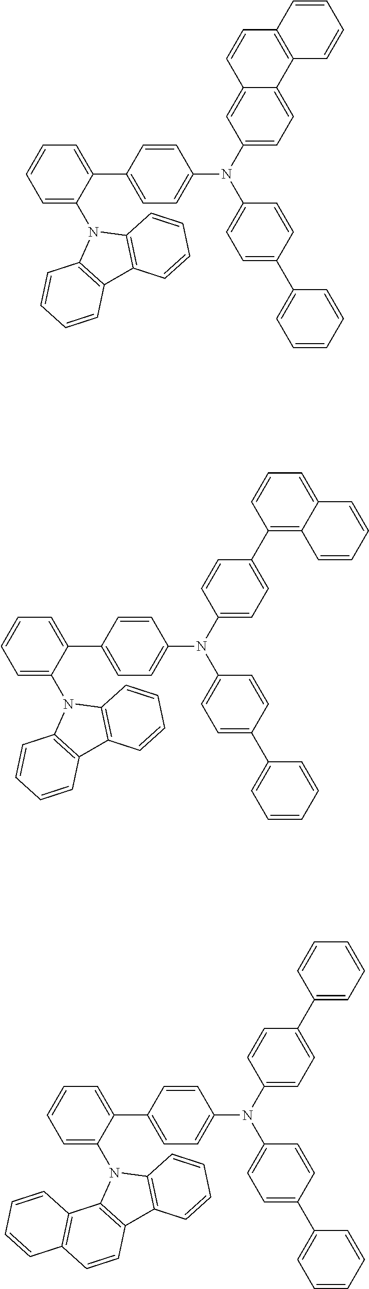 [SMILES: c1ccc(-c2ccc(N(c3ccc(-c4ccccc4-n4c5ccccc5c5ccccc54)cc3)c3ccc4c(ccc5ccccc54)c3)cc2)cc1 ; c1ccc(-c2ccc(N(c3ccc(-c4ccccc4-n4c5ccccc5c5ccccc54)cc3)c3ccc(-c4cccc5ccccc45)cc3)cc2)cc1 ; c1ccc(-c2ccc(N(c3ccc(-c4ccccc4)cc3)c3ccc(-c4ccccc4-n4c5ccccc5c5ccc6ccccc6c54)cc3)cc2)cc1]

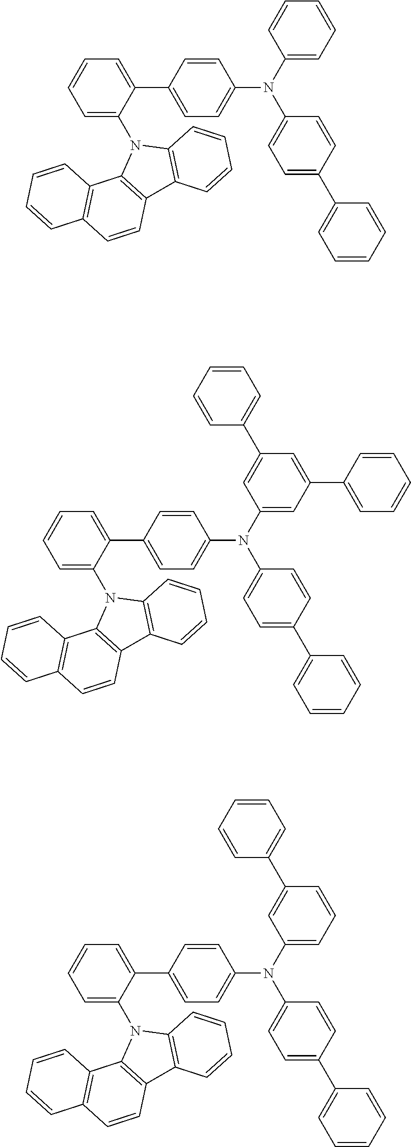 [SMILES: c1ccc(-c2ccc(N(c3ccccc3)c3ccc(-c4ccccc4-n4c5ccccc5c5ccc6ccccc6c54)cc3)cc2)cc1 ; c1ccc(-c2ccc(N(c3ccc(-c4ccccc4-n4c5ccccc5c5ccc6ccccc6c54)cc3)c3cc(-c4ccccc4)cc(-c4ccccc4)c3)cc2)cc1 ; c1ccc(-c2ccc(N(c3ccc(-c4ccccc4-n4c5ccccc5c5ccc6ccccc6c54)cc3)c3cccc(-c4ccccc4)c3)cc2)cc1]

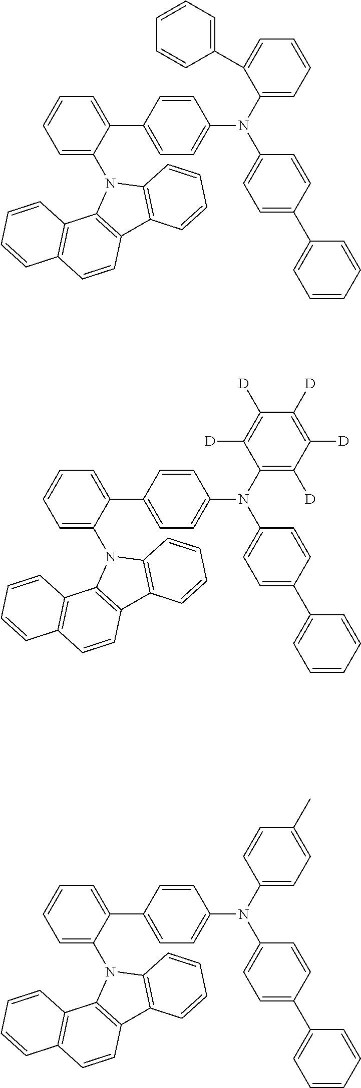 [SMILES: c1ccc(-c2ccc(N(c3ccc(-c4ccccc4-n4c5ccccc5c5ccc6ccccc6c54)cc3)c3ccccc3-c3ccccc3)cc2)cc1 ; [2H]c1c([2H])c([2H])c(N(c2ccc(-c3ccccc3)cc2)c2ccc(-c3ccccc3-n3c4ccccc4c4ccc5ccccc5c43)cc2)c([2H])c1[2H] ; Cc1ccc(N(c2ccc(-c3ccccc3)cc2)c2ccc(-c3ccccc3-n3c4ccccc4c4ccc5ccccc5c43)cc2)cc1]

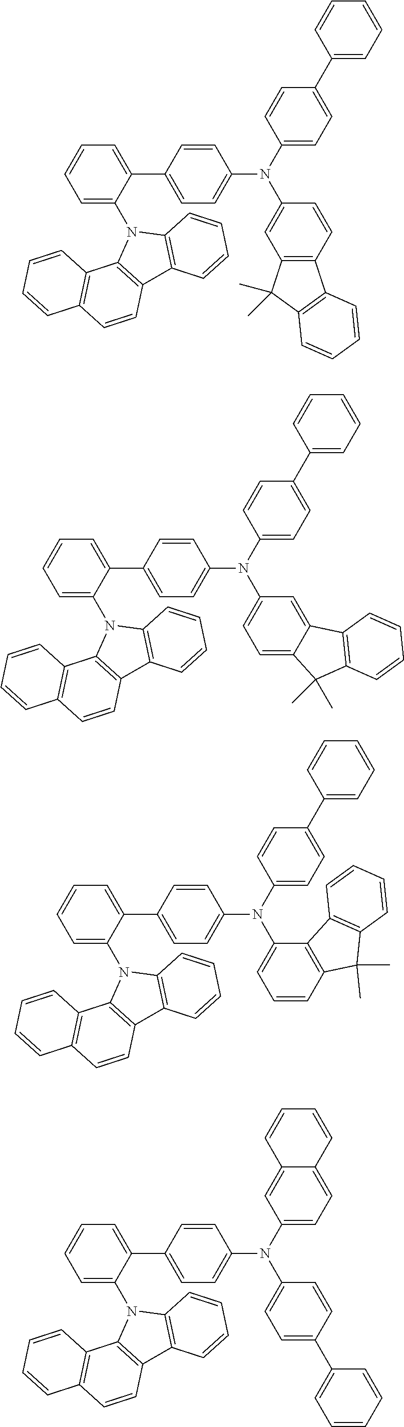

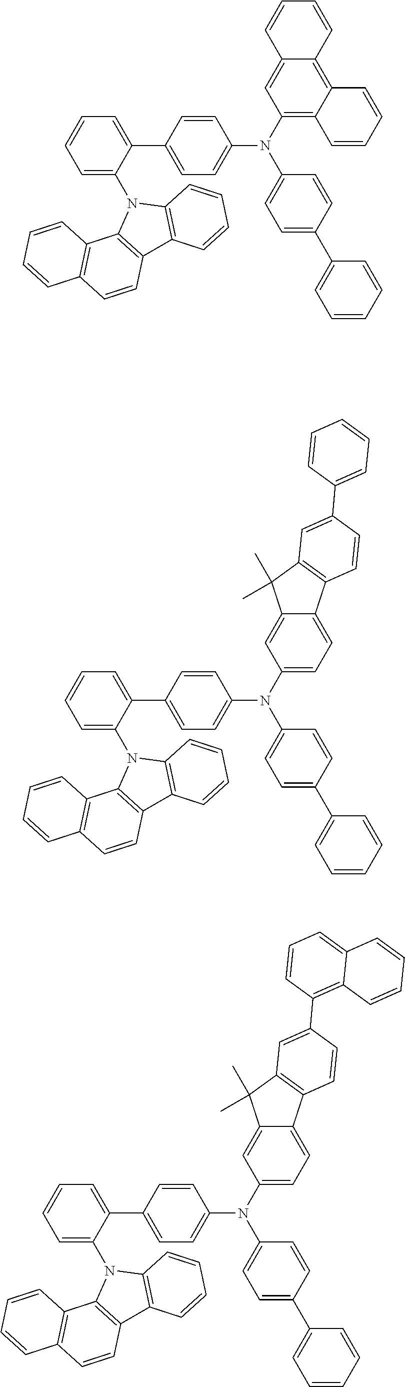 [SMILES: c1ccc(-c2ccc(N(c3ccc(-c4ccccc4-n4c5ccccc5c5ccc6ccccc6c54)cc3)c3cc4ccccc4c4ccccc34)cc2)cc1 ; CC1(C)c2cc(-c3ccccc3)ccc2-c2ccc(N(c3ccc(-c4ccccc4)cc3)c3ccc(-c4ccccc4-n4c5ccccc5c5ccc6ccccc6c54)cc3)cc21 ; CC1(C)c2cc(-c3cccc4ccccc34)ccc2-c2ccc(N(c3ccc(-c4ccccc4)cc3)c3ccc(-c4ccccc4-n4c5ccccc5c5ccc6ccccc6c54)cc3)cc21]

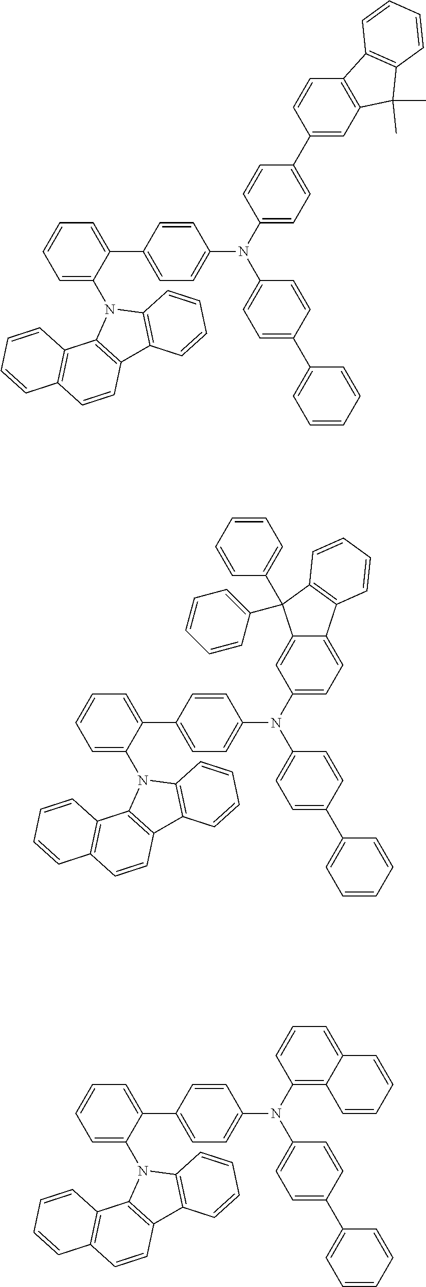 [SMILES: CC1(C)c2ccccc2-c2ccc(-c3ccc(N(c4ccc(-c5ccccc5)cc4)c4ccc(-c5ccccc5-n5c6ccccc6c6ccc7ccccc7c65)cc4)cc3)cc21 ; c1ccc(-c2ccc(N(c3ccc(-c4ccccc4-n4c5ccccc5c5ccc6ccccc6c54)cc3)c3ccc4c(c3)C(c3ccccc3)(c3ccccc3)c3ccccc3-4)cc2)cc1 ; c1ccc(-c2ccc(N(c3ccc(-c4ccccc4-n4c5ccccc5c5ccc6ccccc6c54)cc3)c3cccc4ccccc34)cc2)cc1]

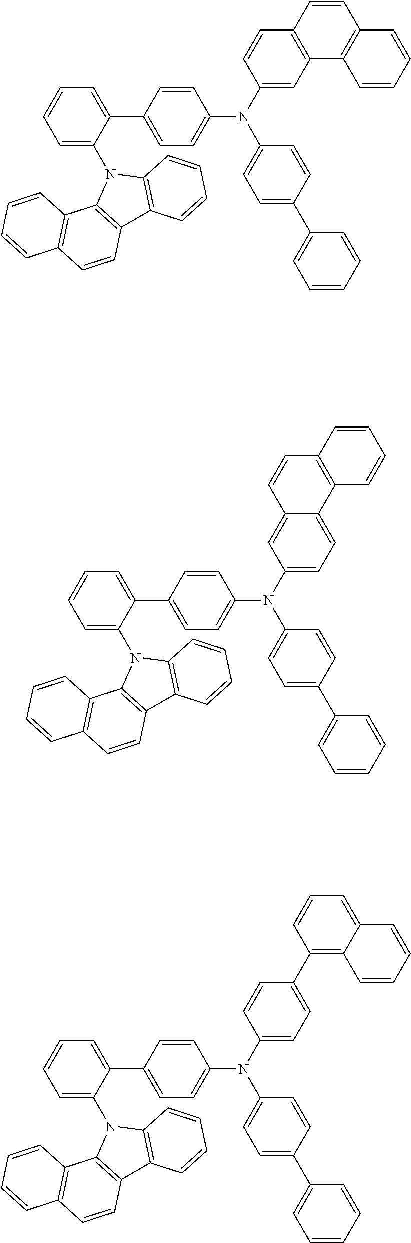 [SMILES: c1ccc(-c2ccc(N(c3ccc(-c4ccccc4-n4c5ccccc5c5ccc6ccccc6c54)cc3)c3ccc4ccc5ccccc5c4c3)cc2)cc1 ; c1ccc(-c2ccc(N(c3ccc(-c4ccccc4-n4c5ccccc5c5ccc6ccccc6c54)cc3)c3ccc4c(ccc5ccccc54)c3)cc2)cc1 ; c1ccc(-c2ccc(N(c3ccc(-c4ccccc4-n4c5ccccc5c5ccc6ccccc6c54)cc3)c3ccc(-c4cccc5ccccc45)cc3)cc2)cc1]

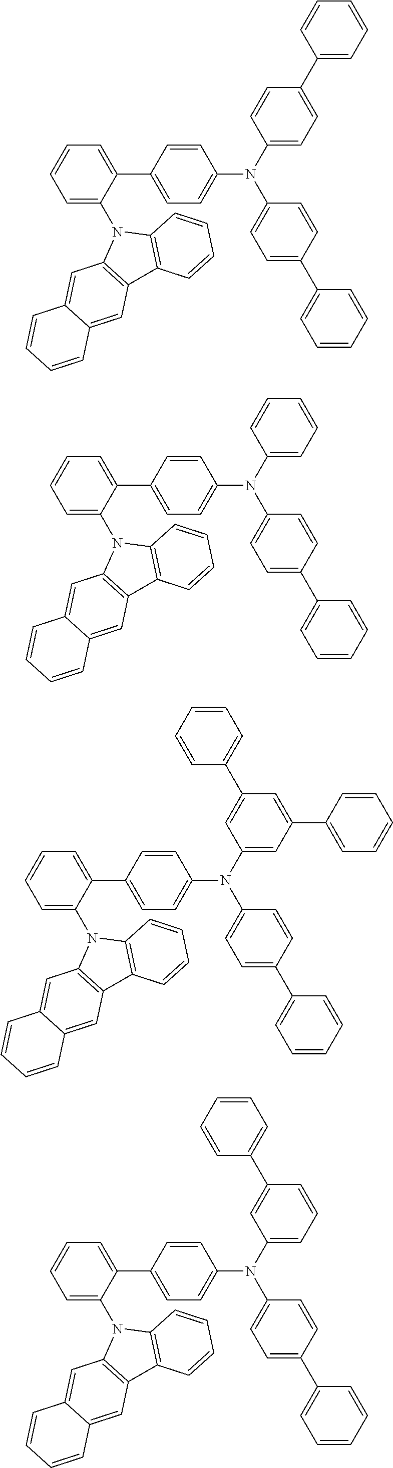 [SMILES: c1ccc(-c2ccc(N(c3ccc(-c4ccccc4)cc3)c3ccc(-c4ccccc4-n4c5ccccc5c5cc6ccccc6cc54)cc3)cc2)cc1 ; c1ccc(-c2ccc(N(c3ccccc3)c3ccc(-c4ccccc4-n4c5ccccc5c5cc6ccccc6cc54)cc3)cc2)cc1 ; c1ccc(-c2ccc(N(c3ccc(-c4ccccc4-n4c5ccccc5c5cc6ccccc6cc54)cc3)c3cc(-c4ccccc4)cc(-c4ccccc4)c3)cc2)cc1 ; c1ccc(-c2ccc(N(c3ccc(-c4ccccc4-n4c5ccccc5c5cc6ccccc6cc54)cc3)c3cccc(-c4ccccc4)c3)cc2)cc1]

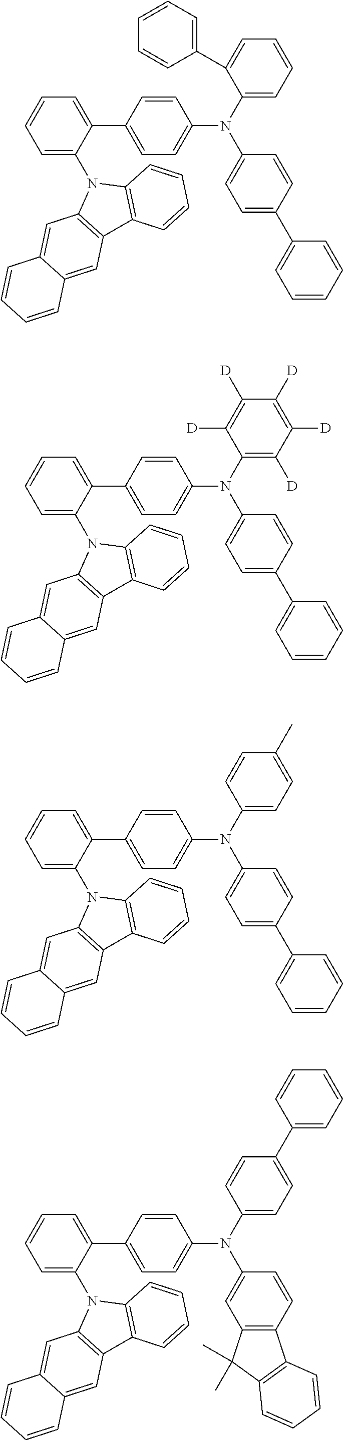 [SMILES: c1ccc(-c2ccc(N(c3ccc(-c4ccccc4-n4c5ccccc5c5cc6ccccc6cc54)cc3)c3ccccc3-c3ccccc3)cc2)cc1 ; [2H]c1c([2H])c([2H])c(N(c2ccc(-c3ccccc3)cc2)c2ccc(-c3ccccc3-n3c4ccccc4c4cc5ccccc5cc43)cc2)c([2H])c1[2H] ; Cc1ccc(N(c2ccc(-c3ccccc3)cc2)c2ccc(-c3ccccc3-n3c4ccccc4c4cc5ccccc5cc43)cc2)cc1 ; CC1(C)c2ccccc2-c2ccc(N(c3ccc(-c4ccccc4)cc3)c3ccc(-c4ccccc4-n4c5ccccc5c5cc6ccccc6cc54)cc3)cc21]

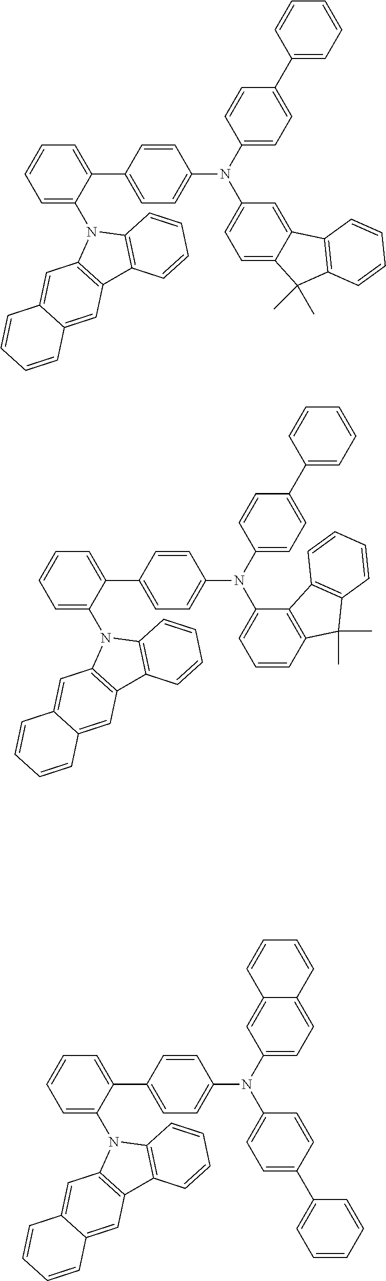 [SMILES: CC1(C)c2ccccc2-c2cc(N(c3ccc(-c4ccccc4)cc3)c3ccc(-c4ccccc4-n4c5ccccc5c5cc6ccccc6cc54)cc3)ccc21 ; CC1(C)c2ccccc2-c2c(N(c3ccc(-c4ccccc4)cc3)c3ccc(-c4ccccc4-n4c5ccccc5c5cc6ccccc6cc54)cc3)cccc21 ; c1ccc(-c2ccc(N(c3ccc(-c4ccccc4-n4c5ccccc5c5cc6ccccc6cc54)cc3)c3ccc4ccccc4c3)cc2)cc1]

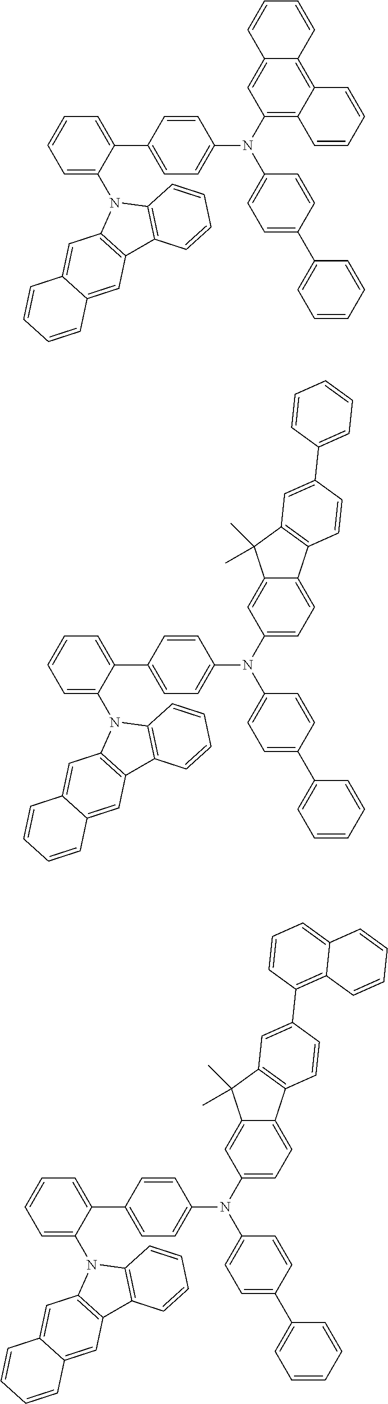 [SMILES: c1ccc(-c2ccc(N(c3ccc(-c4ccccc4-n4c5ccccc5c5cc6ccccc6cc54)cc3)c3cc4ccccc4c4ccccc34)cc2)cc1 ; CC1(C)c2cc(-c3ccccc3)ccc2-c2ccc(N(c3ccc(-c4ccccc4)cc3)c3ccc(-c4ccccc4-n4c5ccccc5c5cc6ccccc6cc54)cc3)cc21 ; CC1(C)c2cc(-c3cccc4ccccc34)ccc2-c2ccc(N(c3ccc(-c4ccccc4)cc3)c3ccc(-c4ccccc4-n4c5ccccc5c5cc6ccccc6cc54)cc3)cc21]

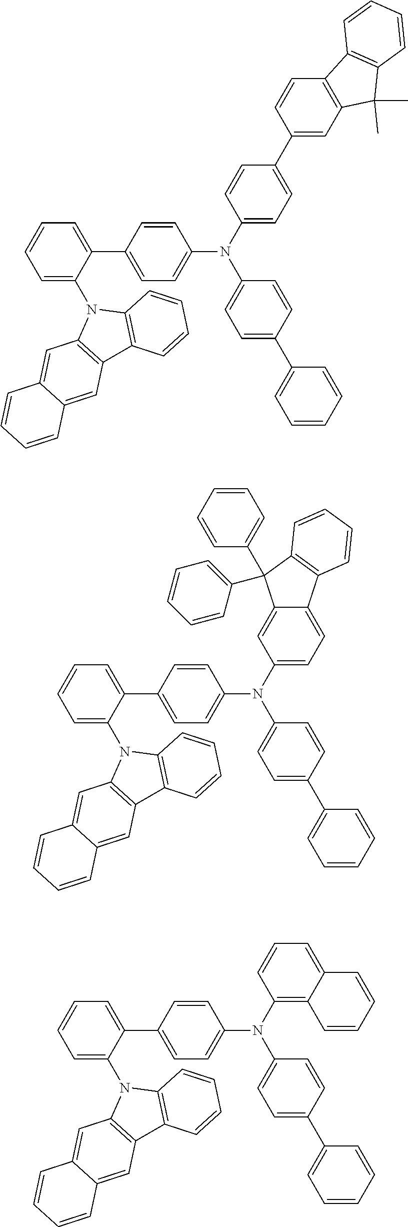 [SMILES: CC1(C)c2ccccc2-c2ccc(-c3ccc(N(c4ccc(-c5ccccc5)cc4)c4ccc(-c5ccccc5-n5c6ccccc6c6cc7ccccc7cc65)cc4)cc3)cc21 ; c1ccc(-c2ccc(N(c3ccc(-c4ccccc4-n4c5ccccc5c5cc6ccccc6cc54)cc3)c3ccc4c(c3)C(c3ccccc3)(c3ccccc3)c3ccccc3-4)cc2)cc1 ; c1ccc(-c2ccc(N(c3ccc(-c4ccccc4-n4c5ccccc5c5cc6ccccc6cc54)cc3)c3cccc4ccccc34)cc2)cc1]

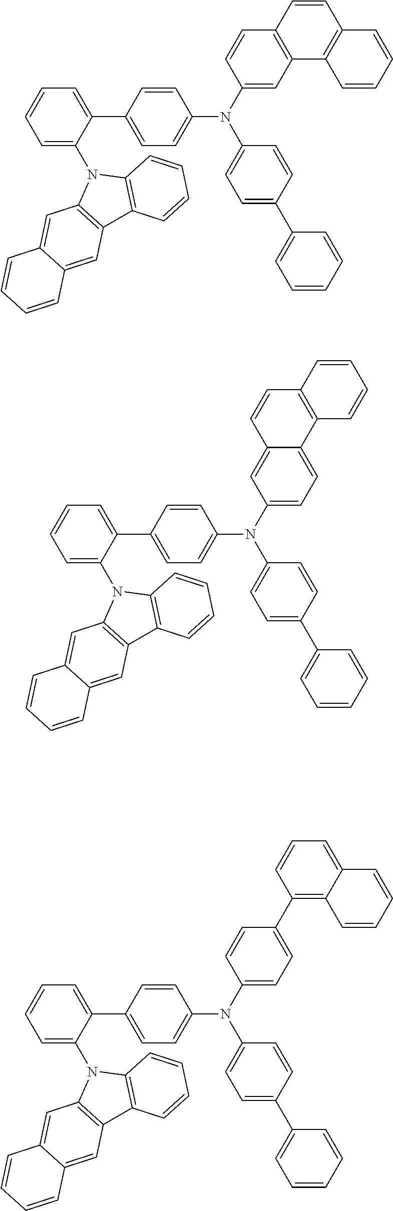 [SMILES: c1ccc(-c2ccc(N(c3ccc(-c4ccccc4-n4c5ccccc5c5cc6ccccc6cc54)cc3)c3ccc4ccc5ccccc5c4c3)cc2)cc1 ; c1ccc(-c2ccc(N(c3ccc(-c4ccccc4-n4c5ccccc5c5cc6ccccc6cc54)cc3)c3ccc4c(ccc5ccccc54)c3)cc2)cc1 ; c1ccc(-c2ccc(N(c3ccc(-c4ccccc4-n4c5ccccc5c5cc6ccccc6cc54)cc3)c3ccc(-c4cccc5ccccc45)cc3)cc2)cc1]

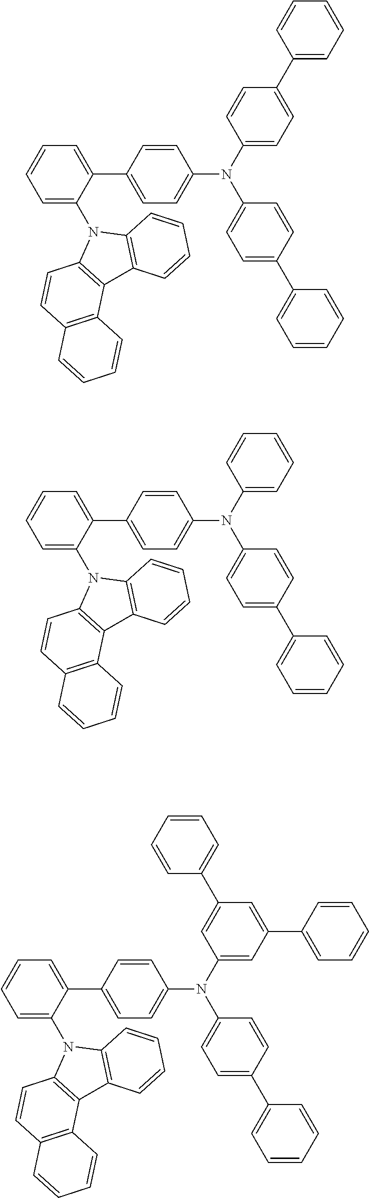 [SMILES: c1ccc(-c2ccc(N(c3ccc(-c4ccccc4)cc3)c3ccc(-c4ccccc4-n4c5ccccc5c5c6ccccc6ccc54)cc3)cc2)cc1 ; c1ccc(-c2ccc(N(c3ccccc3)c3ccc(-c4ccccc4-n4c5ccccc5c5c6ccccc6ccc54)cc3)cc2)cc1 ; c1ccc(-c2ccc(N(c3ccc(-c4ccccc4-n4c5ccccc5c5c6ccccc6ccc54)cc3)c3cc(-c4ccccc4)cc(-c4ccccc4)c3)cc2)cc1]

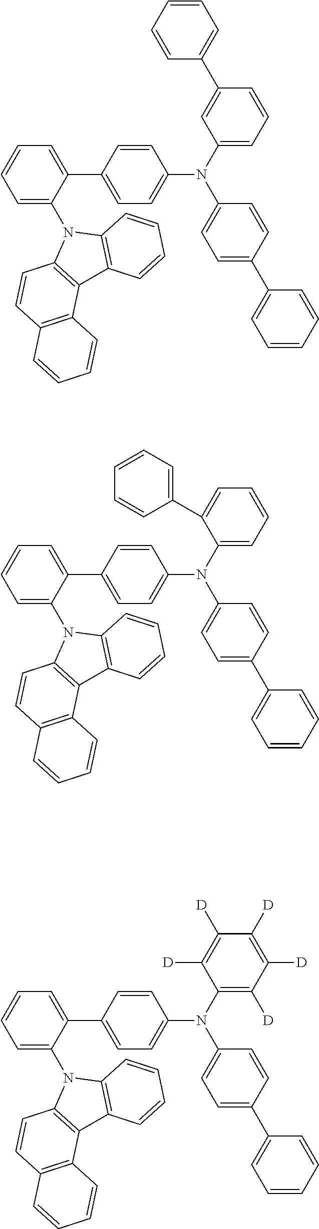 [SMILES: c1ccc(-c2ccc(N(c3ccc(-c4ccccc4-n4c5ccccc5c5c6ccccc6ccc54)cc3)c3cccc(-c4ccccc4)c3)cc2)cc1 ; c1ccc(-c2ccc(N(c3ccc(-c4ccccc4-n4c5ccccc5c5c6ccccc6ccc54)cc3)c3ccccc3-c3ccccc3)cc2)cc1 ; [2H]c1c([2H])c([2H])c(N(c2ccc(-c3ccccc3)cc2)c2ccc(-c3ccccc3-n3c4ccccc4c4c5ccccc5ccc43)cc2)c([2H])c1[2H]]

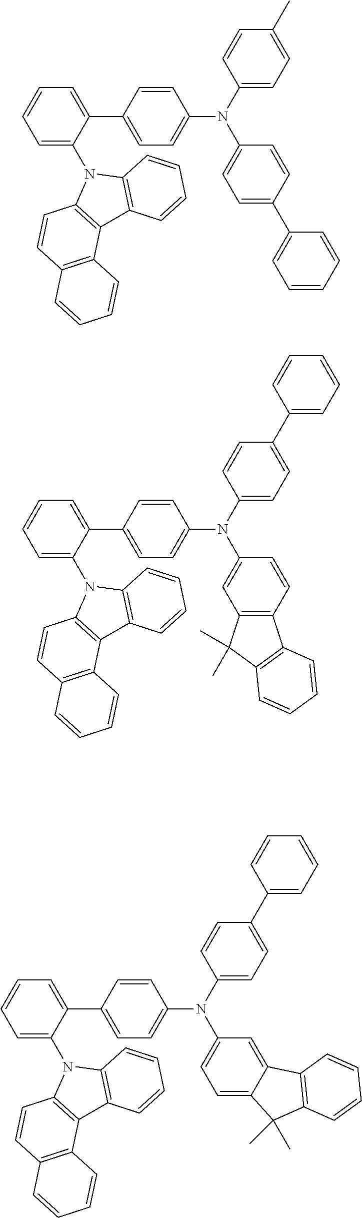 [SMILES: Cc1ccc(N(c2ccc(-c3ccccc3)cc2)c2ccc(-c3ccccc3-n3c4ccccc4c4c5ccccc5ccc43)cc2)cc1 ; CC1(C)c2ccccc2-c2ccc(N(c3ccc(-c4ccccc4)cc3)c3ccc(-c4ccccc4-n4c5ccccc5c5c6ccccc6ccc54)cc3)cc21 ; CC1(C)c2ccccc2-c2cc(N(c3ccc(-c4ccccc4)cc3)c3ccc(-c4ccccc4-n4c5ccccc5c5c6ccccc6ccc54)cc3)ccc21]

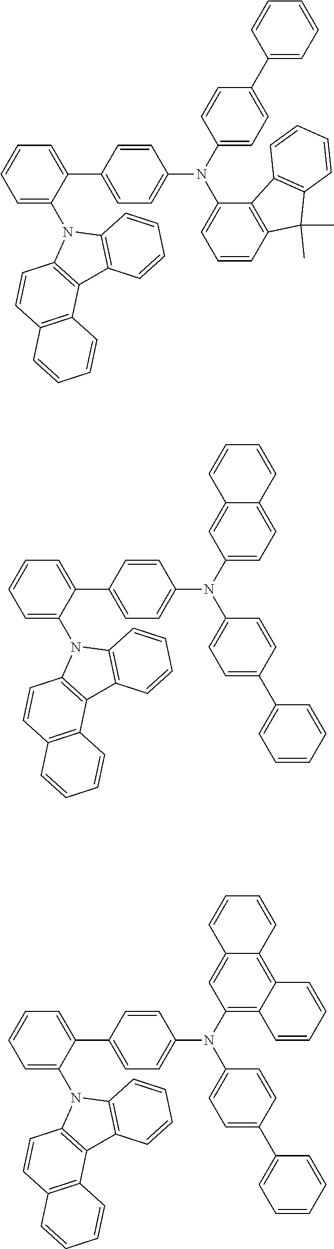 [SMILES: CC1(C)c2ccccc2-c2c(N(c3ccc(-c4ccccc4)cc3)c3ccc(-c4ccccc4-n4c5ccccc5c5c6ccccc6ccc54)cc3)cccc21 ; c1ccc(-c2ccc(N(c3ccc(-c4ccccc4-n4c5ccccc5c5c6ccccc6ccc54)cc3)c3ccc4ccccc4c3)cc2)cc1 ; c1ccc(-c2ccc(N(c3ccc(-c4ccccc4-n4c5ccccc5c5c6ccccc6ccc54)cc3)c3cc4ccccc4c4ccccc34)cc2)cc1]

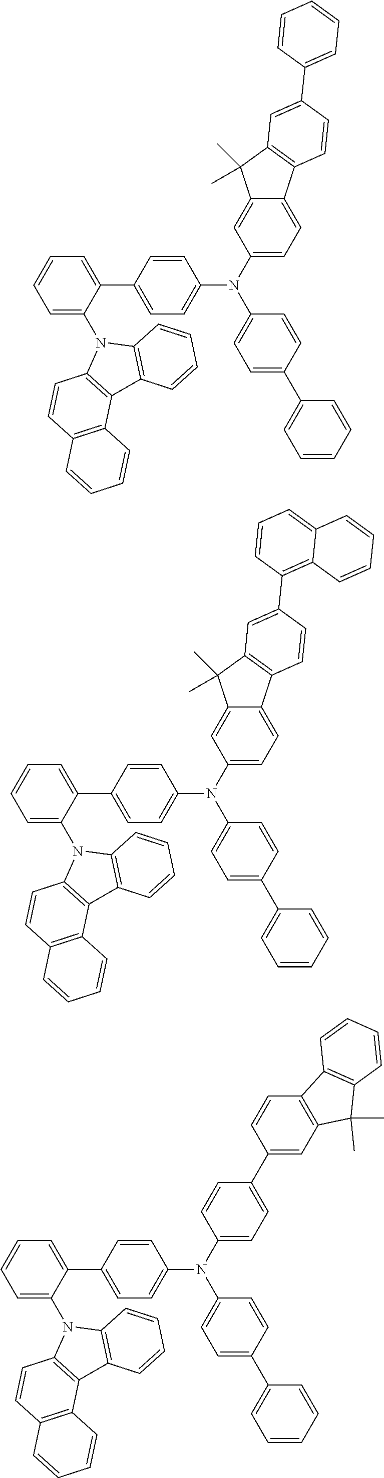 [SMILES: CC1(C)c2cc(-c3ccccc3)ccc2-c2ccc(N(c3ccc(-c4ccccc4)cc3)c3ccc(-c4ccccc4-n4c5ccccc5c5c6ccccc6ccc54)cc3)cc21 ; CC1(C)c2cc(-c3cccc4ccccc34)ccc2-c2ccc(N(c3ccc(-c4ccccc4)cc3)c3ccc(-c4ccccc4-n4c5ccccc5c5c6ccccc6ccc54)cc3)cc21 ; CC1(C)c2ccccc2-c2ccc(-c3ccc(N(c4ccc(-c5ccccc5)cc4)c4ccc(-c5ccccc5-n5c6ccccc6c6c7ccccc7ccc65)cc4)cc3)cc21]

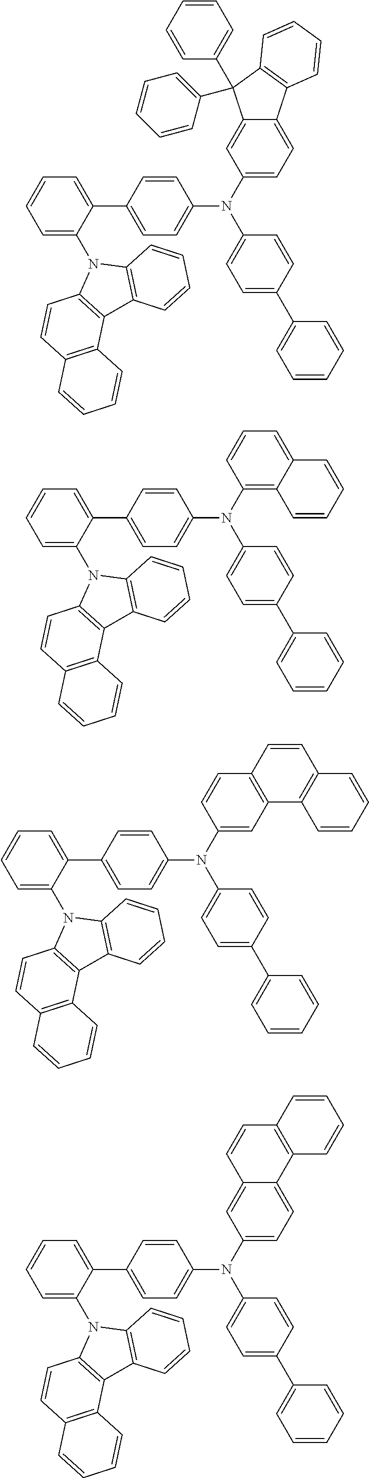 [SMILES: c1ccc(-c2ccc(N(c3ccc(-c4ccccc4-n4c5ccccc5c5c6ccccc6ccc54)cc3)c3ccc4c(c3)C(c3ccccc3)(c3ccccc3)c3ccccc3-4)cc2)cc1 ; c1ccc(-c2ccc(N(c3ccc(-c4ccccc4-n4c5ccccc5c5c6ccccc6ccc54)cc3)c3cccc4ccccc34)cc2)cc1 ; c1ccc(-c2ccc(N(c3ccc(-c4ccccc4-n4c5ccccc5c5c6ccccc6ccc54)cc3)c3ccc4ccc5ccccc5c4c3)cc2)cc1 ; c1ccc(-c2ccc(N(c3ccc(-c4ccccc4-n4c5ccccc5c5c6ccccc6ccc54)cc3)c3ccc4c(ccc5ccccc54)c3)cc2)cc1]

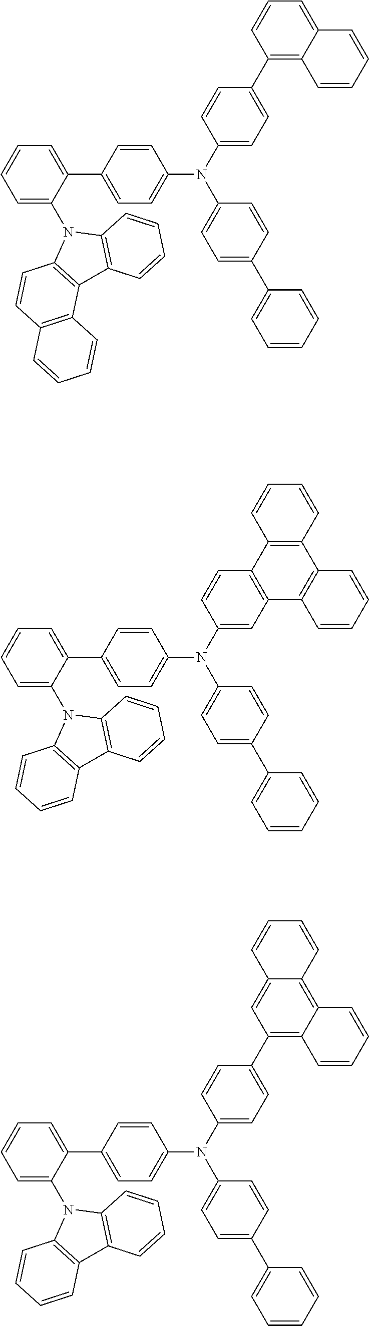 [SMILES: c1ccc(-c2ccc(N(c3ccc(-c4ccccc4-n4c5ccccc5c5c6ccccc6ccc54)cc3)c3ccc(-c4cccc5ccccc45)cc3)cc2)cc1 ; c1ccc(-c2ccc(N(c3ccc(-c4ccccc4-n4c5ccccc5c5ccccc54)cc3)c3ccc4c5ccccc5c5ccccc5c4c3)cc2)cc1 ; c1ccc(-c2ccc(N(c3ccc(-c4ccccc4-n4c5ccccc5c5ccccc54)cc3)c3ccc(-c4cc5ccccc5c5ccccc45)cc3)cc2)cc1]

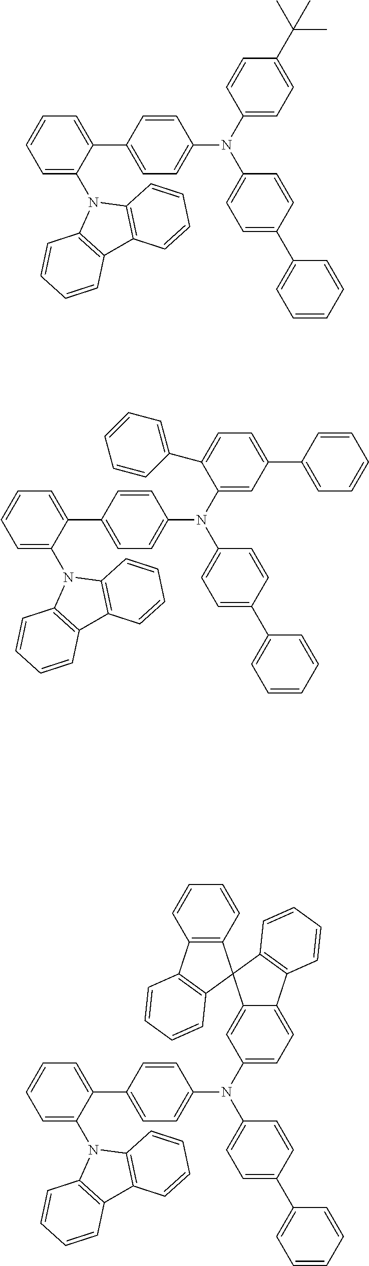 [SMILES: CC(C)(C)c1ccc(N(c2ccc(-c3ccccc3)cc2)c2ccc(-c3ccccc3-n3c4ccccc4c4ccccc43)cc2)cc1 ; c1ccc(-c2ccc(N(c3ccc(-c4ccccc4-n4c5ccccc5c5ccccc54)cc3)c3cc(-c4ccccc4)ccc3-c3ccccc3)cc2)cc1 ; c1ccc(-c2ccc(N(c3ccc(-c4ccccc4-n4c5ccccc5c5ccccc54)cc3)c3ccc4c(c3)C3(c5ccccc5-c5ccccc53)c3ccccc3-4)cc2)cc1]

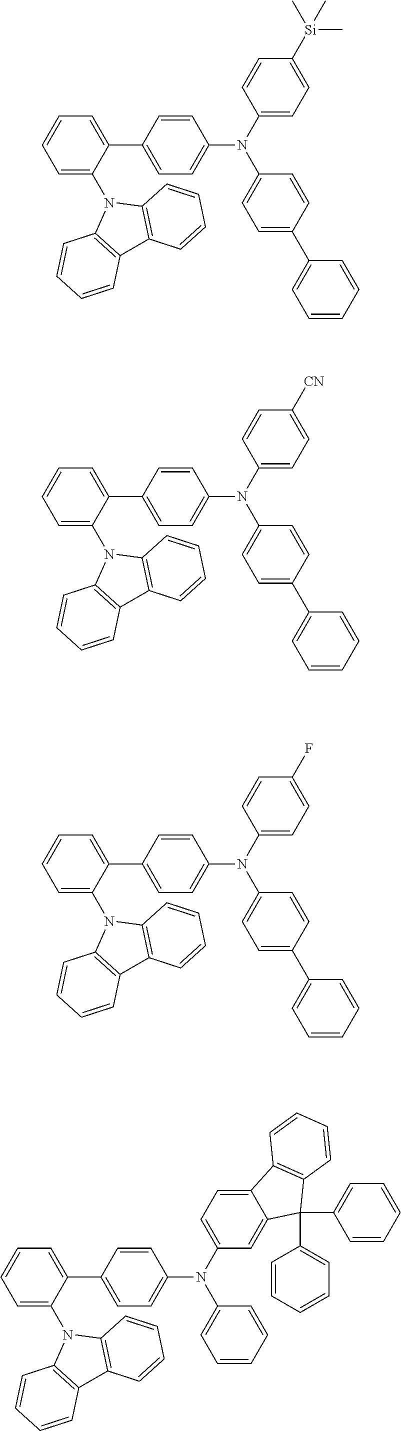 [SMILES: C[Si](C)(C)c1ccc(N(c2ccc(-c3ccccc3)cc2)c2ccc(-c3ccccc3-n3c4ccccc4c4ccccc43)cc2)cc1 ; N#Cc1ccc(N(c2ccc(-c3ccccc3)cc2)c2ccc(-c3ccccc3-n3c4ccccc4c4ccccc43)cc2)cc1 ; Fc1ccc(N(c2ccc(-c3ccccc3)cc2)c2ccc(-c3ccccc3-n3c4ccccc4c4ccccc43)cc2)cc1 ; c1ccc(N(c2ccc(-c3ccccc3-n3c4ccccc4c4ccccc43)cc2)c2ccc3c(c2)C(c2ccccc2)(c2ccccc2)c2ccccc2-3)cc1]

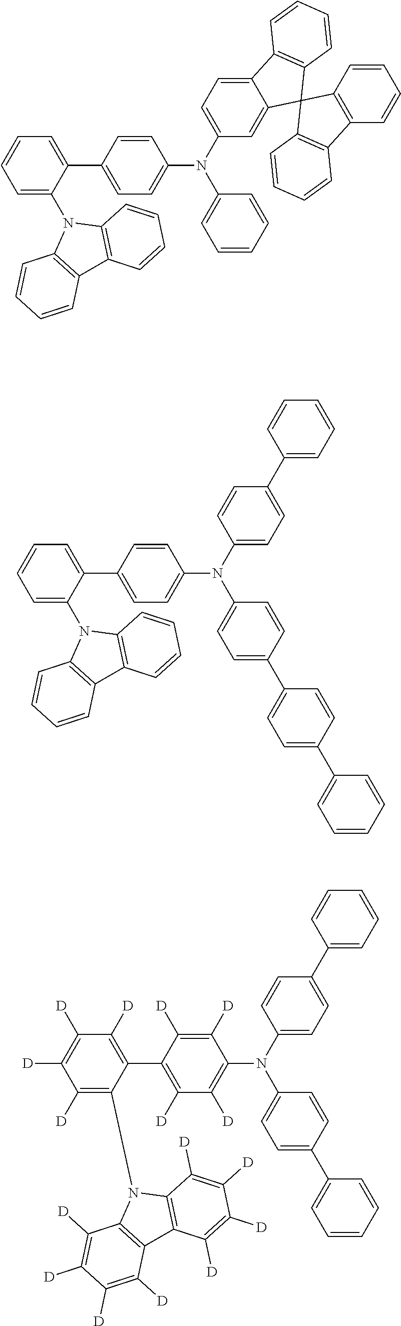 [SMILES: c1ccc(N(c2ccc(-c3ccccc3-n3c4ccccc4c4ccccc43)cc2)c2ccc3c(c2)C2(c4ccccc4-c4ccccc42)c2ccccc2-3)cc1 ; c1ccc(-c2ccc(-c3ccc(N(c4ccc(-c5ccccc5)cc4)c4ccc(-c5ccccc5-n5c6ccccc6c6ccccc65)cc4)cc3)cc2)cc1 ; [2H]c1c([2H])c([2H])c(-n2c3c([2H])c([2H])c([2H])c([2H])c3c3c([2H])c([2H])c([2H])c([2H])c32)c(-c2c([2H])c([2H])c(N(c3ccc(-c4ccccc4)cc3)c3ccc(-c4ccccc4)cc3)c([2H])c2[2H])c1[2H]]

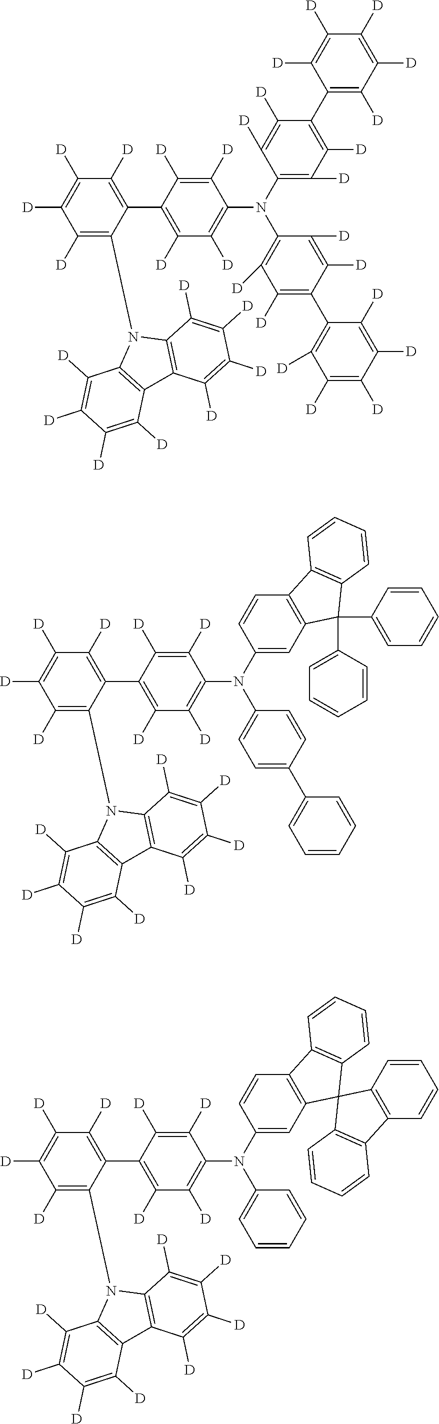

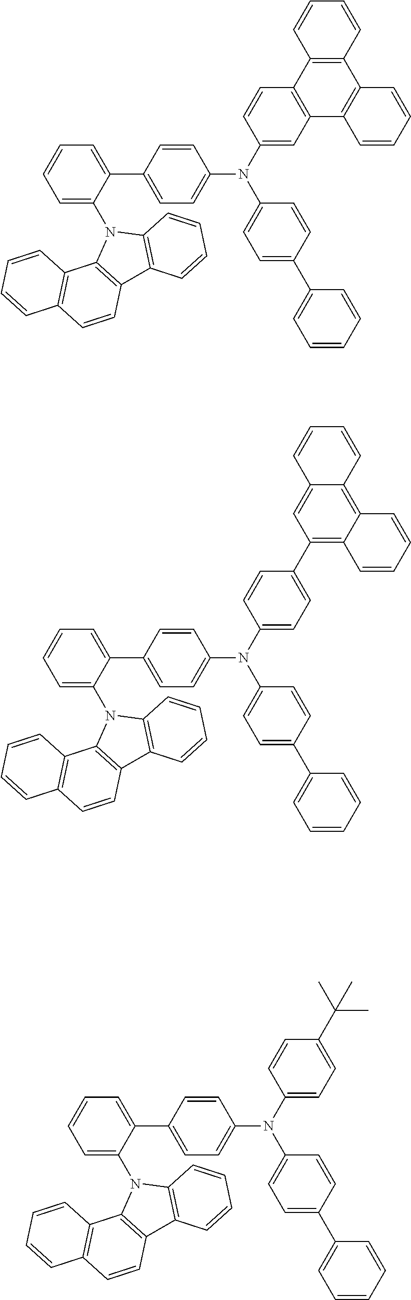 [SMILES: c1ccc(-c2ccc(N(c3ccc(-c4ccccc4-n4c5ccccc5c5ccc6ccccc6c54)cc3)c3ccc4c5ccccc5c5ccccc5c4c3)cc2)cc1 ; c1ccc(-c2ccc(N(c3ccc(-c4ccccc4-n4c5ccccc5c5ccc6ccccc6c54)cc3)c3ccc(-c4cc5ccccc5c5ccccc45)cc3)cc2)cc1 ; CC(C)(C)c1ccc(N(c2ccc(-c3ccccc3)cc2)c2ccc(-c3ccccc3-n3c4ccccc4c4ccc5ccccc5c43)cc2)cc1]

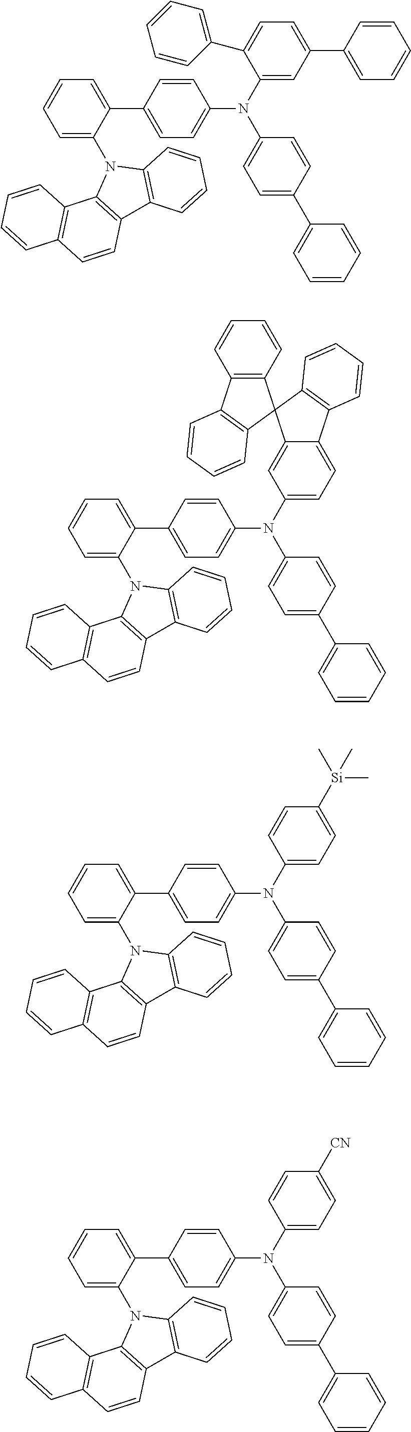 [SMILES: c1ccc(-c2ccc(N(c3ccc(-c4ccccc4-n4c5ccccc5c5ccc6ccccc6c54)cc3)c3cc(-c4ccccc4)ccc3-c3ccccc3)cc2)cc1 ; c1ccc(-c2ccc(N(c3ccc(-c4ccccc4-n4c5ccccc5c5ccc6ccccc6c54)cc3)c3ccc4c(c3)C3(c5ccccc5-c5ccccc53)c3ccccc3-4)cc2)cc1 ; C[Si](C)(C)c1ccc(N(c2ccc(-c3ccccc3)cc2)c2ccc(-c3ccccc3-n3c4ccccc4c4ccc5ccccc5c43)cc2)cc1 ; N#Cc1ccc(N(c2ccc(-c3ccccc3)cc2)c2ccc(-c3ccccc3-n3c4ccccc4c4ccc5ccccc5c43)cc2)cc1]

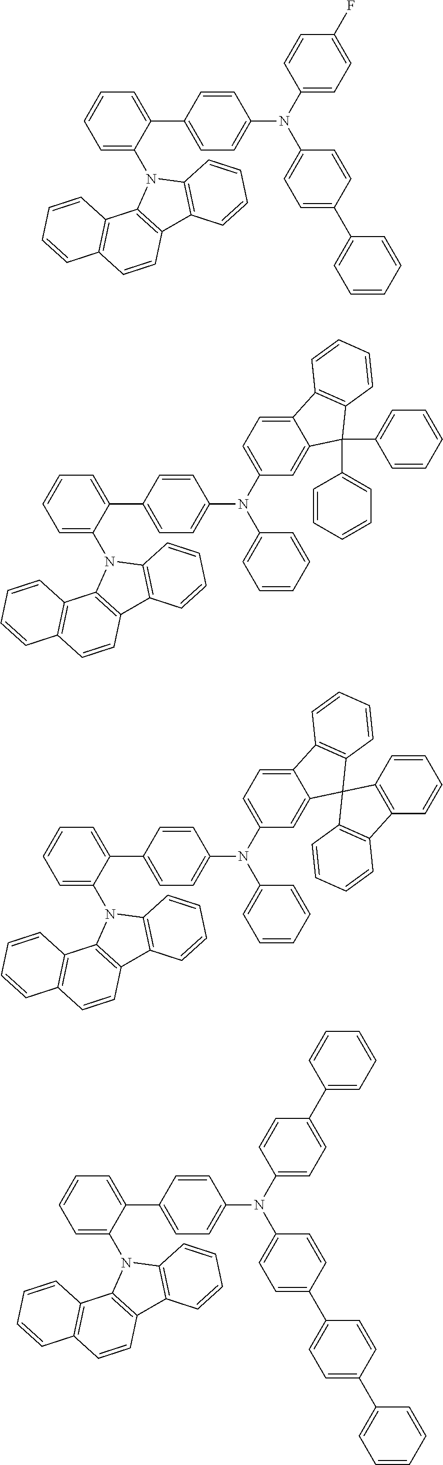 [SMILES: Fc1ccc(N(c2ccc(-c3ccccc3)cc2)c2ccc(-c3ccccc3-n3c4ccccc4c4ccc5ccccc5c43)cc2)cc1 ; c1ccc(N(c2ccc(-c3ccccc3-n3c4ccccc4c4ccc5ccccc5c43)cc2)c2ccc3c(c2)C(c2ccccc2)(c2ccccc2)c2ccccc2-3)cc1 ; c1ccc(N(c2ccc(-c3ccccc3-n3c4ccccc4c4ccc5ccccc5c43)cc2)c2ccc3c(c2)C2(c4ccccc4-c4ccccc42)c2ccccc2-3)cc1 ; c1ccc(-c2ccc(-c3ccc(N(c4ccc(-c5ccccc5)cc4)c4ccc(-c5ccccc5-n5c6ccccc6c6ccc7ccccc7c65)cc4)cc3)cc2)cc1]

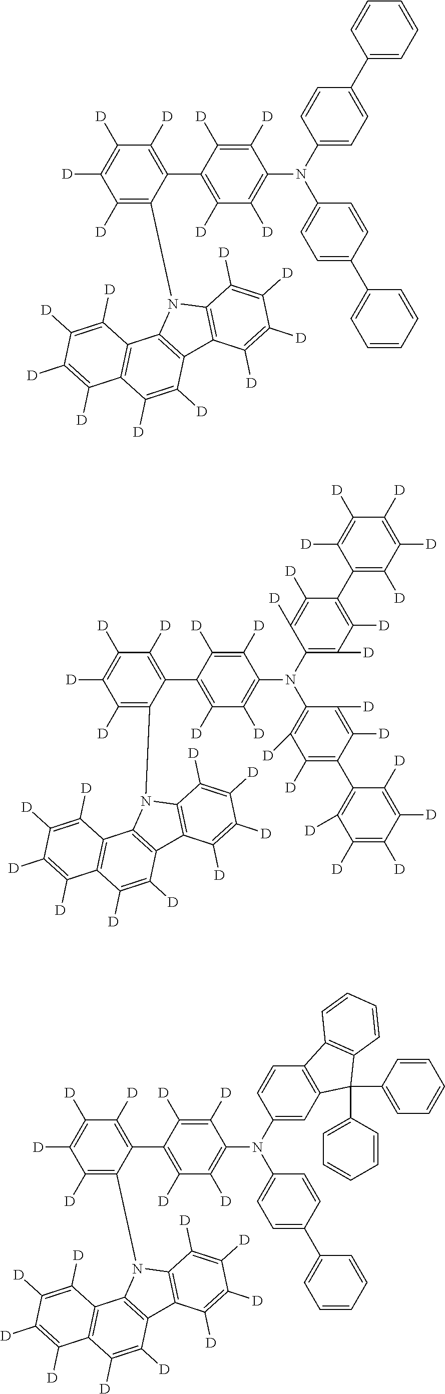

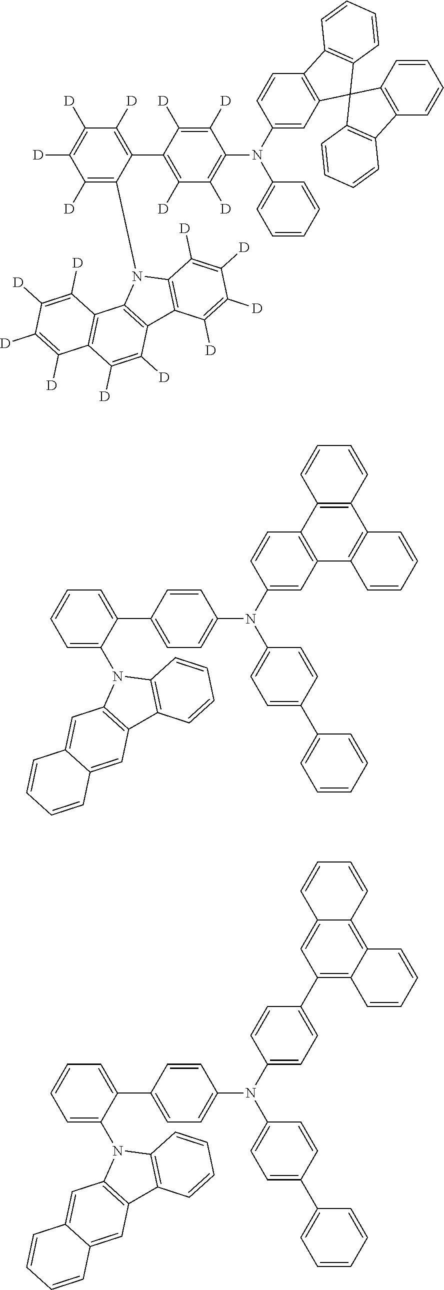 [SMILES: [2H]c1c([2H])c([2H])c(-n2c3c([2H])c([2H])c([2H])c([2H])c3c3c([2H])c([2H])c4c([2H])c([2H])c([2H])c([2H])c4c32)c(-c2c([2H])c([2H])c(N(c3ccccc3)c3ccc4c(c3)C3(c5ccccc5-c5ccccc53)c3ccccc3-4)c([2H])c2[2H])c1[2H] ; c1ccc(-c2ccc(N(c3ccc(-c4ccccc4-n4c5ccccc5c5cc6ccccc6cc54)cc3)c3ccc4c5ccccc5c5ccccc5c4c3)cc2)cc1 ; c1ccc(-c2ccc(N(c3ccc(-c4ccccc4-n4c5ccccc5c5cc6ccccc6cc54)cc3)c3ccc(-c4cc5ccccc5c5ccccc45)cc3)cc2)cc1]

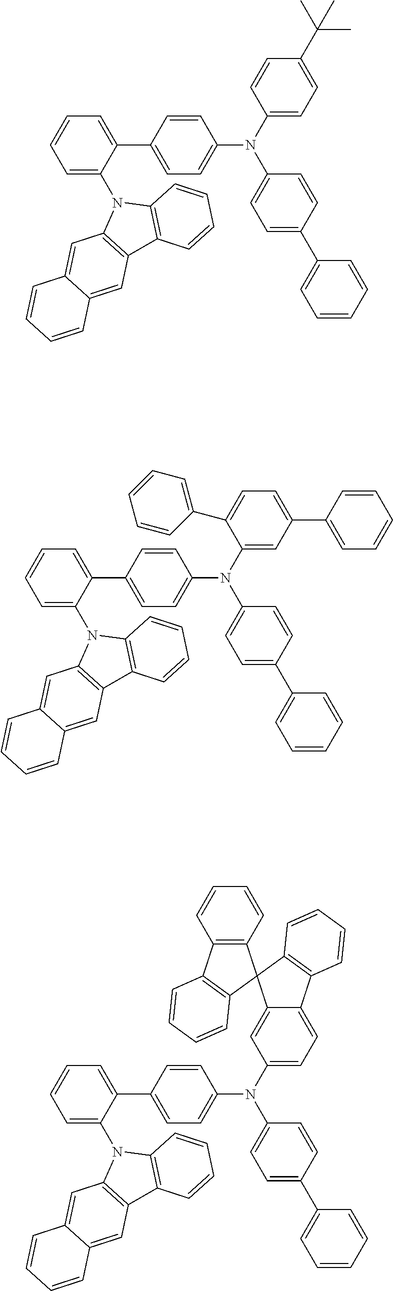 [SMILES: CC(C)(C)c1ccc(N(c2ccc(-c3ccccc3)cc2)c2ccc(-c3ccccc3-n3c4ccccc4c4cc5ccccc5cc43)cc2)cc1 ; c1ccc(-c2ccc(N(c3ccc(-c4ccccc4-n4c5ccccc5c5cc6ccccc6cc54)cc3)c3cc(-c4ccccc4)ccc3-c3ccccc3)cc2)cc1 ; c1ccc(-c2ccc(N(c3ccc(-c4ccccc4-n4c5ccccc5c5cc6ccccc6cc54)cc3)c3ccc4c(c3)C3(c5ccccc5-c5ccccc53)c3ccccc3-4)cc2)cc1]

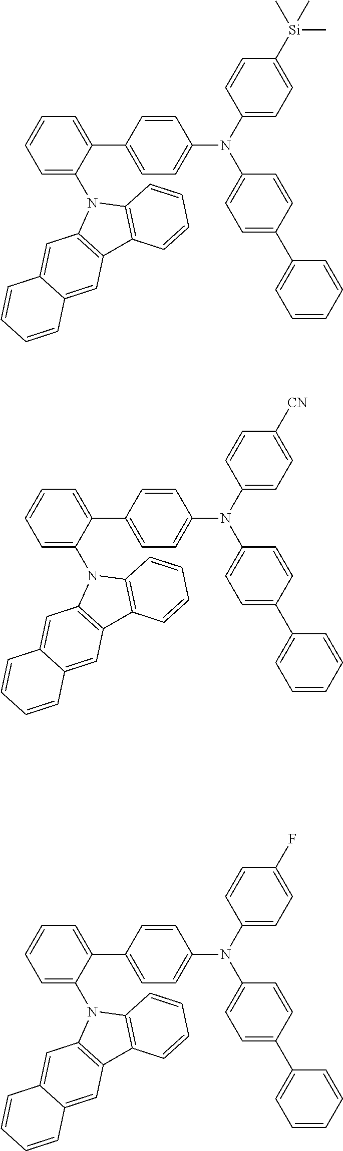 [SMILES: C[Si](C)(C)c1ccc(N(c2ccc(-c3ccccc3)cc2)c2ccc(-c3ccccc3-n3c4ccccc4c4cc5ccccc5cc43)cc2)cc1 ; N#Cc1ccc(N(c2ccc(-c3ccccc3)cc2)c2ccc(-c3ccccc3-n3c4ccccc4c4cc5ccccc5cc43)cc2)cc1 ; Fc1ccc(N(c2ccc(-c3ccccc3)cc2)c2ccc(-c3ccccc3-n3c4ccccc4c4cc5ccccc5cc43)cc2)cc1]

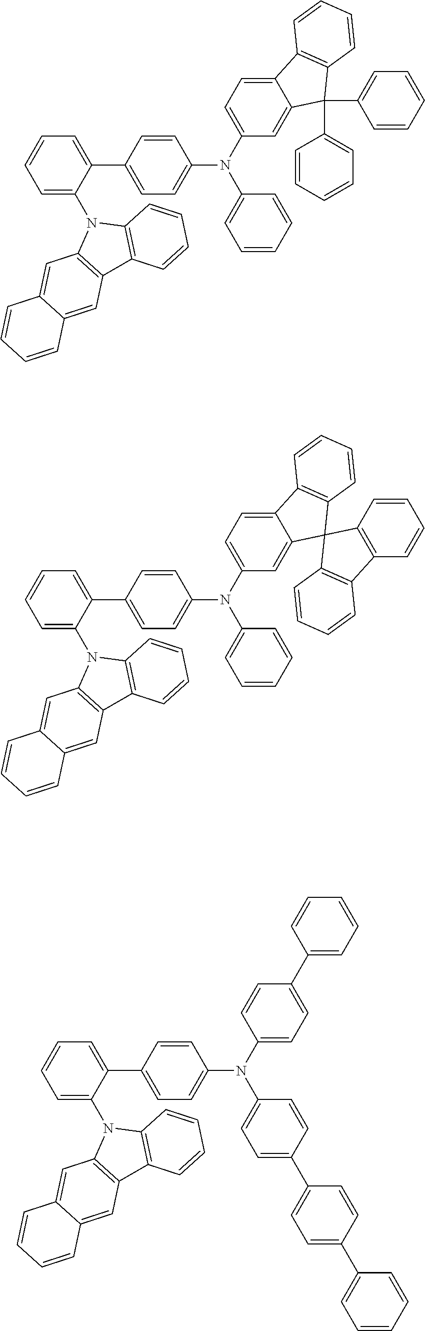 [SMILES: c1ccc(N(c2ccc(-c3ccccc3-n3c4ccccc4c4cc5ccccc5cc43)cc2)c2ccc3c(c2)C(c2ccccc2)(c2ccccc2)c2ccccc2-3)cc1 ; c1ccc(N(c2ccc(-c3ccccc3-n3c4ccccc4c4cc5ccccc5cc43)cc2)c2ccc3c(c2)C2(c4ccccc4-c4ccccc42)c2ccccc2-3)cc1 ; c1ccc(-c2ccc(-c3ccc(N(c4ccc(-c5ccccc5)cc4)c4ccc(-c5ccccc5-n5c6ccccc6c6cc7ccccc7cc65)cc4)cc3)cc2)cc1]

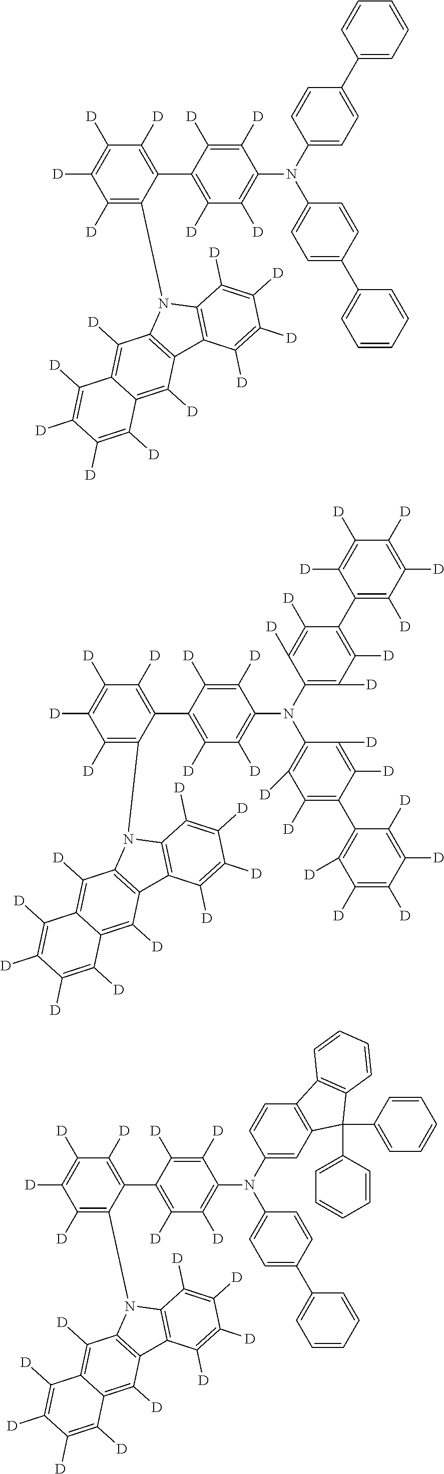

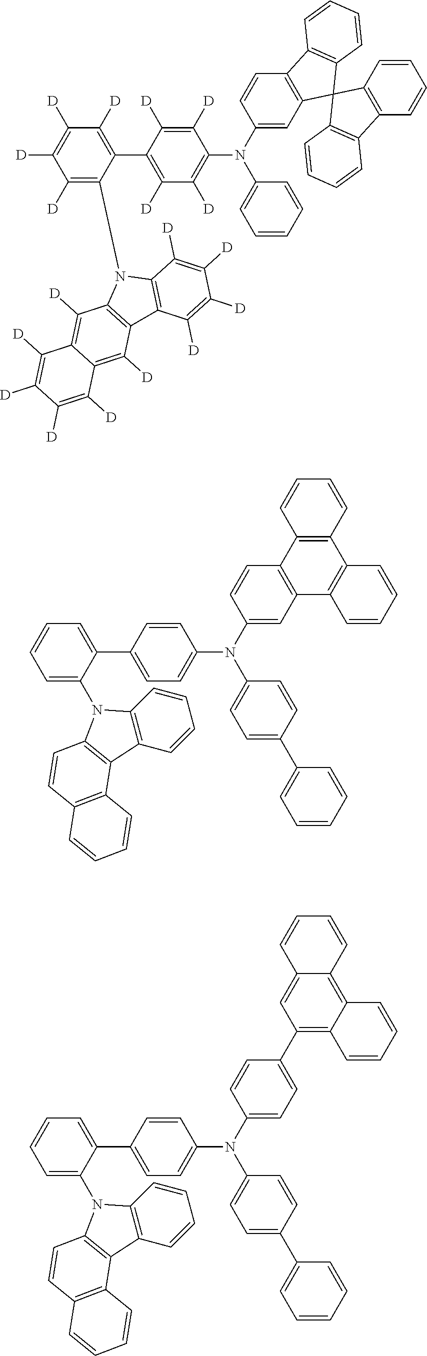 [SMILES: [2H]c1c([2H])c([2H])c(-n2c3c([2H])c([2H])c([2H])c([2H])c3c3c([2H])c4c([2H])c([2H])c([2H])c([2H])c4c([2H])c32)c(-c2c([2H])c([2H])c(N(c3ccccc3)c3ccc4c(c3)C3(c5ccccc5-c5ccccc53)c3ccccc3-4)c([2H])c2[2H])c1[2H] ; c1ccc(-c2ccc(N(c3ccc(-c4ccccc4-n4c5ccccc5c5c6ccccc6ccc54)cc3)c3ccc4c5ccccc5c5ccccc5c4c3)cc2)cc1 ; c1ccc(-c2ccc(N(c3ccc(-c4ccccc4-n4c5ccccc5c5c6ccccc6ccc54)cc3)c3ccc(-c4cc5ccccc5c5ccccc45)cc3)cc2)cc1]

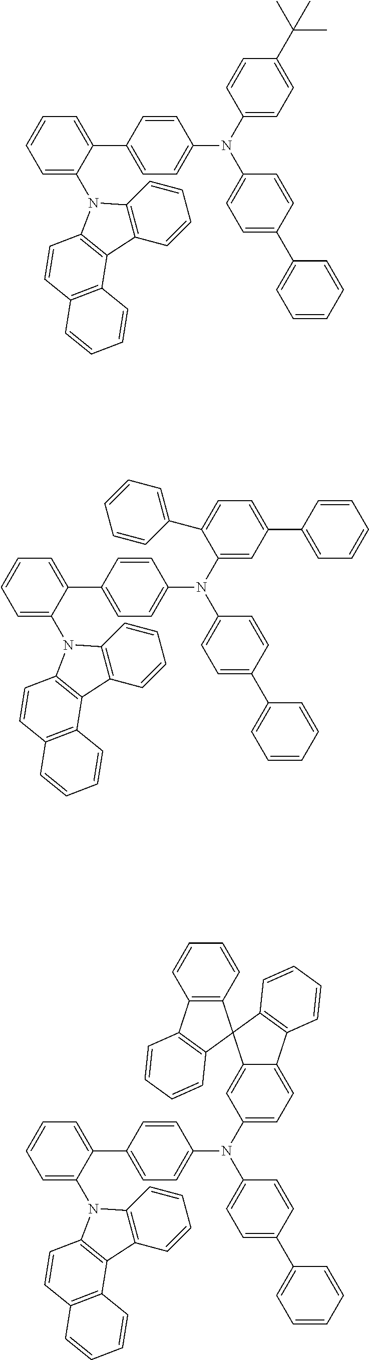 [SMILES: CC(C)(C)c1ccc(N(c2ccc(-c3ccccc3)cc2)c2ccc(-c3ccccc3-n3c4ccccc4c4c5ccccc5ccc43)cc2)cc1 ; c1ccc(-c2ccc(N(c3ccc(-c4ccccc4-n4c5ccccc5c5c6ccccc6ccc54)cc3)c3cc(-c4ccccc4)ccc3-c3ccccc3)cc2)cc1 ; c1ccc(-c2ccc(N(c3ccc(-c4ccccc4-n4c5ccccc5c5c6ccccc6ccc54)cc3)c3ccc4c(c3)C3(c5ccccc5-c5ccccc53)c3ccccc3-4)cc2)cc1]

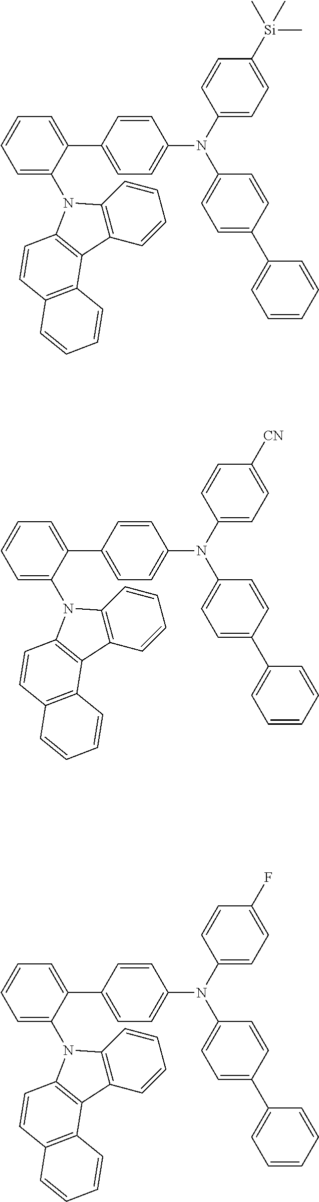 [SMILES: C[Si](C)(C)c1ccc(N(c2ccc(-c3ccccc3)cc2)c2ccc(-c3ccccc3-n3c4ccccc4c4c5ccccc5ccc43)cc2)cc1 ; N#Cc1ccc(N(c2ccc(-c3ccccc3)cc2)c2ccc(-c3ccccc3-n3c4ccccc4c4c5ccccc5ccc43)cc2)cc1 ; Fc1ccc(N(c2ccc(-c3ccccc3)cc2)c2ccc(-c3ccccc3-n3c4ccccc4c4c5ccccc5ccc43)cc2)cc1]

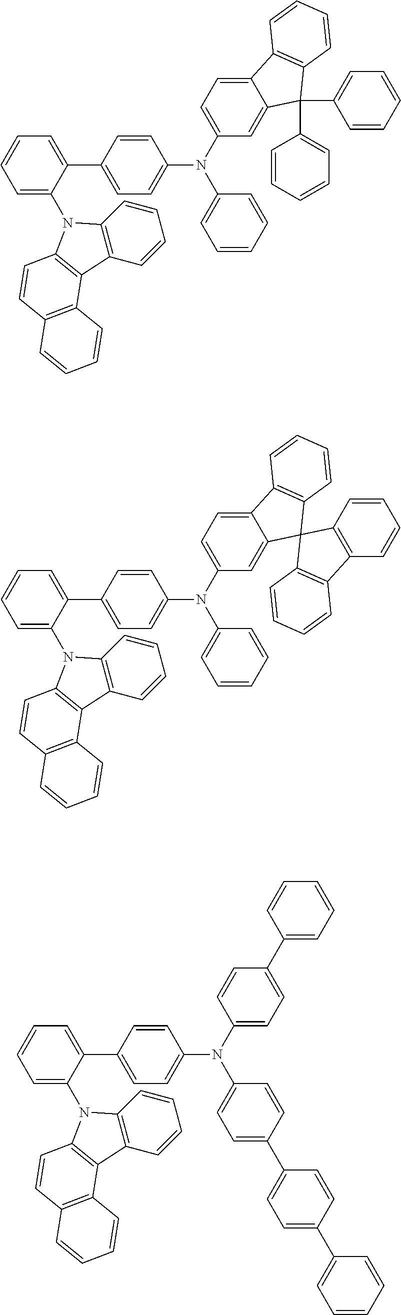 [SMILES: c1ccc(N(c2ccc(-c3ccccc3-n3c4ccccc4c4c5ccccc5ccc43)cc2)c2ccc3c(c2)C(c2ccccc2)(c2ccccc2)c2ccccc2-3)cc1 ; c1ccc(N(c2ccc(-c3ccccc3-n3c4ccccc4c4c5ccccc5ccc43)cc2)c2ccc3c(c2)C2(c4ccccc4-c4ccccc42)c2ccccc2-3)cc1 ; c1ccc(-c2ccc(-c3ccc(N(c4ccc(-c5ccccc5)cc4)c4ccc(-c5ccccc5-n5c6ccccc6c6c7ccccc7ccc65)cc4)cc3)cc2)cc1]

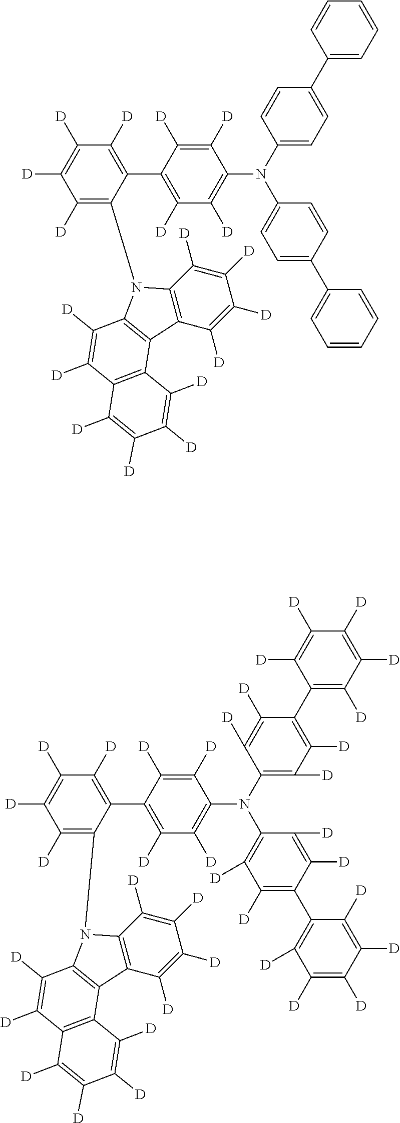 [SMILES: [2H]c1c([2H])c([2H])c(-n2c3c([2H])c([2H])c([2H])c([2H])c3c3c4c([2H])c([2H])c([2H])c([2H])c4c([2H])c([2H])c32)c(-c2c([2H])c([2H])c(N(c3ccc(-c4ccccc4)cc3)c3ccc(-c4ccccc4)cc3)c([2H])c2[2H])c1[2H] ; [2H]c1c([2H])c([2H])c(-c2c([2H])c([2H])c(N(c3c([2H])c([2H])c(-c4c([2H])c([2H])c([2H])c([2H])c4[2H])c([2H])c3[2H])c3c([2H])c([2H])c(-c4c([2H])c([2H])c([2H])c([2H])c4-n4c5c([2H])c([2H])c([2H])c([2H])c5c5c6c([2H])c([2H])c([2H])c([2H])c6c([2H])c([2H])c54)c([2H])c3[2H])c([2H])c2[2H])c([2H])c1[2H]]

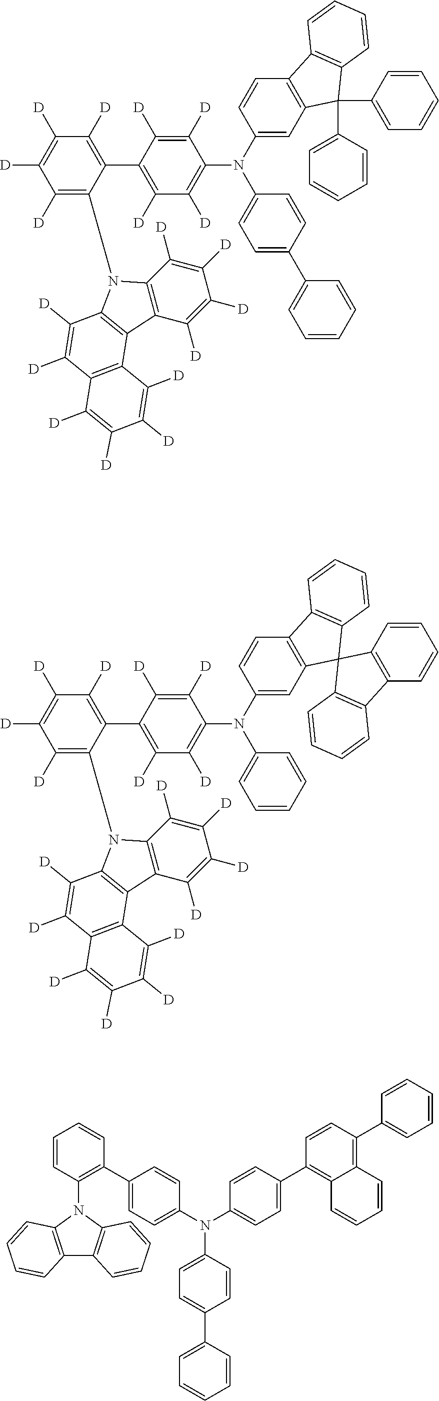

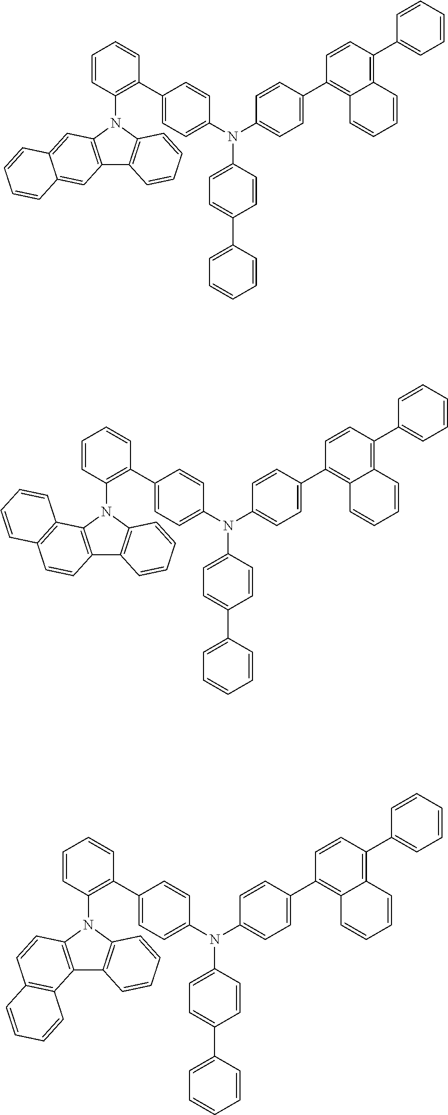 [SMILES: c1ccc(-c2ccc(N(c3ccc(-c4ccccc4-n4c5ccccc5c5cc6ccccc6cc54)cc3)c3ccc(-c4ccc(-c5ccccc5)c5ccccc45)cc3)cc2)cc1 ; c1ccc(-c2ccc(N(c3ccc(-c4ccccc4-n4c5ccccc5c5ccc6ccccc6c54)cc3)c3ccc(-c4ccc(-c5ccccc5)c5ccccc45)cc3)cc2)cc1 ; c1ccc(-c2ccc(N(c3ccc(-c4ccccc4-n4c5ccccc5c5c6ccccc6ccc54)cc3)c3ccc(-c4ccc(-c5ccccc5)c5ccccc45)cc3)cc2)cc1]

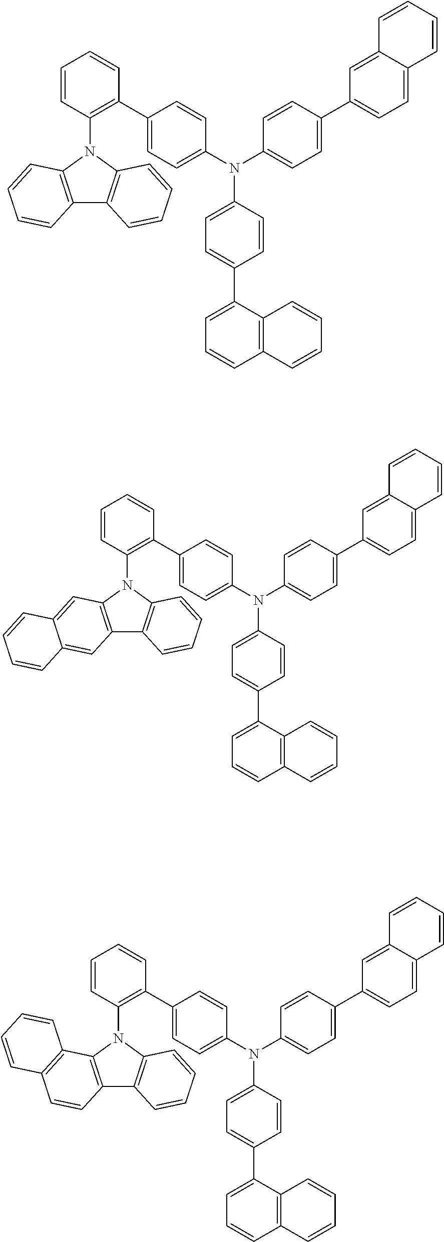 [SMILES: c1ccc(-n2c3ccccc3c3ccccc32)c(-c2ccc(N(c3ccc(-c4ccc5ccccc5c4)cc3)c3ccc(-c4cccc5ccccc45)cc3)cc2)c1 ; c1ccc(-n2c3ccccc3c3cc4ccccc4cc32)c(-c2ccc(N(c3ccc(-c4ccc5ccccc5c4)cc3)c3ccc(-c4cccc5ccccc45)cc3)cc2)c1 ; c1ccc(-n2c3ccccc3c3ccc4ccccc4c32)c(-c2ccc(N(c3ccc(-c4ccc5ccccc5c4)cc3)c3ccc(-c4cccc5ccccc45)cc3)cc2)c1]

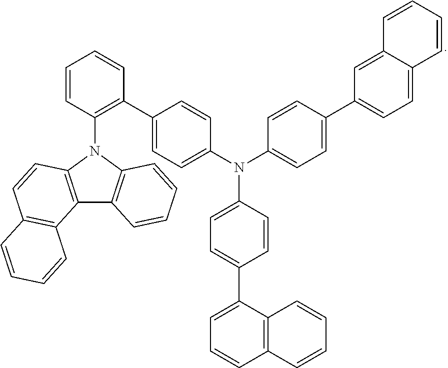 [SMILES: c1ccc(-n2c3ccccc3c3c4ccccc4ccc32)c(-c2ccc(N(c3ccc(-c4ccc5ccccc5c4)cc3)c3ccc(-c4cccc5ccccc45)cc3)cc2)c1]

6. The organic light emitting device according to claim 1, wherein
Ar₂₁ and Ar₂₂ are each independently phenyl, biphenylyl, naphthyl, phenylnaphthyl, naphthylphenyl, dibenzofuranyl, (phenyl)dibenzofuranyl, or benzonaphthofuranyl, and
Ar₂₁ and Ar₂₂ are unsubstituted or substituted with at least one deuterium.

7. The organic light emitting device according to claim 1, wherein
R₂ is hydrogen, deuterium, phenyl, phenyl substituted with 1 to 5 deuteriums, naphthyl or naphthyl substituted with 1 to 7 deuteriums.

8. The organic light emitting device according to claim 1, wherein
one of R₂ is phenyl, phenyl substituted with 1 to 5 deuteriums, naphthyl or naphthyl substituted with 1 to 7 deuteriums, and the rest is hydrogen or deuterium.

9. The organic light emitting device according to claim 1, wherein:
the compound represented by Chemical Formula 2 is any one selected from the group consisting of the following:

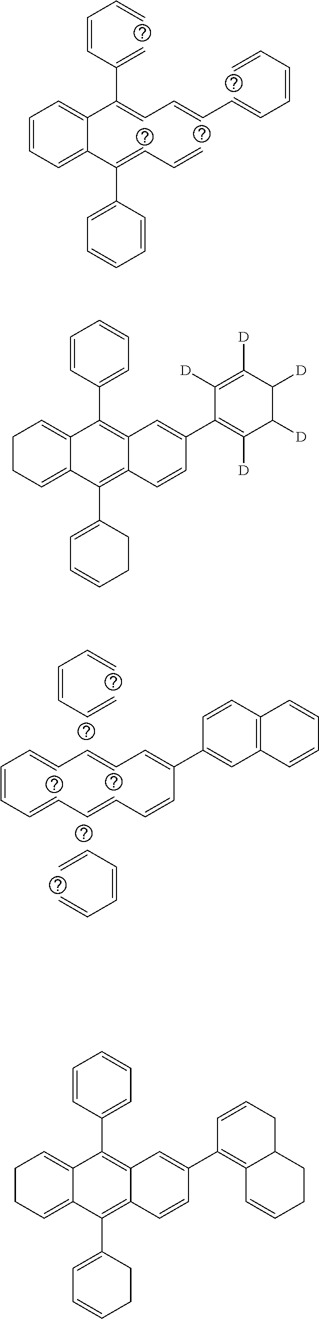

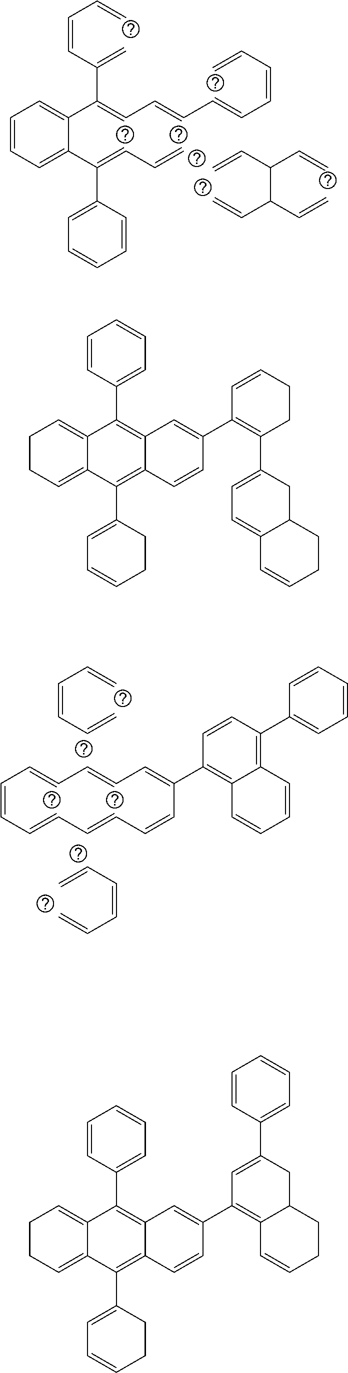

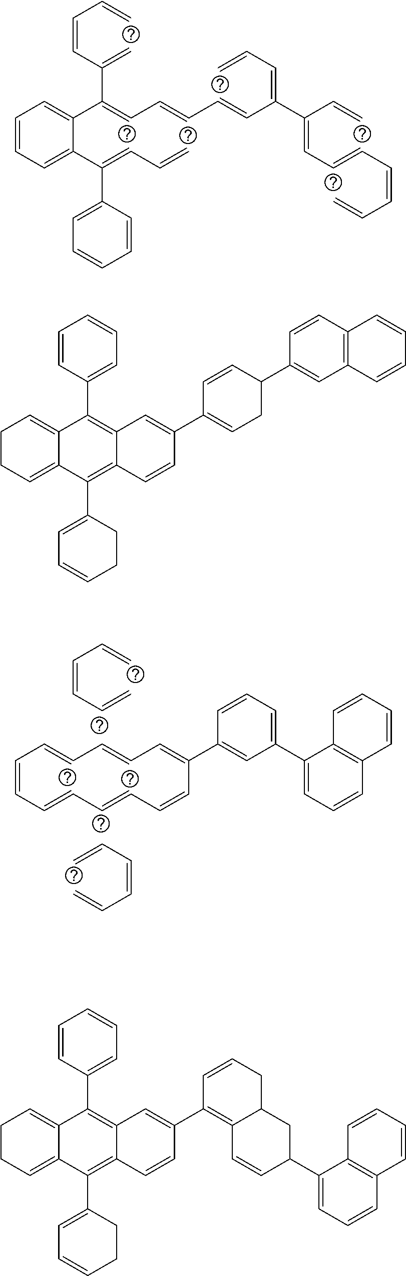

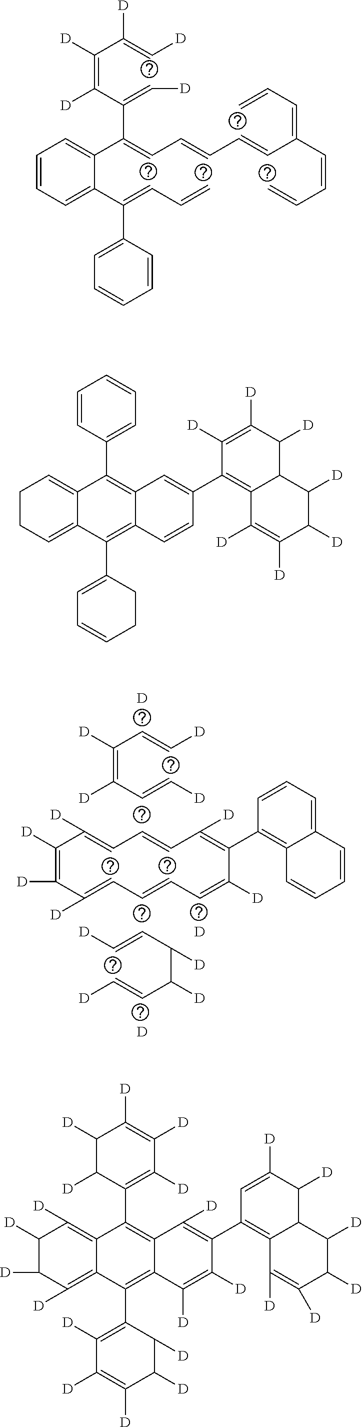

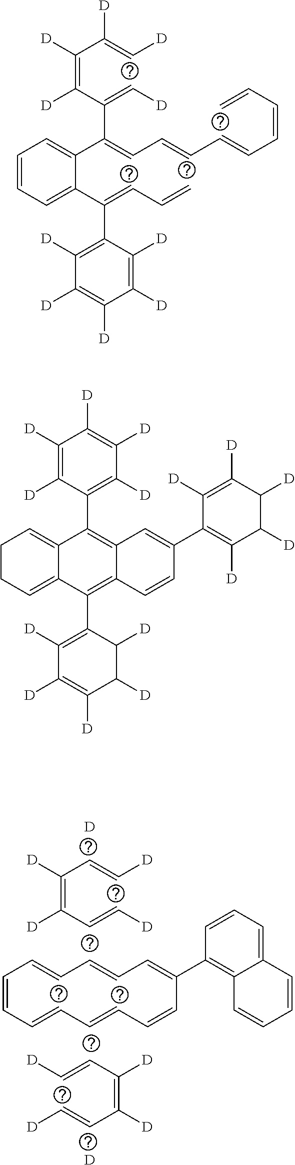

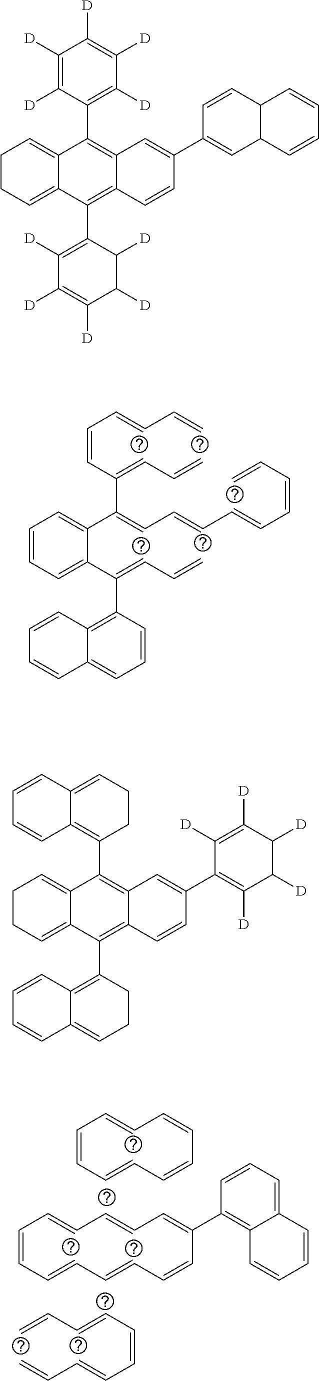

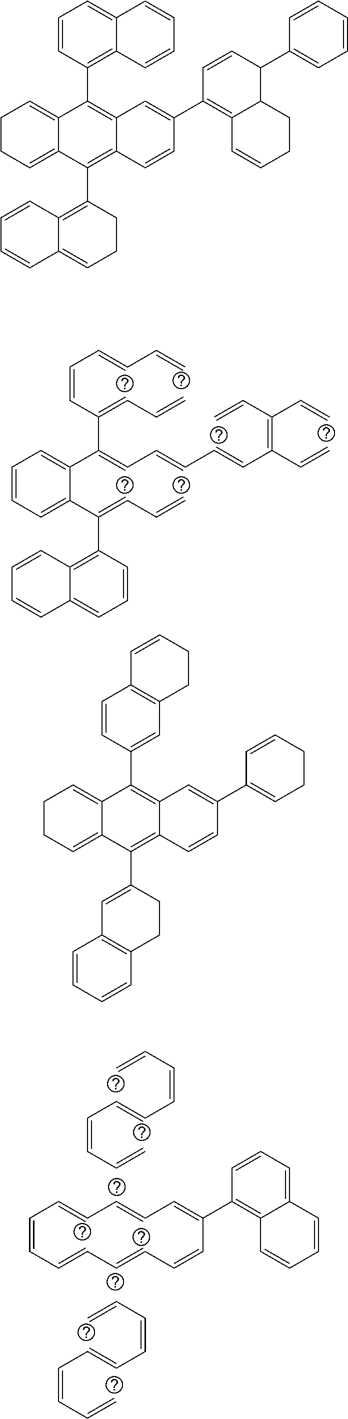

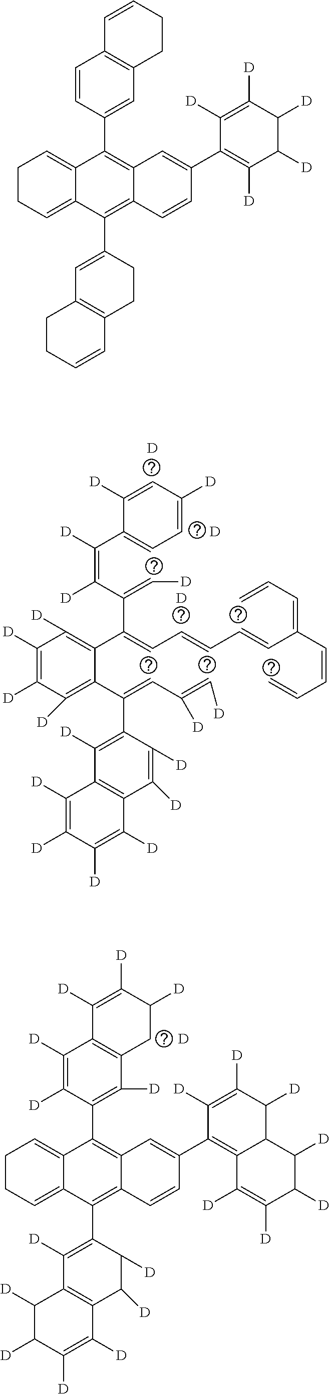

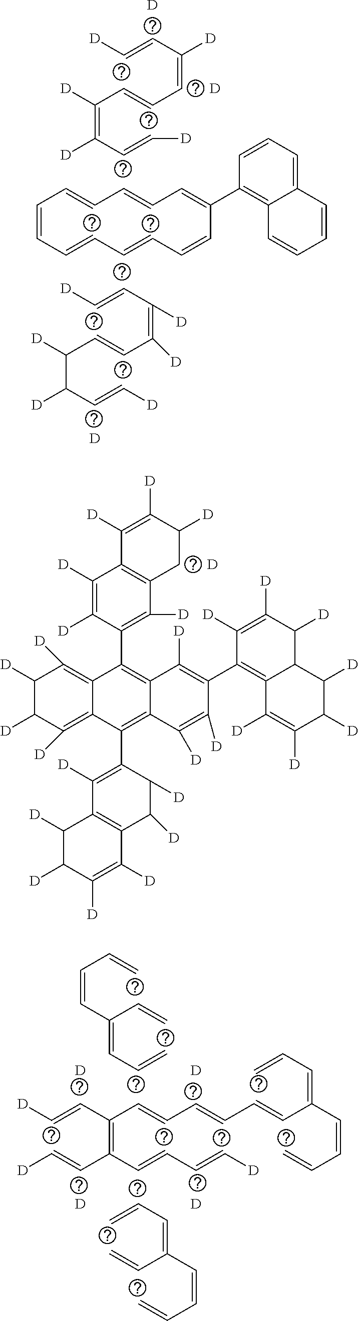

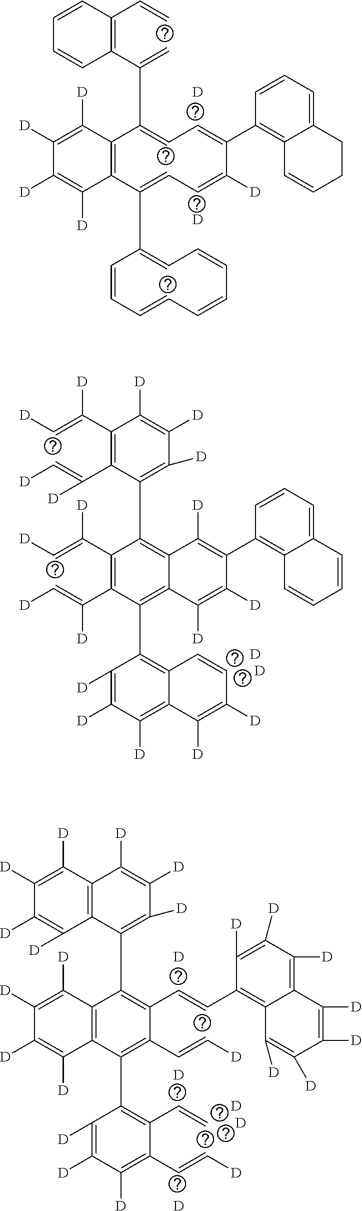

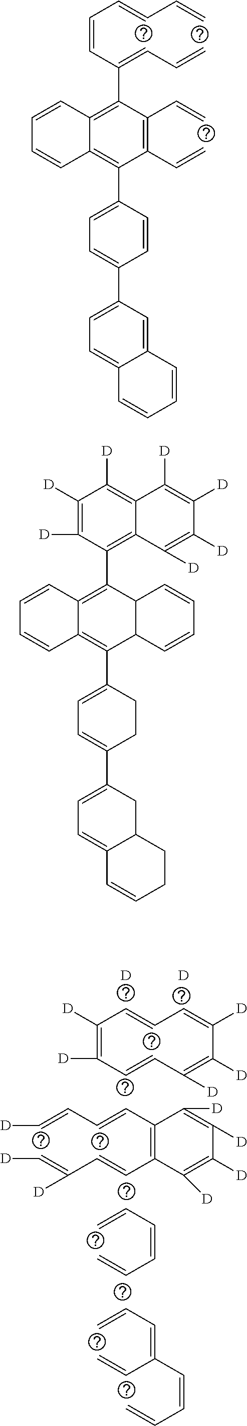

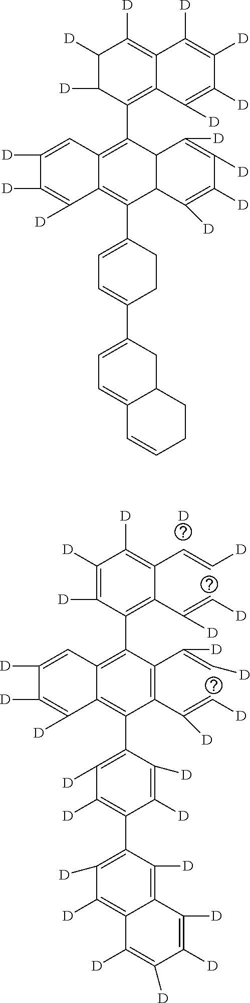

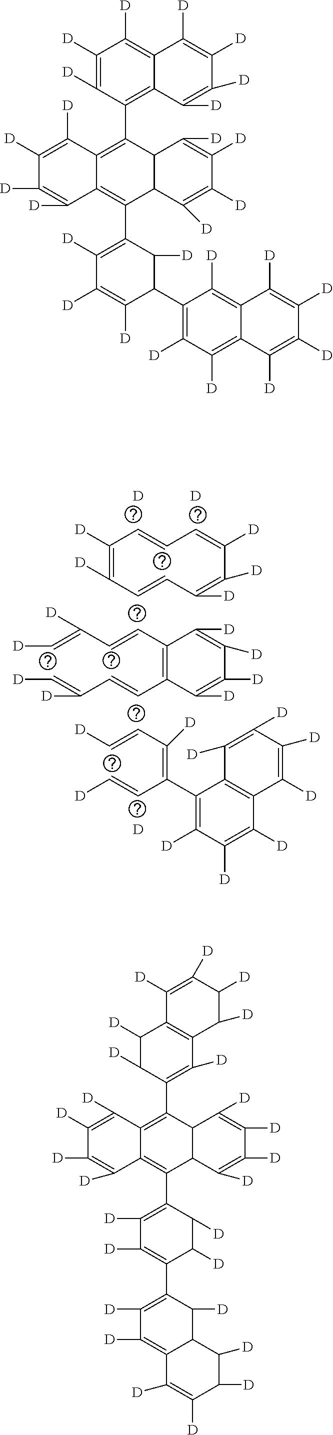

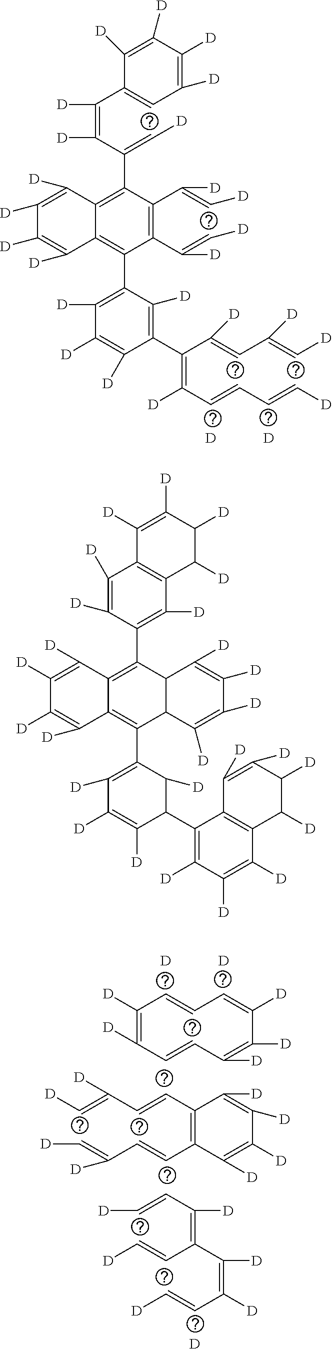

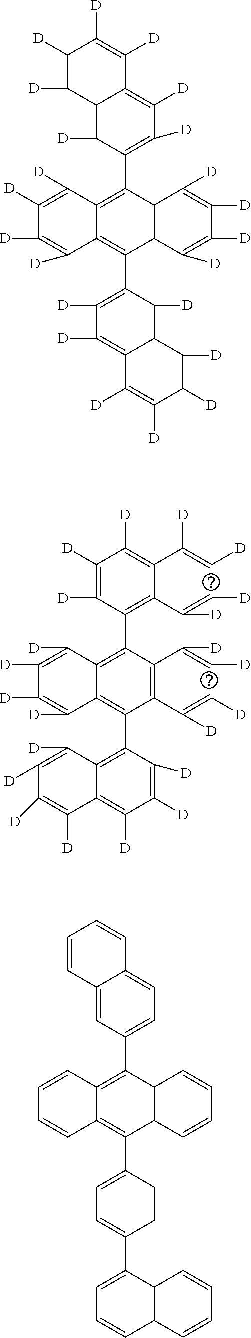

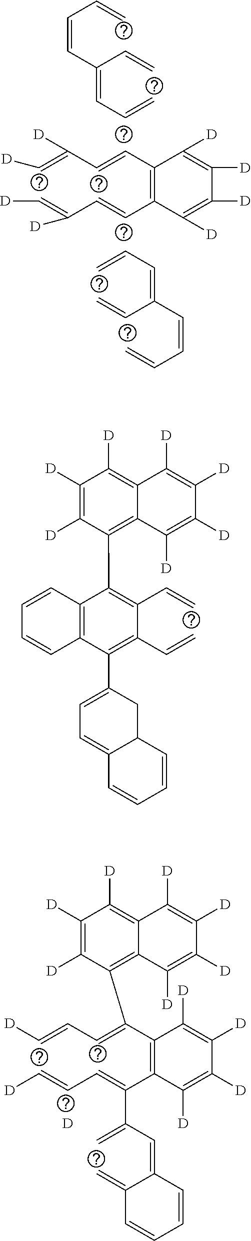

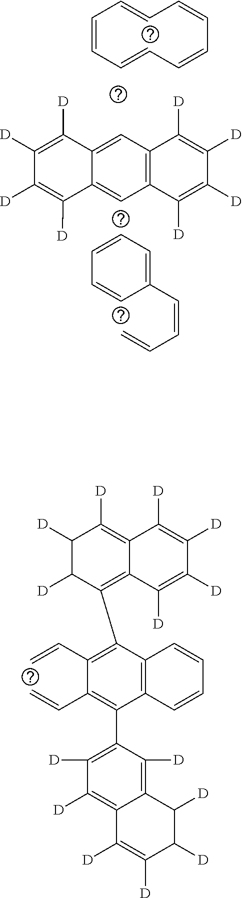

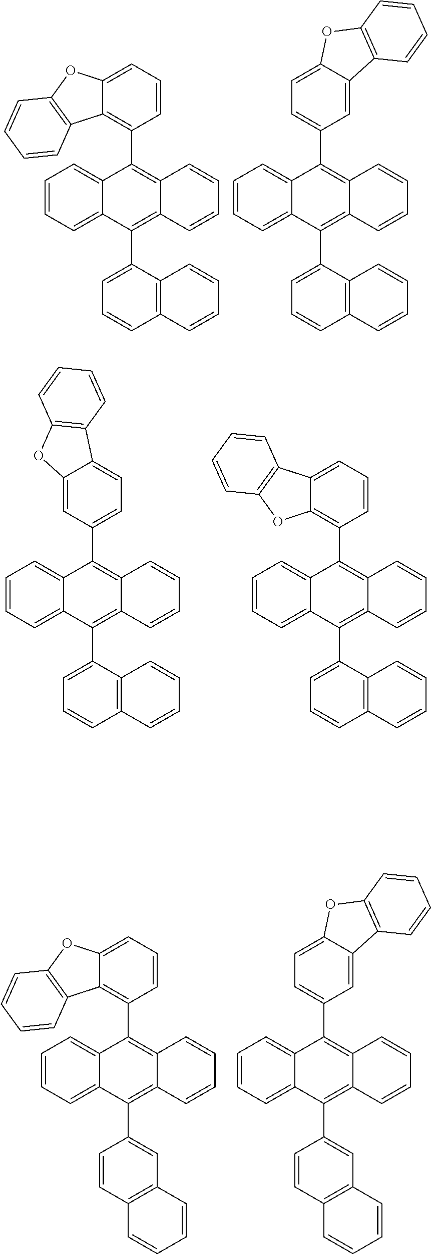

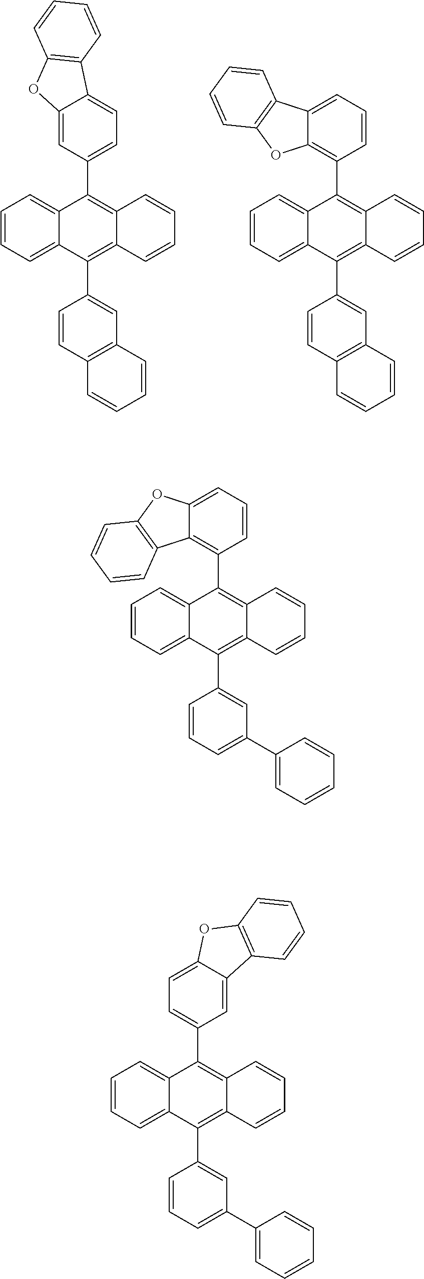 [SMILES: c1ccc2cc(-c3c4ccccc4c(-c4ccc5c(c4)oc4ccccc45)c4ccccc34)ccc2c1 ; c1ccc2cc(-c3c4ccccc4c(-c4cccc5c4oc4ccccc45)c4ccccc34)ccc2c1 ; c1ccc(-c2cccc(-c3c4ccccc4c(-c4cccc5oc6ccccc6c45)c4ccccc34)c2)cc1 ; c1ccc(-c2cccc(-c3c4ccccc4c(-c4ccc5oc6ccccc6c5c4)c4ccccc34)c2)cc1]

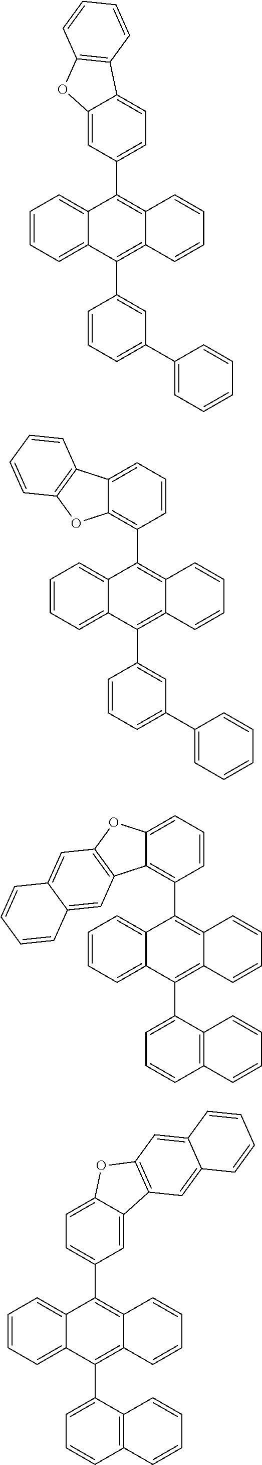

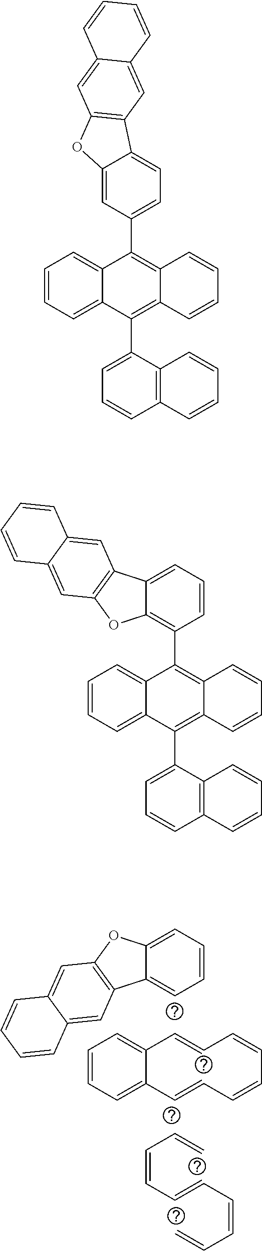

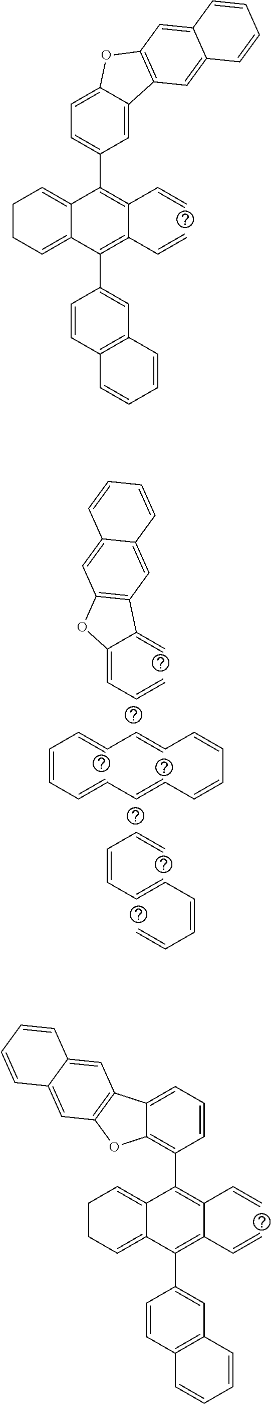

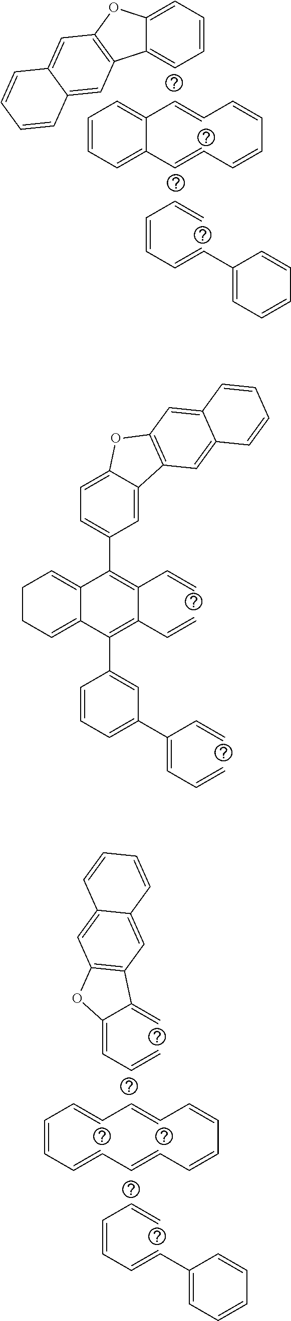

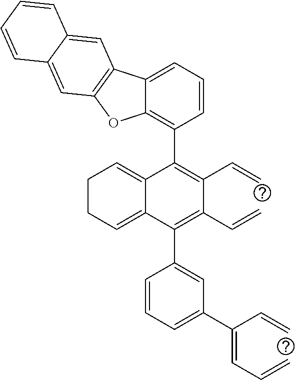 [SMILES: C=C/C=C(\C=C)c1cccc(-c2c(C=C)c(C=C)c(-c3cccc4c3oc3cc5ccccc5cc34)c3c2=CCCC=3)c1]

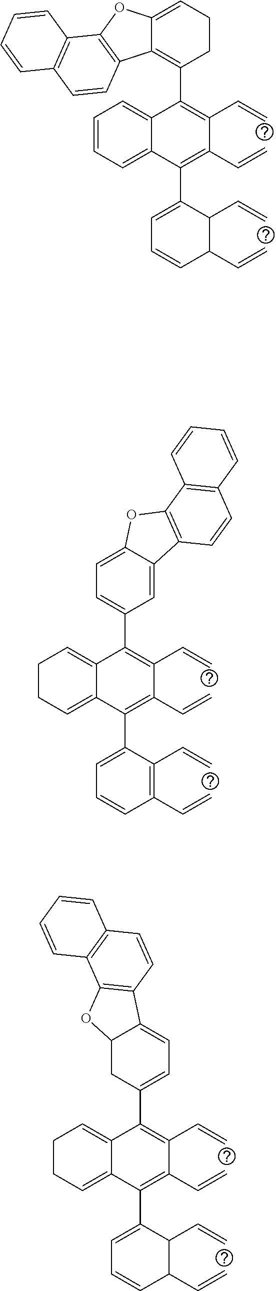 [SMILES: C=Cc1c(C=C)c(C2=c3c(oc4c3ccc3ccccc34)=CCC2)c2ccccc2c1C1=CC=CC(C=C)C1C=C ; C=Cc1cccc(-c2c(C=C)c(C=C)c(-c3ccc4oc5c6ccccc6ccc5c4c3)c3c2=CCCC=3)c1C=C ; C=Cc1c(C=C)c(C2=CC=CC(C=C)C2C=C)c2c(c1C1=CC=C3c4ccc5ccccc5c4OC3C1)=CCCC=2]

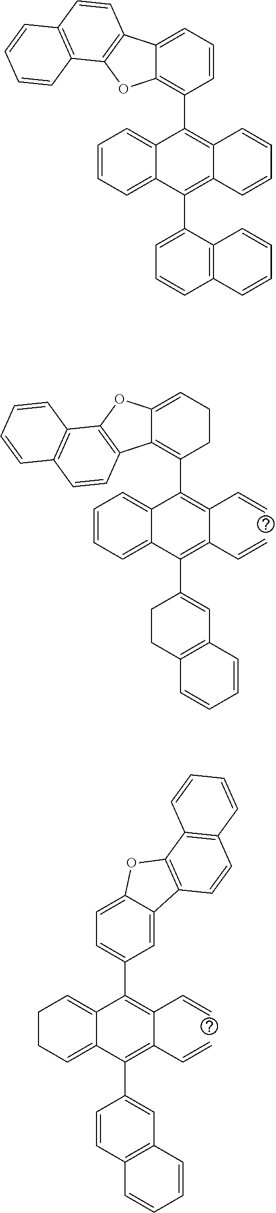 [SMILES: c1ccc2c(-c3c4ccccc4c(-c4cccc5c4oc4c6ccccc6ccc54)c4ccccc34)cccc2c1 ; C=Cc1c(C=C)c(C2=c3c(oc4c3ccc3ccccc34)=CCC2)c2ccccc2c1C1=Cc2ccccc2CC1 ; C=Cc1c(C=C)c(-c2ccc3oc4c5ccccc5ccc4c3c2)c2c(c1-c1ccc3ccccc3c1)=CCCC=2]

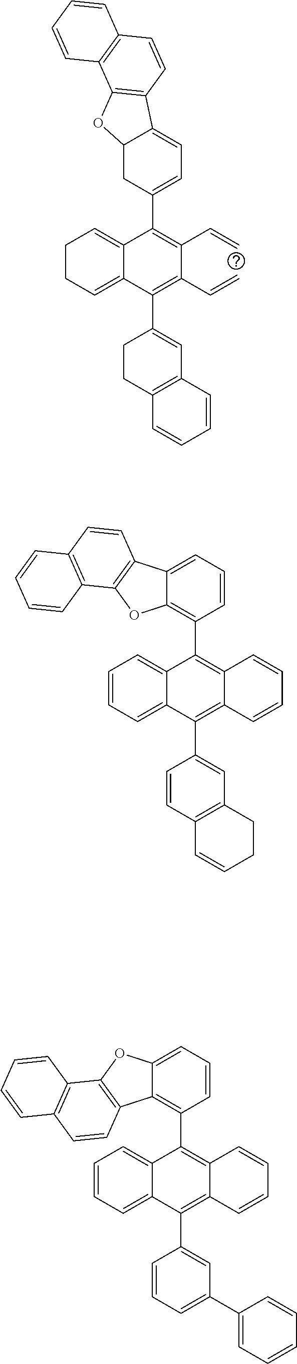 [SMILES: C=Cc1c(C=C)c(C2=CC=C3c4ccc5ccccc5c4OC3C2)c2c(c1C1=Cc3ccccc3CC1)=CCCC=2 ; C1=Cc2ccc(-c3c4ccccc4c(-c4cccc5c4oc4c6ccccc6ccc54)c4ccccc34)cc2CC1 ; c1ccc(-c2cccc(-c3c4ccccc4c(-c4cccc5oc6c7ccccc7ccc6c45)c4ccccc34)c2)cc1]

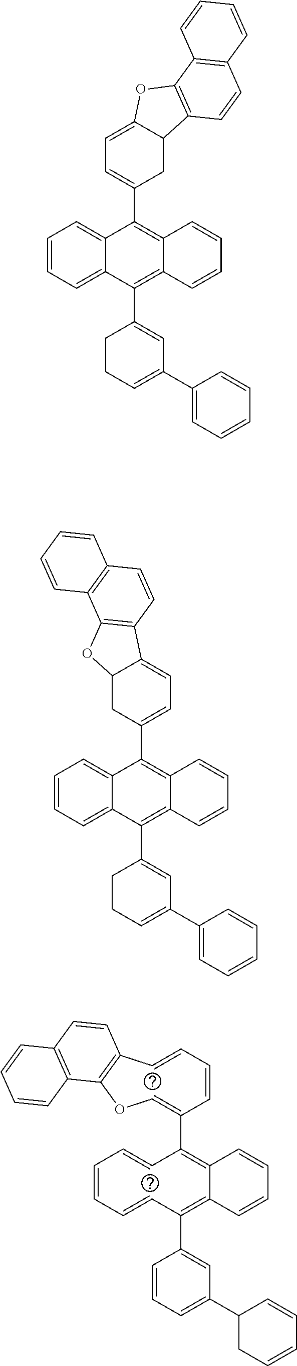 [SMILES: C1=C(c2ccccc2)C=C(c2c3ccccc3c(C3=CC=C4Oc5c(ccc6ccccc56)C4C3)c3ccccc23)CC1 ; C1=C(c2ccccc2)C=C(c2c3ccccc3c(C3=CC=C4c5ccc6ccccc6c5OC4C3)c3ccccc23)CC1 ; C1=CCC(c2cccc(-c3ccccccc(C4=C\Oc5c(ccc6ccccc56)/C=C/C=C\4)c4ccccc34)c2)C=C1]

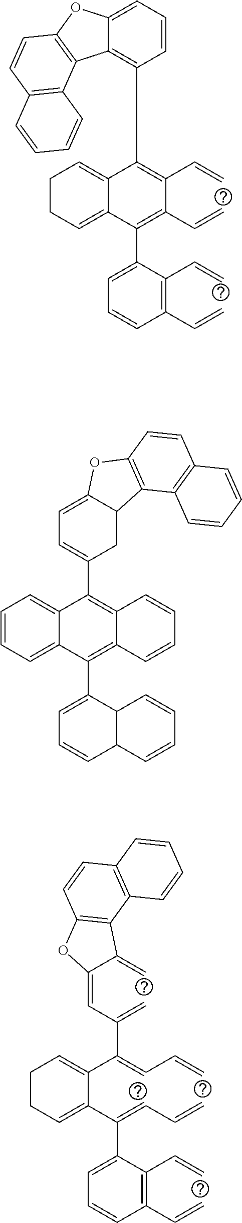 [SMILES: C=Cc1cccc(-c2c(C=C)c(C=C)c(-c3cccc4oc5ccc6ccccc6c5c34)c3c2=CCCC=3)c1C=C ; C1=CC2C=CC=C(c3c4ccccc4c(C4=CC=C5Oc6ccc7ccccc7c6C5C4)c4ccccc34)C2C=C1 ; C=C/C=C(/C1=CCCC=C1/C(=C/C=C)C(=C)/C=c1/oc2ccc3ccccc3c2c1=C)c1cccc(C=C)c1C=C]

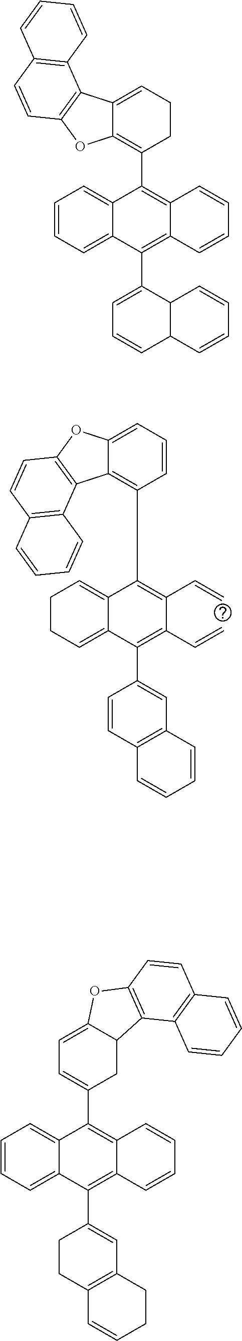 [SMILES: C1=CC2C=CC=C(c3c4ccccc4c(C4=c5oc6ccc7ccccc7c6c5=CCC4)c4ccccc34)C2C=C1 ; C=Cc1c(C=C)c(-c2cccc3oc4ccc5ccccc5c4c23)c2c(c1-c1ccc3ccccc3c1)=CCCC=2 ; C1=CC2=C(C=C(c3c4ccccc4c(C4=CC=C5Oc6ccc7ccccc7c6C5C4)c4ccccc34)CC2)CC1]

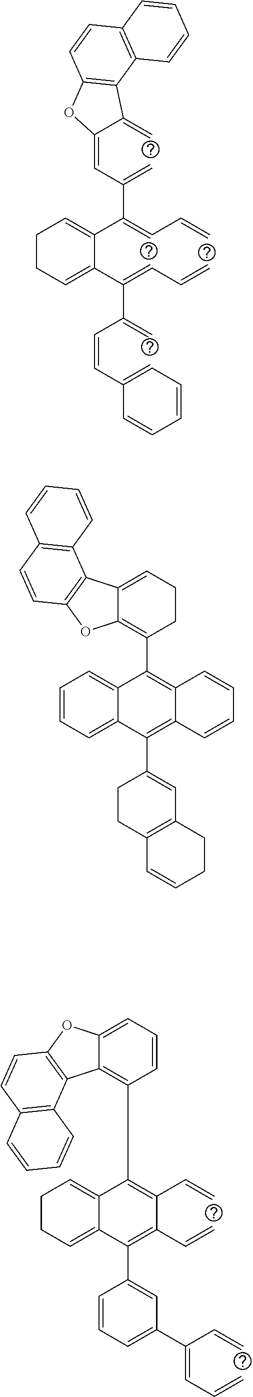 [SMILES: C=C/C=C(\C(=C)/C=C\c1ccccc1)C1=CCCC=C1/C(=C/C=C)C(=C)/C=c1/oc2ccc3ccccc3c2c1=C ; C1=CC2=C(C=C(c3c4ccccc4c(C4=c5oc6ccc7ccccc7c6c5=CCC4)c4ccccc34)CC2)CC1 ; C=C/C=C(\C=C)c1cccc(-c2c(C=C)c(C=C)c(-c3cccc4oc5ccc6ccccc6c5c34)c3c2=CCCC=3)c1]

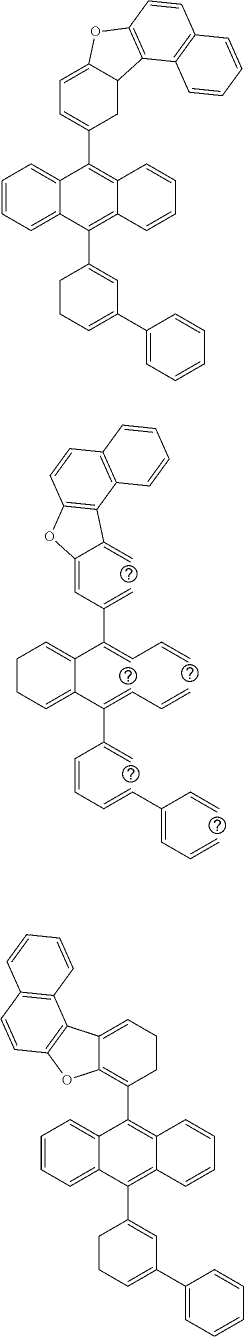 [SMILES: C1=C(c2ccccc2)C=C(c2c3ccccc3c(C3=CC=C4Oc5ccc6ccccc6c5C4C3)c3ccccc23)CC1 ; C=C/C=C(C=C)/C=C/C=C\C(=C)/C(=C\C=C)C1=CCCC=C1/C(=C/C=C)C(=C)/C=c1/oc2ccc3ccccc3c2c1=C ; C1=C(c2ccccc2)C=C(c2c3ccccc3c(C3=c4oc5ccc6ccccc6c5c4=CCC3)c3ccccc23)CC1]

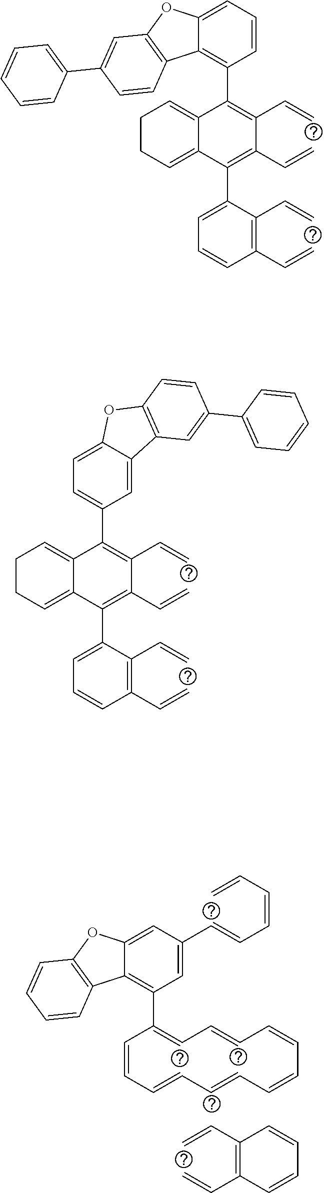

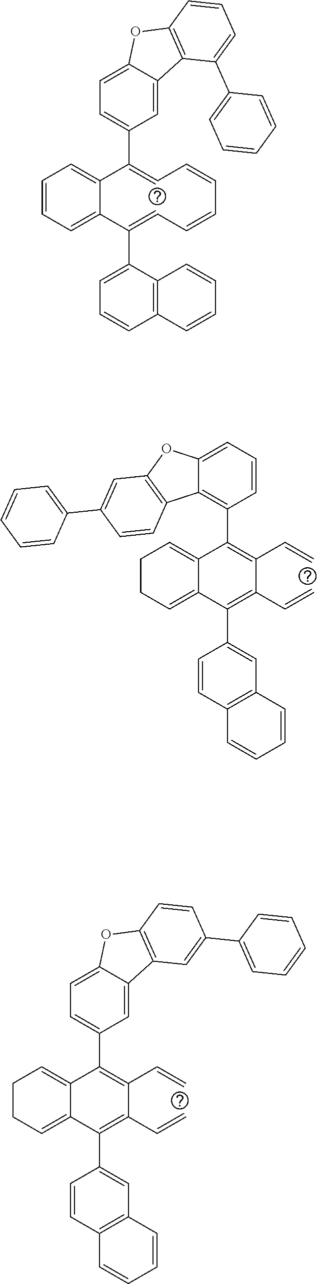 [SMILES: c1ccc(-c2cccc3oc4ccc(-c5ccccccc(-c6cccc7ccccc67)c6ccccc56)cc4c23)cc1 ; C=Cc1c(C=C)c(-c2cccc3oc4cc(-c5ccccc5)ccc4c23)c2c(c1-c1ccc3ccccc3c1)=CCCC=2 ; C=Cc1c(C=C)c(-c2ccc3oc4ccc(-c5ccccc5)cc4c3c2)c2c(c1-c1ccc3ccccc3c1)=CCCC=2]

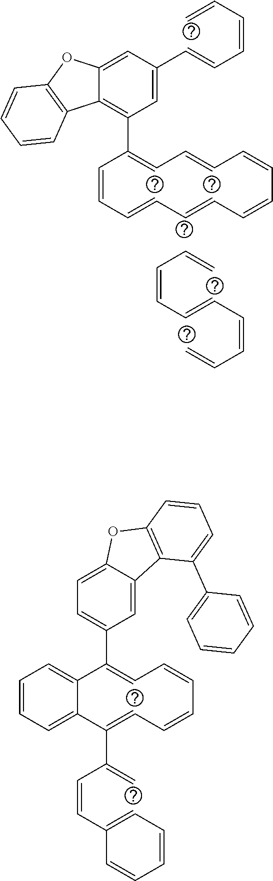

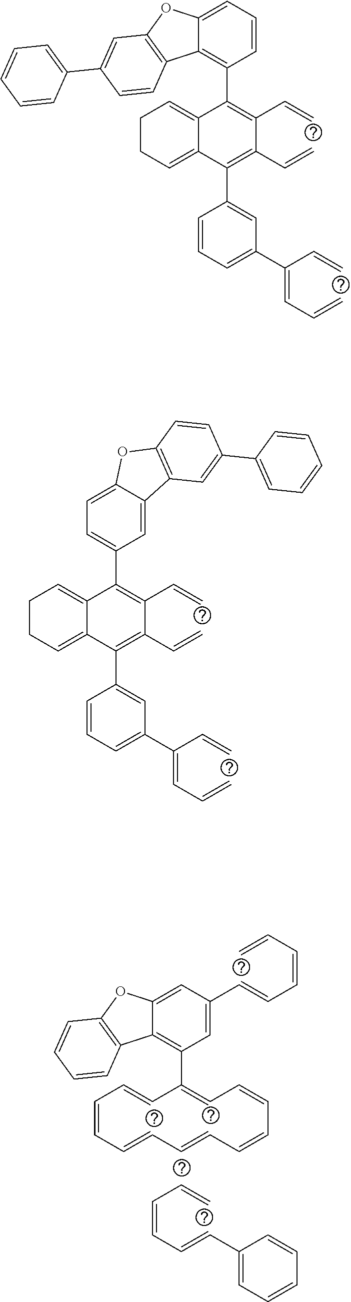

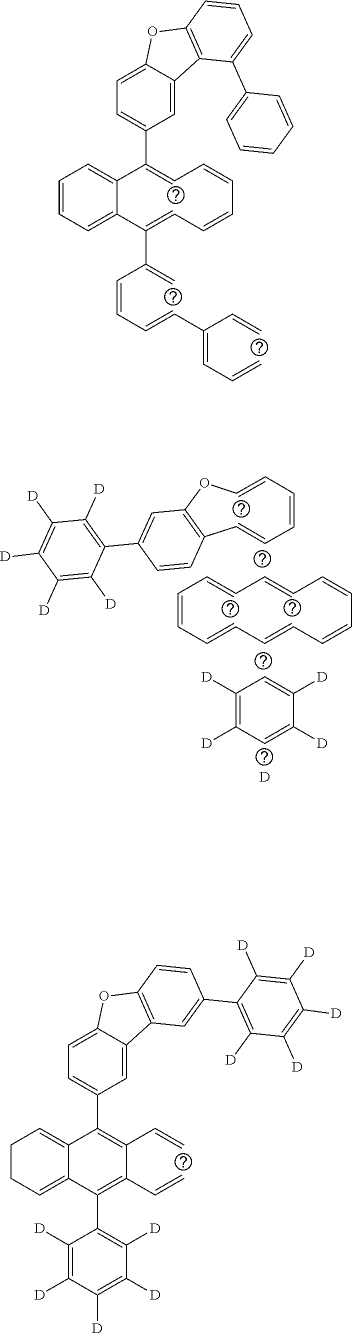

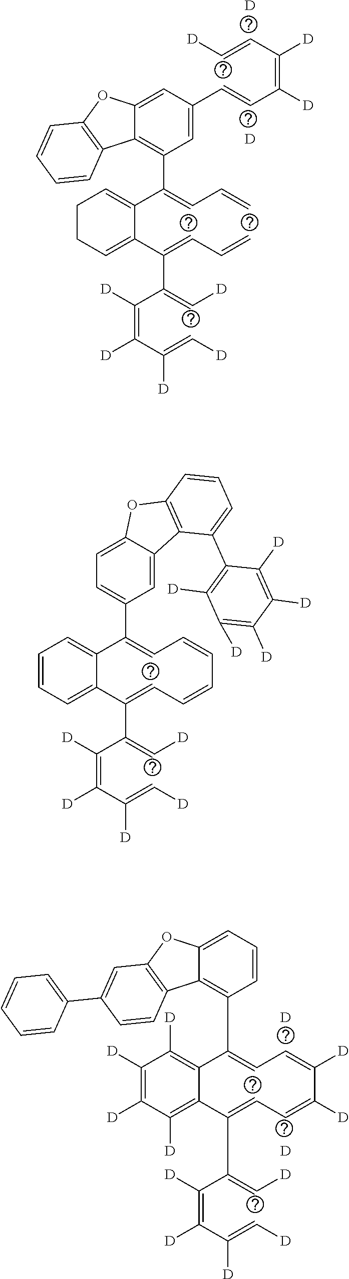

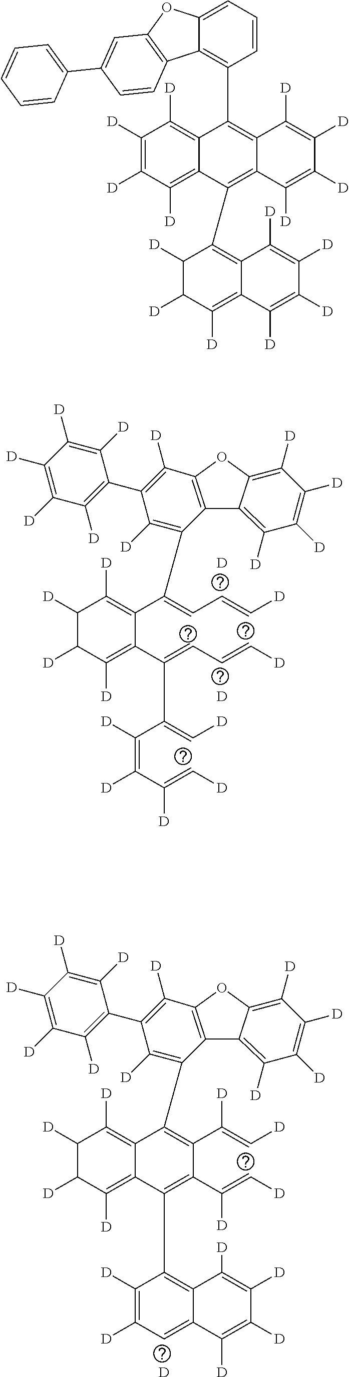

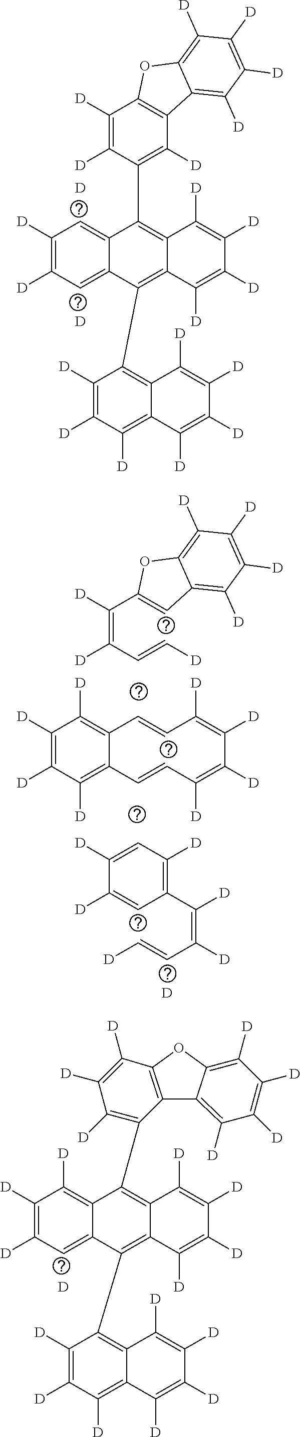

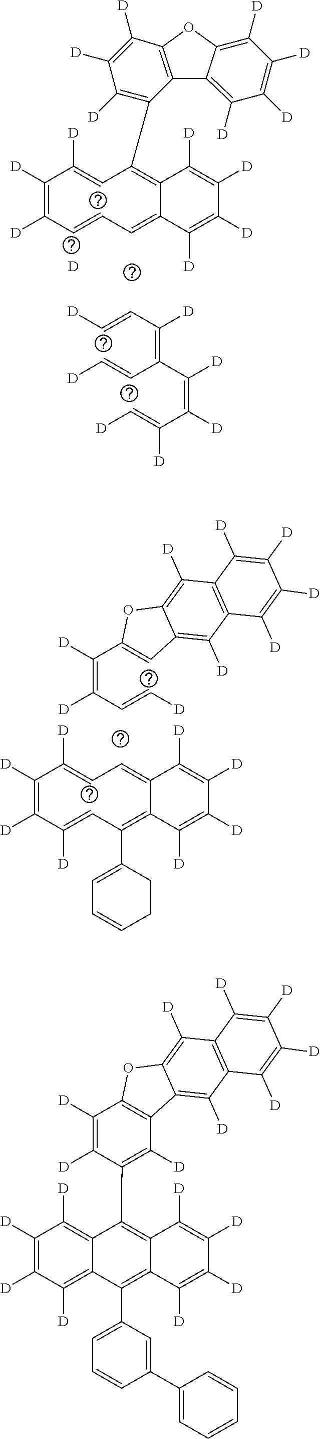

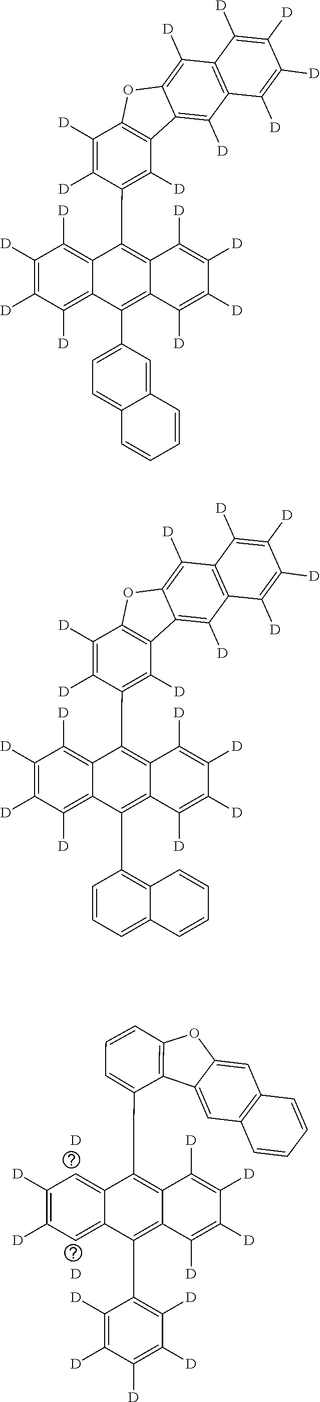

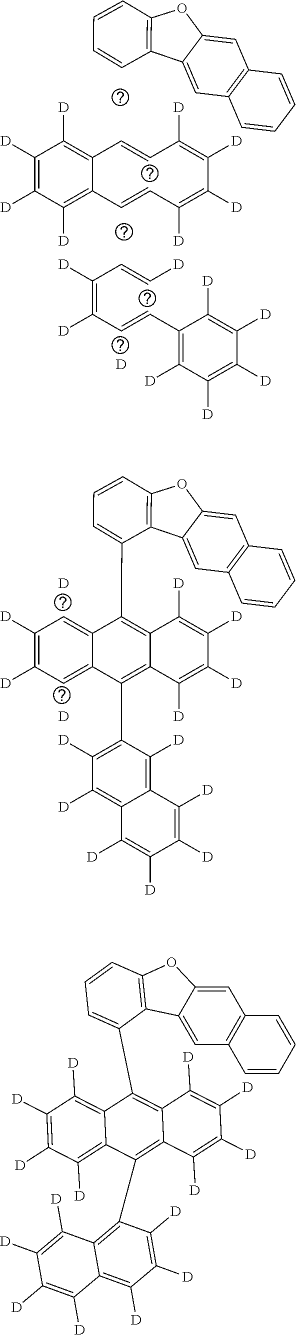

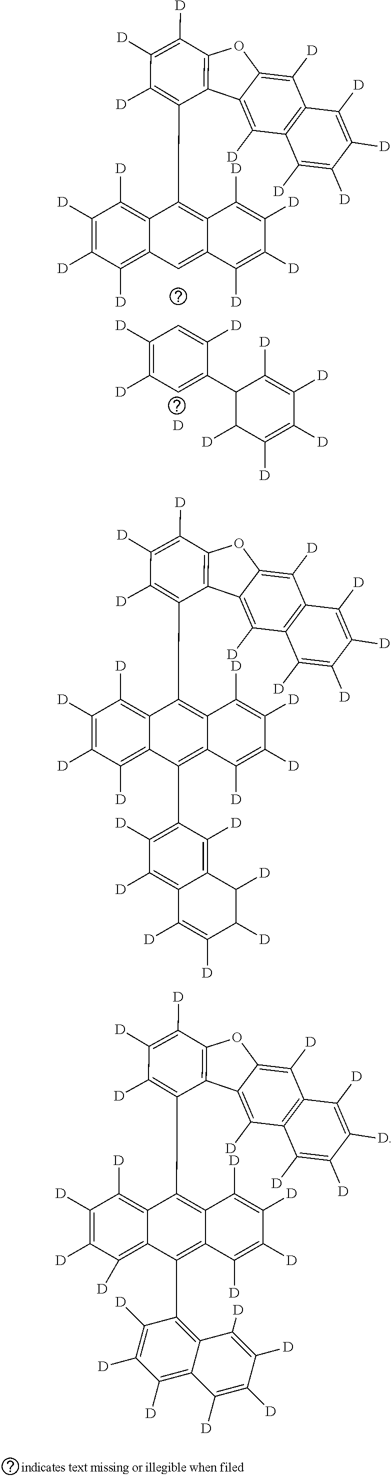

10. The organic light emitting device according to claim 1, wherein
Ar₃₁ and Ar₃₂ are each independently phenyl, biphenylyl, naphthylphenyl, phenylnaphthyl, or pyridinylphenyl,
and Ar₃₁ and Ar₃₂ are unsubstituted or substituted least one deuterium, cyano, or a C₁₋₁₀ alkyl.

11. The organic light emitting device according to claim 1, wherein
L₃₁ and L₃₂ are each independently a single bond or phenylene.

12. The organic light emitting device according to claim 1, wherein
Ar₃₃ is phenyl, biphenylyl, dimethyl fluorenyl, naphthyl, triphenylenyl, fluoranthenyl, diphenylfluorenyl, pyridinyl, pyrimidinyl, quinolinyl, isoquinolinyl, imidazolyl, furanyl, pyridazinyl, dibenzofuranyl, carbazol-9-yl,
and Ar₃₃ is unsubstituted or substituted with at least one cyano, C₁₋₁₀ alkyl, or C₆₋₂₀ aryl.

13. The organic light emitting device according to claim 1, wherein
L₃₃ is a single bond, phenylene, furandiyl, or pyridinylene.

14. (canceled)

15. The organic light emitting device according to claim 1, wherein
the compound represented by Chemical Formula 3 is any one selected from the group consisting of the following:

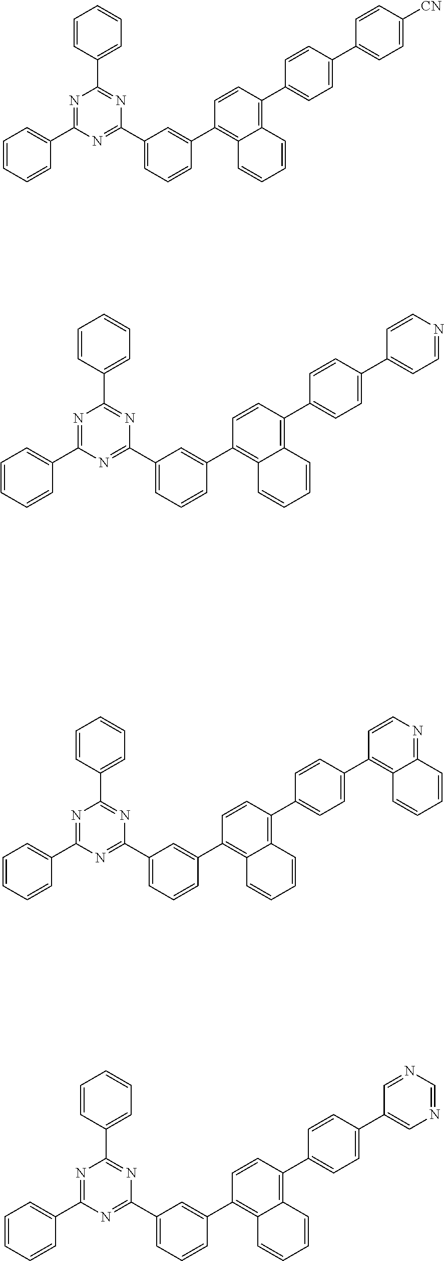 [SMILES: N#Cc1ccc(-c2ccc(-c3ccc(-c4cccc(-c5nc(-c6ccccc6)nc(-c6ccccc6)n5)c4)c4ccccc34)cc2)cc1 ; c1ccc(-c2nc(-c3ccccc3)nc(-c3cccc(-c4ccc(-c5ccc(-c6ccncc6)cc5)c5ccccc45)c3)n2)cc1 ; c1ccc(-c2nc(-c3ccccc3)nc(-c3cccc(-c4ccc(-c5ccc(-c6ccnc7ccccc67)cc5)c5ccccc45)c3)n2)cc1 ; c1ccc(-c2nc(-c3ccccc3)nc(-c3cccc(-c4ccc(-c5ccc(-c6cncnc6)cc5)c5ccccc45)c3)n2)cc1]

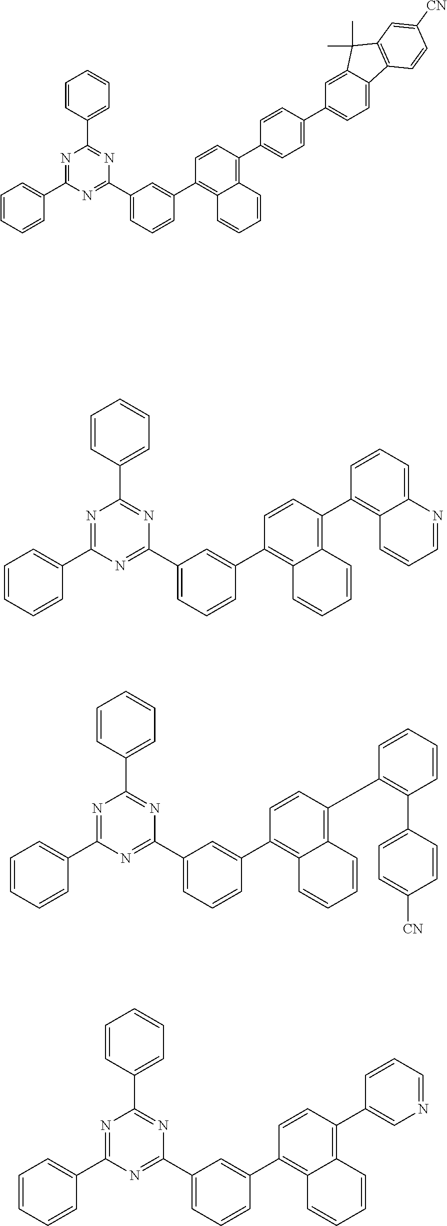 [SMILES: CC1(C)c2cc(C#N)ccc2-c2ccc(-c3ccc(-c4ccc(-c5cccc(-c6nc(-c7ccccc7)nc(-c7ccccc7)n6)c5)c5ccccc45)cc3)cc21 ; c1ccc(-c2nc(-c3ccccc3)nc(-c3cccc(-c4ccc(-c5cccc6ncccc56)c5ccccc45)c3)n2)cc1 ; N#Cc1ccc(-c2ccccc2-c2ccc(-c3cccc(-c4nc(-c5ccccc5)nc(-c5ccccc5)n4)c3)c3ccccc23)cc1 ; c1ccc(-c2nc(-c3ccccc3)nc(-c3cccc(-c4ccc(-c5cccnc5)c5ccccc45)c3)n2)cc1]

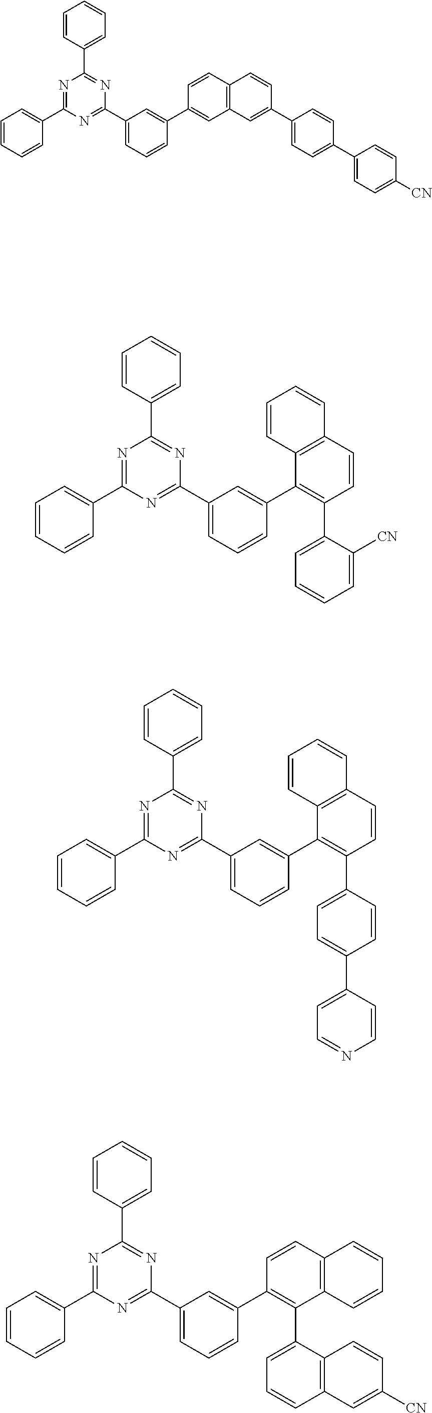 [SMILES: N#Cc1ccc(-c2ccc(-c3ccc4ccc(-c5cccc(-c6nc(-c7ccccc7)nc(-c7ccccc7)n6)c5)cc4c3)cc2)cc1 ; N#Cc1ccccc1-c1ccc2ccccc2c1-c1cccc(-c2nc(-c3ccccc3)nc(-c3ccccc3)n2)c1 ; c1ccc(-c2nc(-c3ccccc3)nc(-c3cccc(-c4c(-c5ccc(-c6ccncc6)cc5)ccc5ccccc45)c3)n2)cc1 ; N#Cc1ccc2c(-c3c(-c4cccc(-c5nc(-c6ccccc6)nc(-c6ccccc6)n5)c4)ccc4ccccc34)cccc2c1]

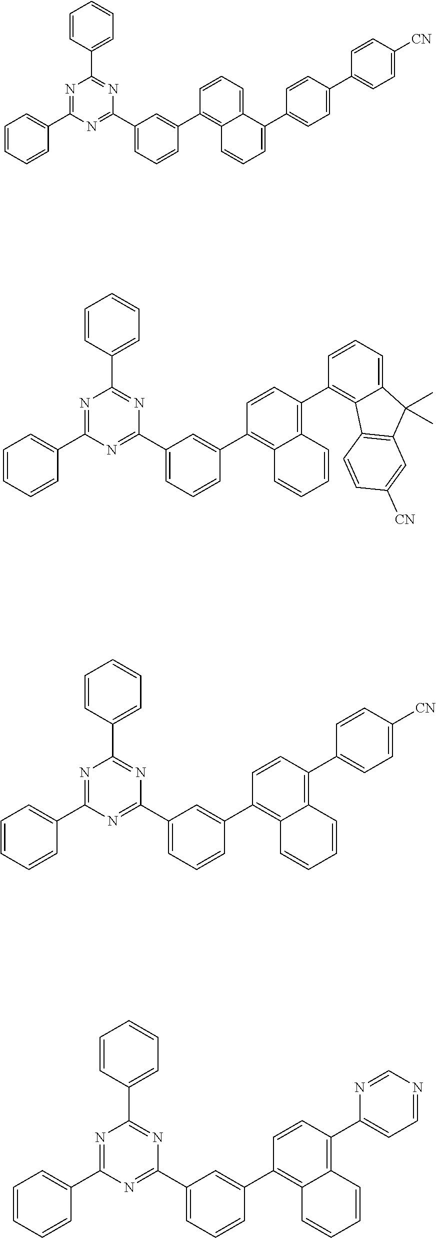 [SMILES: N#Cc1ccc(-c2ccc(-c3cccc4c(-c5cccc(-c6nc(-c7ccccc7)nc(-c7ccccc7)n6)c5)cccc34)cc2)cc1 ; CC1(C)c2cc(C#N)ccc2-c2c(-c3ccc(-c4cccc(-c5nc(-c6ccccc6)nc(-c6ccccc6)n5)c4)c4ccccc34)cccc21 ; N#Cc1ccc(-c2ccc(-c3cccc(-c4nc(-c5ccccc5)nc(-c5ccccc5)n4)c3)c3ccccc23)cc1 ; c1ccc(-c2nc(-c3ccccc3)nc(-c3cccc(-c4ccc(-c5ccncn5)c5ccccc45)c3)n2)cc1]

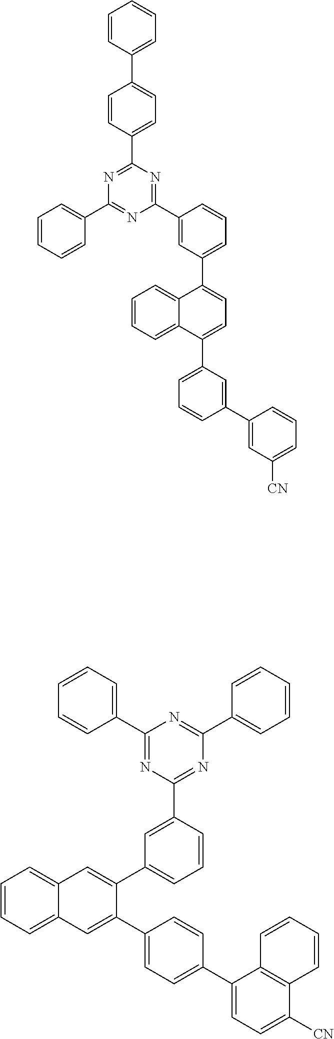 [SMILES: N#Cc1cccc(-c2cccc(-c3ccc(-c4cccc(-c5nc(-c6ccccc6)nc(-c6ccc(-c7ccccc7)cc6)n5)c4)c4ccccc34)c2)c1 ; N#Cc1ccc(-c2ccc(-c3cc4ccccc4cc3-c3cccc(-c4nc(-c5ccccc5)nc(-c5ccccc5)n4)c3)cc2)c2ccccc12]

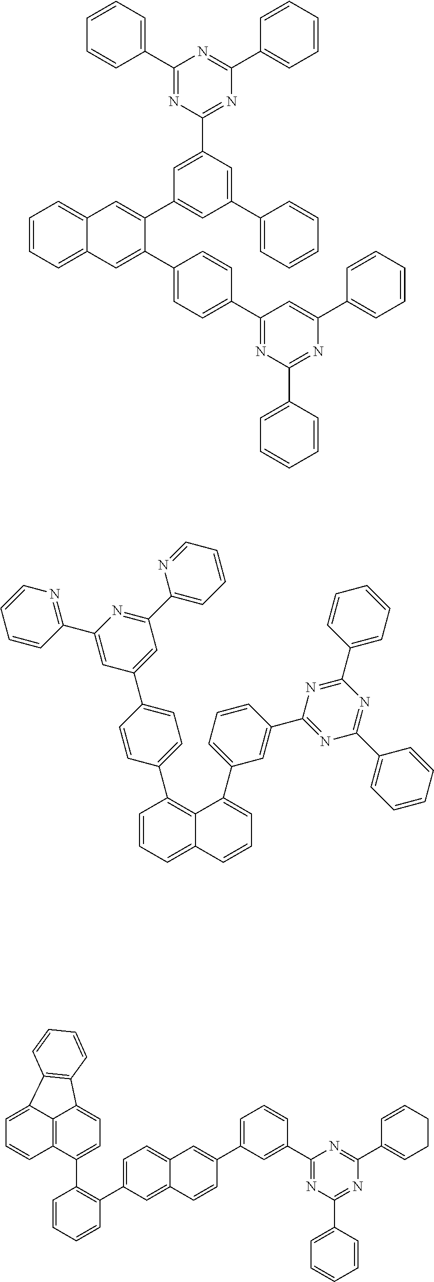 [SMILES: c1ccc(-c2cc(-c3nc(-c4ccccc4)nc(-c4ccccc4)n3)cc(-c3cc4ccccc4cc3-c3ccc(-c4cc(-c5ccccc5)nc(-c5ccccc5)n4)cc3)c2)cc1 ; c1ccc(-c2nc(-c3ccccc3)nc(-c3cccc(-c4cccc5cccc(-c6ccc(-c7cc(-c8ccccn8)nc(-c8ccccn8)c7)cc6)c45)c3)n2)cc1 ; C1=CC(c2nc(-c3ccccc3)nc(-c3cccc(-c4ccc5cc(-c6ccccc6-c6ccc7c8c(cccc68)-c6ccccc6-7)ccc5c4)c3)n2)=CCC1]

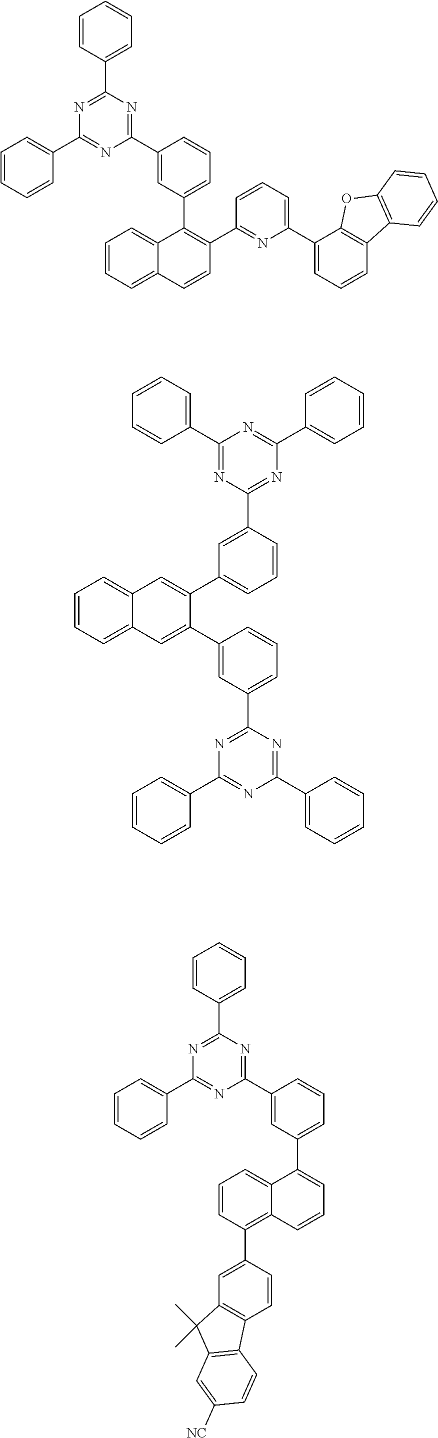 [SMILES: c1ccc(-c2nc(-c3ccccc3)nc(-c3cccc(-c4c(-c5cccc(-c6cccc7c6oc6ccccc67)n5)ccc5ccccc45)c3)n2)cc1 ; c1ccc(-c2nc(-c3ccccc3)nc(-c3cccc(-c4cc5ccccc5cc4-c4cccc(-c5nc(-c6ccccc6)nc(-c6ccccc6)n5)c4)c3)n2)cc1 ; CC1(C)c2cc(C#N)ccc2-c2ccc(-c3cccc4c(-c5cccc(-c6nc(-c7ccccc7)nc(-c7ccccc7)n6)c5)cccc34)cc21]

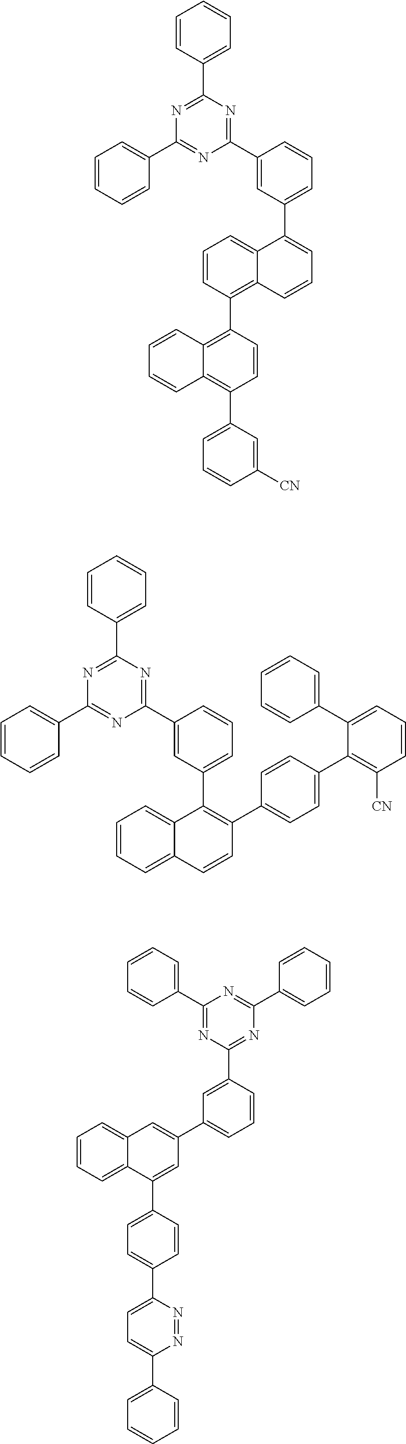 [SMILES: N#Cc1cccc(-c2ccc(-c3cccc4c(-c5cccc(-c6nc(-c7ccccc7)nc(-c7ccccc7)n6)c5)cccc34)c3ccccc23)c1 ; N#Cc1cccc(-c2ccccc2)c1-c1ccc(-c2ccc3ccccc3c2-c2cccc(-c3nc(-c4ccccc4)nc(-c4ccccc4)n3)c2)cc1 ; c1ccc(-c2ccc(-c3ccc(-c4cc(-c5cccc(-c6nc(-c7ccccc7)nc(-c7ccccc7)n6)c5)cc5ccccc45)cc3)nn2)cc1]

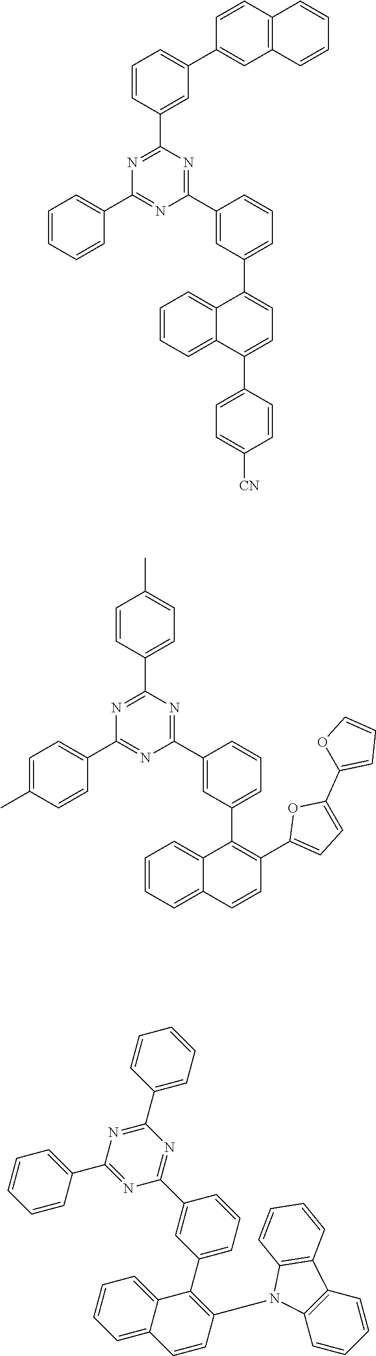 [SMILES: N#Cc1ccc(-c2ccc(-c3cccc(-c4nc(-c5ccccc5)nc(-c5cccc(-c6ccc7ccccc7c6)c5)n4)c3)c3ccccc23)cc1 ; Cc1ccc(-c2nc(-c3ccc(C)cc3)nc(-c3cccc(-c4c(-c5ccc(-c6ccco6)o5)ccc5ccccc45)c3)n2)cc1 ; c1ccc(-c2nc(-c3ccccc3)nc(-c3cccc(-c4c(-n5c6ccccc6c6ccccc65)ccc5ccccc45)c3)n2)cc1]

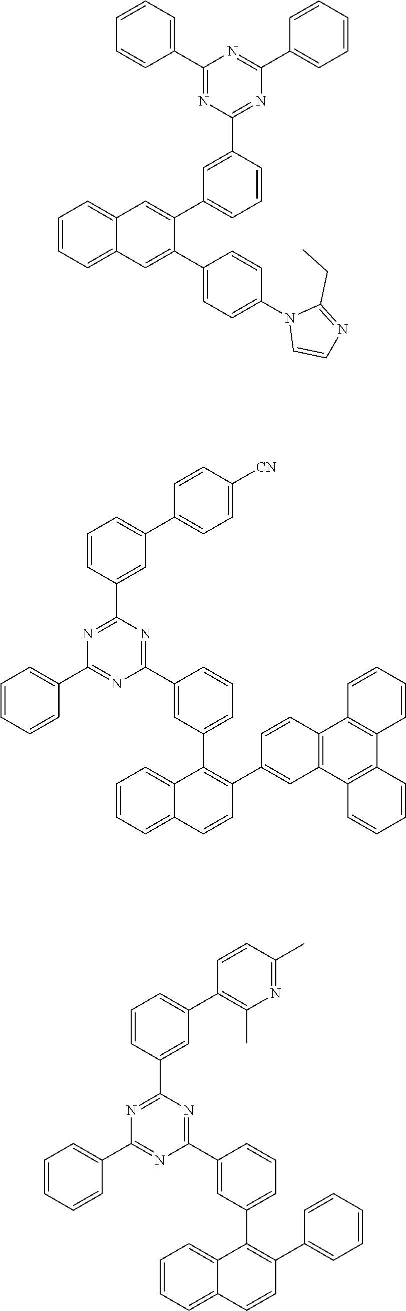 [SMILES: CCc1nccn1-c1ccc(-c2cc3ccccc3cc2-c2cccc(-c3nc(-c4ccccc4)nc(-c4ccccc4)n3)c2)cc1 ; N#Cc1ccc(-c2cccc(-c3nc(-c4ccccc4)nc(-c4cccc(-c5c(-c6ccc7c8ccccc8c8ccccc8c7c6)ccc6ccccc56)c4)n3)c2)cc1 ; Cc1ccc(-c2cccc(-c3nc(-c4ccccc4)nc(-c4cccc(-c5c(-c6ccccc6)ccc6ccccc56)c4)n3)c2)c(C)n1]

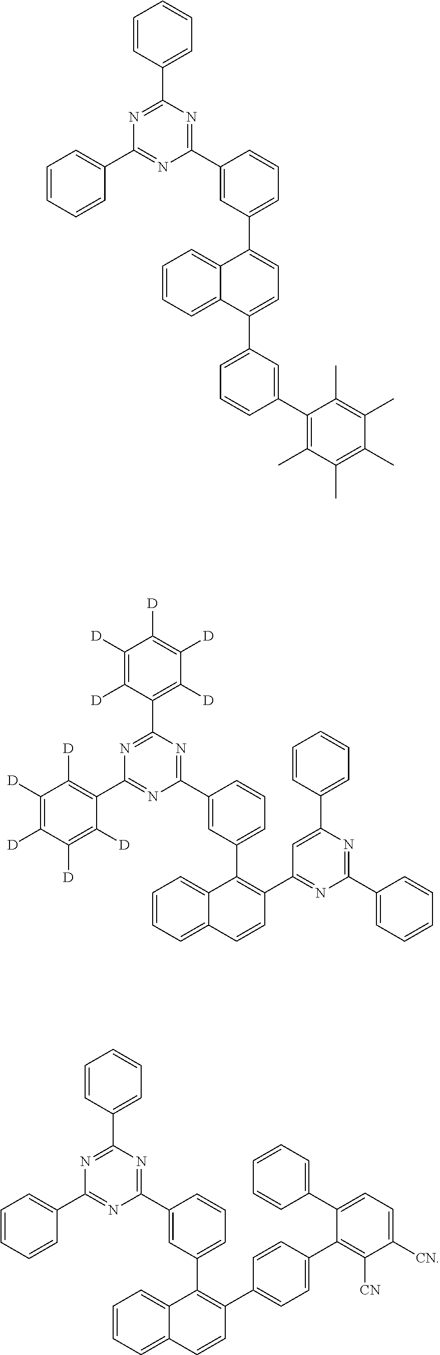 [SMILES: Cc1c(C)c(C)c(-c2cccc(-c3ccc(-c4cccc(-c5nc(-c6ccccc6)nc(-c6ccccc6)n5)c4)c4ccccc34)c2)c(C)c1C ; [2H]c1c([2H])c([2H])c(-c2nc(-c3cccc(-c4c(-c5cc(-c6ccccc6)nc(-c6ccccc6)n5)ccc5ccccc45)c3)nc(-c3c([2H])c([2H])c([2H])c([2H])c3[2H])n2)c([2H])c1[2H] ; N#Cc1ccc(-c2ccccc2)c(-c2ccc(-c3ccc4ccccc4c3-c3cccc(-c4nc(-c5ccccc5)nc(-c5ccccc5)n4)c3)cc2)c1C#N]

16. The organic light emitting device according to claim 1, wherein
the electron blocking layer comes into contact with the light emitting layer.
